(19) United States
(12) Patent Application Publication
(10) Pub. No.: US 2026/0324187 A1
(43) Pub. Date: Oct. 15, 2026

(54) ORGANIC ELECTRLUMINESCENT MATERIAL AND DEVICE THEREOF

(71) Applicant: BEIJING SUMMER SPROUT TECHNOLOGY CO., LTD., Beijing (CN)

(72) Inventors: Zhen Wang, Beijing (CN); Hongbo Li, Beijing (CN); Zheng Wang, Beijing (CN); Chunliang Zhao, Beijing (CN); Ruiwen Liu, Beijing (CN); Dinghao Luo, Beijing (CN); Wei Cai, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 19/634,249

(22) Filed: Mar. 31, 2026

(30) Foreign Application Priority Data
Mar. 31, 2025 (CN) 202510395498.4
Mar. 17, 2026 (CN) 202610327056.0

(51) Int. Cl. H10K 50/12; C07B 59/00; C07F 5/02; H10K 85/30; H10K 85/60; H10K 101/00

(52) U.S. Cl. CPC H10K 50/121; C07B 59/002; C07F 5/027; H10K 85/342; H10K 85/346; H10K 85/371; H10K 85/622; H10K 85/626; H10K 85/654; H10K 85/6572; H10K 85/6574; H10K 85/6576; H10K 85/658; C07B 2200/05; H10K 2101/90

(57) ABSTRACT

Provided are an organic electroluminescent material and a device thereof. The organic electroluminescent material is a compound having a structure of Formula 1. In particular, Formula 1 comprises a particular substituent. These new compounds can be used as light-emitting materials in organic electroluminescent devices, achieve the desired green or yellow light emission and have excellent performance, thus possessing potential application prospects to become excellent light-emitting materials. Further provided are an organic electroluminescent device comprising the compound and a composition comprising the compound.

### CROSS-REFERENCE TO RELATED APPLICATION(S)

This application claims priorities to Chinese Patent Application No. 202510395498.4 filed on Mar. 31, 2025 and Chinese Patent Application No. 202610327056.0 filed on Mar. 17, 2026, the disclosure of which are incorporated herein by reference in their entireties.

### TECHNICAL FIELD

The present disclosure relates to compounds for organic electronic devices such as organic light-emitting devices. Particularly, the present disclosure relates to a compound having a structure of Formula 1, an organic electroluminescent device comprising the compound and a compound composition comprising the compound.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This invention has laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlets and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have a small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting colors, higher efficiency, and longer device lifetime.

Multi-resonance thermally activated delayed fluorescence (MR-TADF) materials containing boron-nitrogen fused-ring skeletons have important application value in the field of OLED luminescence due to narrow full widths at half maximum, high quantum yields and excellent luminescence performance. For example, WO2020080528A1 has disclosed a type of compound having a structure of

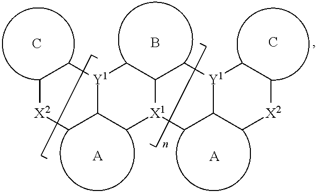

wherein hydrogens on the rings can be optionally substituted with deuterium, cyano or halogen. This application has further specifically disclosed compounds such as

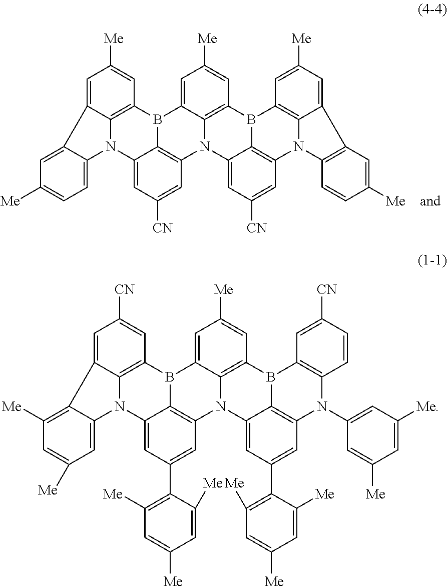

However, this application has neither disclosed nor taught the unique advantages endowed with a compound when a particular substituent is introduced into a particular ring.

At present, MR-TADF materials with boron-nitrogen fused rings and similar structures generally have narrow peak widths and relatively blue luminescence. Such characteristic limits the application of this type of materials in wide color gamut display, especially in the application of green or yellow light-emitting materials. Green or yellow light-emitting materials are an important type of light-emitting materials. Therefore, green or yellow light materials with excellent performance still need to be deeply studied and developed.

### SUMMARY

The present disclosure aims to provide a series of compounds each having a structure of Formula 1 to solve at least part of the preceding problems. The compounds can achieve the desired green or yellow light emission. These new compounds have excellent performance and possess potential application prospects to become excellent light-emitting materials.

According to an embodiment of the present disclosure, a compound is disclosed; the compound has a structure represented by Formula 1:

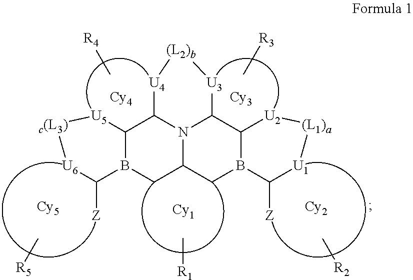

wherein,
Z is, at each occurrence identically or differently, selected from CR or N;
the ring Cy1, the ring Cy2, the ring Cy3, the ring Cy4, and the ring Cy5 are each independently selected from an unsaturated carbocyclic ring having 5 to 30 carbon atoms or an unsaturated heterocyclic ring having 3 to 30 carbon atoms;
L₂ is, at each occurrence identically or differently, selected from a single bond, O, S, Se, PR′, P═OR′, P═SR′, AsR′, As═OR′, As═SR′, CR′R′, SiR′R′, or GeR′R′;
L₁ and L₃ are, at each occurrence identically or differently, selected from a single bond, O, S, Se, BR′, NR′, PR′, P═OR′, P═SR′, AsR′, As═OR′, As═SR′, CR′R′, SiR′R′, or GeR′R′; when a plurality of R′ are present at the same time, the plurality of R′ are identical or different;
a, b, and c are each independently selected from 0, 1, or 2; a+c is greater than or equal to 1;
when a+c is equal to 1, L₁ and L₃ are, at each occurrence identically or differently, selected from a single bond, O, S, Se, BR′, PR′, P═OR′, P═SR′, AsR′, As═OR′, As═SR′, CR′R′, SiR′R′, or GeR′R′;
U₁, U₂, U₃, U₄, U₅, and U₆ are, at each occurrence identically or differently, selected from O, S, Se, N, or C;
when a is selected from 1 or 2, U₁ and U₂ are C;
when b is selected from 1 or 2, U₃ and U₄ are C;
when c is selected from 1 or 2, U₅ and U₆ are C;
R₁, R₂, R₃, R₄, and R₅ represent, at each occurrence identically or differently, mono-substitution, multiple substitutions, or non-substitution;
at least one R₁ is selected from -L-(CN)ₙ or -L-(F)ₙ, wherein n is greater than or equal to 1, and L is selected from a single bond, substituted or unsubstituted alkylene having 1 to 20 carbon atoms, substituted or unsubstituted cycloalkylene having 3 to 20 ring carbon atoms, substituted or unsubstituted heteroalkylene having 1 to 20 carbon atoms, substituted or unsubstituted heterocyclylene having 3 to 20 ring atoms, or a combination thereof;
R, R′, R₁, R₂, R₃, R₄, and R₅ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁ can be optionally joined to form a ring; and
adjacent substituents R, R′, R″, R₂, R₃, R₄, and R₅ can be optionally joined to form a ring.

According to another embodiment of the present disclosure, further disclosed is an organic electroluminescent device comprising an anode, a cathode and an organic layer disposed between the anode and the cathode, wherein the organic layer comprises a compound having a structure of Formula 1, and the specific structure of the compound is as shown in the preceding embodiment.

According to another embodiment of the present disclosure, further disclosed is a compound composition comprising a compound having a structure of Formula 1, and the specific structure of the compound is as shown in the preceding embodiment.

The present disclosure discloses a compound having a structure of Formula 1, the compound can achieve the desired green or yellow light emission, and these compounds have excellent performance and possess potential application prospects to become excellent light-emitting materials.

### BRIEF DESCRIPTION OF DRAWINGS

FIG. 1 is a schematic diagram of an organic light-emitting device that may comprise a compound and a compound composition disclosed herein.

FIG. 2 is a schematic diagram of another organic light-emitting device that may comprise a compound and a compound composition disclosed herein.

### DETAILED DESCRIPTION

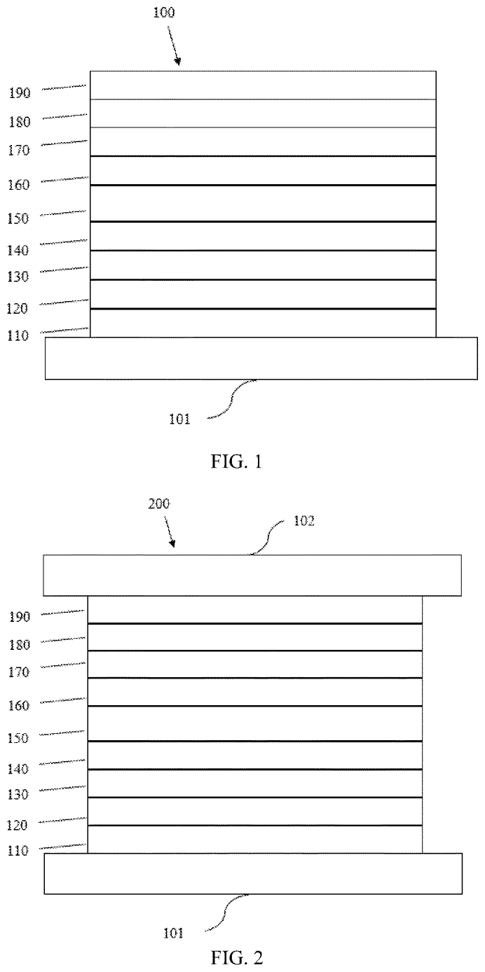

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or some layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows an organic light emitting device 200 without limitation. FIG. 2 differs from FIG. 1 in that the organic light emitting device includes a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, an n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl, and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes noncondensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with at least one aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g., phenyl, phenylene, naphthyl, dibenzofuryl) or as if it were the whole molecule (e.g., benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to their enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions, etc.), which means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined; for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

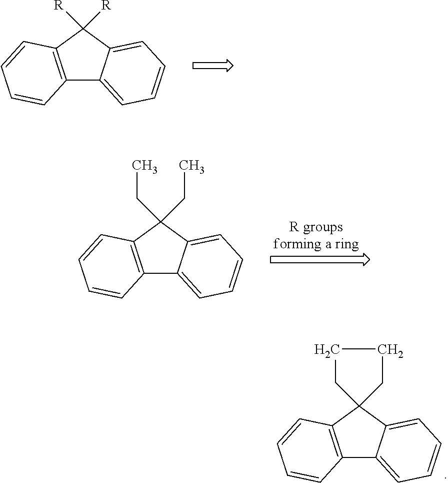

The expression that adjacent substituents can be optionally joined to form a ring is also intended to mean that two substituents bonded to carbon atoms which are directly bonded to each other are joined to each other via a chemical bond to form a ring, which can be exemplified by the following formula:

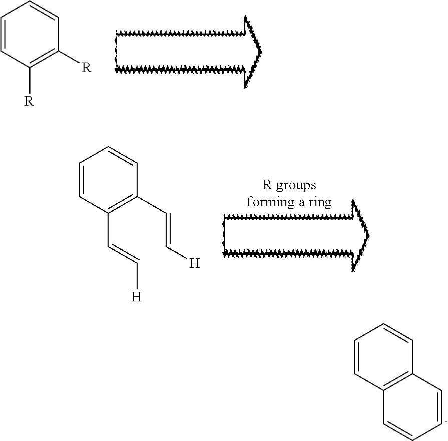

The expression that adjacent substituents can be optionally joined to form a ring is also intended to mean that two substituents bonded to further distant carbon atoms are joined to each other via a chemical bond to form a ring, which can be exemplified by the following formula:

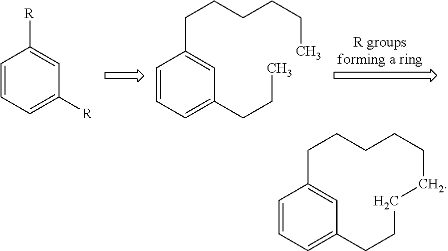

Furthermore, the expression that adjacent substituents can be optionally joined to form a ring is also intended to mean that, in the case where one of the two substituents bonded to carbon atoms represents hydrogen, the second substituent is bonded at a position at which the hydrogen atom is bonded, thereby forming a ring. This is exemplified by the following formula:

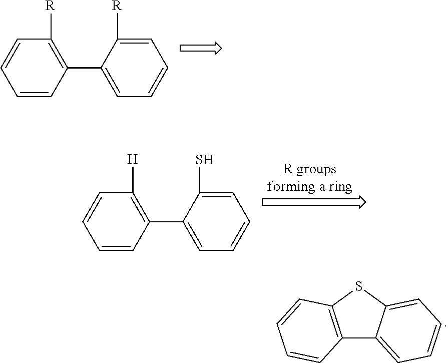

According to an embodiment of the present disclosure, a compound is disclosed; the compound has a structure represented by Formula 1:

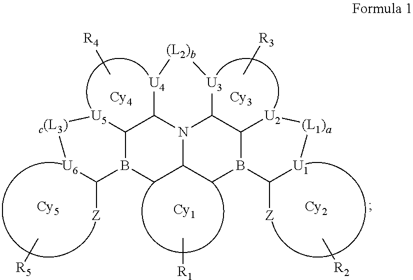

wherein,
Z is, at each occurrence identically or differently, selected from CR or N;
the ring Cy1, the ring Cy2, the ring Cy3, the ring Cy4, and the ring Cy5 are each independently selected from an unsaturated carbocyclic ring having 5 to 30 carbon atoms or an unsaturated heterocyclic ring having 3 to 30 carbon atoms;
L₂ is, at each occurrence identically or differently, selected from a single bond, O, S, Se, PR′, P═OR′, P═SR′, AsR′, As═OR′, As═SR′, CR′R′, SiR′R′, or GeR′R′;
L₁ and L₃ are, at each occurrence identically or differently, selected from a single bond, O, S, Se, BR′, NR′, PR′, P═OR′, P═SR′, AsR′, As═OR′, As═SR′, CR′R′, SiR′R′, or GeR′R′; when a plurality of R′ are present at the same time, the plurality of R′ are identical or different;
a, b, and c are each independently selected from 0, 1, or 2; a+c is greater than or equal to 1;
when a+c is equal to 1, L₁ and L₃ are, at each occurrence identically or differently, selected from a single bond, O, S, Se, BR′, PR′, P═OR′, P═SR′, AsR′, As═OR′, As═SR′, CR′R′, SiR′R′, or GeR′R′;
U₁, U₂, U₃, U₄, U₅, and U₆ are, at each occurrence identically or differently, selected from O, S, Se, N, or C;
when a is selected from 1 or 2, U₁ and U₂ are C;
when b is selected from 1 or 2, U₃ and U₄ are C;
when c is selected from 1 or 2, U₅ and U₆ are C;
R₁, R₂, R₃, R₄, and R₅ represent, at each occurrence identically or differently, mono-substitution, multiple substitutions, or non-substitution;
at least one R₁ is selected from -L-(CN)ₙ or -L-(F)ₙ, wherein n is greater than or equal to 1, and L is selected from a single bond, substituted or unsubstituted alkylene having 1 to 20 carbon atoms, substituted or unsubstituted cycloalkylene having 3 to 20 ring carbon atoms, substituted or unsubstituted heteroalkylene having 1 to 20 carbon atoms, substituted or unsubstituted heterocyclylene having 3 to 20 ring atoms, or a combination thereof;
R, R′, R₁, R₂, R₃, R₄, and R₅ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁ can be optionally joined to form a ring; and
adjacent substituents R, R′, R″, R₂, R₃, R₄, and R₅ can be optionally joined to form a ring.

Herein, when a is selected from 0, U₁ is directly joined to R₂ to form the ring Cy2, and U₂ is directly joined to R₃ to form the ring Cy3; when a is selected from 1 or 2, U₁ and U₂ are C, and C is directly joined to R₂ or R₃ to form the ring Cy2 or the ring Cy3, respectively; similarly, when b or c is selected from 0, 1, or 2, the case is similar to the above.

Herein, the expression that “adjacent substituents R, R′, R₂, R₃, R₄, and R₅ can be optionally joined to form a ring” is intended to mean that any one or more of groups of adjacent substituents on the same ring or the same atom and any one or more of groups of adjacent substituents on the rings joined through linkages, such as two substituents R′, two substituents R₁, two substituents R₂, two substituents R₃, two substituents R₄, two substituents R₅, adjacent substituents R₂ and R₃, adjacent substituents R₃ and R₄, adjacent substituents R₄ and R₅, adjacent substituents R and R₂, and adjacent substituents R and R₅, can be joined to form a ring. Obviously, it is also possible that none of these substituents are joined to form a ring.

According to an embodiment of the present disclosure, L₁ and L₃ are, at each occurrence identically or differently, selected from O, S, Se, BR′, NR′, PR′, P═OR′, P═SR′, AsR′, As═OR′, or As═SR′.

According to an embodiment of the present disclosure, L₁ and L₃ are, at each occurrence identically or differently, selected from O, S, Se, BR′, or NR′.

According to an embodiment of the present disclosure, in Formula 1, a, b, and c are each independently selected from 0 or 1, and a+c is greater than or equal to 1.

According to an embodiment of the present disclosure, in Formula 1, a and c are selected from 1, and b is selected from 0 or 1.

According to an embodiment of the present disclosure, the compound has a structure represented by Formula 2:

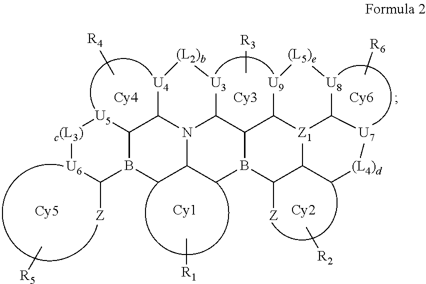

wherein,
Z is, at each occurrence identically or differently, selected from CR or N;
the ring Cy1, the ring Cy2, the ring Cy3, the ring Cy4, the ring Cy5, and the ring Cy6 are each independently selected from an unsaturated carbocyclic ring having 5 to 30 carbon atoms or an unsaturated heterocyclic ring having 3 to 30 carbon atoms;
Z₁ is, at each occurrence identically or differently, selected from B, N, P, P═O, P═S, As, As═O, As═S, SiR₀, or GeR₀;
L₂ is, at each occurrence identically or differently, selected from a single bond, O, S, Se, PR′, P═OR′, P═SR′, AsR′, As═OR′, As═SR′, CR′R′, SiR′R′, or GeR′R′;
L₃, L₄, and L₅ are, at each occurrence identically or differently, selected from a single bond, O, S, Se, BR′, NR′, PR′, P═OR′, P═SR′, AsR′, As═OR′, As═SR′, CR′R′, SiR′R′, or GeR′R′; when a plurality of R′ are present at the same time, the plurality of R′ are identical or different;
b, c, d, and e are each independently selected from 0, 1, or 2; when Z₁ is N, c is selected from 1 or 2;
U₃, U₄, U₅, U₆, U₇, U₈, and U₉ are, at each occurrence identically or differently, selected from O, S, Se, N, or C;
when b is selected from 1 or 2, U₃ and U₄ are C;
when c is selected from 1 or 2, U₅ and U₆ are C;
when d is selected from 1 or 2, U₇ is C;
when e is selected from 1 or 2, U₈ and U₉ are C;
R₁, R₂, R₃, R₄, R₅, and R₆ represent, at each occurrence identically or differently, mono-substitution, multiple substitutions, or non-substitution;
at least one R₁ is selected from -L-(CN)ₙ or -L-(F)ₙ, wherein n is greater than or equal to 1, and L is selected from a single bond, substituted or unsubstituted alkylene having 1 to 20 carbon atoms, substituted or unsubstituted cycloalkylene having 3 to 20 ring carbon atoms, substituted or unsubstituted heteroalkylene having 1 to 20 carbon atoms, substituted or unsubstituted heterocyclylene having 3 to 20 ring atoms, or a combination thereof;
R, R₀, R′, R₁, R₂, R₃, R₄, R₅, and R₆ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁ can be optionally joined to form a ring; and
adjacent substituents R, R′, R″, R₁, R₂, R₃, R₄, R₅, and R₆ can be optionally joined to form a ring.

Herein, when b is selected from 0, U₃ is directly joined to R₃ to form the ring Cy3, and U₄ is directly joined to R₄ to form the ring Cy4; when b is selected from 1 or 2, U₃ and U₄ are C, and C is directly joined to R₃ or R₄ to form the ring Cy3 or the ring Cy4, respectively; similarly, when c, d, or e is selected from 0, 1, or 2, the case is similar to the above.

In this embodiment, the ring Cy6 fragment joined to Z₁ is equivalent to L₁ where a in Formula 1 is equal to 1; when d is equal to 1, the substituents R′ and R₂ in Formula 1 are joined to each other to form a ring; when e is equal to 1, the substituents R′ and R₃ in Formula 1 are joined to each other to form a ring.

Herein, the expression that “adjacent substituents R, R′, R″, R₂, R₃, R₄, R₅, and R₆ can be optionally joined to form a ring” is intended to mean that any one or more of groups of adjacent substituents on the same ring or the same atom and any one or more of groups of substituents on the rings joined through linkages, such as two substituents R′, two substituents R″, two substituents R₂, two substituents R₃, two substituents R₄, two substituents R₅, adjacent substituents R₂ and R₆, adjacent substituents R₃ and R₆, adjacent substituents R₃ and R₄, adjacent substituents R₄ and R₅, adjacent substituents R and R₂, and adjacent substituents R and R₅, can be joined to form a ring. Obviously, it is also possible that none of these substituents are joined to form a ring.

According to an embodiment of the present disclosure, the compound has a structure represented by Formula 2-1:

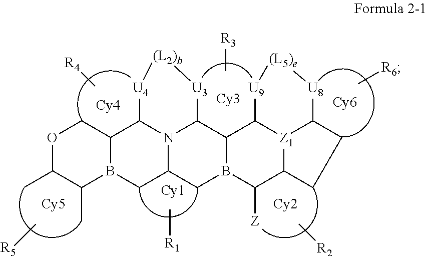

wherein,
Z is, at each occurrence identically or differently, selected from CR or N;
the ring Cy1, the ring Cy2, the ring Cy3, the ring Cy4, the ring Cy5, and the ring Cy6 are each independently selected from an unsaturated carbocyclic ring having 5 to 30 carbon atoms or an unsaturated heterocyclic ring having 3 to 30 carbon atoms;
Z₁ is, at each occurrence identically or differently, selected from B, N, P, P═O, P═S, As, As═O, As═S, SiR₀, or GeR₀;
L₂ is, at each occurrence identically or differently, selected from a single bond, O, S, Se, PR′, P═OR′, P═SR′, AsR′, As═OR′, As═SR′, CR′R′, SiR′R′, or GeR′R′;
L₅ is, at each occurrence identically or differently, selected from a single bond, O, S, Se, BR′, NR′, PR′, P═OR′, P═SR′, AsR′, As═OR′, As═SR′, CR′R′, SiR′R′, or GeR′R′; when a plurality of R′ are present at the same time, the plurality of R′ are identical or different;
b and e are each independently selected from 0, 1, or 2;
U₃, U₄, U₈, and U₉ are, at each occurrence identically or differently, selected from O, S, Se, N, or C;
when b is selected from 1 or 2, U₃ and U₄ are C;
when e is selected from 1 or 2, U₈ and U₉ are C;
R₁, R₂, R₃, R₄, R₅, and R₆ represent, at each occurrence identically or differently, mono-substitution, multiple substitutions, or non-substitution;
at least one R₁ is selected from -L-(CN)ₙ or -L-(F)ₙ, wherein n is greater than or equal to 1, and L is selected from a single bond, substituted or unsubstituted alkylene having 1 to 20 carbon atoms, substituted or unsubstituted cycloalkylene having 3 to 20 ring carbon atoms, substituted or unsubstituted heteroalkylene having 1 to 20 carbon atoms, substituted or unsubstituted heterocyclylene having 3 to 20 ring atoms, or a combination thereof;
R, R₀, R′, R₁, R₂, R₃, R₄, R₅, and R₆ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁ can be optionally joined to form a ring; and
adjacent substituents R, R′, R″, R₁, R₂, R₃, R₄, R₅, and R₆ can be optionally joined to form a ring.

According to an embodiment of the present disclosure, L₃, L₄, and L₅ are, at each occurrence identically or differently, selected from a single bond, O, S, Se, BR′, NR′, PR′, P═OR′, P═SR′, AsR′, As═OR′, or As═SR′.

According to an embodiment of the present disclosure, L₃, L₄, and L₅ are, at each occurrence identically or differently, selected from a single bond, O, S, Se, BR′, or NR′.

According to an embodiment of the present disclosure, the compound has a structure represented by Formula 3:

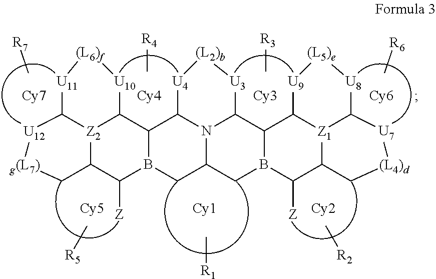

wherein,
Z is, at each occurrence identically or differently, selected from CR or N;
the ring Cy1, the ring Cy2, the ring Cy3, the ring Cy4, the ring Cy5, the ring Cy6, and the ring Cy7 are each independently selected from an unsaturated carbocyclic ring having 5 to 30 carbon atoms or an unsaturated heterocyclic ring having 3 to 30 carbon atoms;
Z₁ and Z₂ are, at each occurrence identically or differently, selected from B, N, P, P═O, P═S, As, As═O, As═S, SiR₀, or GeR₀;
L₂ is, at each occurrence identically or differently, selected from a single bond, O, S, Se, PR′, P═OR′, P═SR′, AsR′, As═OR′, As═SR′, CR′R′, SiR′R′, or GeR′R′;
L₄, L₅, L₆, and L₇ are, at each occurrence identically or differently, selected from a single bond, O, S, Se, BR′, NR′, PR′, P═OR′, P═SR′, AsR′, As═OR′, As═SR′, CR′R′, SiR′R′, or GeR′R′; when a plurality of R′ are present at the same time, the plurality of R′ are identical or different;
b, d, e, f, and g are each independently selected from 0, 1, or 2;
U₃, U₄, U₇, U₈, U₉, U₁₀, and U₁₁ are, at each occurrence identically or differently, selected from O, S, Se, N, or C;
when b is selected from 1 or 2, U₃ and U₄ are C;
when d is selected from 1 or 2, U₇ is C;
when e is selected from 1 or 2, U₈ and U₉ are C;
when f is selected from 1 or 2, U₁₀ and U₁₁ are C; R₁, R₂, R₃, R₄, R₅, R₆, and R₇ represent, at each occurrence identically or differently, mono-substitution, multiple substitutions, or non-substitution;
at least one R₁ is selected from -L-(CN)ₙ or -L-(F)ₙ, wherein n is greater than or equal to 1, and L is selected from a single bond, substituted or unsubstituted alkylene having 1 to 20 carbon atoms, substituted or unsubstituted cycloalkylene having 3 to 20 ring carbon atoms, substituted or unsubstituted heteroalkylene having 1 to 20 carbon atoms, substituted or unsubstituted heterocyclylene having 3 to 20 ring atoms, or a combination thereof;
R, R₀, R′, R₁, R₂, R₃, R₄, R₅, R₆, and R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁ can be optionally joined to form a ring; and
adjacent substituents R, R′, R″, R₂, R₃, R₄, R₅, R₆, and R₇ can be optionally joined to form a ring.

Herein, when b is selected from 0, U₃ is directly joined to R₃ to form the ring Cy3, and U₄ is directly joined to R₄ to form the ring Cy4; when b is selected from 1 or 2, U₃ and U₄ are C, and C is directly joined to R₃ or R₄ to form the ring Cy3 or the ring Cy4, respectively; similarly, when d, e, f, or g is selected from 0, 1, or 2, the case is similar to the above.

In this embodiment, the ring Cy7 fragment joined to Z₂ is equivalent to L₃ where c in Formula 1 is equal to 1; when f is equal to 1, the substituents R′ and R₄ in Formula 1 are joined to each other to form a ring; when g is equal to 1, the substituents R′ and R₅ in Formula 1 are joined to each other to form a ring.

Herein, the expression that “adjacent substituents R, R′, R″, R₂, R₃, R₄, R₅, R₆, and R₇ can be optionally joined to form a ring” is intended to mean that any one or more of groups of adjacent substituents on the same ring or the same atom and any one or more of groups of substituents on the rings joined through linkages, such as two substituents R′, two substituents R″, two substituents R₂, two substituents R₃, two substituents R₄, two substituents R₅, two substituents R₆, two substituents R₇, adjacent substituents R₂ and R₆, adjacent substituents R₃ and R₆, adjacent substituents R₃ and R₄, adjacent substituents R₄ and R₇, adjacent substituents R₅ and R₇, adjacent substituents R and R₅, and adjacent substituents R and R₂, can be joined to form a ring. Obviously, it is also possible that none of these substituents are joined to form a ring.

According to an embodiment of the present disclosure, at least one R₁ is selected from -L-(F)ₙ, wherein n is greater than or equal to 1, and when L is selected from substituted or unsubstituted alkylene having 1 to 20 carbon atoms, substituted or unsubstituted cycloalkylene having 3 to 20 ring carbon atoms, substituted or unsubstituted heteroalkylene having 1 to 20 carbon atoms, substituted or unsubstituted heterocyclylene having 3 to 20 ring atoms, or a combination thereof; at least one of the n F is separated from the ring Cy1 by one atom.

According to an embodiment of the present disclosure, at least one R₁ is selected from -L-(F)ₙ, wherein n is greater than or equal to 1, and when L is selected from substituted or unsubstituted alkylene having 1 to 20 carbon atoms, substituted or unsubstituted cycloalkylene having 3 to 20 ring carbon atoms, substituted or unsubstituted heteroalkylene having 1 to 20 carbon atoms, substituted or unsubstituted heterocyclylene having 3 to 20 ring atoms, or a combination thereof; at least one of the n F is separated from the ring Cy1 by one C atom.

According to an embodiment of the present disclosure, wherein at least one R₁ is CN, at least one R₁ is F, or at least one R₁ is CF₃.

According to an embodiment of the present disclosure, wherein at least one R₁ is CN.

According to an embodiment of the present disclosure, wherein at least one R₁ is F.

According to an embodiment of the present disclosure, wherein at least one R₁ is CF₃.

According to an embodiment of the present disclosure, wherein the ring Cy1, the ring Cy2, the ring Cy3, the ring Cy4, the ring Cy5, the ring Cy6, and the ring Cy7 are each independently selected from a five-membered unsaturated carbocyclic ring, an aromatic ring having 6 to 18 carbon atoms, a heteroaromatic ring having 3 to 18 carbon atoms, or a combination thereof.

According to an embodiment of the present disclosure, wherein the ring Cy1, the ring Cy2, the ring Cy3, the ring Cy4, the ring Cy5, the ring Cy6, and the ring Cy7 are each independently selected from a benzene ring, a pyridine ring, a naphthalene ring, a phenanthrene ring, an anthracene ring, an indene ring, a fluorene ring, an indole ring, a carbazole ring, a benzofuran ring, a dibenzofuran ring, a benzosilole ring, a dibenzosilole ring, a benzothiophene ring, a dibenzothiophene ring, a dibenzoselenophene ring, a cyclopentadienyl ring, a furan ring, a thiophene ring, a silole ring, or a combination thereof.

According to an embodiment of the present disclosure, wherein the ring Cy1, the ring Cy2, the ring Cy3, the ring Cy4, the ring Cy5, the ring Cy6, and the ring Cy7 are benzene rings.

According to an embodiment of the present disclosure, wherein b, d, e, f, and g are each independently selected from 0 or 1.

According to an embodiment of the present disclosure, wherein b, e, and f are 0; d and g are each independently selected from 0 or 1.

According to an embodiment of the present disclosure, wherein L₂ is, at each occurrence identically or differently, selected from a single bond, O, S, Se, PR′, P═OR′, P═SR′, CR′R′, or SiR′R′.

According to an embodiment of the present disclosure, wherein L₂ is, at each occurrence identically or differently, selected from a single bond, O, S, CR′R′, or SiR′R′.

According to an embodiment of the present disclosure, wherein L₄, L₅, L₆, and L₇ are, at each occurrence identically or differently, selected from a single bond, O, S, Se, BR′, NR′, P═OR′, CR′R′, or SiR′R′; and R′ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, wherein L₄, L₅, L₆, and L₇ are, at each occurrence identically or differently, selected from a single bond, O, S, NR′, CR′R′, or SiR′R′; and R′ is, at each occurrence identically or differently, selected from the group consisting of: substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, wherein the compound has a structure represented by any one of Formula 3-1 to Formula 3-4:

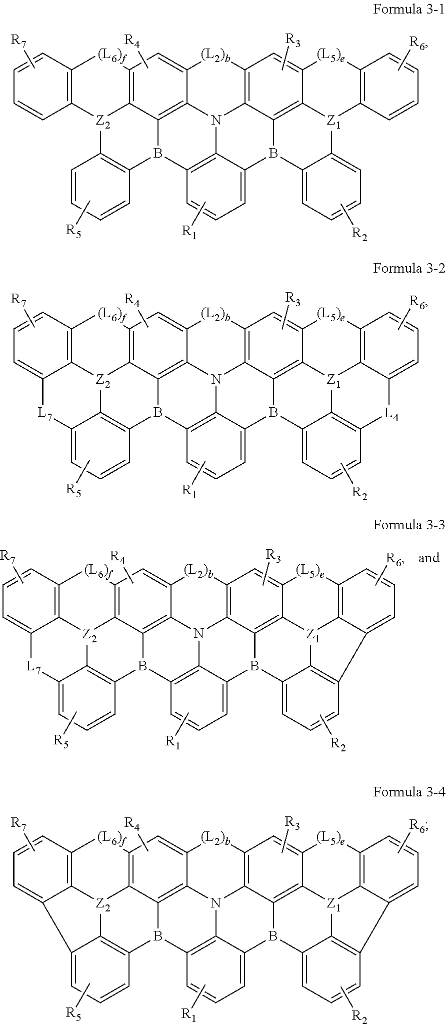

wherein,
Z₁ and Z₂ are, at each occurrence identically or differently, selected from B, N, P, P═O, P═S, As, As═O, As═S, SiR₀, or GeR₀;
L₂ is, at each occurrence identically or differently, selected from a single bond, O, S, Se, PR′, P═OR′, P═SR′, AsR′, As═OR′, As═SR′, CR′R′, SiR′R′, or GeR′R′;
L₄ and L₇ are, at each occurrence identically or differently, selected from O, S, Se, BR′, NR′, PR′, P═OR′, P═SR′, AsR′, As═OR′, As═SR′, CR′R′, SiR′R′, or GeR′R′;
L₅ and L₆ are, at each occurrence identically or differently, selected from a single bond, O, S, Se, BR′, NR′, PR′, P═OR′, P═SR′, AsR′, As═OR′, As═SR′, CR′R′, SiR′R′, or GeR′R′; when a plurality of R′ are present at the same time, the plurality of R′ are identical or different;
b, e, and f are each independently selected from 0 or 1;
R₁, R₂, R₃, R₄, R₅, R₆, and R₇ represent, at each occurrence identically or differently, mono-substitution, multiple substitutions, or non-substitution;
at least one R₁ is selected from CN, F, or CF₃;
R₀, R₁, R′, R₂, R₃, R₄, R₅, R₆, and R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁ can be optionally joined to form a ring; and
adjacent substituents R′, R″, R₂, R₃, R₄, R₅, R₆, and R₇ can be optionally joined to form a ring.

According to an embodiment of the present disclosure, wherein the compound has a structure represented by any one of Formula 3-1-1 to Formula 3-4-4:

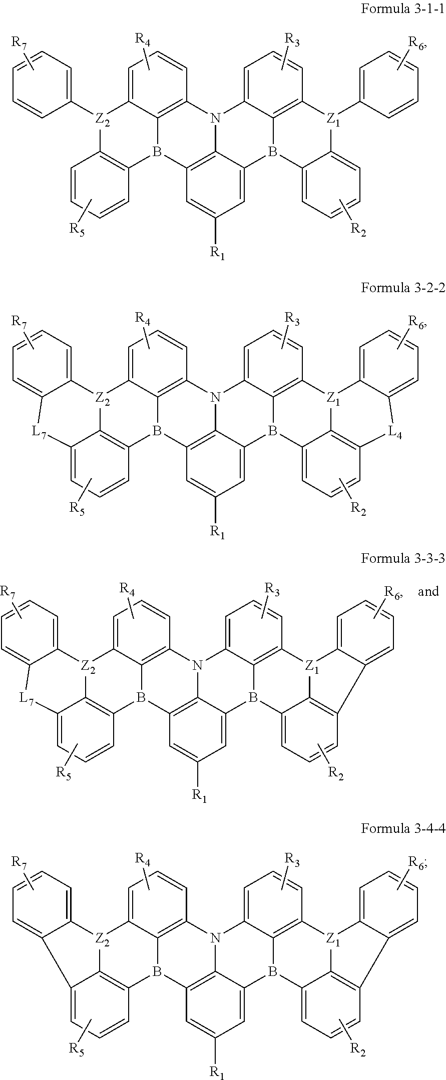

wherein,
Z₁ and Z₂ are, at each occurrence identically or differently, selected from B, N, P, P═O, P═S, As, As═O, As═S, SiR₀, or GeR₀;
L₄ and L₇ are, at each occurrence identically or differently, selected from O, S, Se, BR′, NR′, PR′, P═OR′, P═SR′, AsR′, As═OR′, As═SR′, CR′R′, SiR′R′, or GeR′R′;
R₂, R₃, R₄, R₆, and R₇ represent, at each occurrence identically or differently, mono-substitution, multiple substitutions, or non-substitution;
R₁ is selected from CN, F, or CF₃;
R₀, R′, R₂, R₃, R₄, R₅, R₆, and R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R′, R″, R₂, R₃, R₄, R₅, R₆, and R₇ can be optionally joined to form a ring.

According to an embodiment of the present disclosure, wherein Z₁ and Z₂ are, at each occurrence identically or differently, selected from B, N, P, P═O, or P═S.

According to an embodiment of the present disclosure, wherein Z₁ and Z₂ are, at each occurrence identically or differently, selected from B or N.

According to an embodiment of the present disclosure, wherein Z₁ and Z₂ are N at each occurrence.

According to an embodiment of the present disclosure, wherein R₁, R₂, R₃, R₄, R₅, R₆, and R₇ are, at each occurrence identically or differently, selected from the group consisting of: hydrogen, deuterium, fluorine, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted amino having 0 to 20 carbon atoms, a cyano group, and combinations thereof.

According to an embodiment of the present disclosure, R₁, R₂, R₃, R₄, R₅, R₆, and R₇ are, at each occurrence identically or differently, selected from the group consisting of: hydrogen, deuterium, fluorine, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted amino having 0 to 20 carbon atoms, a cyano group, and combinations thereof.

According to an embodiment of the present disclosure, R₁, R₂, R₃, R₄, R₅, R₆, and R₇ are, at each occurrence identically or differently, selected from the group consisting of: hydrogen, deuterium, fluorine, substituted or unsubstituted alkyl having 1 to 12 carbon atoms, substituted or unsubstituted aryl having 6 to 12 carbon atoms, substituted or unsubstituted carbazolyl having 3 to 20 carbon atoms, substituted or unsubstituted amino having 0 to 20 carbon atoms, a cyano group, and combinations thereof.

According to an embodiment of the present disclosure, wherein a maximum emission wavelength in a photoluminescence (PL) spectrum of the compound ranges from 490 nm to 680 nm.

According to an embodiment of the present disclosure, wherein a maximum emission wavelength in a photoluminescence (PL) spectrum of the compound ranges from 510 nm to 650 nm.

According to an embodiment of the present disclosure, wherein a maximum emission wavelength in a photoluminescence (PL) spectrum of the compound ranges from 540 nm to 580 nm.

According to an embodiment of the present disclosure, wherein the compound accounts for 0.1% to 30% of a total weight of an emissive layer.

According to an embodiment of the present disclosure, wherein the compound accounts for 0.5% to 15% of a total weight of an emissive layer.

According to an embodiment of the present disclosure, wherein the compound accounts for 0.5% to 10% of a total weight of an emissive layer.

According to an embodiment of the present disclosure, the compound is selected from the group consisting of Compound 1-1 to Compound 1-898, Compound 2-1 to Compound 2-330, Compound 3-1 to Compound 3-162, Compound 4-1 to Compound 4-587, Compound 5-1 to Compound 5-270, and Compound 6-1 to Compound 6-77, wherein the specific structures of Compound 1-1 to Compound 1-898, Compound 2-1 to Compound 2-330, Compound 3-1 to Compound 3-162, Compound 4-1 to Compound 4-587, Compound 5-1 to Compound 5-270, Compound 6-1 to Compound 6-77, and Compound 7-1 to Compound 7-45 are referred to claim 12.

According to an embodiment of the present disclosure, hydrogens in the structures of Compound 1-1 to Compound 1-898, Compound 2-1 to Compound 2-330, Compound 3-1 to Compound 3-162, Compound 4-1 to Compound 4-587, Compound 5-1 to Compound 5-270, Compound 6-1 to Compound 6-77, and Compound 7-1 to Compound 7-45 can be partially or fully substituted with deuterium.

According to an embodiment of the present disclosure, disclosed is an organic electroluminescent device comprising an anode, a cathode and an organic layer disposed between the anode and the cathode, wherein the organic layer comprises a compound having a structure of Formula 1, and the specific structure of the compound is as shown in any one of the preceding embodiments.

According to an embodiment of the present disclosure, wherein the organic layer is an emissive layer and the compound is a light-emitting material.

According to an embodiment of the present disclosure, wherein the organic electroluminescent device emits green or yellow light.

According to an embodiment of the present disclosure, wherein the emissive layer comprises at least a first host compound or comprises at least a first host compound and a second host compound.

According to an embodiment of the present disclosure, wherein the first host compound has a structure represented by Formula X-1 or Formula X-2:

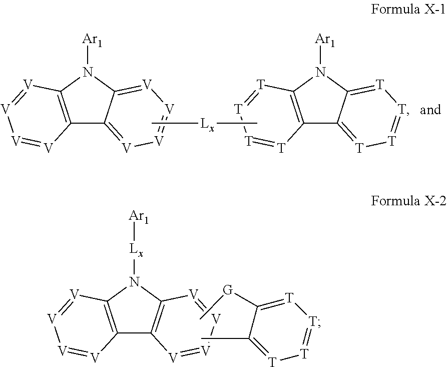

wherein,
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms, or a combination thereof;
G is, at each occurrence identically or differently, selected from C(R_{g})₂, NR_{g}, O, or S;
V is, at each occurrence identically or differently, selected from C, CRᵥ, or N;
in Formula X-1, T is, at each occurrence identically or differently, selected from C, CRₜ, or N;
in Formula X-2, T is, at each occurrence identically or differently, selected from CRₜ or N;
R_{g}, Rᵥ, and Rₜ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar₁ is, at each occurrence identically or differently, selected from substituted or unsubstituted aryl having 6 to 30 carbon atoms, substituted or unsubstituted heteroaryl having 3 to 30 carbon atoms, or a combination thereof; and
adjacent substituents R_{g}, Rᵥ, and Rₜ can be optionally joined to form a ring.

In this embodiment, the expression that “adjacent substituents R_{g}, Rᵥ, and Rₜ can be optionally joined to form a ring” is intended to mean that any one or more of groups of adjacent substituents, such as two substituents Rᵥ, two substituents Rₜ, two substituents R_{g}, substituents Rᵥ and Rₜ, substituents Rᵥ and R_{g}, and substituents R_{g} and Rₜ, may be joined to form a ring. Obviously, it is also possible that none of these substituents are joined to form a ring.

According to an embodiment of the present disclosure, the first host compound has a structure represented by one of Formula X-a to Formula X-p:

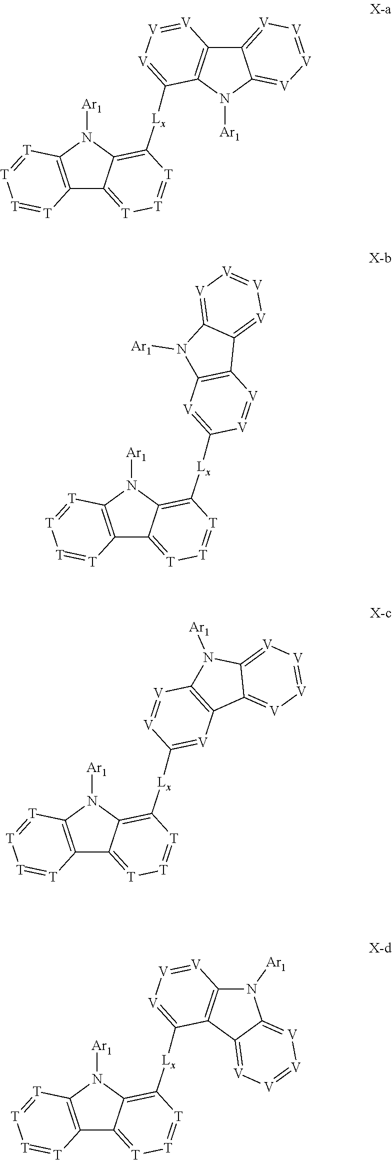

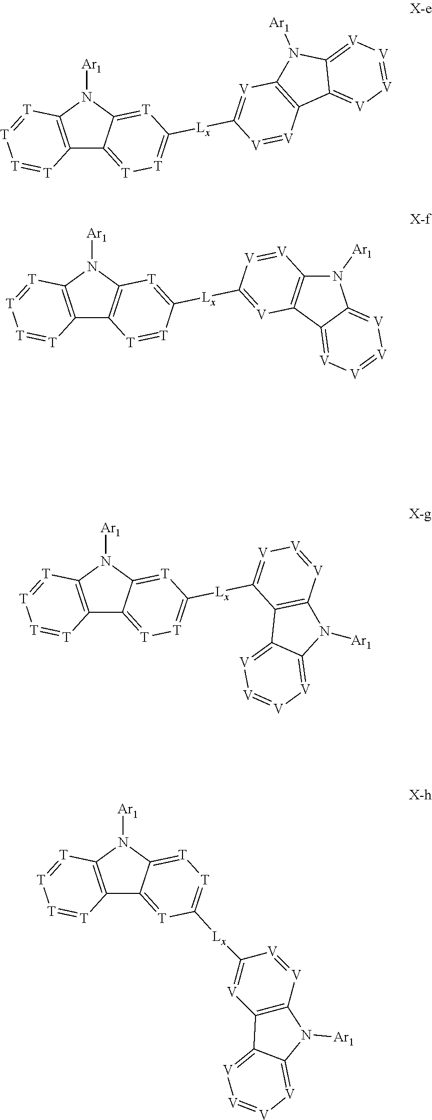

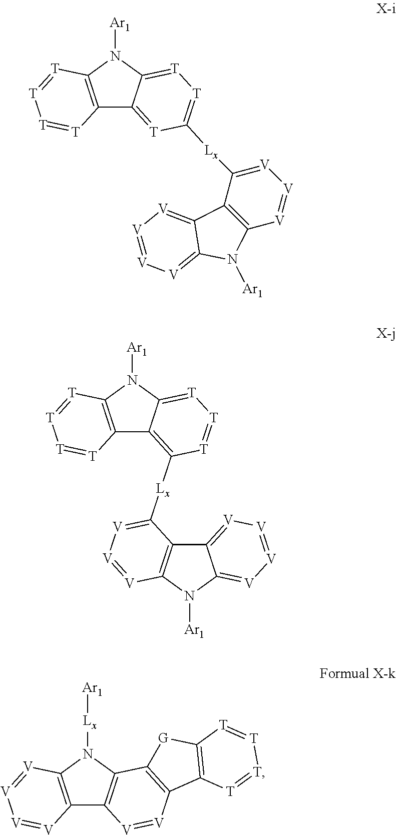

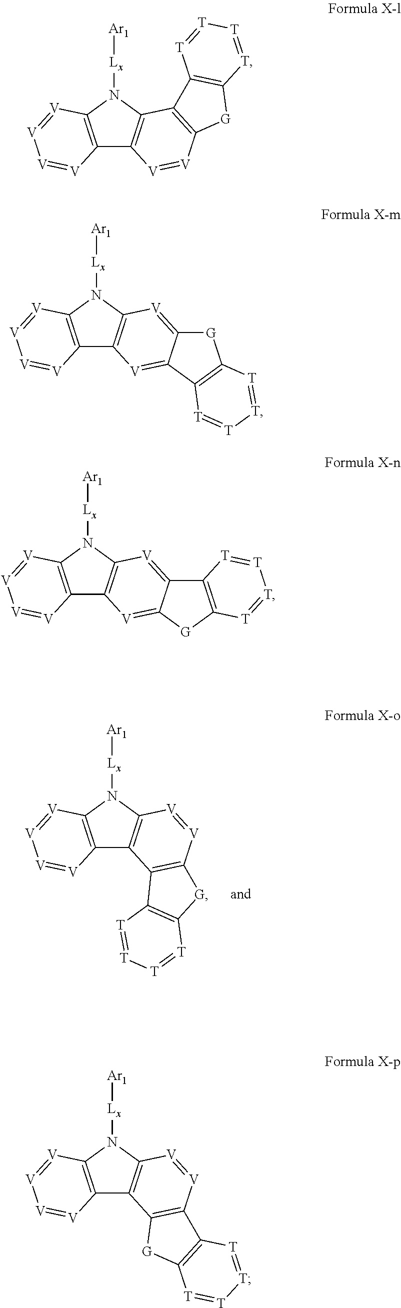

wherein,
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms, or a combination thereof;
G is, at each occurrence identically or differently, selected from C(R_{g})₂, NR_{g}, O, or S;
V is, at each occurrence identically or differently, selected from CRᵥ or N;
T is, at each occurrence identically or differently, selected from CRₜ or N;
R_{g}, Rᵥ, and Rₜ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar₁ is, at each occurrence identically or differently, selected from substituted or unsubstituted aryl having 6 to 30 carbon atoms, substituted or unsubstituted heteroaryl having 3 to 30 carbon atoms, or a combination thereof; and
adjacent substituents R_{g}, Rᵥ, and Rₜ can be optionally joined to form a ring.

According to an embodiment of the present disclosure, wherein the first host compound is selected from the group consisting of Compound PH-1 to Compound PH-115, wherein the specific structures of Compound PH-1 to Compound PH-115 are referred to claim 15.

According to an embodiment of the present disclosure, wherein hydrogens in the Compound PH-1 to Compound PH-115 can be partially or fully substituted with deuterium.

According to an embodiment of the present disclosure, wherein the second host compound has a structure represented by Formula 6:

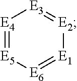

wherein,
E₁ to E₆ are, at each occurrence identically or differently, selected from C, CRₑ, or N, at least two of E₁ to E₆ are N, and at least one of E₁ to E₆ is C and joined to Formula A:

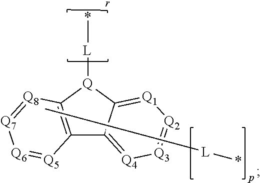

wherein,
Q is, at each occurrence identically or differently, selected from the group consisting of O, S, Se, N, NR_{Q}, CR_{Q}R_{Q}, SiR_{Q}R_{Q}, GeR_{Q}R_{Q}, and R_{Q}C═CR_{Q}; when two R_{Q} are present at the same time, the two R_{Q} may be identical or different;
p is 0 or 1; r is 0 or 1;
when Q is selected from N, p is 0, and r is 1;
when Q is selected from the group consisting of O, S, Se, NR_{Q}, CR_{Q}R_{Q}, SiR_{Q}R_{Q}, GeR_{Q}R_{Q}, and R_{Q}C═CR_{Q}, p is 1, and r is 0;
L_{q} is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms, or a combination thereof;
Q₁ to Q₈ are, at each occurrence identically or differently, selected from C, CR_{q}, or N;
Rₑ, R_{Q}, and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a substituted or unsubstituted alkylgermanyl having 3 to 20 carbon atoms, a substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
“*” represents a position where Formula A is joined to Formula 6; and
adjacent substituents Rₑ, R_{Q}, and R_{q} can be optionally joined to form a ring.

Herein, the expression that “adjacent substituents Rₑ, R_{Q}, and R_{q} can be optionally joined to form a ring” is intended to mean that any one or more of groups of adjacent substituents, such as two substituents Rₑ, two substituents R_{Q}, two substituents R_{q}, and two substituents R_{Q} and R_{q}, may be joined to form a ring. Obviously, it is also possible that none of these substituents are joined to form a ring.

According to an embodiment of the present disclosure, wherein the second host compound is selected from the group consisting of Compound H-1 to Compound H-200, wherein the specific structures of Compound H-1 to Compound H-200 are referred to claim 15.

According to an embodiment of the present disclosure, wherein hydrogens in the structures of the Compound H-1 to Compound H-200 can be partially or fully substituted with deuterium.

According to an embodiment of the present disclosure, wherein the emissive layer comprises at least one metal complex.

According to an embodiment of the present disclosure, wherein the metal complex is a phosphorescent sensitizer.

According to an embodiment of the present disclosure, wherein the metal complex has a general formula of M(Lₐ)ₘ(L_{b})ₙ(L_{c})_{q};
M is selected from a metal with a relative atomic mass greater than 40;
Lₐ, L_{b}, and L_{c} are a first ligand, a second ligand, and a third ligand coordinated to M, respectively, and Lₐ, L_{b}, and L_{c} can be optionally joined to form a multidentate ligand;
Lₐ, L_{b}, and L_{c} are identical or different; m is 1, 2, or 3, n is 0, 1, or 2, q is 0, 1, or 2, and m+n+q is equal to the oxidation state of M; when m is greater than or equal to 2, multiple Lₐ are identical or different; when n is 2, two L_{b} are identical or different; when q is 2, two L_{c} are identical or different;
Lₐ is, at each occurrence identically or differently, selected from a structure represented by Formula 2:

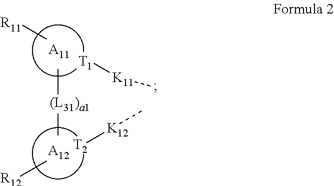

wherein,
the ring A₁₁ and the ring A₁₂ are each selected from an aromatic ring having 6 to 30 ring atoms, a heteroaromatic ring having 5 to 30 ring atoms, or a combination thereof;
T₁ and T₂ are, at each occurrence identically or differently, selected from C or N;
K₁₁ and K₁₂ are, at each occurrence identically or differently, selected from a single bond, O, S, or NRₖ;
L₃₁ is, at each occurrence identically or differently, selected from the group consisting of: a single bond, BR_{L11}, CR_{L11}R_{L11}, NR_{L11}, O, SiR_{L11}R_{L11}, PR_{L11}, S, GeR_{L11}R_{L11}, Se, substituted or unsubstituted vinylene, ethynylene, substituted or unsubstituted arylene having 6 to 30 carbon atoms, substituted or unsubstituted heteroarylene having 3 to 30 carbon atoms, and combinations thereof; when two R_{L11} are present at the same time, the two R_{L11} are identical or different;
a₁ is selected from 0 or 1;
R₁₁ and R₁₂ represent, at each occurrence identically or differently, mono-substitution, multiple substitutions, or non-substitution;
R_{L11}, R₁₁, R₁₂, and Rₖ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{L11}, R₁₁, and R₁₂ can be optionally joined to form a ring;
L_{b} and L_{c} are, at each occurrence identically or differently, selected from any one of the following structures:

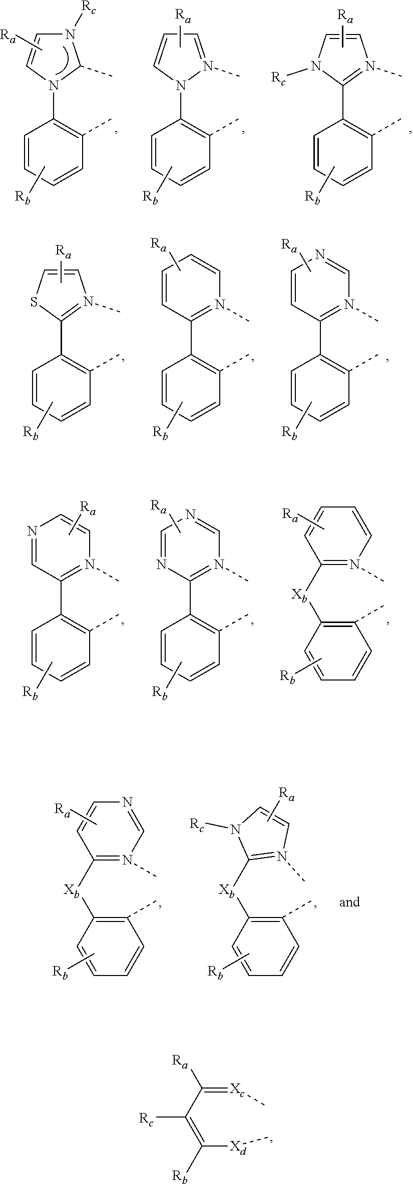

wherein,
Rₐ, R_{b}, and R_{c} represent, at each occurrence identically or differently, mono-substitution, multiple substitutions, or non-substitution;
X_{b} is, at each occurrence identically or differently, selected from the group consisting of: O, S, Se, NR_{N1}, and CR_{C1}R_{C2};
X_{c} and X_{d} are, at each occurrence identically or differently, selected from the group consisting of: O, S, Se, and NR_{N2};
Rₐ, R_{b}, R_{c}, R_{N1}, R_{N2}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents Rₐ, R_{b}, R_{c}, R_{N1}, R_{N2}, R_{C1}, and R_{C2} can be optionally joined to form a ring.

Herein, the expression that “adjacent substituents R_{L11}, R₁₁, and R₁₂ can be optionally joined to form a ring” is intended to mean that when substituents R_{L11}, R₁₁, and R₁₂ are present, any one or more of groups of adjacent substituents, such as adjacent substituents R_{L11}, adjacent substituents R₁₁, adjacent substituents R₁₂, adjacent substituents R_{L11} and R₁₁, adjacent substituents R_{L11} and R₁₂, and adjacent substituents R₁₁ and R₁₂, can be joined to form a ring. Obviously, in the presence of substituents R_{L11}, R₁₁, and R₁₂, it is also possible that none of these groups of substituents are joined to form a ring.

Herein, the expression that “adjacent substituents Rₐ, R_{b}, R_{c}, R_{N1}, R_{N2}, R_{C1}, and R_{C2} can be optionally joined to form a ring” is intended to mean that any one or more of groups of adjacent substituents, such as two substituents Rₐ, two substituents R_{b}, two substituents R_{c}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, substituents Rₐ and R_{N2}, substituents R_{b} and R_{N2}, and substituents R_{C1} and R_{C2}, may be joined to form a ring. Obviously, it is also possible that none of these substituents are joined to form a ring.

According to an embodiment of the present disclosure, the metal complex is selected from the group consisting of Compound GD1 to Compound GD185, wherein the specific structures of Compound GD1 to Compound GD185 are referred to claim 16.

According to an embodiment of the present disclosure, hydrogens in the structures of the Compound GD1 to Compound GD185 can be partially or fully substituted with deuterium.

According to an embodiment of the present disclosure, wherein the metal complex is doped in the first host compound and the second host compound, and a weight of the metal complex accounts for 1% to 30% of the total weight of the emissive layer.

According to an embodiment of the present disclosure, wherein the metal complex is doped in the first host compound and the second host compound, and a weight of the metal complex accounts for 3% to 13% of the total weight of the emissive layer.

According to another embodiment of the present disclosure, further disclosed is a compound composition comprising the compound having a structure of Formula 1, and the specific structure of the compound is as shown in any one of the preceding embodiments.

Combination with Other Materials

The materials described in the present disclosure for a particular layer in an organic light emitting device can be used in combination with various other materials present in the device. The combinations of these materials are described in more detail in U.S. Pat. App. No. 20160359122 at paragraphs 0132-0161, which is incorporated by reference herein in its entirety. The materials described or referred to in the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, the emissive dopants disclosed herein may be used in combination with a wide variety of hosts, transport layers, blocking layers, injection layers, electrodes and other layers that may be present. The combination of these materials is described in detail in paragraphs 0080-0101 of U.S. Pat. App. No. 20150349273, which is incorporated by reference herein in its entirety. The materials described or referred to in the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were tested using the conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well-known to the persons skilled in the art. As the persons skilled in the art are aware of the above-mentioned equipment use, test methods, and other related contents, the inherent data of the sample can be obtained with certainty and without influence, so the above related contents are not further described in this application.

### Material Synthesis Example

A method for preparing the compound of the present disclosure is not limited. Those skilled in the art may select appropriate raw materials and process routes according to synthesis targets. Alternatively, those skilled in the art may prepare the compound of the present disclosure according to the synthesis route illustrated below.

### Synthetic Example: Synthesis of Compound 7-33

### Step 1: Synthesis of Intermediate 3

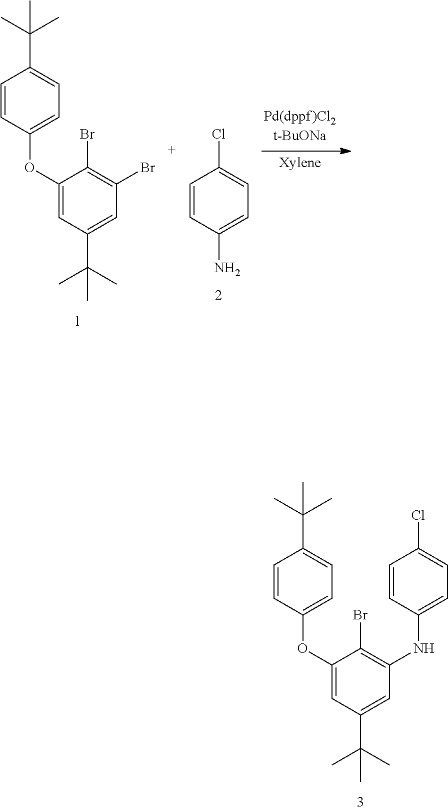 [SMILES: CC(C)(C)c1ccc(Oc2cc(C(C)(C)C)cc(Br)c2Br)cc1 ; Nc1ccc(Cl)cc1 ; CC(C)(C)c1ccc(Oc2cc(C(C)(C)C)cc(Nc3ccc(Cl)cc3)c2Br)cc1]

Under nitrogen protection, Intermediate 1 (61 g, 139.3 mmol), Intermediate 2 (26.5 g, 208.7 mmol), Pd(dppf)Cl₂ (6.08 g, 8.3 mmol), sodium tert-butoxide (26.6 g, 276.8 mmol), and xylene (1000 mL) were sequentially added to a dry 2 L three-necked round-bottom flask. The mixture was heated and stirred at 130° C. for 2 h. After completion of the reaction, the mixture was cooled, filtered through Celite, and concentrated under reduced pressure. The crude product was purified by column chromatography with gradient elution using PE:DCM=10:1 to 8:1, yielding Intermediate 3 (40 g, yield: 59.2%).

### Step 2: Synthesis of Intermediate 5

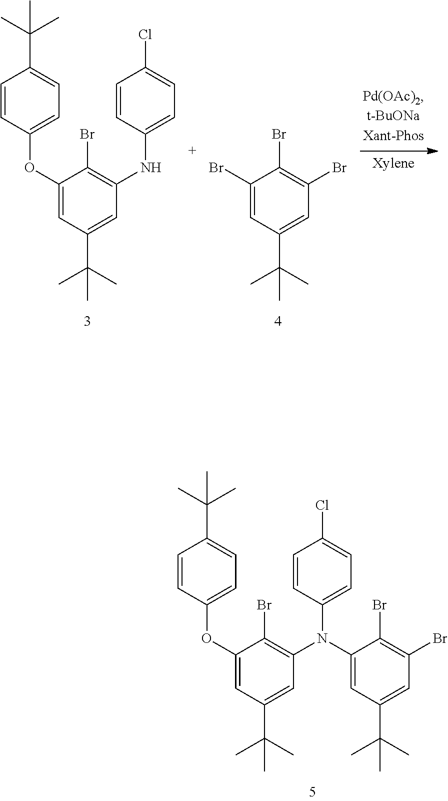 [SMILES: CC(C)(C)c1ccc(Oc2cc(C(C)(C)C)cc(Nc3ccc(Cl)cc3)c2Br)cc1 ; CC(C)(C)c1cc(Br)c(Br)c(Br)c1 ; CC(C)(C)c1ccc(Oc2cc(C(C)(C)C)cc(N(c3ccc(Cl)cc3)c3cc(C(C)(C)C)cc(Br)c3Br)c2Br)cc1]

Under nitrogen protection, Intermediate 3 (37.2 g, 76.7 mmol), Intermediate 4 (47.9 g, 130.2 mmol), palladium acetate (1.72 g, 7.64 mmol), Xant-Phos (6.63 g, 11.46 mmol), sodium tert-butoxide (18.36 g, 191 mmol), and xylene (700 mL) were sequentially added to a dry 2 L three-necked round-bottom flask. The mixture was heated and stirred at 120° C. for 8 h. After completion of the reaction, the mixture was cooled, filtered through Celite, and concentrated under reduced pressure. The crude product was purified by column chromatography with gradient elution using PE:DCM=15:1 to 8:1, yielding Intermediate 5 (50.7 g, yield: 64.6%).

### Step 3: Synthesis of Intermediate 7

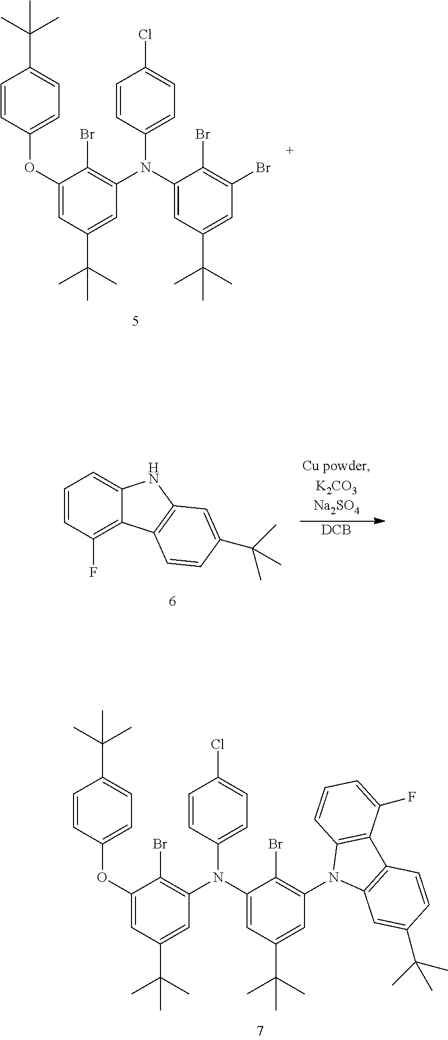

Under nitrogen protection, Intermediate 5 (49.2 g, 64.9 mmol), Intermediate 6 (19.85 g, 82.3 mmol), copper powder (8.05 g, 126.7 mmol), potassium carbonate (39.33 g, 285.03 mmol), anhydrous sodium sulfate (40.49 g, 285.03 mmol), and dichlorobenzene (DCB, 400 mL) were sequentially added to a dry 2 L single-necked round-bottom flask. The mixture was heated and stirred at 220° C. for 12 h. After completion of the reaction, the mixture was cooled, filtered through Celite, and concentrated under reduced pressure. The crude product was purified by column chromatography with gradient elution using PE:DCM=20:1 to 5:1, yielding Intermediate 7 (46 g, yield: 75.9%).

### Step 4: Synthesis of Intermediate 8

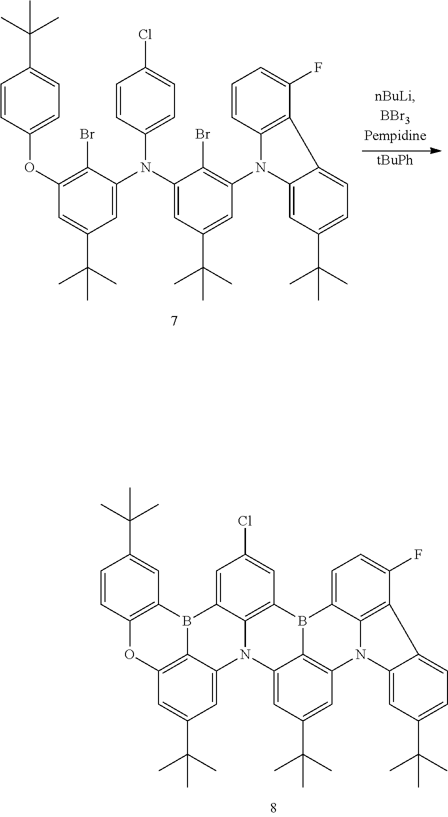 [SMILES: CC(C)(C)c1ccc(Oc2cc(C(C)(C)C)cc(N(c3ccc(Cl)cc3)c3cc(C(C)(C)C)cc(-n4c5cc(C(C)(C)C)ccc5c5c(F)cccc54)c3Br)c2Br)cc1 ; "tBuPh" ; CC(C)(C)c1ccc2c(c1)B1c3cc(Cl)cc4c3N(c3cc(C(C)(C)C)cc(c31)O2)c1cc(C(C)(C)C)cc2c1B4c1ccc(F)c3c4ccc(C(C)(C)C)cc4n-2c13]

Intermediate 7 (38.6 g, 41.3 mmol) was dissolved in tert-butylbenzene (800 mL). The system was purged with nitrogen for four times. n-Butyllithium (2.5 M, 41.28 mL, 103.2 mmol) was added dropwise at −70° C. The mixture was warmed to 15° C. and reacted for 1.5 h, then cooled to −40° C., and boron tribromide (28.9 g, 115.6 mmol) was added slowly. The mixture was then heated to 80° C. and reacted overnight, and subsequently heated to 120° C. and reacted for 6-12 h. The system was cooled again to 0° C., pentamethylpiperidine (25.6 g, 165.2 mmol) was added, and the mixture was heated to 180° C. and reacted for 48-72 h. After filtration and concentration to remove the solvent, the residue was purified by column chromatography eluting with PE:DCM=5:1. After concentration, the product was further purified by alumina column chromatography eluting with dichloromethane. The solvent was removed under concentration, and the residue was recrystallized from petroleum ether, and filtered under suction. The filter cake was recrystallized from toluene and methanol, and then filtered under suction to afford Intermediate 8 (0.62 g, yield: 1.9%).

### Step 5: Synthesis of Compound 7-33

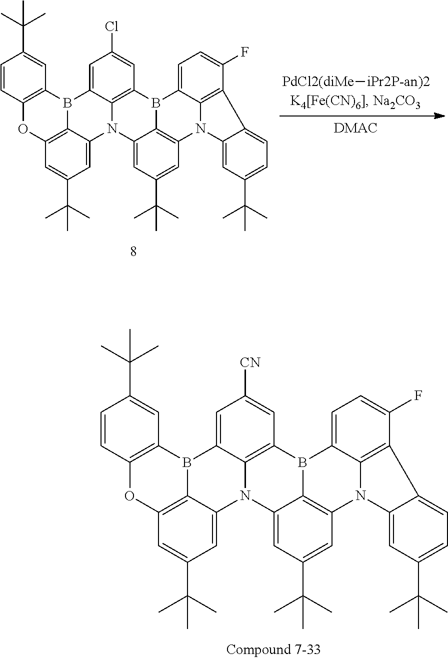

Under nitrogen protection, Intermediate 8 (900 mg, 1.1 mmol), dichlorobis[2-(diisopropylphosphino)-N,N-dimethylaniline]palladium (83 mg, 0.1 mmol), potassium ferrocyanide (1.67 g, 4.5 mmol), and sodium carbonate (477 mg, 4.5 mmol) were added to dimethylacetamide (DMAC, 80 mL). The mixture was heated to 140° C. and reacted for 12 h. After completion of the reaction, the mixture was filtered, and the filtrate was concentrated and then purified by column chromatography eluting with PE:DCM=2:1. Concentration afforded Compound 7-33 (100 mg, 0.13 mmol). The product was identified as the target compound with a molecular weight of 785.4.

Those skilled in the art should understand that the above preparation method is only an illustrative example, and it can be modified by those skilled in the art to obtain other selected compound structures of the present disclosure.

In the present invention, the maximum emission wavelength λₘₐₓ-PL in the photoluminescence spectrum and the full width at half maximum FWHM-PL in the photoluminescence spectrum were determined as follows:

Photoluminescence (PL) spectra of the target compounds were measured using a F98 fluorescence spectrophotometer manufactured by Shanghai Lengguang Technology Co., Ltd. The compound to be tested was dissolved in toluene to prepare a solution with a concentration of 1×10⁻⁶ mol/L. Nitrogen was bubbled through the prepared solution for 5 min to remove oxygen. The solution was placed in a quartz sample tube and excited at the maximum absorption wavelength of the compound at room temperature (298 K), and the emission spectrum was recorded. As an example, the maximum emission wavelength λₘₐₓ-PL and FWHM-PL of the following compounds were measured by the above method, and the results are shown in Table 1:

TABLE 1
Photoluminescence Data of Compounds

| Compound No. | λₘₐₓ [nm] | FWHM [nm] |
|---|---|---|
| 7-33 | 527 | 36.65 |
| d | 519 | 34.23 |

The specific structures of the compounds are shown below:

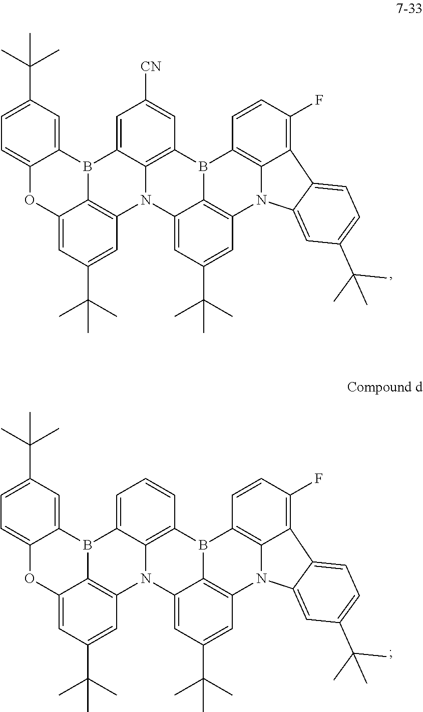 [SMILES: CC(C)(C)c1ccc2c(c1)B1c3cc(C#N)cc4c3N(c3cc(C(C)(C)C)cc(c31)O2)c1cc(C(C)(C)C)cc2c1B4c1ccc(F)c3c4ccc(C(C)(C)C)cc4n-2c13 ; CC(C)(C)c1ccc2c(c1)B1c3cccc4c3N(c3cc(C(C)(C)C)cc(c31)O2)c1cc(C(C)(C)C)cc2c1B4c1ccc(F)c3c4ccc(C(C)(C)C)cc4n-2c13]

### DISCUSSION

Compared with Compound d, Compound 7-33 of the present disclosure only differs by cyano substitution at a specific position of the backbone. As can be seen from the data in Table 1, Compound 7-33 exhibits an obvious red shift of 8 nm relative to reference Compound d, enabling effective tuning of the emission wavelength and realizing more saturated green emission. Therefore, it has promising potential applications as an excellent green-emitting material.

Those skilled in the art will appreciate that the above preparation method is merely exemplary. Those skilled in the art can obtain other compound structures selected in the present disclosure through modifications of the preparation method.

Due to a polycyclic structural design with a particular substituent, the compounds of the present disclosure can achieve the desired green or yellow light emission. To further verify the luminescence effect, the maximum emission wavelengths and energy levels of some compounds of the present disclosure and Comparative Compound a, Comparative Compound b, and Comparative Compound c were calculated by the density functional theory (DFT).

DFT calculation method used in the present disclosure:

The compounds of the present disclosure and Comparative Compound a, Comparative Compound b, and Comparative Compound c were subjected to DFT calculations by using a B3LYP hybrid functional and a 6-311G** basis set in a Gaussian software package in a tetrahydrofuran (THF) solvent environment simulated by a solvation model based on density (SMD). The HOMO values, LUMO values, and singlet energy levels (S1) of the compounds were obtained, and the maximum emission wavelengths λₘₐₓ (nm) of the compounds were obtained through conversion according to the formula λₘₐₓ (nm)=1240/S1. The data are recorded and listed in Table 2.

TABLE 2
DFT calculation results

| Compound No. | HOMO (eV) | LUMO (eV) | S1 (ev) | λₘₐₓ (nm) |
|---|---|---|---|---|
| 1-152 | −5.05 | −2.03 | 2.2569 | 549.42 |
| 1-259 | −5.22 | −2.19 | 2.2652 | 547.40 |
| 1-898 | −5.52 | −2.48 | 2.2667 | 547.05 |
| 2-109 | −5.32 | −2.34 | 2.2153 | 559.75 |
| 4-191 | −5.49 | −2.50 | 2.2670 | 546.97 |
| 4-388 | −5.40 | −2.54 | 2.1796 | 568.90 |
| 4-854 | −5.70 | −2.74 | 2.2331 | 555.28 |
| 4-855 | −5.72 | −2.74 | 2.2474 | 551.74 |
| a | −4.88 | −1.84 | 2.3261 | 533.07 |
| b | −5.36 | −2.29 | 2.3318 | 531.78 |
| c | −5.49 | −2.52 | 2.3162 | 535.37 |

The related compounds have the following structures:

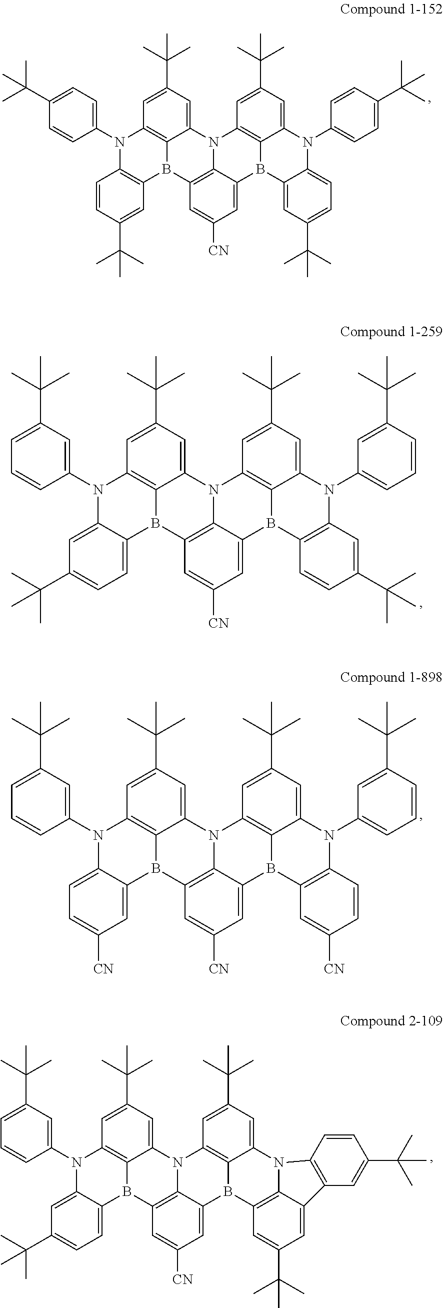

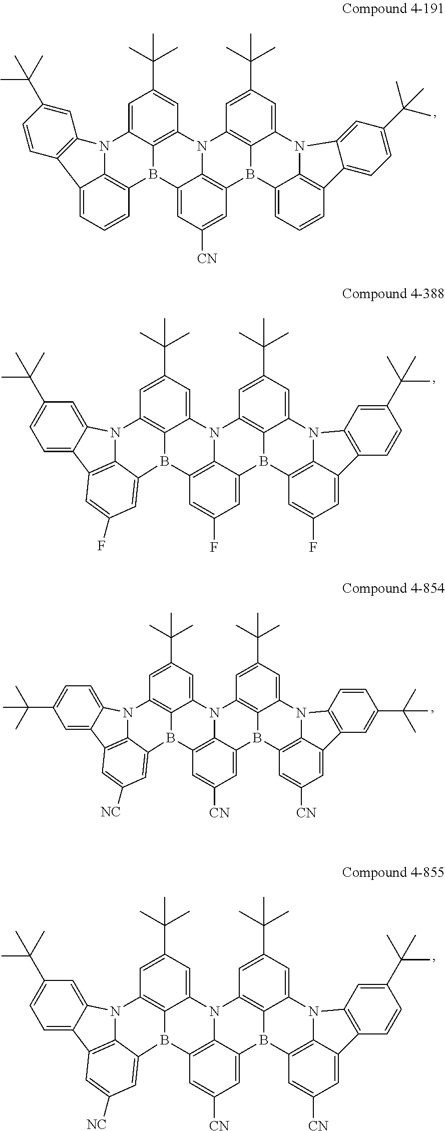

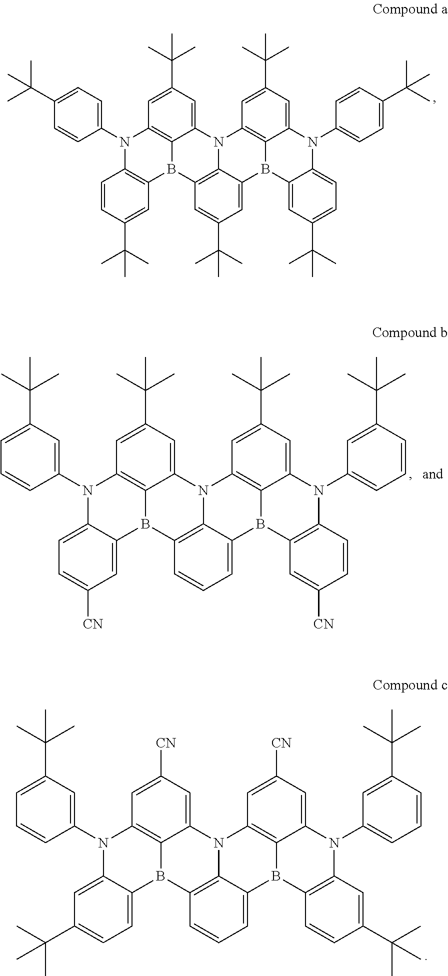

As can be seen from the data in Table 2, the desired yellow light can be emitted by the compound of the present disclosure where a particular substituent is introduced at a particular position of the polycyclic skeleton; compared with Compound a, Compound 1-152, Compound 1-259, and Compound 2-109 of the present disclosure mainly differ in that a particular substituent (CN) is introduced at a particular position of the polycyclic skeleton, and the maximum emission wavelengths of Compound 1-152, Compound 1-259, and Compound 2-109 are all significantly redshifted by 14-26 nm relative to that of Compound a which only has a t-butyl substitution on a particular ring. This redshift effect is unexpected.

Compared with Compound b and Compound c, a particular substituent is also introduced at a particular position of the polycyclic skeleton of Compound 1-898 and Compound 1-259. The calculation results show that compared with Compound b and Compound c of the comparative examples, the compounds of the present disclosure can both significantly redshift the maximum emission wavelengths by 10 nm or more.

Compared with Compound b, a particular substituent is similarly introduced at a particular position of Compound 4-388, Compound 4-854, and Compound 4-855. The calculation results show that compared with Compound b, the maximum emission wavelengths of the compounds of the present disclosure are all unexpectedly redshifted by 20-40 nm.

In conclusion, the compound having a particular structure of Formula 1 of the present disclosure successfully achieves a significant redshift of the emission wavelength due to the introduction of a particular substituent into a particular ring of the boron-nitrogen fused-ring skeleton, which is of great significance for the spectral modulation of the fluorescent material based on the B—N skeleton. More importantly, the compound of the present disclosure has the potential to become an excellent green or yellow light material, thus exhibiting broad potential application prospects of this type of material in the fields such as wide color gamut display and white light OLED.

It should be understood that various embodiments described herein are merely embodiments and not intended to limit the scope of the present disclosure. Therefore, it is apparent to those skilled in the art that the present disclosure as claimed may include variations of specific embodiments and preferred embodiments described herein. Many of the materials and structures described herein may be replaced with other materials and structures without departing from the spirit of the present disclosure. It should be understood that various theories as to why the present disclosure works are not intended to be limitative.

What is claimed is:

1. A compound having a structure represented by Formula 1: 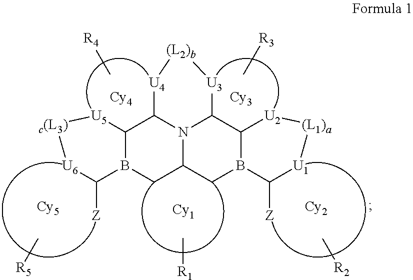
wherein,
Z is, at each occurrence identically or differently, selected from CR or N;
the ring Cy1, the ring Cy2, the ring Cy3, the ring Cy4, and the ring Cy5 are each independently selected from an unsaturated carbocyclic ring having 5 to 30 carbon atoms or an unsaturated heterocyclic ring having 3 to 30 carbon atoms;
L₂ is, at each occurrence identically or differently, selected from a single bond, O, S, Se, PR′, P═OR′, P═SR′, AsR′, As═OR′, As═SR′, CR′R′, SiR′R′, or GeR′R′;
L₁ and L₃ are, at each occurrence identically or differently, selected from a single bond, O, S, Se, BR′, NR′, PR′, P═OR′, P═SR′, AsR′, As═OR′, As═SR′, CR′R′, SiR′R′, or GeR′R′; when a plurality of R′ are present at the same time, the plurality of R′ are identical or different;
a, b, and c are each independently selected from 0, 1, or 2; a+c is greater than or equal to 1;
when a+c is equal to 1, L₁ and L₃ are, at each occurrence identically or differently, selected from a single bond, O, S, Se, BR′, PR′, P═OR′, P═SR′, AsR′, As═OR′, As═SR′, CR′R′, SiR′R′, or GeR′R′;
U₁, U₂, U₃, U₄, U₅, and U₆ are, at each occurrence identically or differently, selected from O, S, Se, N, or C;
when a is selected from 1 or 2, U₁ and U₂ are C;
when b is selected from 1 or 2, U₃ and U₄ are C;
when c is selected from 1 or 2, U₅ and U₆ are C;
R₁, R₂, R₃, R₄, and R₅ represent, at each occurrence identically or differently, mono-substitution, multiple substitutions, or non-substitution;
at least one R₁ is selected from -L-(CN)ₙ or -L-(F)ₙ, wherein n is greater than or equal to 1, and L is selected from a single bond, substituted or unsubstituted alkylene having 1 to 20 carbon atoms, substituted or unsubstituted cycloalkylene having 3 to 20 ring carbon atoms, substituted or unsubstituted heteroalkylene having 1 to 20 carbon atoms, substituted or unsubstituted heterocyclylene having 3 to 20 ring atoms, or a combination thereof;
R, R′, R₁, R₂, R₃, R₄, and R₅ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁ can be optionally joined to form a ring; and
adjacent substituents R, R′, R″, R₂, R₃, R₄, and R₅ can be optionally joined to form a ring.

2. The compound according to claim 1, wherein L₁ and L₃ are, at each occurrence identically or differently, selected from O, S, Se, BR′, NR′, PR′, P═OR′, P═SR′, AsR′, As═OR′, or As═SR′; and
preferably, L₁ and L₃ are, at each occurrence identically or differently, selected from O, S, Se, BR′, or NR′.

3. The compound according to claim 1, wherein in Formula 1, a, b and c are each independently selected from 0 or 1, and a+c is greater than or equal to 1; and
preferably, in Formula 1, a and c are selected from 1, and b is selected from 0 or 1.

4. The compound according to claim 1, the compound has a structure represented by Formula 2: 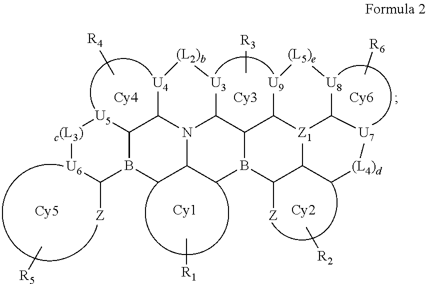
wherein,
Z is, at each occurrence identically or differently, selected from CR or N;
the ring Cy1, the ring Cy2, the ring Cy3, the ring Cy4, the ring Cy5, and the ring Cy6 are each independently selected from an unsaturated carbocyclic ring having 5 to 30 carbon atoms or an unsaturated heterocyclic ring having 3 to 30 carbon atoms;
Z₁ is, at each occurrence identically or differently, selected from B, N, P, P═O, P═S, As, As═O, As═S, SiR₀, or GeR₀;
L₂ is, at each occurrence identically or differently, selected from a single bond, O, S, Se, PR′, P═OR′, P═SR′, AsR′, As═OR′, As═SR′, CR′R′, SiR′R′, or GeR′R′;
L₃, L₄, and L₅ are, at each occurrence identically or differently, selected from a single bond, O, S, Se, BR′, NR′, PR′, P═OR′, P═SR′, AsR′, As═OR′, As═SR′, CR′R′, SiR′R′, or GeR′R′; when a plurality of R′ are present at the same time, the plurality of R′ are identical or different;
b, c, d, and e are each independently selected from 0, 1, or 2; when Z₁ is N, c is selected from 1 or 2;
U₃, U₄, U₅, U₆, U₇, U₈, and U₉ are, at each occurrence identically or differently, selected from O, S, Se, N, or C;
when b is selected from 1 or 2, U₃ and U₄ are C;
when c is selected from 1 or 2, U₅ and U₆ are C;
when d is selected from 1 or 2, U₇ is C;
when e is selected from 1 or 2, U₈ and U₉ are C;
R₁, R₂, R₃, R₄, R₅, and R₆ represent, at each occurrence identically or differently, mono-substitution, multiple substitutions, or non-substitution;
at least one R₁ is selected from -L-(CN)ₙ or -L-(F)ₙ, wherein n is greater than or equal to 1, and L is selected from a single bond, substituted or unsubstituted alkylene having 1 to 20 carbon atoms, substituted or unsubstituted cycloalkylene having 3 to 20 ring carbon atoms, substituted or unsubstituted heteroalkylene having 1 to 20 carbon atoms, substituted or unsubstituted heterocyclylene having 3 to 20 ring atoms, or a combination thereof;
R, R₀, R′, R₁, R₂, R₃, R₄, R₅, and R₆ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, a substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁ can be optionally joined to form a ring; and
adjacent substituents R, R′, R″, R₁, R₂, R₃, R₄, R₅, and R₆ can be optionally joined to form a ring.

5. The compound according to claim 4, wherein the compound has a structure represented by Formula 3: 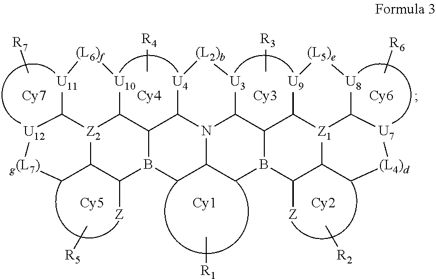
wherein,
Z is, at each occurrence identically or differently, selected from CR or N;
the ring Cy1, the ring Cy2, the ring Cy3, the ring Cy4, the ring Cy5, the ring Cy6, and the ring Cy7 are each independently selected from an unsaturated carbocyclic ring having 5 to 30 carbon atoms or an unsaturated heterocyclic ring having 3 to 30 carbon atoms;
Z₁ and Z₂ are, at each occurrence identically or differently, selected from B, N, P, P═O, P═S, As, As═O, As═S, SiR₀, or GeR₀;
L₂ is, at each occurrence identically or differently, selected from a single bond, O, S, Se, PR′, P═OR′, P═SR′, AsR′, As═OR′, As═SR′, CR′R′, SiR′R′, or GeR′R′;
L₄, L₅, L₆, and L₇ are, at each occurrence identically or differently, selected from a single bond, O, S, Se, BR′, NR′, PR′, P═OR′, P═SR′, AsR′, As═OR′, As═SR′, CR′R′, SiR′R′, or GeR′R′; when a plurality of R′ are present at the same time, the plurality of R′ are identical or different;
b, d, e, f, and g are each independently selected from 0, 1, or 2;
U₃, U₄, U₇, U₈, U₉, U₁₀, and Uₙ are, at each occurrence identically or differently, selected from O, S, Se, N, or C;
when b is selected from 1 or 2, U₃ and U₄ are C;
when d is selected from 1 or 2, U₇ is C;
when e is selected from 1 or 2, U₈ and U₉ are C;
when f is selected from 1 or 2, U₁₀ and U₁₁ are C;
R₁, R₂, R₃, R₄, R₅, R₆, and R₇ represent, at each occurrence identically or differently, mono-substitution, multiple substitutions, or non-substitution;
at least one R₁ is selected from -L-(CN)ₙ or -L-(F)ₙ, wherein n is greater than or equal to 1, and L is selected from a single bond, substituted or unsubstituted alkylene having 1 to 20 carbon atoms, substituted or unsubstituted cycloalkylene having 3 to 20 ring carbon atoms, substituted or unsubstituted heteroalkylene having 1 to 20 carbon atoms, substituted or unsubstituted heterocyclylene having 3 to 20 ring atoms, or a combination thereof;
R, R₀, R′, R₁, R₂, R₃, R₄, R₅, R₆, and R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁ can be optionally joined to form a ring; and
adjacent substituents R, R′, R″, R₂, R₃, R₄, R₅, R₆, and R₇ can be optionally joined to form a ring.

6. The compound according to claim 1, wherein at least one R₁ is selected from -L-(F)ₙ, wherein n is greater than or equal to 1, and when L is selected from substituted or unsubstituted alkylene having 1 to 20 carbon atoms, substituted or unsubstituted cycloalkylene having 3 to 20 ring carbon atoms, substituted or unsubstituted heteroalkylene having 1 to 20 carbon atoms, substituted or unsubstituted heterocyclylene having 3 to 20 ring atoms, or a combination thereof; at least one of the n F is separated from the ring Cy1 by one atom; and
preferably, at least one R₁ is selected from -L-(F)ₙ, wherein n is greater than or equal to 1, and when L is selected from substituted or unsubstituted alkylene having 1 to 20 carbon atoms, substituted or unsubstituted cycloalkylene having 3 to 20 ring carbon atoms, substituted or unsubstituted heteroalkylene having 1 to 20 carbon atoms, substituted or unsubstituted heterocyclylene having 3 to 20 ring atoms, or a combination thereof; at least one of the n F is separated from the ring Cy1 by one C atom.

7. The compound according to claim 5, wherein b, d, e, f, and g are each independently selected from 0 or 1; and
preferably, b, e, and f are 0; d and g are each independently selected from 0 or 1.

8. The compound according to claim 5, wherein L₄, L₅, L₆, and L₇ are, at each occurrence identically or differently, selected from a single bond, O, S, Se, BR′, NR′, P═OR′, CR′R′, or SiR′R′; L₂ is, at each occurrence identically or differently, selected from a single bond, O, S, Se, PR′, P═OR′, P═SR′, CR′R′, or SiR′R′; and
preferably, L₄, L₅, L₆, and L₇ are, at each occurrence identically or differently, selected from a single bond, O, S, NR′, CR′R′, or SiR′R′; L₂ is, at each occurrence identically or differently, selected from a single bond, O, S, CR′R′, or SiR′R′.

9. The compound according to claim 5, wherein the compound has a structure represented by any one of Formula 3-1 to Formula 3-4: 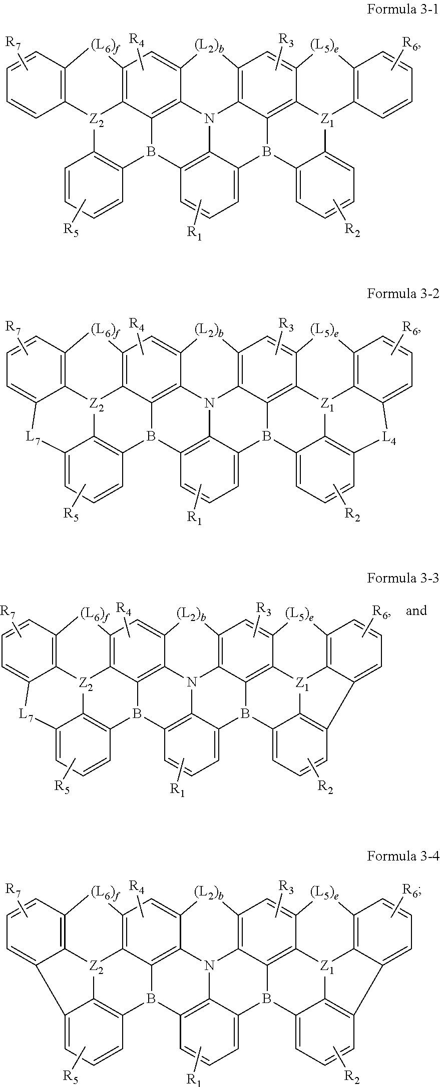
wherein,
Z₁ and Z₂ are, at each occurrence identically or differently, selected from B, N, P, P═O, P═S, As, As═O, As═S, SiR₀, or GeR₀;
L₂ is, at each occurrence identically or differently, selected from a single bond, O, S, Se, PR′, P═OR′, P═SR′, AsR′, As═OR′, As═SR′, CR′R′, SiR′R′, or GeR′R′;
L₄ and L₇ are, at each occurrence identically or differently, selected from O, S, Se, BR′, NR′, PR′, P═OR′, P═SR′, AsR′, As═OR′, As═SR′, CR′R′, SiR′R′, or GeR′R′;
L₅ and L₆ are, at each occurrence identically or differently, selected from a single bond, O, S, Se, BR′, NR′, PR′, P═OR′, P═SR′, AsR′, As═OR′, As═SR′, CR′R′, SiR′R′, or GeR′R′; when a plurality of R′ are present at the same time, the plurality of R′ are identical or different;
b, e, and f are each independently selected from 0 or 1;
R₁, R₂, R₃, R₄, R₅, R₆, and R₇ represent, at each occurrence identically or differently, mono-substitution, multiple substitutions, or non-substitution;
at least one R₁ is selected from CN, F, or CF₃;
R₀, R′, R₁, R₂, R₃, R₄, R₅, R₆, and R₇ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, —BR″R″, and combinations thereof;
R″ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁ can be optionally joined to form a ring; and
adjacent substituents R′, R″, R₂, R₃, R₄, R₅, R₆, and R₇ can be optionally joined to form a ring.

10. The compound according to claim 5, wherein Z₁ and Z₂ are, at each occurrence identically or differently, selected from B, N, P, P═O, or P═S;
preferably, Z₁ and Z₂ are, at each occurrence identically or differently, selected from B or N; and
more preferably, Z₁ and Z₂ are N.

11. The compound according to claim 5, wherein R₁, R₂, R₃, R₄, R₅, R₆, and R₇ are, at each occurrence identically or differently, selected from the group consisting of: hydrogen, deuterium, fluorine, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, substituted or unsubstituted amino having 0 to 20 carbon atoms, a cyano group, and combinations thereof;
preferably, R₁, R₂, R₃, R₄, R₅, R₆, and R₇ are, at each occurrence identically or differently, selected from the group consisting of: hydrogen, deuterium, fluorine, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted amino having 0 to 20 carbon atoms, a cyano group, and combinations thereof; and
more preferably, R₁, R₂, R₃, R₄, R₅, R₆, and R₇ are, at each occurrence identically or differently, selected from the group consisting of: hydrogen, deuterium, fluorine, substituted or unsubstituted alkyl having 1 to 12 carbon atoms, substituted or unsubstituted aryl having 6 to 12 carbon atoms, substituted or unsubstituted carbazolyl having 3 to 20 carbon atoms, substituted or unsubstituted amino having 0 to 20 carbon atoms, a cyano group, and combinations thereof.

12. The compound according to claim 5, wherein the compound is selected from the group consisting of Compound 1-1 to Compound 1-898, Compound 2-1 to Compound 2-330, Compound 3-1 to Compound 3-162, Compound 4-1 to Compound 4-587, Compound 5-1 to Compound 5-270, Compound 6-1 to Compound 6-77, and Compound 7-1 to Compound 7-45;
the Compound 1-1 to Compound 1-898 each have the following structure: 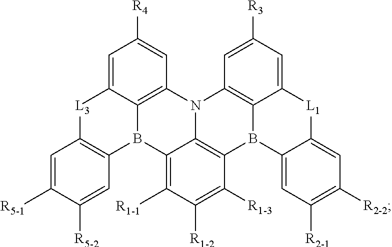
wherein R₂₋₁ and R₅₋₂ are identical, R₂₋₂ and R₅₋₁ are identical, and R₃ and R₄ are identical; L₁, L₃, R₁₋₁, R₁₋₂, R₁₋₃, R₂₋₁/R₅₋₂, R₂₋₂/R₅₋₁, and R₃/R₄ are selected from atoms or groups in the following table, respectively:

| Compound | L₁ | L₃ | R₁₋₁ | R₁₋₂ | R₁₋₃ | R₂₋₁/R₅₋₂ | R₂₋₂/R₅₋₁ | R₃/R₄ |
|---|---|---|---|---|---|---|---|---|
| 1-1 | L₁₋ₐ | L₁₋ₐ | CN | H | H | H | H | H |
| 1-2 | L₁₋ₐ | L₁₋ₐ | CN | H | H | tBu | H | H |
| 1-3 | L₁₋ₐ | L₁₋ₐ | CN | H | H | H | tBu | H |
| 1-4 | L₁₋ₐ | L₁₋ₐ | CN | H | H | H | H | tBu |
| 1-5 | L₁₋ₐ | L₁₋ₐ | CN | H | H | tBu | H | tBu |
| 1-6 | L₁₋ₐ | L₁₋ₐ | CN | H | H | H | tBu | tBu |
| 1-7 | L₁₋ₐ | L₁₋ₐ | CN | H | H | F | H | H |
| 1-8 | L₁₋ₐ | L₁₋ₐ | CN | H | H | H | F | H |
| 1-9 | L₁₋ₐ | L₁₋ₐ | CN | H | H | H | H | F |
| 1-10 | L₁₋ₐ | L₁₋ₐ | CN | H | H | F | H | tBu |
| 1-11 | L₁₋ₐ | L₁₋ₐ | CN | H | H | H | F | tBu |
| 1-12 | L₁₋ₐ | L₁₋ₐ | CN | H | H | tBu | H | F |
| 1-13 | L₁₋ₐ | L₁₋ₐ | CN | H | H | H | tBu | F |
| 1-14 | L₁₋ₐ | L₁₋ₐ | CN | H | H | F | H | F |
| 1-15 | L₁₋ₐ | L₁₋ₐ | CN | H | H | CN | H | tBu |
| 1-16 | L₁₋ₐ | L₁₋ₐ | CN | H | H | H | CN | tBu |
| 1-17 | L₁₋ₐ | L₁₋ₐ | CN | H | H | H | tBu | CN |
| 1-18 | L₁₋ₐ | L₁₋ₐ | CN | H | H | H | Ph | tBu |
| 1-19 | L₁₋ₐ | L₁₋ₐ | CN | H | H | H | Ph | Ph |
| 1-20 | L₁₋ₐ | L₁₋ₐ | CN | H | H | P-1 | H | tBu |
| 1-21 | L₁₋ₐ | L₁₋ₐ | CN | H | H | P-1 | H | P-1 |
| 1-22 | L₁₋ₐ | L₁₋ₐ | CN | H | H | H | P-1 | tBu |
| 1-23 | L₁₋ₐ | L₁₋ₐ | CN | H | H | H | P-1 | P-1 |
| 1-24 | L₁₋ₐ | L₁₋ₐ | CN | H | H | P-2 | H | tBu |
| 1-25 | L₁₋ₐ | L₁₋ₐ | CN | H | H | P-2 | H | P-2 |
| 1-26 | L₁₋ₐ | L₁₋ₐ | CN | H | H | H | P-2 | tBu |
| 1-27 | L₁₋ₐ | L₁₋ₐ | CN | H | H | H | P-2 | P-2 |
| 1-28 | L_{1-b} | L_{1-b} | CN | H | H | H | H | H |
| 1-29 | L_{1-b} | L_{1-b} | CN | H | H | tBu | H | H |
| 1-30 | L_{1-b} | L_{1-b} | CN | H | H | H | tBu | H |
| 1-31 | L_{1-b} | L_{1-b} | CN | H | H | H | H | tBu |
| 1-32 | L_{1-b} | L_{1-b} | CN | H | H | tBu | H | tBu |
| 1-33 | L_{1-b} | L_{1-b} | CN | H | H | H | tBu | tBu |
| 1-34 | L_{1-b} | L_{1-b} | CN | H | H | F | H | H |
| 1-35 | L_{1-b} | L_{1-b} | CN | H | H | H | F | H |
| 1-36 | L_{1-b} | L_{1-b} | CN | H | H | H | H | F |
| 1-37 | L_{1-b} | L_{1-b} | CN | H | H | F | H | tBu |
| 1-38 | L_{1-b} | L_{1-b} | CN | H | H | H | F | tBu |
| 1-39 | L_{1-b} | L_{1-b} | CN | H | H | tBu | H | F |
| 1-40 | L_{1-b} | L_{1-b} | CN | H | H | H | tBu | F |
| 1-41 | L_{1-b} | L_{1-b} | CN | H | H | F | H | F |
| 1-42 | L_{1-b} | L_{1-b} | CN | H | H | CN | H | tBu |
| 1-43 | L_{1-b} | L_{1-b} | CN | H | H | H | CN | tBu |
| 1-44 | L_{1-b} | L_{1-b} | CN | H | H | H | tBu | CN |
| 1-45 | L_{1-b} | L_{1-b} | CN | H | H | H | Ph | tBu |
| 1-46 | L_{1-b} | L_{1-b} | CN | H | H | H | Ph | Ph |
| 1-47 | L_{1-b} | L_{1-b} | CN | H | H | P-1 | H | tBu |
| 1-48 | L_{1-b} | L_{1-b} | CN | H | H | P-1 | H | P-1 |
| 1-49 | L_{1-b} | L_{1-b} | CN | H | H | H | P-1 | tBu |
| 1-50 | L_{1-b} | L_{1-b} | CN | H | H | H | P-1 | P-1 |
| 1-51 | L_{1-b} | L_{1-b} | CN | H | H | P-2 | H | tBu |
| 1-52 | L_{1-b} | L_{1-b} | CN | H | H | P-2 | H | P-2 |
| 1-53 | L_{1-b} | L_{1-b} | CN | H | H | H | P-2 | tBu |
| 1-54 | L_{1-b} | L_{1-b} | CN | H | H | H | P-2 | P-2 |
| 1-55 | O | O | CN | H | H | H | H | H |
| 1-56 | O | O | CN | H | H | tBu | H | H |
| 1-57 | O | O | CN | H | H | H | tBu | H |
| 1-58 | O | O | CN | H | H | H | H | tBu |
| 1-59 | O | O | CN | H | H | tBu | H | tBu |
| 1-60 | O | O | CN | H | H | H | tBu | tBu |
| 1-61 | O | O | CN | H | H | F | H | H |
| 1-62 | O | O | CN | H | H | H | F | H |
| 1-63 | O | O | CN | H | H | H | H | F |
| 1-64 | O | O | CN | H | H | F | H | tBu |
| 1-65 | O | O | CN | H | H | H | F | tBL |
| 1-66 | O | O | CN | H | H | tBu | H | F |
| 1-67 | O | O | CN | H | H | H | tBu | F |
| 1-68 | O | O | CN | H | H | F | H | F |
| 1-69 | O | O | CN | H | H | CN | H | tBu |
| 1-70 | O | O | CN | H | H | H | CN | tBu |
| 1-71 | O | O | CN | H | H | H | tBu | CN |
| 1-72 | O | O | CN | H | H | H | Ph | tBu |
| 1-73 | O | O | CN | H | H | H | Ph | Ph |
| 1-74 | O | O | CN | H | H | P-1 | H | tBu |
| 1-75 | O | O | CN | H | H | P-1 | H | P-1 |
| 1-76 | O | O | CN | H | H | H | P-1 | tBu |
| 1-77 | O | O | CN | H | H | H | P-1 | P-1 |
| 1-78 | O | O | CN | H | H | P-2 | H | tBu |
| 1-79 | O | O | CN | H | H | P-2 | H | P-2 |
| 1-80 | O | O | CN | H | H | H | P-2 | tBu |
| 1-81 | O | O | CN | H | H | H | P-2 | P-2 |
| 1-82 | S | S | CN | H | H | H | H | H |
| 1-83 | S | S | CN | H | H | tBu | H | H |
| 1-84 | S | S | CN | H | H | H | tBu | H |
| 1-85 | S | S | CN | H | H | H | H | tBu |
| 1-86 | S | S | CN | H | H | tBu | H | tBu |
| 1-87 | S | S | CN | H | H | H | tBu | tBu |
| 1-88 | S | S | CN | H | H | F | H | H |
| 1-89 | S | S | CN | H | H | H | F | H |
| 1-90 | S | S | CN | H | H | H | H | F |
| 1-91 | S | S | CN | H | H | F | H | tBu |
| 1-92 | S | S | CN | H | H | H | F | tBu |
| 1-93 | S | S | CN | H | H | tBu | H | F |
| 1-94 | S | S | CN | H | H | H | tBu | F |
| 1-95 | S | S | CN | H | H | F | H | F |
| 1-96 | S | S | CN | H | H | CN | H | tBu |
| 1-97 | S | S | CN | H | H | H | CN | tBu |
| 1-98 | S | S | CN | H | H | H | tBu | CN |
| 1-99 | S | S | CN | H | H | H | Ph | tBu |
| 1-100 | S | S | CN | H | H | H | Ph | Ph |
| 1-101 | S | S | CN | H | H | P-1 | H | tBu |
| 1-102 | S | S | CN | H | H | P-1 | H | P-1 |
| 1-103 | S | S | CN | H | H | H | P-1 | tBu |
| 1-104 | S | S | CN | H | H | H | P-1 | P-1 |
| 1-105 | S | S | CN | H | H | P-2 | H | tBu |
| 1-106 | S | S | CN | H | H | P-2 | H | P-2 |
| 1-107 | S | S | CN | H | H | H | P-2 | tBu |
| 1-108 | S | S | CN | H | H | H | P-2 | P-2 |
| 1-109 | Se | Se | CN | H | H | H | H | H |
| 1-110 | Se | Se | CN | H | H | tBu | H | H |
| 1-111 | Se | Se | CN | H | H | H | tBu | H |
| 1-112 | Se | Se | CN | H | H | H | H | tBu |
| 1-113 | Se | Se | CN | H | H | tBu | H | tBu |
| 1-114 | Se | Se | CN | H | H | H | tBu | tBu |
| 1-115 | L_{1-c} | L_{1-c} | CN | H | H | H | H | H |
| 1-116 | L_{1-c} | L_{1-c} | CN | H | H | tBu | H | H |
| 1-117 | L_{1-c} | L_{1-c} | CN | H | H | H | tBu | H |
| 1-118 | L_{1-c} | L_{1-c} | CN | H | H | H | H | tBu |
| 1-119 | L_{1-c} | L_{1-c} | CN | H | H | tBu | H | tBu |
| 1-120 | L_{1-c} | L_{1-c} | CN | H | H | H | tBu | tBu |
| 1-121 | L₁₋ₐ | L₁₋ₐ | H | CN | H | H | H | H |
| 1-122 | L₁₋ₐ | L₁₋ₐ | H | CN | H | tBu | H | H |
| 1-123 | L₁₋ₐ | L₁₋ₐ | H | CN | H | H | tBu | H |
| 1-124 | L₁₋ₐ | L₁₋ₐ | H | CN | H | H | H | tBu |
| 1-125 | L₁₋ₐ | L₁₋ₐ | H | CN | H | tBu | H | tBu |
| 1-126 | L₁₋ₐ | L₁₋ₐ | H | CN | H | H | tBu | tBu |
| 1-127 | L₁₋ₐ | L₁₋ₐ | H | CN | H | F | H | H |
| 1-128 | L₁₋ₐ | L₁₋ₐ | H | CN | H | H | F | H |
| 1-129 | L₁₋ₐ | L₁₋ₐ | H | CN | H | H | H | F |
| 1-130 | L₁₋ₐ | L₁₋ₐ | H | CN | H | F | H | tBu |
| 1-131 | L₁₋ₐ | L₁₋ₐ | H | CN | H | H | F | tBu |
| 1-132 | L₁₋ₐ | L₁₋ₐ | H | CN | H | tBu | H | F |
| 1-133 | L₁₋ₐ | L₁₋ₐ | H | CN | H | H | tBu | F |
| 1-134 | L₁₋ₐ | L₁₋ₐ | H | CN | H | F | H | F |
| 1-135 | L₁₋ₐ | L₁₋ₐ | H | CN | H | CN | H | tBu |
| 1-136 | L₁₋ₐ | L₁₋ₐ | H | CN | H | H | CN | tBu |
| 1-137 | L₁₋ₐ | L₁₋ₐ | H | CN | H | H | tBu | CN |
| 1-138 | L₁₋ₐ | L₁₋ₐ | H | CN | H | H | Ph | tBu |
| 1-139 | L₁₋ₐ | L₁₋ₐ | H | CN | H | H | Ph | Ph |
| 1-140 | L₁₋ₐ | L₁₋ₐ | H | CN | H | P-1 | H | tBu |
| 1-141 | L₁₋ₐ | L₁₋ₐ | H | CN | H | P-1 | H | P-1 |
| 1-142 | L₁₋ₐ | L₁₋ₐ | H | CN | H | H | P-1 | tBu |
| 1-143 | L₁₋ₐ | L₁₋ₐ | H | CN | H | H | P-1 | P-1 |
| 1-144 | L₁₋ₐ | L₁₋ₐ | H | CN | H | P-2 | H | tBu |
| 1-145 | L₁₋ₐ | L₁₋ₐ | H | CN | H | P-2 | H | P-2 |
| 1-146 | L₁₋ₐ | L₁₋ₐ | H | CN | H | H | P-2 | tBu |
| 1-147 | L₁₋ₐ | L₁₋ₐ | H | CN | H | H | P-2 | P-2 |
| 1-148 | L_{1-b} | L_{1-b} | H | CN | H | H | H | H |
| 1-149 | L_{1-b} | L_{1-b} | H | CN | H | tBu | H | H |
| 1-150 | L_{1-b} | L_{1-b} | H | CN | H | H | tBu | H |
| 1-151 | L_{1-b} | L_{1-b} | H | CN | H | H | H | tBu |
| 1-152 | L_{1-b} | L_{1-b} | H | CN | H | tBu | H | tBu |
| 1-153 | L_{1-b} | L_{1-b} | H | CN | H | H | tBu | tBu |
| 1-154 | L_{1-b} | L_{1-b} | H | CN | H | F | H | H |
| 1-155 | L_{1-b} | L_{1-b} | H | CN | H | H | F | H |
| 1-156 | L_{1-b} | L_{1-b} | H | CN | H | H | H | F |
| 1-157 | L_{1-b} | L_{1-b} | H | CN | H | F | H | tBu |
| 1-158 | L_{1-b} | L_{1-b} | H | CN | H | H | F | tBu |
| 1-159 | L_{1-b} | L_{1-b} | H | CN | H | tBu | H | F |
| 1-160 | L_{1-b} | L_{1-b} | H | CN | H | H | tBu | F |
| 1-161 | L_{1-b} | L_{1-b} | H | CN | H | F | H | F |
| 1-162 | L_{1-b} | L_{1-b} | H | CN | H | CN | H | tBu |
| 1-163 | L_{1-b} | L_{1-b} | H | CN | H | H | CN | tBu |
| 1-164 | L_{1-b} | L_{1-b} | H | CN | H | H | tBu | CN |
| 1-165 | L_{1-b} | L_{1-b} | H | CN | H | H | Ph | tBu |
| 1-166 | L_{1-b} | L_{1-b} | H | CN | H | H | Ph | Ph |
| 1-167 | L_{1-b} | L_{1-b} | H | CN | H | P-1 | H | tBu |
| 1-168 | L_{1-b} | L_{1-b} | H | CN | H | P-1 | H | P-1 |
| 1-169 | L_{1-b} | L_{1-b} | H | CN | H | H | P-1 | tBu |
| 1-170 | L_{1-b} | L_{1-b} | H | CN | H | H | P-1 | P-1 |
| 1-171 | L_{1-b} | L_{1-b} | H | CN | H | P-2 | H | tBu |
| 1-172 | L_{1-b} | L_{1-b} | H | CN | H | P-2 | H | P-2 |
| 1-173 | L_{1-b} | L_{1-b} | H | CN | H | H | P-2 | tBu |
| 1-174 | L_{1-b} | L_{1-b} | H | CN | H | H | P-2 | P-2 |
| 1-175 | O | O | H | CN | H | H | H | H |
| 1-176 | O | O | H | CN | H | tBu | H | H |
| 1-177 | O | O | H | CN | H | H | tBu | H |
| 1-178 | O | O | H | CN | H | H | H | tBu |
| 1-179 | O | O | H | CN | H | tBu | H | tBu |
| 1-180 | O | O | H | CN | H | H | tBu | tBu |
| 1-181 | O | O | H | CN | H | F | H | H |
| 1-182 | O | O | H | CN | H | H | F | H |
| 1-183 | O | O | H | CN | H | H | H | F |
| 1-184 | O | O | H | CN | H | F | H | tBu |
| 1-185 | O | O | H | CN | H | H | F | tBu |
| 1-186 | O | O | H | CN | H | tBu | H | F |
| 1-187 | O | O | H | CN | H | H | tBu | F |
| 1-188 | O | O | H | CN | H | F | H | F |
| 1-189 | O | O | H | CN | H | CN | H | tBu |
| 1-190 | O | O | H | CN | H | H | CN | tBu |
| 1-191 | O | O | H | CN | H | H | tBu | CN |
| 1-192 | O | O | H | CN | H | H | Ph | tBu |
| 1-193 | O | O | H | CN | H | H | Ph | Ph |
| 1-194 | O | O | H | CN | H | P-1 | H | tBu |
| 1-195 | O | O | H | CN | H | P-1 | H | P-1 |
| 1-196 | O | O | H | CN | H | H | P-1 | tBu |
| 1-197 | O | O | H | CN | H | H | P-1 | P-1 |
| 1-198 | O | O | H | CN | H | P-2 | H | tBu |
| 1-199 | O | O | H | CN | H | P-2 | H | P-2 |
| 1-200 | O | O | H | CN | H | H | P-2 | tBu |
| 1-201 | O | O | H | CN | H | H | P-2 | P-2 |
| 1-202 | S | S | H | CN | H | H | H | H |
| 1-203 | S | S | H | CN | H | tBu | H | H |
| 1-204 | S | S | H | CN | H | H | tBu | H |
| 1-205 | S | S | H | CN | H | H | H | tBu |
| 1-206 | S | S | H | CN | H | tBu | H | tBu |
| 1-207 | S | S | H | CN | H | H | tBu | tBu |
| 1-208 | S | S | H | CN | H | F | H | H |
| 1-209 | S | S | H | CN | H | H | F | H |
| 1-210 | S | S | H | CN | H | H | H | F |
| 1-211 | S | S | H | CN | H | F | H | tBu |
| 1-212 | S | S | H | CN | H | H | F | tBu |
| 1-213 | S | S | H | CN | H | tBu | H | F |
| 1-214 | S | S | H | CN | H | H | tBu | F |
| 1-215 | S | S | H | CN | H | F | H | F |
| 1-216 | S | S | H | CN | H | CN | H | tBu |
| 1-217 | S | S | H | CN | H | H | CN | tBu |
| 1-218 | S | S | H | CN | H | H | tBu | CN |
| 1-219 | S | S | H | CN | H | H | Ph | tBu |
| 1-220 | S | S | H | CN | H | H | Ph | Ph |
| 1-221 | S | S | H | CN | H | P-1 | H | tBu |
| 1-222 | S | S | H | CN | H | P-1 | H | P-1 |
| 1-223 | S | S | H | CN | H | H | P-1 | tBu |
| 1-224 | S | S | H | CN | H | H | P-1 | P-1 |
| 1-225 | S | S | H | CN | H | P-2 | H | tBu |
| 1-226 | S | S | H | CN | H | P-2 | H | P-2 |
| 1-227 | S | S | H | CN | H | H | P-2 | tBu |
| 1-228 | S | S | H | CN | H | H | P-2 | P-2 |
| 1-229 | Se | Se | H | CN | H | H | H | H |
| 1-230 | Se | Se | H | CN | H | tBu | H | H |
| 1-231 | Se | Se | H | CN | H | H | tBu | H |
| 1-232 | Se | Se | H | CN | H | H | H | tBu |
| 1-233 | Se | Se | H | CN | H | tBu | H | tBu |
| 1-234 | Se | Se | H | CN | H | H | tBu | tBu |
| 1-235 | L_{1-c} | L_{1-c} | H | CN | H | H | H | H |
| 1-236 | L_{1-c} | L_{1-c} | H | CN | H | tBu | H | H |
| 1-237 | L_{1-c} | L_{1-c} | H | CN | H | H | tBu | H |
| 1-238 | L_{1-c} | L_{1-c} | H | CN | H | H | H | tBu |
| 1-239 | L_{1-c} | L_{1-c} | H | CN | H | tBu | H | tBu |
| 1-240 | L_{1-c} | L_{1-c} | H | CN | H | H | tBu | tBu |
| 1-241 | L_{1-b} | O | H | CN | H | H | H | H |
| 1-242 | L_{1-b} | O | H | CN | H | tBu | H | H |
| 1-243 | L_{1-b} | O | H | CN | H | H | Bu | H |
| 1-244 | L_{1-b} | O | H | CN | H | H | H | tBu |
| 1-245 | L_{1-b} | O | H | CN | H | tBu | H | tBu |
| 1-246 | L_{1-b} | O | H | CN | H | H | tBu | tBu |
| 1-247 | L_{1-b} | S | H | CN | H | H | H | H |
| 1-248 | L_{1-b} | S | H | CN | H | tBu | H | H |
| 1-249 | L_{1-b} | S | H | CN | H | H | tBu | H |
| 1-250 | L_{1-b} | S | H | CN | H | H | H | tBu |
| 1-251 | L_{1-b} | S | H | CN | H | tBu | H | tBu |
| 1-252 | L_{1-b} | S | H | CN | H | H | tBu | tBu |
| 1-253 | O | S | H | CN | H | H | H | H |
| 1-254 | O | S | H | CN | H | tBu | H | H |
| 1-255 | O | S | H | CN | H | H | tBu | H |
| 1-256 | O | S | H | CN | H | H | H | tBu |
| 1-257 | O | S | H | CN | H | tBu | H | tBu |
| 1-258 | O | S | H | CN | H | H | tBu | tBu |
| 1-259 | L_{1-d} | L_{1-d} | H | CN | H | H | tBu | tBu |
| 1-260 | L₁₋ₐ | L₁₋ₐ | F | H | H | H | H | H |
| 1-261 | L₁₋ₐ | L₁₋ₐ | F | H | H | tBu | H | H |
| 1-262 | L₁₋ₐ | L₁₋ₐ | F | H | H | H | tBu | H |
| 1-263 | L₁₋ₐ | L₁₋ₐ | F | H | H | H | H | tBu |
| 1-264 | L₁₋ₐ | L₁₋ₐ | F | H | H | tBu | H | tBu |
| 1-265 | L₁₋ₐ | L₁₋ₐ | F | H | H | H | tBu | tBu |
| 1-266 | L₁₋ₐ | L₁₋ₐ | F | H | H | F | H | H |
| 1-267 | L₁₋ₐ | L₁₋ₐ | F | H | H | H | F | H |
| 1-268 | L₁₋ₐ | L₁₋ₐ | F | H | H | H | H | F |
| 1-269 | L₁₋ₐ | L₁₋ₐ | F | H | H | F | H | tBu |
| 1-270 | L₁₋ₐ | L₁₋ₐ | F | H | H | H | F | tBu |
| 1-271 | L₁₋ₐ | L₁₋ₐ | F | H | H | tBu | H | F |
| 1-272 | L₁₋ₐ | L₁₋ₐ | F | H | H | H | tBu | F |
| 1-273 | L₁₋ₐ | L₁₋ₐ | F | H | H | F | H | F |
| 1-274 | L₁₋ₐ | L₁₋ₐ | F | H | H | CN | H | tBu |
| 1-275 | L₁₋ₐ | L₁₋ₐ | F | H | H | H | CN | tBu |
| 1-276 | L₁₋ₐ | L₁₋ₐ | F | H | H | H | tBu | CN |
| 1-277 | L₁₋ₐ | L₁₋ₐ | F | H | H | H | Ph | tBu |
| 1-278 | L₁₋ₐ | L₁₋ₐ | F | H | H | H | Ph | Ph |
| 1-279 | L₁₋ₐ | L₁₋ₐ | F | H | H | P-1 | H | tBu |
| 1-280 | L₁₋ₐ | L₁₋ₐ | F | H | H | P-1 | H | P-1 |
| 1-281 | L₁₋ₐ | L₁₋ₐ | F | H | H | H | P-1 | tBu |
| 1-282 | L₁₋ₐ | L₁₋ₐ | F | H | H | H | P-1 | P-1 |
| 1-283 | L₁₋ₐ | L₁₋ₐ | F | H | H | P-2 | H | tBu |
| 1-284 | L₁₋ₐ | L₁₋ₐ | F | H | H | P-2 | H | P-2 |
| 1-285 | L₁₋ₐ | L₁₋ₐ | F | H | H | H | P-2 | tBu |
| 1-286 | L₁₋ₐ | L₁₋ₐ | F | H | H | H | P-2 | P-2 |
| 1-287 | L_{1-b} | L_{1-b} | F | H | H | H | H | H |
| 1-288 | L_{1-b} | L_{1-b} | F | H | H | tBu | H | H |
| 1-289 | L_{1-b} | L_{1-b} | F | H | H | H | tBu | H |
| 1-290 | L_{1-b} | L_{1-b} | F | H | H | H | H | tBu |
| 1-291 | L_{1-b} | L_{1-b} | F | H | H | tBu | H | tBu |
| 1-292 | L_{1-b} | L_{1-b} | F | H | H | H | tBu | tBu |
| 1-293 | L_{1-b} | L_{1-b} | F | H | H | F | H | H |
| 1-294 | L_{1-b} | L_{1-b} | F | H | H | H | F | H |
| 1-295 | L_{1-b} | L_{1-b} | F | H | H | H | H | F |
| 1-296 | L_{1-b} | L_{1-b} | F | H | H | F | H | tBu |
| 1-297 | L_{1-b} | L_{1-b} | F | H | H | H | F | tBu |
| 1-298 | L_{1-b} | L_{1-b} | F | H | H | tBu | H | F |
| 1-299 | L_{1-b} | L_{1-b} | F | H | H | H | tBu | F |
| 1-300 | L_{1-b} | L_{1-b} | F | H | H | F | H | F |
| 1-301 | L_{1-b} | L_{1-b} | F | H | H | CN | H | tBu |
| 1-302 | L_{1-b} | L_{1-b} | F | H | H | H | CN | tBu |
| 1-303 | L_{1-b} | L_{1-b} | F | H | H | H | tBu | CN |
| 1-304 | L_{1-b} | L_{1-b} | F | H | H | H | Ph | tBu |
| 1-305 | L_{1-b} | L_{1-b} | F | H | H | H | Ph | Ph |
| 1-306 | L_{1-b} | L_{1-b} | F | H | H | P-1 | H | tBu |
| 1-307 | L_{1-b} | L_{1-b} | F | H | H | P-1 | H | P-1 |
| 1-308 | L_{1-b} | L_{1-b} | F | H | H | H | P-1 | tBu |
| 1-309 | L_{1-b} | L_{1-b} | F | H | H | H | P-1 | P-1 |
| 1-310 | L_{1-b} | L_{1-b} | F | H | H | P-2 | H | tBu |
| 1-311 | L_{1-b} | L_{1-b} | F | H | H | P-2 | H | P-2 |
| 1-312 | L_{1-b} | L_{1-b} | F | H | H | H | P-2 | tBu |
| 1-313 | L_{1-b} | L_{1-b} | F | H | H | H | P-2 | P-2 |
| 1-314 | O | O | F | H | H | H | H | H |
| 1-315 | O | O | F | H | H | tBu | H | H |
| 1-316 | O | O | F | H | H | H | tBu | H |
| 1-317 | O | O | F | H | H | H | H | tBu |
| 1-318 | O | O | F | H | H | tBu | H | tBu |
| 1-319 | O | O | F | H | H | H | tBu | tBu |
| 1-320 | O | O | F | H | H | F | H | H |
| 1-321 | O | O | F | H | H | H | F | H |
| 1-322 | O | O | F | H | H | H | H | F |
| 1-323 | O | O | F | H | H | F | H | tBu |
| 1-324 | O | O | F | H | H | H | F | tBu |
| 1-325 | O | O | F | H | H | tBu | H | F |
| 1-326 | O | O | F | H | H | H | tBu | F |
| 1-327 | O | O | F | H | H | F | H | F |
| 1-328 | O | O | F | H | H | CN | H | tBu |
| 1-329 | O | O | F | H | H | H | CN | tBu |
| 1-330 | O | O | F | H | H | H | tBu | CN |
| 1-331 | O | O | F | H | H | H | Ph | tBu |
| 1-332 | O | O | F | H | H | H | Ph | Ph |
| 1-333 | O | O | F | H | H | P-1 | H | tBu |
| 1-334 | O | O | F | H | H | P-1 | H | P-1 |
| 1-335 | O | O | F | H | H | H | P-1 | tBu |
| 1-336 | O | O | F | H | H | H | P-1 | P-1 |
| 1-337 | O | O | F | H | H | P-2 | H | tBu |
| 1-338 | O | O | F | H | H | P-2 | H | P-2 |
| 1-339 | O | O | F | H | H | H | P-2 | tBu |
| 1-340 | O | O | F | H | H | H | P-2 | P-2 |
| 1-341 | S | S | F | H | H | H | H | H |
| 1-342 | S | S | F | H | H | tBu | H | H |
| 1-343 | S | S | F | H | H | H | tBu | H |
| 1-344 | S | S | F | H | H | H | H | tBu |
| 1-345 | S | S | F | H | H | tBu | H | tBu |
| 1-346 | S | S | F | H | H | H | tBu | tBu |
| 1-347 | S | S | F | H | H | F | H | H |
| 1-348 | S | S | F | H | H | H | F | H |
| 1-349 | S | S | F | H | H | H | H | F |
| 1-350 | S | S | F | H | H | F | H | tBu |
| 1-351 | S | S | F | H | H | H | F | tBu |
| 1-352 | S | S | F | H | H | tBu | H | F |
| 1-353 | S | S | F | H | H | H | tBu | F |
| 1-354 | S | S | F | H | H | F | H | F |
| 1-355 | S | S | F | H | H | CN | H | tBu |
| 1-356 | S | S | F | H | H | H | CN | tBu |
| 1-357 | S | S | F | H | H | H | tBu | CN |
| 1-358 | S | S | F | H | H | H | Ph | tBu |
| 1-359 | S | S | F | H | H | H | Ph | Ph |
| 1-360 | S | S | F | H | H | P-1 | H | tBu |
| 1-361 | S | S | F | H | H | P-1 | H | P-1 |
| 1-362 | S | S | F | H | H | H | P-1 | tBu |
| 1-363 | S | S | F | H | H | H | P-1 | P-1 |
| 1-364 | S | S | F | H | H | P-2 | H | tBu |
| 1-365 | S | S | F | H | H | P-2 | H | P-2 |
| 1-366 | S | S | F | H | H | H | P-2 | tBu |
| 1-367 | S | S | F | H | H | H | P-2 | P-2 |
| 1-368 | Se | Se | F | H | H | H | H | H |
| 1-369 | Se | Se | F | H | H | tBu | H | H |
| 1-370 | Se | Se | F | H | H | H | tBu | H |
| 1-371 | Se | Se | F | H | H | H | H | tBu |
| 1-372 | Se | Se | F | H | H | tBu | H | tBu |
| 1-373 | Se | Se | F | H | H | H | tBu | tBu |
| 1-374 | L_{1-c} | L_{1-c} | F | H | H | H | H | H |
| 1-375 | L_{1-c} | L_{1-c} | F | H | H | tBu | H | H |
| 1-376 | L_{1-c} | L_{1-c} | F | H | H | H | tBu | H |
| 1-377 | L_{1-c} | L_{1-c} | F | H | H | H | H | tBu |
| 1-378 | L_{1-c} | L_{1-c} | F | H | H | tBu | H | tBu |
| 1-379 | L_{1-c} | L_{1-c} | F | H | H | H | tBu | tBu |
| 1-380 | L₁₋ₐ | L₁₋ₐ | H | F | H | H | H | H |
| 1-381 | L₁₋ₐ | L₁₋ₐ | H | F | H | tBu | H | H |
| 1-382 | L₁₋ₐ | L₁₋ₐ | H | F | H | H | tBu | H |
| 1-383 | L₁₋ₐ | L₁₋ₐ | H | F | H | H | H | tBu |
| 1-384 | L₁₋ₐ | L₁₋ₐ | H | F | H | tBu | H | tBu |
| 1-385 | L₁₋ₐ | L₁₋ₐ | H | F | H | H | tBu | tBu |
| 1-386 | L₁₋ₐ | L₁₋ₐ | H | F | H | F | H | H |
| 1-387 | L₁₋ₐ | L₁₋ₐ | H | F | H | H | F | H |
| 1-388 | L₁₋ₐ | L₁₋ₐ | H | F | H | H | H | F |
| 1-389 | L₁₋ₐ | L₁₋ₐ | H | F | H | F | H | tBu |
| 1-390 | L₁₋ₐ | L₁₋ₐ | H | F | H | H | F | tBu |
| 1-391 | L₁₋ₐ | L₁₋ₐ | H | F | H | tBu | H | F |
| 1-392 | L₁₋ₐ | L₁₋ₐ | H | F | H | H | tBu | F |
| 1-393 | L₁₋ₐ | L₁₋ₐ | H | F | H | F | H | F |
| 1-394 | L₁₋ₐ | L₁₋ₐ | H | F | H | CN | H | tBu |
| 1-395 | L₁₋ₐ | L₁₋ₐ | H | F | H | H | CN | tBu |
| 1-396 | L₁₋ₐ | L₁₋ₐ | H | F | H | H | tBu | CN |
| 1-397 | L₁₋ₐ | L₁₋ₐ | H | F | H | H | Ph | tBu |
| 1-398 | L₁₋ₐ | L₁₋ₐ | H | F | H | H | Ph | Ph |
| 1-399 | L₁₋ₐ | L₁₋ₐ | H | F | H | P-1 | H | tBu |
| 1-400 | L₁₋ₐ | L₁₋ₐ | H | F | H | P-1 | H | P-1 |
| 1-401 | L₁₋ₐ | L₁₋ₐ | H | F | H | H | P-1 | tBu |
| 1-402 | L₁₋ₐ | L₁₋ₐ | H | F | H | H | P-1 | P-1 |
| 1-403 | L₁₋ₐ | L₁₋ₐ | H | F | H | P-2 | H | tBu |
| 1-404 | L₁₋ₐ | L₁₋ₐ | H | F | H | P-2 | H | P-2 |
| 1-405 | L₁₋ₐ | L₁₋ₐ | H | F | H | H | P-2 | tBu |
| 1-406 | L₁₋ₐ | L₁₋ₐ | H | F | H | H | P-2 | P-2 |
| 1-407 | L_{1-b} | L_{1-b} | H | F | H | H | H | H |
| 1-408 | L_{1-b} | L_{1-b} | H | F | H | tBu | H | H |
| 1-409 | L_{1-b} | L_{1-b} | H | F | H | H | tBu | H |
| 1-410 | L_{1-b} | L_{1-b} | H | F | H | H | H | tBu |
| 1-411 | L_{1-b} | L_{1-b} | H | F | H | tBu | H | tBu |
| 1-412 | L_{1-b} | L_{1-b} | H | F | H | H | tBu | tBu |
| 1-413 | L_{1-b} | L_{1-b} | H | F | H | F | H | H |
| 1-414 | L_{1-b} | L_{1-b} | H | F | H | H | F | H |
| 1-415 | L_{1-b} | L_{1-b} | H | F | H | H | H | F |
| 1-416 | L_{1-b} | L_{1-b} | H | F | H | F | H | tBu |
| 1-417 | L_{1-b} | L_{1-b} | H | F | H | H | F | tBu |
| 1-418 | L_{1-b} | L_{1-b} | H | F | H | tBu | H | F |
| 1-419 | L_{1-b} | L_{1-b} | H | F | H | H | tBu | F |
| 1-420 | L_{1-b} | L_{1-b} | H | F | H | F | H | F |
| 1-421 | L_{1-b} | L_{1-b} | H | F | H | CN | H | tBu |
| 1-422 | L_{1-b} | L_{1-b} | H | F | H | H | CN | tBu |
| 1-423 | L_{1-b} | L_{1-b} | H | F | H | H | tBu | CN |
| 1-424 | L_{1-b} | L_{1-b} | H | F | H | H | Ph | tBu |
| 1-425 | L_{1-b} | L_{1-b} | H | F | H | H | Ph | Ph |
| 1-426 | L_{1-b} | L_{1-b} | H | F | H | P-1 | H | tBu |
| 1-427 | L_{1-b} | L_{1-b} | H | F | H | P-1 | H | P-1 |
| 1-428 | L_{1-b} | L_{1-b} | H | F | H | H | P-1 | tBu |
| 1-429 | L_{1-b} | L_{1-b} | H | F | H | H | P-1 | P-1 |
| 1-430 | L_{1-b} | L_{1-b} | H | F | H | P-2 | H | tBu |
| 1-431 | L_{1-b} | L_{1-b} | H | F | H | P-2 | H | P-2 |
| 1-432 | L_{1-b} | L_{1-b} | H | F | H | H | P-2 | tBu |
| 1-433 | L_{1-b} | L_{1-b} | H | F | H | H | P-2 | P-2 |
| 1-434 | O | O | H | F | H | H | H | H |
| 1-435 | O | O | H | F | H | tBu | H | H |
| 1-436 | O | O | H | F | H | H | tBu | H |
| 1-437 | O | O | H | F | H | H | H | tBu |
| 1-438 | O | O | H | F | H | tBu | H | tBu |
| 1-439 | O | O | H | F | H | H | tBu | tBu |
| 1-440 | O | O | H | F | H | F | H | H |
| 1-441 | O | O | H | F | H | H | F | H |
| 1-442 | O | O | H | F | H | H | H | F |
| 1-443 | O | O | H | F | H | F | H | tBu |
| 1-444 | O | O | H | F | H | H | F | tBu |
| 1-445 | O | O | H | F | H | tBu | H | F |
| 1-446 | O | O | H | F | H | H | tBu | F |
| 1-447 | O | O | H | F | H | F | H | F |
| 1-448 | O | O | H | F | H | CN | H | tBu |
| 1-449 | O | O | H | F | H | H | CN | tBu |
| 1-450 | O | O | H | F | H | H | tBu | CN |
| 1-451 | O | O | H | F | H | H | Ph | tBu |
| 1-452 | O | O | H | F | H | H | Ph | Ph |
| 1-453 | O | O | H | F | H | P-1 | H | tBu |
| 1-454 | O | O | H | F | H | P-1 | H | P-1 |
| 1-455 | O | O | H | F | H | H | P-1 | tBu |
| 1-456 | O | O | H | F | H | H | P-1 | P-1 |
| 1-457 | O | O | H | F | H | P-2 | H | tBu |
| 1-458 | O | O | H | F | H | P-2 | H | P-2 |
| 1-459 | O | O | H | F | H | H | P-2 | tBu |
| 1-460 | O | O | H | F | H | H | P-2 | P-2 |
| 1-461 | S | S | H | F | H | H | H | H |
| 1-462 | S | S | H | F | H | tBu | H | H |
| 1-463 | S | S | H | F | H | H | tBu | H |
| 1-464 | S | S | H | F | H | H | H | tBu |
| 1-465 | S | S | H | F | H | tBu | H | tBu |
| 1-466 | S | S | H | F | H | H | tBu | tBu |
| 1-467 | S | S | H | F | H | F | H | H |
| 1-468 | S | S | H | F | H | H | F | H |
| 1-469 | S | S | H | F | H | H | H | F |
| 1-470 | S | S | H | F | H | F | H | tBu |
| 1-471 | S | S | H | F | H | H | F | tBu |
| 1-472 | S | S | H | F | H | tBu | H | F |
| 1-473 | S | S | H | F | H | H | tBu | F |
| 1-474 | S | S | H | F | H | F | H | F |
| 1-475 | S | S | H | F | H | CN | H | tBu |
| 1-476 | S | S | H | F | H | H | CN | tBu |
| 1-477 | S | S | H | F | H | H | tBu | CN |
| 1-478 | S | S | H | F | H | H | Ph | tBu |
| 1-479 | S | S | H | F | H | H | Ph | Ph |
| 1-480 | S | S | H | F | H | P-1 | H | tBu |
| 1-481 | S | S | H | F | H | P-1 | H | P-1 |
| 1-482 | S | S | H | F | H | H | P-1 | tBu |
| 1-483 | S | S | H | F | H | H | P-1 | P-1 |
| 1-484 | S | S | H | F | H | P-2 | H | tBu |
| 1-485 | S | S | H | F | H | P-2 | H | P-2 |
| 1-486 | S | S | H | F | H | H | P-2 | tBu |
| 1-487 | S | S | H | F | H | H | P-2 | P-2 |
| 1-488 | Se | Se | H | F | H | H | H | H |
| 1-489 | Se | Se | H | F | H | tBu | H | H |
| 1-490 | Se | Se | H | F | H | H | tBu | H |
| 1-491 | Se | Se | H | F | H | H | H | tBu |
| 1-492 | Se | Se | H | F | H | tBu | H | tBu |
| 1-493 | Se | Se | H | F | H | H | tBu | tBu |
| 1-494 | L_{1-c} | L_{1-c} | H | F | H | H | H | H |
| 1-495 | L_{1-c} | L_{1-c} | H | F | H | tBu | H | H |
| 1-496 | L_{1-c} | L_{1-c} | H | F | H | H | tBu | H |
| 1-497 | L_{1-c} | L_{1-c} | H | F | H | H | H | tBu |
| 1-498 | L_{1-c} | L_{1-c} | H | F | H | tBu | H | tBu |
| 1-499 | L_{1-c} | L_{1-c} | H | F | H | H | tBu | tBu |
| 1-500 | L_{1-b} | O | H | F | H | H | H | H |
| 1-501 | L_{1-b} | O | H | F | H | tBu | H | H |
| 1-502 | L_{1-b} | O | H | F | H | H | tBu | H |
| 1-503 | L_{1-b} | O | H | F | H | H | H | tBu |
| 1-504 | L_{1-b} | O | H | F | H | tBu | H | tBu |
| 1-505 | L_{1-b} | O | H | F | H | H | tBu | tBu |
| 1-506 | L_{1-b} | S | H | F | H | H | H | H |
| 1-507 | L_{1-b} | S | H | F | H | tBu | H | H |
| 1-508 | L_{1-b} | S | H | F | H | H | tBu | H |
| 1-509 | L_{1-b} | S | H | F | H | H | H | tBu |
| 1-510 | L_{1-b} | S | H | F | H | tBu | H | tBu |
| 1-511 | L_{1-b} | S | H | F | H | H | tBu | tBu |
| 1-512 | O | S | H | F | H | H | H | H |
| 1-513 | O | S | H | F | H | tBu | H | H |
| 1-514 | O | S | H | F | H | H | tBu | H |
| 1-515 | O | S | H | F | H | H | H | tBu |
| 1-516 | O | S | H | F | H | tBu | H | tBu |
| 1-517 | O | S | H | F | H | H | tBu | tBu |
| 1-518 | L_{1-d} | L_{1-d} | H | F | H | H | tBu | tBu |
| 1-519 | L₁₋ₐ | L₁₋ₐ | F | H | F | H | H | H |
| 1-520 | L₁₋ₐ | L₁₋ₐ | F | H | F | tBu | H | H |
| 1-521 | L₁₋ₐ | L₁₋ₐ | F | H | F | H | tBu | H |
| 1-522 | L₁₋ₐ | L₁₋ₐ | F | H | F | H | H | tBu |
| 1-523 | L₁₋ₐ | L₁₋ₐ | F | H | F | tBu | H | tBu |
| 1-524 | L₁₋ₐ | L₁₋ₐ | F | H | F | H | tBu | tBu |
| 1-525 | L₁₋ₐ | L₁₋ₐ | F | H | F | F | H | H |
| 1-526 | L₁₋ₐ | L₁₋ₐ | F | H | F | H | F | H |
| 1-527 | L₁₋ₐ | L₁₋ₐ | F | H | F | H | H | F |
| 1-528 | L₁₋ₐ | L₁₋ₐ | F | H | F | F | H | tBu |
| 1-529 | L₁₋ₐ | L₁₋ₐ | F | H | F | H | F | tBu |
| 1-530 | L₁₋ₐ | L₁₋ₐ | F | H | F | tBu | H | F |
| 1-531 | L₁₋ₐ | L₁₋ₐ | F | H | F | H | tBu | F |
| 1-532 | L₁₋ₐ | L₁₋ₐ | F | H | F | F | H | F |
| 1-533 | L₁₋ₐ | L₁₋ₐ | F | H | F | CN | H | tBu |
| 1-534 | L₁₋ₐ | L₁₋ₐ | F | H | F | H | CN | tBu |
| 1-535 | L₁₋ₐ | L₁₋ₐ | F | H | F | H | tBu | CN |
| 1-536 | L₁₋ₐ | L₁₋ₐ | F | H | F | H | Ph | tBu |
| 1-537 | L₁₋ₐ | L₁₋ₐ | F | H | F | H | Ph | Ph |
| 1-538 | L₁₋ₐ | L₁₋ₐ | F | H | F | P-1 | H | tBu |
| 1-539 | L₁₋ₐ | L₁₋ₐ | F | H | F | P-1 | H | P-1 |
| 1-540 | L₁₋ₐ | L₁₋ₐ | F | H | F | H | P-1 | tBu |
| 1-541 | L₁₋ₐ | L₁₋ₐ | F | H | F | H | P-1 | P-1 |
| 1-542 | L₁₋ₐ | L₁₋ₐ | F | H | F | P-2 | H | tBu |
| 1-543 | L₁₋ₐ | L₁₋ₐ | F | H | F | P-2 | H | P-2 |
| 1-544 | L₁₋ₐ | L₁₋ₐ | F | H | F | H | P-2 | tBu |
| 1-545 | L₁₋ₐ | L₁₋ₐ | F | H | F | H | P-2 | P-2 |
| 1-546 | L_{1-b} | L_{1-b} | F | H | F | H | H | H |
| 1-547 | L_{1-b} | L_{1-b} | F | H | F | tBu | H | H |
| 1-548 | L_{1-b} | L_{1-b} | F | H | F | H | tBu | H |
| 1-549 | L_{1-b} | L_{1-b} | F | H | F | H | H | tBu |
| 1-550 | L_{1-b} | L_{1-b} | F | H | F | tBu | H | tBu |
| 1-551 | L_{1-b} | L_{1-b} | F | H | F | H | tBu | tBu |
| 1-552 | L_{1-b} | L_{1-b} | F | H | F | F | H | H |
| 1-553 | L_{1-b} | L_{1-b} | F | H | F | H | F | H |
| 1-554 | L_{1-b} | L_{1-b} | F | H | F | H | H | F |
| 1-555 | L_{1-b} | L_{1-b} | F | H | F | F | H | tBu |
| 1-556 | L_{1-b} | L_{1-b} | F | H | F | H | F | tBu |
| 1-557 | L_{1-b} | L_{1-b} | F | H | F | tBu | H | F |
| 1-558 | L_{1-b} | L_{1-b} | F | H | F | H | tBu | F |
| 1-559 | L_{1-b} | L_{1-b} | F | H | F | F | H | F |
| 1-560 | L_{1-b} | L_{1-b} | F | H | F | CN | H | tBu |
| 1-561 | L_{1-b} | L_{1-b} | F | H | F | H | CN | tBu |
| 1-562 | L_{1-b} | L_{1-b} | F | H | F | H | tBu | CN |
| 1-563 | L_{1-b} | L_{1-b} | F | H | F | H | Ph | tBu |
| 1-564 | L_{1-b} | L_{1-b} | F | H | F | H | Ph | Ph |
| 1-565 | L_{1-b} | L_{1-b} | F | H | F | P-1 | H | tBu |
| 1-566 | L_{1-b} | L_{1-b} | F | H | F | P-1 | H | P-1 |
| 1-567 | L_{1-b} | L_{1-b} | F | H | F | H | P-1 | tBu |
| 1-568 | L_{1-b} | L_{1-b} | F | H | F | H | P-1 | P-1 |
| 1-569 | L_{1-b} | L_{1-b} | F | H | F | P-2 | H | tBu |
| 1-570 | L_{1-b} | L_{1-b} | F | H | F | P-2 | H | P-2 |
| 1-571 | L_{1-b} | L_{1-b} | F | H | F | H | P-2 | tBu |
| 1-572 | L_{1-b} | L_{1-b} | F | H | F | H | P-2 | P-2 |
| 1-573 | O | O | F | H | F | H | H | H |
| 1-574 | O | O | F | H | F | tBu | H | H |
| 1-575 | O | O | F | H | F | H | tBu | H |
| 1-576 | O | O | F | H | F | H | H | tBu |
| 1-577 | O | O | F | H | F | tBu | H | tBu |
| 1-578 | O | O | F | H | F | H | tBu | tBu |
| 1-579 | O | O | F | H | F | F | H | H |
| 1-580 | O | O | F | H | F | H | F | H |
| 1-581 | O | O | F | H | F | H | H | F |
| 1-582 | O | O | F | H | F | F | H | tBu |
| 1-583 | O | O | F | H | F | H | F | tBu |
| 1-584 | O | O | F | H | F | tBu | H | F |
| 1-585 | O | O | F | H | F | H | tBu | F |
| 1-586 | O | O | F | H | F | F | H | F |
| 1-587 | O | O | F | H | F | CN | H | tBu |
| 1-588 | O | O | F | H | F | H | CN | tBu |
| 1-589 | O | O | F | H | F | H | tBu | CN |
| 1-590 | O | O | F | H | F | H | Ph | tBu |
| 1-591 | O | O | F | H | F | H | Ph | Ph |
| 1-592 | O | O | F | H | F | P-1 | H | tBu |
| 1-593 | O | O | F | H | F | P-1 | H | P-1 |
| 1-594 | O | O | F | H | F | H | P-1 | tBu |
| 1-595 | O | O | F | H | F | H | P-1 | P-1 |
| 1-596 | O | O | F | H | F | P-2 | H | tBu |
| 1-597 | O | O | F | H | F | P-2 | H | P-2 |
| 1-598 | O | O | F | H | F | H | P-2 | tBu |
| 1-599 | O | O | F | H | F | H | P-2 | P-2 |
| 1-600 | S | S | F | H | F | H | H | H |
| 1-601 | S | S | F | H | F | tBu | H | H |
| 1-602 | S | S | F | H | F | H | tBu | H |
| 1-603 | S | S | F | H | F | H | H | tBu |
| 1-604 | S | S | F | H | F | tBu | H | tBu |
| 1-605 | S | S | F | H | F | H | tBu | tBu |
| 1-606 | S | S | F | H | F | F | H | H |
| 1-607 | S | S | F | H | F | H | F | H |
| 1-608 | S | S | F | H | F | H | H | F |
| 1-609 | S | S | F | H | F | F | H | tBu |
| 1-610 | S | S | F | H | F | H | F | tBu |
| 1-611 | S | S | F | H | F | tBu | H | F |
| 1-612 | S | S | F | H | F | H | tBu | F |
| 1-613 | S | S | F | H | F | F | H | F |
| 1-614 | S | S | F | H | F | CN | H | tBu |
| 1-615 | S | S | F | H | F | H | CN | tBu |
| 1-616 | S | S | F | H | F | H | tBu | CN |
| 1-617 | S | S | F | H | F | H | Ph | tBu |
| 1-618 | S | S | F | H | F | H | Ph | Ph |
| 1-619 | S | S | F | H | F | P-1 | H | tBu |
| 1-620 | S | S | F | H | F | P-1 | H | P-1 |
| 1-621 | S | S | F | H | F | H | P-1 | tBu |
| 1-622 | S | S | F | H | F | H | P-1 | P-1 |
| 1-623 | S | S | F | H | F | P-2 | H | tBu |
| 1-624 | S | S | F | H | F | P-2 | H | P-2 |
| 1-625 | S | S | F | H | F | H | P-2 | tBu |
| 1-626 | S | S | F | H | F | H | P-2 | P-2 |
| 1-627 | Se | Se | F | H | F | H | H | H |
| 1-628 | Se | Se | F | H | F | tBu | H | H |
| 1-629 | Se | Se | F | H | F | H | tBu | H |
| 1-630 | Se | Se | F | H | F | H | H | tBu |
| 1-631 | Se | Se | F | H | F | tBu | H | tBu |
| 1-632 | Se | Se | F | H | F | H | tBu | tBu |
| 1-633 | L_{1-c} | L_{1-c} | F | H | F | H | H | H |
| 1-634 | L_{1-c} | L_{1-c} | F | H | F | tBu | H | H |
| 1-635 | L_{1-c} | L_{1-c} | F | H | F | H | tBu | H |
| 1-636 | L_{1-c} | L_{1-c} | F | H | F | H | H | tBu |
| 1-637 | L_{1-c} | L_{1-c} | F | H | F | tBu | H | tBu |
| 1-638 | L_{1-c} | L_{1-c} | F | H | F | H | tBu | tBu |
| 1-639 | L₁₋ₐ | L₁₋ₐ | CF₃ | H | H | H | H | H |
| 1-640 | L₁₋ₐ | L₁₋ₐ | CF₃ | H | H | tBu | H | H |
| 1-641 | L₁₋ₐ | L₁₋ₐ | CF₃ | H | H | H | tBu | H |
| 1-642 | L₁₋ₐ | L₁₋ₐ | CF₃ | H | H | H | H | Bu |
| 1-643 | L₁₋ₐ | L₁₋ₐ | CF₃ | H | H | tBu | H | tBu |
| 1-644 | L₁₋ₐ | L₁₋ₐ | CF₃ | H | H | H | tBu | tBu |
| 1-645 | L₁₋ₐ | L₁₋ₐ | CF₃ | H | H | F | H | H |
| 1-646 | L₁₋ₐ | L₁₋ₐ | CF₃ | H | H | H | F | H |
| 1-647 | L₁₋ₐ | L₁₋ₐ | CF₃ | H | H | H | H | F |
| 1-648 | L₁₋ₐ | L₁₋ₐ | CF₃ | H | H | F | H | tBu |
| 1-649 | L₁₋ₐ | L₁₋ₐ | CF₃ | H | H | H | F | tBu |
| 1-650 | L₁₋ₐ | L₁₋ₐ | CF₃ | H | H | tBu | H | F |
| 1-651 | L₁₋ₐ | L₁₋ₐ | CF₃ | H | H | H | tBu | F |
| 1-652 | L₁₋ₐ | L₁₋ₐ | CF₃ | H | H | F | H | F |
| 1-653 | L₁₋ₐ | L₁₋ₐ | CF₃ | H | H | CN | H | tBu |
| 1-654 | L₁₋ₐ | L₁₋ₐ | CF₃ | H | H | H | CN | tBu |
| 1-655 | L₁₋ₐ | L₁₋ₐ | CF₃ | H | H | H | tBu | CN |
| 1-656 | L₁₋ₐ | L₁₋ₐ | CF₃ | H | H | H | Ph | tBu |
| 1-657 | L₁₋ₐ | L₁₋ₐ | CF₃ | H | H | H | Ph | Ph |
| 1-658 | L₁₋ₐ | L₁₋ₐ | CF₃ | H | H | P-1 | H | tBu |
| 1-659 | L₁₋ₐ | L₁₋ₐ | CF₃ | H | H | P-1 | H | P-1 |
| 1-660 | L₁₋ₐ | L₁₋ₐ | CF₃ | H | H | H | P-1 | tBu |
| 1-661 | L₁₋ₐ | L₁₋ₐ | CF₃ | H | H | H | P-1 | P-1 |
| 1-662 | L₁₋ₐ | L₁₋ₐ | CF₃ | H | H | P-2 | H | tBu |
| 1-663 | L₁₋ₐ | L₁₋ₐ | CF₃ | H | H | P-2 | H | P-2 |
| 1-664 | L₁₋ₐ | L₁₋ₐ | CF₃ | H | H | H | P-2 | tBu |
| 1-665 | L₁₋ₐ | L₁₋ₐ | CF₃ | H | H | H | P-2 | P-2 |
| 1-666 | L_{1-b} | L_{1-b} | CF₃ | H | H | H | H | H |
| 1-667 | L_{1-b} | L_{1-b} | CF₃ | H | H | tBu | H | H |
| 1-668 | L_{1-b} | L_{1-b} | CF₃ | H | H | H | tBu | H |
| 1-669 | L_{1-b} | L_{1-b} | CF₃ | H | H | H | H | tBu |
| 1-670 | L_{1-b} | L_{1-b} | CF₃ | H | H | tBu | H | tBu |
| 1-671 | L_{1-b} | L_{1-b} | CF₃ | H | H | H | tBu | tBu |
| 1-672 | L_{1-b} | L_{1-b} | CF₃ | H | H | F | H | H |
| 1-673 | L_{1-b} | L_{1-b} | CF₃ | H | H | H | F | H |
| 1-674 | L_{1-b} | L_{1-b} | CF₃ | H | H | H | H | F |
| 1-675 | L_{1-b} | L_{1-b} | CF₃ | H | H | F | H | tBu |
| 1-676 | L_{1-b} | L_{1-b} | CF₃ | H | H | H | F | tBu |
| 1-677 | L_{1-b} | L_{1-b} | CF₃ | H | H | tBu | H | F |
| 1-678 | L_{1-b} | L_{1-b} | CF₃ | H | H | H | tBu | F |
| 1-679 | L_{1-b} | L_{1-b} | CF₃ | H | H | F | H | F |
| 1-680 | L_{1-b} | L_{1-b} | CF₃ | H | H | CN | H | tBu |
| 1-681 | L_{1-b} | L_{1-b} | CF₃ | H | H | H | CN | tBu |
| 1-682 | L_{1-b} | L_{1-b} | CF₃ | H | H | H | tBu | CN |
| 1-683 | L_{1-b} | L_{1-b} | CF₃ | H | H | H | Ph | tBu |
| 1-684 | L_{1-b} | L_{1-b} | CF₃ | H | H | H | Ph | Ph |
| 1-685 | L_{1-b} | L_{1-b} | CF₃ | H | H | P-1 | H | tBu |
| 1-686 | L_{1-b} | L_{1-b} | CF₃ | H | H | P-1 | H | P-1 |
| 1-687 | L_{1-b} | L_{1-b} | CF₃ | H | H | H | P-1 | tBu |
| 1-688 | L_{1-b} | L_{1-b} | CF₃ | H | H | H | P-1 | P-1 |
| 1-689 | L_{1-b} | L_{1-b} | CF₃ | H | H | P-2 | H | tBu |
| 1-690 | L_{1-b} | L_{1-b} | CF₃ | H | H | P-2 | H | P-2 |
| 1-691 | L_{1-b} | L_{1-b} | CF₃ | H | H | H | P-2 | tBu |
| 1-692 | L_{1-b} | L_{1-b} | CF₃ | H | H | H | P-2 | P-2 |
| 1-693 | O | O | CF₃ | H | H | H | H | H |
| 1-694 | O | O | CF₃ | H | H | tBu | H | H |
| 1-695 | O | O | CF₃ | H | H | H | tBu | H |
| 1-696 | O | O | CF₃ | H | H | H | H | tBu |
| 1-697 | O | O | CF₃ | H | H | tBu | H | tBu |
| 1-698 | O | O | CF₃ | H | H | H | Bu | tBu |
| 1-699 | O | O | CF₃ | H | H | F | H | H |
| 1-700 | O | O | CF₃ | H | H | H | F | H |
| 1-701 | O | O | CF₃ | H | H | H | H | F |
| 1-702 | O | O | CF₃ | H | H | F | H | tBu |
| 1-703 | O | O | CF₃ | H | H | H | F | tBu |
| 1-704 | O | O | CF₃ | H | H | tBu | H | F |
| 1-705 | O | O | CF₃ | H | H | H | tBu | F |
| 1-706 | O | O | CF₃ | H | H | F | H | F |
| 1-707 | O | O | CF₃ | H | H | CN | H | tBu |
| 1-708 | O | O | CF₃ | H | H | H | CN | tBu |
| 1-709 | O | O | CF₃ | H | H | H | tBu | CN |
| 1-710 | O | O | CF₃ | H | H | H | Ph | tBu |
| 1-711 | O | O | CF₃ | H | H | H | Ph | Ph |
| 1-712 | O | O | CF₃ | H | H | P-1 | H | tBu |
| 1-713 | O | O | CF₃ | H | H | P-1 | H | P-1 |
| 1-714 | O | O | CF₃ | H | H | H | P-1 | tBu |
| 1-715 | O | O | CF₃ | H | H | H | P-1 | P-1 |
| 1-716 | O | O | CF₃ | H | H | P-2 | H | tBu |
| 1-717 | O | O | CF₃ | H | H | P-2 | H | P-2 |
| 1-718 | O | O | CF₃ | H | H | H | P-2 | tBu |
| 1-719 | O | O | CF₃ | H | H | H | P-2 | P-2 |
| 1-720 | S | S | CF₃ | H | H | H | H | H |
| 1-721 | S | S | CF₃ | H | H | tBu | H | H |
| 1-722 | S | S | CF₃ | H | H | H | tBu | H |
| 1-723 | S | S | CF₃ | H | H | H | H | tBu |
| 1-724 | S | S | CF₃ | H | H | tBu | H | tBu |
| 1-725 | S | S | CF₃ | H | H | H | tBu | tBu |
| 1-726 | S | S | CF₃ | H | H | F | H | H |
| 1-727 | S | S | CF₃ | H | H | H | F | H |
| 1-728 | S | S | CF₃ | H | H | H | H | F |
| 1-729 | S | S | CF₃ | H | H | F | H | tBu |
| 1-730 | S | S | CF₃ | H | H | H | F | tBu |
| 1-731 | S | S | CF₃ | H | H | tBu | H | F |
| 1-732 | S | S | CF₃ | H | H | H | tBu | F |
| 1-733 | S | S | CF₃ | H | H | F | H | F |
| 1-734 | S | S | CF₃ | H | H | CN | H | tBu |
| 1-735 | S | S | CF₃ | H | H | H | CN | tBu |
| 1-736 | S | S | CF₃ | H | H | H | tBu | CN |
| 1-737 | S | S | CF₃ | H | H | H | Ph | tBu |
| 1-738 | S | S | CF₃ | H | H | H | Ph | Ph |
| 1-739 | S | S | CF₃ | H | H | P-1 | H | tBu |
| 1-740 | S | S | CF₃ | H | H | P-1 | H | P-1 |
| 1-741 | S | S | CF₃ | H | H | H | P-1 | tBu |
| 1-742 | S | S | CF₃ | H | H | H | P-1 | P-1 |
| 1-743 | S | S | CF₃ | H | H | P-2 | H | tBu |
| 1-744 | S | S | CF₃ | H | H | P-2 | H | P-2 |
| 1-745 | S | S | CF₃ | H | H | H | P-2 | tBu |
| 1-746 | S | S | CF₃ | H | H | H | P-2 | P-2 |
| 1-747 | Se | Se | CF₃ | H | H | H | H | H |
| 1-748 | Se | Se | CF₃ | H | H | tBu | H | H |
| 1-749 | Se | Se | CF₃ | H | H | H | tBu | H |
| 1-750 | Se | Se | CF₃ | H | H | H | H | tBu |
| 1-751 | Se | Se | CF₃ | H | H | tBu | H | tBu |
| 1-752 | Se | Se | CF₃ | H | H | H | tBu | tBu |
| 1-753 | L_{1-c} | L_{1-c} | CF₃ | H | H | H | H | H |
| 1-754 | L_{1-c} | L_{1-c} | CF₃ | H | H | tBu | H | H |
| 1-755 | L_{1-c} | L_{1-c} | CF₃ | H | H | H | tBu | H |
| 1-756 | L_{1-c} | L_{1-c} | CF₃ | H | H | H | H | tBu |
| 1-757 | L_{1-c} | L_{1-c} | CF₃ | H | H | tBu | H | tBu |
| 1-758 | L_{1-c} | L_{1-c} | CF₃ | H | H | H | tBu | tBu |
| 1-759 | L₁₋ₐ | L₁₋ₐ | H | CF₃ | H | H | H | H |
| 1-760 | L₁₋ₐ | L₁₋ₐ | H | CF₃ | H | tBu | H | H |
| 1-761 | L₁₋ₐ | L₁₋ₐ | H | CF₃ | H | H | tBu | H |
| 1-762 | L₁₋ₐ | L₁₋ₐ | H | CF₃ | H | H | H | tBu |
| 1-763 | L₁₋ₐ | L₁₋ₐ | H | CF₃ | H | tBu | H | tBu |
| 1-764 | L₁₋ₐ | L₁₋ₐ | H | CF₃ | H | H | tBu | tBu |
| 1-765 | L₁₋ₐ | L₁₋ₐ | H | CF₃ | H | F | H | H |
| 1-766 | L₁₋ₐ | L₁₋ₐ | H | CF₃ | H | H | F | H |
| 1-767 | L₁₋ₐ | L₁₋ₐ | H | CF₃ | H | H | H | F |
| 1-768 | L₁₋ₐ | L₁₋ₐ | H | CF₃ | H | F | H | tBu |
| 1-769 | L₁₋ₐ | L₁₋ₐ | H | CF₃ | H | H | F | tBu |
| 1-770 | L₁₋ₐ | L₁₋ₐ | H | CF₃ | H | tBu | H | F |
| 1-771 | L₁₋ₐ | L₁₋ₐ | H | CF₃ | H | H | tBu | F |
| 1-772 | L₁₋ₐ | L₁₋ₐ | H | CF₃ | H | F | H | F |
| 1-773 | L₁₋ₐ | L₁₋ₐ | H | CF₃ | H | CN | H | tBu |
| 1-774 | L₁₋ₐ | L₁₋ₐ | H | CF₃ | H | H | CN | tBu |
| 1-775 | L₁₋ₐ | L₁₋ₐ | H | CF₃ | H | H | tBu | CN |
| 1-776 | L₁₋ₐ | L₁₋ₐ | H | CF₃ | H | H | Ph | tBu |
| 1-777 | L₁₋ₐ | L₁₋ₐ | H | CF₃ | H | H | Ph | Ph |
| 1-778 | L₁₋ₐ | L₁₋ₐ | H | CF₃ | H | P-1 | H | tBu |
| 1-779 | L₁₋ₐ | L₁₋ₐ | H | CF₃ | H | P-1 | H | P-1 |
| 1-780 | L₁₋ₐ | L₁₋ₐ | H | CF₃ | H | H | P-1 | tBu |
| 1-781 | L₁₋ₐ | L₁₋ₐ | H | CF₃ | H | H | P-1 | P-1 |
| 1-782 | L₁₋ₐ | L₁₋ₐ | H | CF₃ | H | P-2 | H | tBu |
| 1-783 | L₁₋ₐ | L₁₋ₐ | H | CF₃ | H | P-2 | H | P-2 |
| 1-784 | L₁₋ₐ | L₁₋ₐ | H | CF₃ | H | H | P-2 | tBu |
| 1-785 | L₁₋ₐ | L₁₋ₐ | H | CF₃ | H | H | P-2 | P-2 |
| 1-786 | L_{1-b} | L_{1-b} | H | CF₃ | H | H | H | H |
| 1-787 | L_{1-b} | L_{1-b} | H | CF₃ | H | tBu | H | H |
| 1-788 | L_{1-b} | L_{1-b} | H | CF₃ | H | H | tBu | H |
| 1-789 | L_{1-b} | L_{1-b} | H | CF₃ | H | H | H | tBu |
| 1-790 | L_{1-b} | L_{1-b} | H | CF₃ | H | tBu | H | tBu |
| 1-791 | L_{1-b} | L_{1-b} | H | CF₃ | H | H | tBu | tBu |
| 1-792 | L_{1-b} | L_{1-b} | H | CF₃ | H | F | H | H |
| 1-793 | L_{1-b} | L_{1-b} | H | CF₃ | H | H | F | H |
| 1-794 | L_{1-b} | L_{1-b} | H | CF₃ | H | H | H | F |
| 1-795 | L_{1-b} | L_{1-b} | H | CF₃ | H | F | H | tBu |
| 1-796 | L_{1-b} | L_{1-b} | H | CF₃ | H | H | F | tBu |
| 1-797 | L_{1-b} | L_{1-b} | H | CF₃ | H | tBu | H | F |
| 1-798 | L_{1-b} | L_{1-b} | H | CF₃ | H | H | tBu | F |
| 1-799 | L_{1-b} | L_{1-b} | H | CF₃ | H | F | H | F |
| 1-800 | L_{1-b} | L_{1-b} | H | CF₃ | H | CN | H | tBu |
| 1-801 | L_{1-b} | L_{1-b} | H | CF₃ | H | H | CN | tBu |
| 1-802 | L_{1-b} | L_{1-b} | H | CF₃ | H | H | tBu | CN |
| 1-803 | L_{1-b} | L_{1-b} | H | CF₃ | H | H | Ph | tBu |
| 1-804 | L_{1-b} | L_{1-b} | H | CF₃ | H | H | Ph | Ph |
| 1-805 | L_{1-b} | L_{1-b} | H | CF₃ | H | P-1 | H | tBu |
| 1-806 | L_{1-b} | L_{1-b} | H | CF₃ | H | P-1 | H | P-1 |
| 1-807 | L_{1-b} | L_{1-b} | H | CF₃ | H | H | P-1 | tBu |
| 1-808 | L_{1-b} | L_{1-b} | H | CF₃ | H | H | P-1 | P-1 |
| 1-809 | L_{1-b} | L_{1-b} | H | CF₃ | H | P-2 | H | tBu |
| 1-810 | L_{1-b} | L_{1-b} | H | CF₃ | H | P-2 | H | P-2 |
| 1-811 | L_{1-b} | L_{1-b} | H | CF₃ | H | H | P-2 | tBu |
| 1-812 | L_{1-b} | L_{1-b} | H | CF₃ | H | H | P-2 | P-2 |
| 1-813 | O | O | H | CF₃ | H | H | H | H |
| 1-814 | O | O | H | CF₃ | H | tBu | H | H |
| 1-815 | O | O | H | CF₃ | H | H | tBu | H |
| 1-816 | O | O | H | CF₃ | H | H | H | tBu |
| 1-817 | O | O | H | CF₃ | H | tBu | H | tBu |
| 1-818 | O | O | H | CF₃ | H | H | tBu | tBu |
| 1-819 | O | O | H | CF₃ | H | F | H | H |
| 1-820 | O | O | H | CF₃ | H | H | F | H |
| 1-821 | O | O | H | CF₃ | H | H | H | F |
| 1-822 | O | O | H | CF₃ | H | F | H | tBu |
| 1-823 | O | O | H | CF₃ | H | H | F | tBu |
| 1-824 | O | O | H | CF₃ | H | tBu | H | F |
| 1-825 | O | O | H | CF₃ | H | H | tBu | F |
| 1-826 | O | O | H | CF₃ | H | F | H | F |
| 1-827 | O | O | H | CF₃ | H | CN | H | tBu |
| 1-828 | O | O | H | CF₃ | H | H | CN | tBu |
| 1-829 | O | O | H | CF₃ | H | H | tBu | CN |
| 1-830 | O | O | H | CF₃ | H | H | Ph | tBu |
| 1-831 | O | O | H | CF₃ | H | H | Ph | Ph |
| 1-832 | O | O | H | CF₃ | H | P-1 | H | tBu |
| 1-833 | O | O | H | CF₃ | H | P-1 | H | P-1 |
| 1-834 | O | O | H | CF₃ | H | H | P-1 | tBu |
| 1-835 | O | O | H | CF₃ | H | H | P-1 | P-1 |
| 1-836 | O | O | H | CF₃ | H | P-2 | H | tBu |
| 1-837 | O | O | H | CF₃ | H | P-2 | H | P-2 |
| 1-838 | O | O | H | CF₃ | H | H | P-2 | tBu |
| 1-839 | O | O | H | CF₃ | H | H | P-2 | P-2 |
| 1-840 | S | S | H | CF₃ | H | H | H | H |
| 1-841 | S | S | H | CF₃ | H | tBu | H | H |
| 1-842 | S | S | H | CF₃ | H | H | tBu | H |
| 1-843 | S | S | H | CF₃ | H | H | H | tBu |
| 1-844 | S | S | H | CF₃ | H | tBu | H | tBu |
| 1-845 | S | S | H | CF₃ | H | H | tBu | tBu |
| 1-846 | S | S | H | CF₃ | H | F | H | H |
| 1-847 | S | S | H | CF₃ | H | H | F | H |
| 1-848 | S | S | H | CF₃ | H | H | H | F |
| 1-849 | S | S | H | CF₃ | H | F | H | tBu |
| 1-850 | S | S | H | CF₃ | H | H | F | tBu |
| 1-851 | S | S | H | CF₃ | H | tBu | H | F |
| 1-852 | S | S | H | CF₃ | H | H | tBu | F |
| 1-853 | S | S | H | CF₃ | H | F | H | F |
| 1-854 | S | S | H | CF₃ | H | CN | H | tBu |
| 1-855 | S | S | H | CF₃ | H | H | CN | tBu |
| 1-856 | S | S | H | CF₃ | H | H | tBu | CN |
| 1-857 | S | S | H | CF₃ | H | H | Ph | tBu |
| 1-858 | S | S | H | CF₃ | H | H | Ph | Ph |
| 1-859 | S | S | H | CF₃ | H | P-1 | H | tBu |
| 1-860 | S | S | H | CF₃ | H | P-1 | H | P-1 |
| 1-861 | S | S | H | CF₃ | H | H | P-1 | tBu |
| 1-862 | S | S | H | CF₃ | H | H | P-1 | P-1 |
| 1-863 | S | S | H | CF₃ | H | P-2 | H | tBu |
| 1-864 | S | S | H | CF₃ | H | P-2 | H | P-2 |
| 1-865 | S | S | H | CF₃ | H | H | P-2 | tBu |
| 1-866 | S | S | H | CF₃ | H | H | P-2 | P-2 |
| 1-867 | Se | Se | H | CF₃ | H | H | H | H |
| 1-868 | Se | Se | H | CF₃ | H | tBu | H | H |
| 1-869 | Se | Se | H | CF₃ | H | H | tBu | H |
| 1-870 | Se | Se | H | CF₃ | H | H | H | tBu |
| 1-871 | Se | Se | H | CF₃ | H | tBu | H | tBu |
| 1-872 | Se | Se | H | CF₃ | H | H | tBu | tBu |
| 1-873 | L_{1-c} | L_{1-c} | H | CF₃ | H | H | H | H |
| 1-874 | L_{1-c} | L_{1-c} | H | CF₃ | H | tBu | H | H |
| 1-875 | L_{1-c} | L_{1-c} | H | CF₃ | H | H | tBu | H |
| 1-876 | L_{1-c} | L_{1-c} | H | CF₃ | H | H | H | tBu |
| 1-877 | L_{1-c} | L_{1-c} | H | CF₃ | H | tBu | H | tBu |
| 1-878 | L_{1-c} | L_{1-c} | H | CF₃ | H | H | tBu | tBu |
| 1-879 | L_{1-b} | O | H | CF₃ | H | H | H | H |
| 1-880 | L_{1-b} | O | H | CF₃ | H | tBu | H | H |
| 1-881 | L_{1-b} | O | H | CF₃ | H | H | tBu | H |
| 1-882 | L_{1-b} | O | H | CF₃ | H | H | H | tBu |
| 1-883 | L_{1-b} | O | H | CF₃ | H | tBu | H | tBu |
| 1-884 | L_{1-b} | O | H | CF₃ | H | H | tBu | tBu |
| 1-885 | L_{1-b} | S | H | CF₃ | H | H | H | H |
| 1-886 | L_{1-b} | S | H | CF₃ | H | tBu | H | H |
| 1-887 | L_{1-b} | S | H | CF₃ | H | H | tBu | H |
| 1-888 | L_{1-b} | S | H | CF₃ | H | H | H | tBu |
| 1-889 | L_{1-b} | S | H | CF₃ | H | tBu | H | tBu |
| 1-890 | L_{1-b} | S | H | CF₃ | H | H | tBu | tBu |
| 1-891 | O | S | H | CF₃ | H | H | H | H |
| 1-892 | O | S | H | CF₃ | H | tBu | H | H |
| 1-893 | O | S | H | CF₃ | H | H | tBu | H |
| 1-894 | O | S | H | CF₃ | H | H | H | tBu |
| 1-895 | O | S | H | CF₃ | H | tBu | H | tBu |
| 1-896 | O | S | H | CF₃ | H | H | tBu | tBu |
| 1-897 | L_{1-d} | L_{1-d} | H | CF₃ | H | H | tBu | tBu |
| 1-898 | L_{1-d} | L_{1-d} | H | CN | H | CN | H | tBu |

the Compound 2-1 to Compound 2-330 each have the following structure: 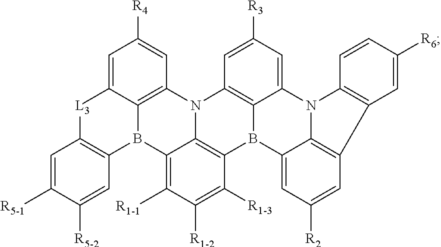
wherein R₂ and R₆ are identical, and R₃ and R₄ are identical; L₃, R₁₋₁, R₁₋₂, R₁₋₃, R₂/R₆, R₃/R₄₋₁, R₅₋₁ and R₅₋₂ are selected from atoms or groups in the following table, respectively;

| Compound | L₃ | R₁₋₁ | R₁₋₂ | R₁₋₃ | R₂/ R₆ | R₃/ R₄ | R₅₋₁ | R₅₋₂ |
|---|---|---|---|---|---|---|---|---|
| 2-1 | L_{1-b} | CN | H | H | H | H | H | H |
| 2-2 | L_{1-b} | CN | H | H | tBu | H | H | H |
| 2-3 | L_{1-b} | CN | H | H | H | tBu | H | H |
| 2-4 | L_{1-b} | CN | H | H | H | H | tBu | H |
| 2-5 | L_{1-b} | CN | H | H | H | H | H | tBu |
| 2-6 | L_{1-b} | CN | H | H | tBu | tBu | tBu | H |
| 2-7 | L_{1-b} | CN | H | H | tBu | tBu | H | tBu |
| 2-8 | L_{1-b} | CN | H | H | H | H | P-1 | H |
| 2-9 | L_{1-b} | CN | H | H | tBu | H | P-1 | H |
| 2-10 | L_{1-b} | CN | H | H | H | tBu | P-1 | H |
| 2-11 | L_{1-b} | CN | H | H | tBu | tBu | P-1 | H |
| 2-12 | L_{1-b} | CN | H | H | Ph | tBu | tBu | H |
| 2-13 | O | CN | H | H | H | H | H | H |
| 2-14 | O | CN | H | H | tBu | H | H | H |
| 2-15 | O | CN | H | H | H | tBu | H | H |
| 2-16 | O | CN | H | H | H | H | tBu | H |
| 2-17 | O | CN | H | H | H | H | H | tBu |
| 2-18 | O | CN | H | H | tBu | tBu | tBu | H |
| 2-19 | O | CN | H | H | tBu | tBu | H | tBu |
| 2-20 | O | CN | H | H | H | H | P-1 | H |
| 2-21 | O | CN | H | H | tBu | H | P-1 | H |
| 2-22 | O | CN | H | H | H | tBu | P-1 | H |
| 2-23 | O | CN | H | H | tBu | tBu | P-1 | H |
| 2-24 | O | CN | H | H | Ph | tBu | tBu | H |
| 2-25 | S | CN | H | H | H | H | H | H |
| 2-26 | S | CN | H | H | tBu | H | H | H |
| 2-27 | S | CN | H | H | H | tBu | H | H |
| 2-28 | S | CN | H | H | H | H | tBu | H |
| 2-29 | S | CN | H | H | H | H | H | tBu |
| 2-30 | S | CN | H | H | tBu | tBu | tBu | H |
| 2-31 | S | CN | H | H | tBu | tBu | H | tBu |
| 2-32 | S | CN | H | H | H | H | P-1 | H |
| 2-33 | S | CN | H | H | tBu | H | P-1 | H |
| 2-34 | S | CN | H | H | H | tBu | P-1 | H |
| 2-35 | S | CN | H | H | tBu | tBu | P-1 | H |
| 2-36 | S | CN | H | H | Ph | tBu | tBu | H |
| 2-37 | L_{1-b} | H | CN | H | H | H | H | H |
| 2-38 | L_{1-b} | H | CN | H | tBu | H | H | H |
| 2-39 | L_{1-b} | H | CN | H | H | tBu | H | H |
| 2-40 | L_{1-b} | H | CN | H | H | H | tBu | H |
| 2-41 | L_{1-b} | H | CN | H | H | H | H | tBu |
| 2-42 | L_{1-b} | H | CN | H | tBu | tBu | tBu | H |
| 2-43 | L_{1-b} | H | CN | H | tBu | tBu | H | tBu |
| 2-44 | L_{1-b} | H | CN | H | H | H | P-1 | H |
| 2-45 | L_{1-b} | H | CN | H | tBu | H | P-1 | H |
| 2-46 | L_{1-b} | H | CN | H | H | tBu | P-1 | H |
| 2-47 | L_{1-b} | H | CN | H | tBu | tBu | P-1 | H |
| 2-48 | L_{1-b} | H | CN | H | Ph | tBu | tBu | H |
| 2-49 | O | H | CN | H | H | H | H | H |
| 2-50 | O | H | CN | H | tBu | H | H | H |
| 2-51 | O | H | CN | H | H | tBu | H | H |
| 2-52 | O | H | CN | H | H | H | tBu | H |
| 2-53 | O | H | CN | H | H | H | H | tBu |
| 2-54 | O | H | CN | H | tBu | tBu | tBu | H |
| 2-55 | O | H | CN | H | tBu | tBu | H | tBu |
| 2-56 | O | H | CN | H | H | H | P-1 | H |
| 2-57 | O | H | CN | H | tBu | H | P-1 | H |
| 2-58 | O | H | CN | H | H | tBu | P-1 | H |
| 2-59 | O | H | CN | H | tBu | tBu | P-1 | H |
| 2-60 | O | H | CN | H | Ph | tBu | tBu | H |
| 2-61 | S | H | CN | H | H | H | H | H |
| 2-62 | S | H | CN | H | tBu | H | H | H |
| 2-63 | S | H | CN | H | H | tBu | H | H |
| 2-64 | S | H | CN | H | H | H | tBu | H |
| 2-65 | S | H | CN | H | H | H | H | tBu |
| 2-66 | S | H | CN | H | tBu | tBu | tBu | H |
| 2-67 | S | H | CN | H | tBu | tBu | H | tBu |
| 2-68 | S | H | CN | H | H | H | P-1 | H |
| 2-69 | S | H | CN | H | tBu | H | P-1 | H |
| 2-70 | S | H | CN | H | H | tBu | P-1 | H |
| 2-71 | S | H | CN | H | tBu | tBu | P-1 | H |
| 2-72 | S | H | CN | H | Ph | tBu | tBu | H |
| 2-73 | L_{1-b} | H | H | CN | H | H | H | H |
| 2-74 | L_{1-b} | H | H | CN | tBu | H | H | H |
| 2-75 | L_{1-b} | H | H | CN | H | tBu | H | H |
| 2-76 | L₁₋₁ | H | H | CN | H | H | tBu | H |
| 2-77 | L_{1-b} | H | H | CN | H | H | H | tBu |
| 2-78 | L_{1-b} | H | H | CN | tBu | tBu | tBu | H |
| 2-79 | L_{1-b} | H | H | CN | tBu | tBu | H | tBu |
| 2-80 | L₁₋₁ | H | H | CN | H | H | P-1 | H |
| 2-81 | L₁₋₁ | H | H | CN | tBu | H | P-1 | H |
| 2-82 | L₁₋₁ | H | H | CN | H | tBu | P-1 | H |
| 2-83 | L_{1-b} | H | H | CN | tBu | tBu | P-1 | H |
| 2-84 | L_{1-b} | H | H | CN | Ph | tBu | tBu | H |
| 2-85 | O | H | H | CN | H | H | H | H |
| 2-86 | O | H | H | CN | tBu | H | H | H |
| 2-87 | O | H | H | CN | H | tBu | H | H |
| 2-88 | O | H | H | CN | H | H | tBu | H |
| 2-89 | O | H | H | CN | H | H | H | tBu |
| 2-90 | O | H | H | CN | tBu | tBu | tBu | H |
| 2-91 | O | H | H | CN | tBu | tBu | H | tBu |
| 2-92 | O | H | H | CN | H | H | P-1 | H |
| 2-93 | O | H | H | CN | tBu | H | P-1 | H |
| 2-94 | O | H | H | CN | H | tBu | P-1 | H |
| 2-95 | O | H | H | CN | tBu | tBu | P-1 | H |
| 2-96 | O | H | H | CN | Ph | tBu | tBu | H |
| 2-97 | S | H | H | CN | H | H | H | H |
| 2-98 | S | H | H | CN | tBu | H | H | H |
| 2-99 | S | H | H | CN | H | tBu | H | H |
| 2-100 | S | H | H | CN | H | H | tBu | H |
| 2-101 | S | H | H | CN | H | H | H | tBu |
| 2-102 | S | H | H | CN | tBu | tBu | tBu | H |
| 2-103 | S | H | H | CN | tBu | tBu | H | tBu |
| 2-104 | S | H | H | CN | H | H | P-1 | H |
| 2-105 | S | H | H | CN | tBu | H | P-1 | H |
| 2-106 | S | H | H | CN | H | tBu | P-1 | H |
| 2-107 | S | H | H | CN | tBu | tBu | P-1 | H |
| 2-108 | S | H | H | CN | Ph | tBu | tBu | H |
| 2-109 | L_{1-d} | H | CN | H | tBu | tBu | tBu | H |
| 2-110 | L_{1-d} | H | CN | H | tBu | tBu | H | tBu |
| 2-111 | L_{1-b} | F | H | H | H | H | H | H |
| 2-112 | L_{1-b} | F | H | H | tBu | H | H | H |
| 2-113 | L_{1-b} | F | H | H | H | tBu | H | H |
| 2-114 | L_{1-b} | F | H | H | H | H | tBu | H |
| 2-115 | L_{1-b} | F | H | H | H | H | H | tBu |
| 2-116 | L_{1-b} | F | H | H | tBu | tBu | tBu | H |
| 2-117 | L_{1-b} | F | H | H | tBu | tBu | H | tBu |
| 2-118 | L_{1-b} | F | H | H | H | H | P-1 | H |
| 2-119 | L_{1-b} | F | H | H | tBu | H | P-1 | H |
| 2-120 | L_{1-b} | F | H | H | H | tBu | P-1 | H |
| 2-121 | L_{1-b} | F | H | H | tBu | tBu | P-1 | H |
| 2-122 | L_{1-b} | F | H | H | Ph | tBu | tBu | H |
| 2-123 | O | F | H | H | H | H | H | H |
| 2-124 | O | F | H | H | tBu | H | H | H |
| 2-125 | O | F | H | H | H | tBu | H | H |
| 2-126 | O | F | H | H | H | H | tBu | H |
| 2-127 | O | F | H | H | H | H | H | tBu |
| 2-128 | O | F | H | H | tBu | tBu | tBu | H |
| 2-129 | O | F | H | H | tBu | tBu | H | tBu |
| 2-130 | O | F | H | H | H | H | P-1 | H |
| 2-131 | O | F | H | H | tBu | H | P-1 | H |
| 2-132 | O | F | H | H | H | tBu | P-1 | H |
| 2-133 | O | F | H | H | tBu | tBu | P-1 | H |
| 2-134 | O | F | H | H | Ph | tBu | tBu | H |
| 2-135 | S | F | H | H | H | H | H | H |
| 2-136 | S | F | H | H | tBu | H | H | H |
| 2-137 | S | F | H | H | H | tBu | H | H |
| 2-138 | S | F | H | H | H | H | tBu | H |
| 2-139 | S | F | H | H | H | H | H | tBu |
| 2-140 | S | F | H | H | tBu | tBu | tBu | H |
| 2-141 | S | F | H | H | tBu | tBu | H | tBu |
| 2-142 | S | F | H | H | H | H | P-1 | H |
| 2-143 | S | F | H | H | tBu | H | P-1 | H |
| 2-144 | S | F | H | H | H | tBu | P-1 | H |
| 2-145 | S | F | H | H | tBu | tBu | P-1 | H |
| 2-146 | S | F | H | H | Ph | tBu | tBu | H |
| 2-147 | L_{1-b} | H | F | H | H | H | H | H |
| 2-148 | L_{1-b} | H | F | H | tBu | H | H | H |
| 2-149 | L_{1-b} | H | F | H | H | tBu | H | H |
| 2-150 | L_{1-b} | H | F | H | H | H | tBu | H |
| 2-151 | L_{1-b} | H | F | H | H | H | H | tBu |
| 2-152 | L_{1-b} | H | F | H | tBu | tBu | tBu | H |
| 2-153 | L_{1-b} | H | F | H | tBu | tBu | H | tBu |
| 2-154 | L_{1-b} | H | F | H | H | H | P-1 | H |
| 2-155 | L_{1-b} | H | F | H | tBu | H | P-1 | H |
| 2-156 | L_{1-b} | H | F | H | H | tBu | P-1 | H |
| 2-157 | L_{1-b} | H | F | H | tBu | tBu | P-1 | H |
| 2-158 | L_{1-b} | H | F | H | Ph | tBu | tBu | H |
| 2-159 | O | H | F | H | H | H | H | H |
| 2-160 | O | H | F | H | tBu | H | H | H |
| 2-161 | O | H | F | H | H | tBu | H | H |
| 2-162 | O | H | F | H | H | H | tBu | H |
| 2-163 | O | H | F | H | H | H | H | tBu |
| 2-164 | O | H | F | H | tBu | tBu | tBu | H |
| 2-165 | O | H | F | H | tBu | tBu | H | tBu |
| 2-166 | O | H | F | H | H | H | P-1 | H |
| 2-167 | O | H | F | H | tBu | H | P-1 | H |
| 2-168 | O | H | F | H | H | tBu | P-1 | H |
| 2-169 | O | H | F | H | tBu | tBu | P-1 | H |
| 2-170 | O | H | F | H | Ph | tBu | tBu | H |
| 2-171 | S | H | F | H | H | H | H | H |
| 2-172 | S | H | F | H | tBu | H | H | H |
| 2-173 | S | H | F | H | H | tBu | H | H |
| 2-174 | S | H | F | H | H | H | tBu | H |
| 2-175 | S | H | F | H | H | H | H | tBu |
| 2-176 | S | H | F | H | tBu | tBu | tBu | H |
| 2-177 | S | H | F | H | tBu | tBu | H | tBu |
| 2-178 | S | H | F | H | H | H | P-1 | H |
| 2-179 | S | H | F | H | tBu | H | P-1 | H |
| 2-180 | S | H | F | H | H | tBu | P-1 | H |
| 2-181 | S | H | F | H | tBu | tBu | P-1 | H |
| 2-182 | S | H | F | H | Ph | tBu | tBu | H |
| 2-183 | L_{1-b} | H | H | F | H | H | H | H |
| 2-184 | L_{1-b} | H | H | F | tBu | H | H | H |
| 2-185 | L_{1-b} | H | H | F | H | tBu | H | H |
| 2-186 | L_{1-b} | H | H | F | H | H | tBu | H |
| 2-187 | L_{1-b} | H | H | F | H | H | H | tBu |
| 2-188 | L_{1-b} | H | H | F | tBu | tBu | tBu | H |
| 2-189 | L_{1-b} | H | H | F | tBu | tBu | H | tBu |
| 2-190 | L_{1-b} | H | H | F | H | H | P-1 | H |
| 2-191 | L_{1-b} | H | H | F | tBu | H | P-1 | H |
| 2-192 | L_{1-b} | H | H | F | H | tBu | P-1 | H |
| 2-193 | L_{1-b} | H | H | F | tBu | tBu | P-1 | H |
| 2-194 | L_{1-b} | H | H | F | Ph | tBu | tBu | H |
| 2-195 | O | H | H | F | H | H | H | H |
| 2-196 | O | H | H | F | tBu | H | H | H |
| 2-197 | O | H | H | F | H | tBu | H | H |
| 2-198 | O | H | H | F | H | H | tBu | H |
| 2-199 | O | H | H | F | H | H | H | tBu |
| 2-200 | O | H | H | F | tBu | tBu | tBu | H |
| 2-201 | O | H | H | F | tBu | tBu | H | tBu |
| 2-202 | O | H | H | F | H | H | P-1 | H |
| 2-203 | O | H | H | F | tBu | H | P-1 | H |
| 2-204 | O | H | H | F | H | tBu | P-1 | H |
| 2-205 | O | H | H | F | tBu | tBu | P-1 | H |
| 2-206 | O | H | H | F | Ph | tBu | tBu | H |
| 2-207 | S | H | H | F | H | H | H | H |
| 2-208 | S | H | H | F | tBu | H | H | H |
| 2-209 | S | H | H | F | H | tBu | H | H |
| 2-210 | S | H | H | F | H | H | tBu | H |
| 2-211 | S | H | H | F | H | H | H | tBu |
| 2-212 | S | H | H | F | tBu | tBu | tBu | H |
| 2-213 | S | H | H | F | tBu | tBu | H | tBu |
| 2-214 | S | H | H | F | H | H | P-1 | H |
| 2-215 | S | H | H | F | tBu | H | P-1 | H |
| 2-216 | S | H | H | F | H | tBu | P-1 | H |
| 2-217 | S | H | H | F | tBu | tBu | P-1 | H |
| 2-218 | S | H | H | F | Ph | tBu | tBu | H |
| 2-219 | L_{1-d} | H | F | H | tBu | tBu | tBu | H |
| 2-220 | L_{1-d} | H | F | H | tBu | tBu | H | tBu |
| 2-221 | L_{1-b} | CF₃ | H | H | H | H | H | H |
| 2-222 | L_{1-b} | CF₃ | H | H | tBu | H | H | H |
| 2-223 | L_{1-b} | CF₃ | H | H | H | tBu | H | H |
| 2-224 | L_{1-b} | CF₃ | H | H | H | H | tBu | H |
| 2-225 | L_{1-b} | CF₃ | H | H | H | H | H | tBu |
| 2-226 | L_{1-b} | CF₃ | H | H | tBu | tBu | tBu | H |
| 2-227 | L_{1-b} | CF₃ | H | H | tBu | tBu | H | tBu |
| 2-228 | L_{1-b} | CF₃ | H | H | H | H | P-1 | H |
| 2-229 | L_{1-b} | CF₃ | H | H | tBu | H | P-1 | H |
| 2-230 | L_{1-b} | CF₃ | H | H | H | tBu | P-1 | H |
| 2-231 | L_{1-b} | CF₃ | H | H | tBu | tBu | P-1 | H |
| 2-232 | L_{1-b} | CF₃ | H | H | Ph | tBu | tBu | H |
| 2-233 | O | CF₃ | H | H | H | H | H | H |
| 2-234 | O | CF₃ | H | H | tBu | H | H | H |
| 2-235 | O | CF₃ | H | H | H | tBu | H | H |
| 2-236 | O | CF₃ | H | H | H | H | tBu | H |
| 2-237 | O | CF₃ | H | H | H | H | H | tBu |
| 2-238 | O | CF₃ | H | H | tBu | tBu | tBu | H |
| 2-239 | O | CF₃ | H | H | tBu | tBu | H | tBu |
| 2-240 | O | CF₃ | H | H | H | H | P-1 | H |
| 2-241 | O | CF₃ | H | H | tBu | H | P-1 | H |
| 2-242 | O | CF₃ | H | H | H | tBu | P-1 | H |
| 2-243 | O | CF₃ | H | H | tBu | tBu | P-1 | H |
| 2-244 | O | CF₃ | H | H | Ph | tBu | tBu | H |
| 2-245 | S | CF₃ | H | H | H | H | H | H |
| 2-246 | S | CF₃ | H | H | tBu | H | H | H |
| 2-247 | S | CF₃ | H | H | H | tBu | H | H |
| 2-248 | S | CF₃ | H | H | H | H | tBu | H |
| 2-249 | S | CF₃ | H | H | H | H | H | tBu |
| 2-250 | S | CF₃ | H | H | tBu | tBu | tBu | H |
| 2-251 | S | CF₃ | H | H | tBu | tBu | H | tBu |
| 2-252 | S | CF₃ | H | H | H | H | P-1 | H |
| 2-253 | S | CF₃ | H | H | tBu | H | P-1 | H |
| 2-254 | S | CF₃ | H | H | H | tBu | P-1 | H |
| 2-255 | S | CF₃ | H | H | tBu | tBu | P-1 | H |
| 2-256 | S | CF₃ | H | H | Ph | tBu | tBu | H |
| 2-257 | L_{1-b} | H | CF₃ | H | H | H | H | H |
| 2-258 | L_{1-b} | H | CF₃ | H | tBu | H | H | H |
| 2-259 | L_{1-b} | H | CF₃ | H | H | tBu | H | H |
| 2-260 | L_{1-b} | H | CF₃ | H | H | H | tBu | H |
| 2-261 | L_{1-b} | H | CF₃ | H | H | H | H | tBu |
| 2-262 | L_{1-b} | H | CF₃ | H | tBu | tBu | tBu | H |
| 2-263 | L_{1-b} | H | CF₃ | H | tBu | tBu | H | tBu |
| 2-264 | L_{1-b} | H | CF₃ | H | H | H | P-1 | H |
| 2-265 | L_{1-b} | H | CF₃ | H | tBu | H | P-1 | H |
| 2-266 | L_{1-b} | H | CF₃ | H | H | tBu | P-1 | H |
| 2-267 | L₁₋₁ | H | CF₃ | H | tBu | tBu | P-1 | H |
| 2-268 | L_{1-b} | H | CF₃ | H | Ph | tBu | tBu | H |
| 2-269 | O | H | CF₃ | H | H | H | H | H |
| 2-270 | O | H | CF₃ | H | tBu | H | H | H |
| 2-271 | O | H | CF₃ | H | H | tBu | H | H |
| 2-272 | O | H | CF₃ | H | H | H | tBu | H |
| 2-273 | O | H | CF₃ | H | H | H | H | tBu |
| 2-274 | O | H | CF₃ | H | tBu | tBu | tBu | H |
| 2-275 | O | H | CF₃ | H | tBu | tBu | H | tBu |
| 2-276 | O | H | CF₃ | H | H | H | P-1 | H |
| 2-277 | O | H | CF₃ | H | tBu | H | P-1 | H |
| 2-278 | O | H | CF₃ | H | H | tBu | P-1 | H |
| 2-279 | O | H | CF₃ | H | tBu | tBu | P-1 | H |
| 2-280 | O | H | CF₃ | H | Ph | tBu | tBu | H |
| 2-281 | S | H | CF₃ | H | H | H | H | H |
| 2-282 | S | H | CF₃ | H | tBu | H | H | H |
| 2-283 | S | H | CF₃ | H | H | tBu | H | H |
| 2-284 | S | H | CF₃ | H | H | H | tBu | H |
| 2-285 | S | H | CF₃ | H | H | H | H | tBu |
| 2-286 | S | H | CF₃ | H | tBu | tBu | tBu | H |
| 2-287 | S | H | CF₃ | H | tBu | tBu | H | tBu |
| 2-288 | S | H | CF₃ | H | H | H | P-1 | H |
| 2-289 | S | H | CF₃ | H | tBu | H | P-1 | H |
| 2-290 | S | H | CF₃ | H | H | tBu | P-1 | H |
| 2-291 | S | H | CF₃ | H | tBu | tBu | P-1 | H |
| 2-292 | S | H | CF₃ | H | Ph | tBu | tBu | H |
| 2-293 | L_{1-b} | H | H | CF₃ | H | H | H | H |
| 2-294 | L_{1-b} | H | H | CF₃ | tBu | H | H | H |
| 2-295 | L_{1-b} | H | H | CF₃ | H | tBu | H | H |
| 2-296 | L_{1-b} | H | H | CF₃ | H | H | tBu | H |
| 2-297 | L_{1-b} | H | H | CF₃ | H | H | H | tBu |
| 2-298 | L_{1-b} | H | H | CF₃ | tBu | tBu | tBu | H |
| 2-299 | L_{1-b} | H | H | CF₃ | tBu | tBu | H | tBu |
| 2-300 | L_{1-b} | H | H | CF₃ | H | H | P-1 | H |
| 2-301 | L_{1-b} | H | H | CF₃ | tBu | H | P-1 | H |
| 2-302 | L_{1-b} | H | H | CF₃ | H | tBu | P-1 | H |
| 2-303 | L_{1-b} | H | H | CF₃ | tBu | tBu | P-1 | H |
| 2-304 | L_{1-b} | H | H | CF₃ | Ph | tBu | tBu | H |
| 2-305 | O | H | H | CF₃ | H | H | H | H |
| 2-306 | O | H | H | CF₃ | tBu | H | H | H |
| 2-307 | O | H | H | CF₃ | H | tBu | H | H |
| 2-308 | O | H | H | CF₃ | H | H | tBu | H |
| 2-309 | O | H | H | CF₃ | H | H | H | tBu |
| 2-310 | O | H | H | CF₃ | tBu | tBu | tBu | H |
| 2-311 | O | H | H | CF₃ | tBu | tBu | H | tBu |
| 2-312 | O | H | H | CF₃ | H | H | P-1 | H |
| 2-313 | O | H | H | CF₃ | tBu | H | P-1 | H |
| 2-314 | O | H | H | CF₃ | H | tBu | P-1 | H |
| 2-315 | O | H | H | CF₃ | tBu | tBu | P-1 | H |
| 2-316 | O | H | H | CF₃ | Ph | tBu | tBu | H |
| 2-317 | S | H | H | CF₃ | H | H | H | H |
| 2-318 | S | H | H | CF₃ | tBu | H | H | H |
| 2-319 | S | H | H | CF₃ | H | tBu | H | H |
| 2-320 | S | H | H | CF₃ | H | H | tBu | H |
| 2-321 | S | H | H | CF₃ | H | H | H | tBu |
| 2-322 | S | H | H | CF₃ | tBu | tBu | tBu | H |
| 2-323 | S | H | H | CF₃ | tBu | tBu | H | tBu |
| 2-324 | S | H | H | CF₃ | H | H | P-1 | H |
| 2-325 | S | H | H | CF₃ | tBu | H | P-1 | H |
| 2-326 | S | H | H | CF₃ | H | tBu | P-1 | H |
| 2-327 | S | H | H | CF₃ | tBu | tBu | P-1 | H |
| 2-328 | S | H | H | CF₃ | Ph | tBu | tBu | H |
| 2-329 | L_{1-d} | H | CF₃ | H | tBu | tBu | tBu | H |
| 2-330 | L_{1-d} | H | CF₃ | H | tBu | tBu | H | tBu |

the Compound 3-1 to Compound 3-162 each have the following structure: 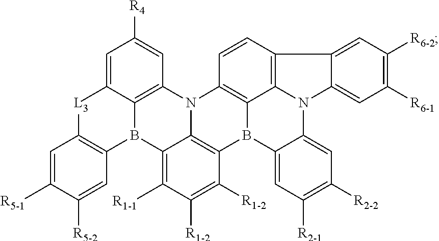
wherein R₂₋₁ and R₅₋₂ are identical, and R₂₋₂ and R₅₋₁ are identical; L₃, R₁₋₁, R₁₋₂, R₁₋₃, R₂₋₁/R₅₋₂, R₂₋₂/R₅₋₁, R₆₋₁, R₆₋₂, and R₄ are selected from atoms or groups in the following table, respectively:

| Compound | L₃ | R₁₋₁ | R₁₋₂ | R₁₋₃ | R₂₋₁/R₅₋₂ | R₂₋₂/R₅₋₁ | R₆₋₁ | R₆₋₂ | R₄ |
|---|---|---|---|---|---|---|---|---|---|
| 3-1 | L_{1-b} | CN | H | H | H | H | H | H | H |
| 3-2 | L_{1-b} | CN | H | H | tBu | H | H | H | H |
| 3-3 | L_{1-b} | CN | H | H | H | tBu | H | H | H |
| 3-4 | L_{1-b} | CN | H | H | H | H | tBu | H | H |
| 3-5 | L_{1-b} | CN | H | H | H | H | H | tBu | H |
| 3-6 | L_{1-b} | CN | H | H | H | H | H | H | tBu |
| 3-7 | L_{1-b} | CN | H | H | tBu | H | tBu | H | H |
| 3-8 | L_{1-b} | CN | H | H | tBu | H | H | tBu | H |
| 3-9 | L_{1-b} | CN | H | H | tBu | H | H | H | tBu |
| 3-10 | L_{1-b} | CN | H | H | H | tBu | tBu | H | H |
| 3-11 | L_{1-b} | CN | H | H | H | tBu | H | tBu | H |
| 3-12 | L_{1-b} | CN | H | H | H | tBu | H | H | tBu |
| 3-13 | L_{1-b} | CN | H | H | H | H | tBu | H | tBu |
| 3-14 | L_{1-b} | CN | H | H | H | H | H | tBu | tBu |
| 3-15 | L_{1-b} | CN | H | H | tBu | H | tBu | H | tBu |
| 3-16 | L_{1-b} | CN | H | H | H | H | H | tBu | tBu |
| 3-17 | L_{1-b} | CN | H | H | H | tBu | tBu | H | tBu |
| 3-18 | L_{1-b} | CN | H | H | H | tBu | H | tBu | tBu |
| 3-19 | L_{1-b} | H | CN | H | H | H | H | H | H |
| 3-20 | L_{1-b} | H | CN | H | tBu | H | H | H | H |
| 3-21 | L_{1-b} | H | CN | H | H | tBu | H | H | H |
| 3-22 | L_{1-b} | H | CN | H | H | H | tBu | H | H |
| 3-23 | L_{1-b} | H | CN | H | H | H | H | tBu | H |
| 3-24 | L_{1-b} | H | CN | H | H | H | H | H | tBu |
| 3-25 | L_{1-b} | H | CN | H | tBu | H | tBu | H | H |
| 3-26 | L_{1-b} | H | CN | H | tBu | H | H | tBu | H |
| 3-27 | L_{1-b} | H | CN | H | tBu | H | H | H | tBu |
| 3-28 | L_{1-b} | H | CN | H | H | tBu | tBu | H | H |
| 3-29 | L_{1-b} | H | CN | H | H | tBu | H | tBu | H |
| 3-30 | L_{1-b} | H | CN | H | H | tBu | H | H | tBu |
| 3-31 | L_{1-b} | H | CN | H | H | H | tBu | H | tBu |
| 3-32 | L_{1-b} | H | CN | H | H | H | H | tBu | tBu |
| 3-33 | L_{1-b} | H | CN | H | tBu | H | tBu | H | tBu |
| 3-34 | L_{1-b} | H | CN | H | H | H | H | tBu | tBu |
| 3-35 | L_{1-b} | H | CN | H | H | tBu | tBu | H | tBu |
| 3-36 | L_{1-b} | H | CN | H | H | tBu | H | tBu | tBu |
| 3-37 | L_{1-b} | H | H | CN | H | H | H | H | H |
| 3-38 | L_{1-b} | H | H | CN | tBu | H | H | H | H |
| 3-39 | L_{1-b} | H | H | CN | H | tBu | H | H | H |
| 3-40 | L_{1-b} | H | H | CN | H | H | tBu | H | H |
| 3-41 | L_{1-b} | H | H | CN | H | H | H | tBu | H |
| 3-42 | L_{1-b} | H | H | CN | H | H | H | H | tBu |
| 3-43 | L_{1-b} | H | H | CN | tBu | H | tBu | H | H |
| 3-44 | L_{1-b} | H | H | CN | tBu | H | H | tBu | H |
| 3-45 | L_{1-b} | H | H | CN | tBu | H | H | H | tBu |
| 3-46 | L_{1-b} | H | H | CN | H | tBu | tBu | H | H |
| 3-47 | L_{1-b} | H | H | CN | H | tBu | H | tBu | H |
| 3-48 | L_{1-b} | H | H | CN | H | tBu | H | H | tBu |
| 3-49 | L_{1-b} | H | H | CN | H | H | tBu | H | tBu |
| 3-50 | L_{1-b} | H | H | CN | H | H | H | tBu | tBu |
| 3-51 | L_{1-b} | H | H | CN | tBu | H | tBu | H | tBu |
| 3-52 | L_{1-b} | H | H | CN | H | H | H | tBu | tBu |
| 3-53 | L_{1-b} | H | H | CN | H | tBu | tBu | H | tBu |
| 3-54 | L_{1-b} | H | H | CN | H | tBu | H | tBu | tBu |
| 3-55 | L_{1-b} | F | H | H | H | H | H | H | H |
| 3-56 | L_{1-b} | F | H | H | tBu | H | H | H | H |
| 3-57 | L_{1-b} | F | H | H | H | tBu | H | H | H |
| 3-58 | L_{1-b} | F | H | H | H | H | tBu | H | H |
| 3-59 | L_{1-b} | F | H | H | H | H | H | tBu | H |
| 3-60 | L_{1-b} | F | H | H | H | H | H | H | tBu |
| 3-61 | L_{1-b} | F | H | H | tBu | H | tBu | H | H |
| 3-62 | L_{1-b} | F | H | H | tBu | H | H | tBu | H |
| 3-63 | L_{1-b} | F | H | H | tBu | H | H | H | tBu |
| 3-64 | L_{1-b} | F | H | H | H | tBu | tBu | H | H |
| 3-65 | L_{1-b} | F | H | H | H | tBu | H | tBu | H |
| 3-66 | L_{1-b} | F | H | H | H | tBu | H | H | tBu |
| 3-67 | L_{1-b} | F | H | H | H | H | tBu | H | tBu |
| 3-68 | L_{1-b} | F | H | H | H | H | H | tBu | tBu |
| 3-69 | L_{1-b} | F | H | H | tBu | H | tBu | H | tBu |
| 3-70 | L_{1-b} | F | H | H | H | H | H | tBu | tBu |
| 3-71 | L_{1-b} | F | H | H | H | tBu | tBu | H | tBu |
| 3-72 | L_{1-b} | F | H | H | H | tBu | H | tBu | tBu |
| 3-73 | L_{1-b} | H | F | H | H | H | H | H | H |
| 3-74 | L_{1-b} | H | F | H | tBu | H | H | H | H |
| 3-75 | L_{1-b} | H | F | H | H | tBu | H | H | H |
| 3-76 | L_{1-b} | H | F | H | H | H | tBu | H | H |
| 3-77 | L_{1-b} | H | F | H | H | H | H | tBu | H |
| 3-78 | L_{1-b} | H | F | H | H | H | H | H | tBu |
| 3-79 | L_{1-b} | H | F | H | tBu | H | tBu | H | H |
| 3-80 | L_{1-b} | H | F | H | tBu | H | H | tBu | H |
| 3-81 | L_{1-b} | H | F | H | tBu | H | H | H | tBu |
| 3-82 | L_{1-b} | H | F | H | H | tBu | tBu | H | H |
| 3-83 | L_{1-b} | H | F | H | H | tBu | H | tBu | H |
| 3-84 | L_{1-b} | H | F | H | H | tBu | H | H | tBu |
| 3-85 | L_{1-b} | H | F | H | H | H | tBu | H | tBu |
| 3-86 | L_{1-b} | H | F | H | H | H | H | tBu | tBu |
| 3-87 | L_{1-b} | H | F | H | tBu | H | tBu | H | tBu |
| 3-88 | L_{1-b} | H | F | H | H | H | H | tBu | tBu |
| 3-89 | L_{1-b} | H | F | H | H | tBu | tBu | H | tBu |
| 3-90 | L_{1-b} | H | F | H | H | tBu | H | tBu | tBu |
| 3-91 | L_{1-b} | H | H | F | H | H | H | H | H |
| 3-92 | L_{1-b} | H | H | F | tBu | H | H | H | H |
| 3-93 | L_{1-b} | H | H | F | H | tBu | H | H | H |
| 3-94 | L_{1-b} | H | H | F | H | H | tBu | H | H |
| 3-95 | L_{1-b} | H | H | F | H | H | H | tBu | H |
| 3-96 | L_{1-b} | H | H | F | H | H | H | H | tBu |
| 3-97 | L_{1-b} | H | H | F | tBu | H | tBu | H | H |
| 3-98 | L_{1-b} | H | H | F | tBu | H | H | tBu | H |
| 3-99 | L_{1-b} | H | H | F | tBu | H | H | H | tBu |
| 3-100 | L_{1-b} | H | H | F | H | tBu | tBu | H | H |
| 3-101 | L_{1-b} | H | H | F | H | tBu | H | tBu | H |
| 3-102 | L_{1-b} | H | H | F | H | tBu | H | H | tBu |
| 3-103 | L_{1-b} | H | H | F | H | H | tBu | H | tBu |
| 3-104 | L_{1-b} | H | H | F | H | H | H | tBu | tBu |
| 3-105 | L_{1-b} | H | H | F | tBu | H | tBu | H | tBu |
| 3-106 | L_{1-b} | H | H | F | H | H | H | tBu | tBu |
| 3-107 | L_{1-b} | H | H | F | H | tBu | tBu | H | tBu |
| 3-108 | L_{1-b} | H | H | F | H | tBu | H | tBu | tBu |
| 3-109 | L_{1-b} | CF₃ | H | H | H | H | H | H | H |
| 3-110 | L_{1-b} | CF₃ | H | H | tBu | H | H | H | H |
| 3-111 | L_{1-b} | CF₃ | H | H | H | tBu | H | H | H |
| 3-112 | L_{1-b} | CF₃ | H | H | H | H | tBu | H | H |
| 3-113 | L_{1-b} | CF₃ | H | H | H | H | H | tBu | H |
| 3-114 | L_{1-b} | CF₃ | H | H | H | H | H | H | tBu |
| 3-115 | L_{1-b} | CF₃ | H | H | tBu | H | tBu | H | H |
| 3-116 | L_{1-b} | CF₃ | H | H | tBu | H | H | tBu | H |
| 3-117 | L_{1-b} | CF₃ | H | H | tBu | H | H | H | tBu |
| 3-118 | L_{1-b} | CF₃ | H | H | H | tBu | tBu | H | H |
| 3-119 | L_{1-b} | CF₃ | H | H | H | tBu | H | tBu | H |
| 3-120 | L_{1-b} | CF₃ | H | H | H | tBu | H | H | tBu |
| 3-121 | L_{1-b} | CF₃ | H | H | H | H | tBu | H | tBu |
| 3-122 | L_{1-b} | CF₃ | H | H | H | H | H | tBu | tBu |
| 3-123 | L_{1-b} | CF₃ | H | H | tBu | H | tBu | H | tBu |
| 3-124 | L_{1-b} | CF₃ | H | H | H | H | H | tBu | tBu |
| 3-125 | L_{1-b} | CF₃ | H | H | H | tBu | tBu | H | tBu |
| 3-126 | L_{1-b} | CF₃ | H | H | H | tBu | H | tBu | tBu |
| 3-127 | L_{1-b} | H | CF₃ | H | H | H | H | H | H |
| 3-128 | L_{1-b} | H | CF₃ | H | tBu | H | H | H | H |
| 3-129 | L_{1-b} | H | CF₃ | H | H | tBu | H | H | H |
| 3-130 | L_{1-b} | H | CF₃ | H | H | H | tBu | H | H |
| 3-131 | L_{1-b} | H | CF₃ | H | H | H | H | tBu | H |
| 3-132 | L_{1-b} | H | CF₃ | H | H | H | H | H | tBu |
| 3-133 | L_{1-b} | H | CF₃ | H | tBu | H | tBu | H | H |
| 3-134 | L_{1-b} | H | CF₃ | H | tBu | H | H | tBu | H |
| 3-135 | L_{1-b} | H | CF₃ | H | tBu | H | H | H | tBu |
| 3-136 | L_{1-b} | H | CF₃ | H | H | tBu | tBu | H | H |
| 3-137 | L_{1-b} | H | CF₃ | H | H | tBu | H | tBu | H |
| 3-138 | L_{1-b} | H | CF₃ | H | H | tBu | H | H | tBu |
| 3-139 | L_{1-b} | H | CF₃ | H | H | H | tBu | H | tBu |
| 3-140 | L_{1-b} | H | CF₃ | H | H | H | H | tBu | tBu |
| 3-141 | L_{1-b} | H | CF₃ | H | tBu | H | tBu | H | tBu |
| 3-142 | L_{1-b} | H | CF₃ | H | H | H | H | tBu | tBu |
| 3-143 | L_{1-b} | H | CF₃ | H | H | tBu | tBu | H | tBu |
| 3-144 | L_{1-b} | H | CF₃ | H | H | tBu | H | tBu | tBu |
| 3-145 | L_{1-b} | H | H | CF₃ | H | H | H | H | H |
| 3-146 | L_{1-b} | H | H | CF₃ | tBu | H | H | H | H |
| 3-147 | L_{1-b} | H | H | CF₃ | H | tBu | H | H | H |
| 3-148 | L_{1-b} | H | H | CF₃ | H | H | tBu | H | H |
| 3-149 | L_{1-b} | H | H | CF₃ | H | H | H | tBu | H |
| 3-150 | L_{1-b} | H | H | CF₃ | H | H | H | H | tBu |
| 3-151 | L_{1-b} | H | H | CF₃ | tBu | H | tBu | H | H |
| 3-152 | L_{1-b} | H | H | CF₃ | tBu | H | H | tBu | H |
| 3-153 | L_{1-b} | H | H | CF₃ | tBu | H | H | H | tBu |
| 3-154 | L_{1-b} | H | H | CF₃ | H | tBu | tBu | H | H |
| 3-155 | L_{1-b} | H | H | CF₃ | H | tBu | H | tBu | H |
| 3-156 | L_{1-b} | H | H | CF₃ | H | tBu | H | H | tBu |
| 3-157 | L_{1-b} | H | H | CF₃ | H | H | tBu | H | tBu |
| 3-158 | L_{1-b} | H | H | CF₃ | H | H | H | tBu | tBu |
| 3-159 | L_{1-b} | H | H | CF₃ | tBu | H | tBu | H | tBu |
| 3-160 | L_{1-b} | H | H | CF₃ | H | H | H | tBu | tBu |
| 3-161 | L_{1-b} | H | H | CF₃ | H | tBu | tBu | H | tBu |
| 3-162 | L_{1-b} | H | H | CF₃ | H | tBu | H | tBu | tBu |

the Compound 4-1 to Compound 4-587 each have the following structure: 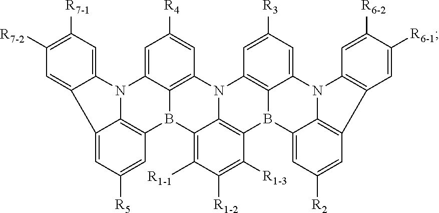
wherein R₂ and R₅ are identical, R₃ and R₄ are identical, R₆₋₁ and R₇₋₂ are identical, and R₆₋₂ and R₇₋₁ are identical; R₁₋₁, R₁₋₂, R₁₋₃, R₂/R₅, R₃/R₄, R₆₋₁/R₇₋₁, and R₆₋₂/R₇₋₁ are selected from atoms or groups in the following table, respectively;

| Compound | R₁₋₁ | R₁₋₂ | R₁₋₃ | R₂/R₅ | R₃/R₄ | R₆₋₁/R₇₋₂ | R₆₋₂/R₇₋₁ |
|---|---|---|---|---|---|---|---|
| 4-1 | CN | H | H | H | H | H | H |
| 4-2 | CN | H | H | tBu | H | H | H |
| 4-3 | CN | H | H | H | tBu | H | H |
| 4-4 | CN | H | H | H | H | tBu | H |
| 4-5 | CN | H | H | tBu | tBu | H | H |
| 4-6 | CN | H | H | H | tBu | tBu | H |
| 4-7 | CN | H | H | tBu | tBu | tBu | H |
| 4-8 | CN | H | H | Ph | H | H | H |
| 4-9 | CN | H | H | Ph | tBu | H | H |
| 4-10 | CN | H | H | Ph | H | tBu | H |
| 4-11 | CN | H | H | Ph | tBu | tBu | H |
| 4-12 | CN | H | H | F | H | H | H |
| 4-13 | CN | H | H | F | tBu | H | H |
| 4-14 | CN | H | H | F | H | tBu | H |
| 4-15 | CN | H | H | F | tBu | tBu | H |
| 4-16 | CN | H | H | P-1 | H | H | H |
| 4-17 | CN | H | H | P-1 | tBu | H | H |
| 4-18 | CN | H | H | P-1 | H | tBu | H |
| 4-19 | CN | H | H | P-1 | tBu | tBu | H |
| 4-20 | CN | H | H | P-2 | H | H | H |
| 4-21 | CN | H | H | P-2 | tBu | H | H |
| 4-22 | CN | H | H | P-2 | H | tBu | H |
| 4-23 | CN | H | H | P-2 | tBu | tBu | H |
| 4-24 | CN | H | H | P-3 | H | H | H |
| 4-25 | CN | H | H | P-3 | tBu | H | H |
| 4-26 | CN | H | H | P-3 | H | tBu | H |
| 4-27 | CN | H | H | P-3 | tBu | tBu | H |
| 4-28 | CN | H | H | P-4 | H | H | H |
| 4-29 | CN | H | H | P-4 | tBu | H | H |
| 4-30 | CN | H | H | P-4 | H | tBu | H |
| 4-31 | CN | H | H | P-4 | tBu | tBu | H |
| 4-32 | CN | H | H | P-5 | H | H | H |
| 4-33 | CN | H | H | P-5 | tBu | H | H |
| 4-34 | CN | H | H | P-5 | H | tBu | H |
| 4-35 | CN | H | H | P-5 | tBu | tBu | H |
| 4-36 | CN | H | H | H | Ph | H | H |
| 4-37 | CN | H | H | tBu | Ph | H | H |
| 4-38 | CN | H | H | H | Ph | tBu | H |
| 4-39 | CN | H | H | tBu | Ph | tBu | H |
| 4-40 | CN | H | H | H | F | H | H |
| 4-41 | CN | H | H | tBu | F | H | H |
| 4-42 | CN | H | H | H | F | tBu | H |
| 4-43 | CN | H | H | tBu | F | tBu | H |
| 4-44 | CN | H | H | H | P-1 | H | H |
| 4-45 | CN | H | H | tBu | P-1 | H | H |
| 4-46 | CN | H | H | H | P-1 | tBu | H |
| 4-47 | CN | H | H | tBu | P-1 | tBu | H |
| 4-48 | CN | H | H | H | P-2 | H | H |
| 4-49 | CN | H | H | tBu | P-2 | H | H |
| 4-50 | CN | H | H | H | P-2 | tBu | H |
| 4-51 | CN | H | H | tBu | P-2 | tBu | H |
| 4-52 | CN | H | H | H | P-3 | H | H |
| 4-53 | CN | H | H | tBu | P-3 | H | H |
| 4-54 | CN | H | H | H | P-3 | tBu | H |
| 4-55 | CN | H | H | tBu | P-3 | tBu | H |
| 4-56 | CN | H | H | H | P-4 | H | H |
| 4-57 | CN | H | H | tBu | P-4 | H | H |
| 4-58 | CN | H | H | H | P-4 | tBu | H |
| 4-59 | CN | H | H | tBu | P-4 | tBu | H |
| 4-60 | CN | H | H | H | P-5 | H | H |
| 4-61 | CN | H | H | tBu | P-5 | H | H |
| 4-62 | CN | H | H | H | P-5 | tBu | H |
| 4-63 | CN | H | H | tBu | P-5 | tBu | H |
| 4-64 | CN | H | H | H | H | Ph | H |
| 4-65 | CN | H | H | tBu | H | Ph | H |
| 4-66 | CN | H | H | H | tBu | Ph | H |
| 4-67 | CN | H | H | tBu | tBu | Ph | H |
| 4-68 | CN | H | H | H | H | F | H |
| 4-69 | CN | H | H | tBu | H | F | H |
| 4-70 | CN | H | H | H | tBu | F | H |
| 4-71 | CN | H | H | tBu | tBu | F | H |
| 4-72 | CN | H | H | H | H | P-1 | H |
| 4-73 | CN | H | H | tBu | H | P-1 | H |
| 4-74 | CN | H | H | H | tBu | P-1 | H |
| 4-75 | CN | H | H | tBu | tBu | P-1 | H |
| 4-76 | CN | H | H | H | H | P-2 | H |
| 4-77 | CN | H | H | tBu | H | P-2 | H |
| 4-78 | CN | H | H | H | tBu | P-2 | H |
| 4-79 | CN | H | H | tBu | tBu | P-2 | H |
| 4-80 | CN | H | H | H | H | P-3 | H |
| 4-81 | CN | H | H | tBu | H | P-3 | H |
| 4-82 | CN | H | H | H | tBu | P-3 | H |
| 4-83 | CN | H | H | tBu | tBu | P-3 | H |
| 4-84 | CN | H | H | H | H | P-4 | H |
| 4-85 | CN | H | H | tBu | H | P-4 | H |
| 4-86 | CN | H | H | H | tBu | P-4 | H |
| 4-87 | CN | H | H | tBu | tBu | P-4 | H |
| 4-88 | CN | H | H | H | H | P-5 | H |
| 4-89 | CN | H | H | tBu | H | P-5 | H |
| 4-90 | CN | H | H | H | tBu | P-5 | H |
| 4-91 | CN | H | H | tBu | tBu | P-5 | H |
| 4-92 | CN | H | H | P-3 | P-3 | H | H |
| 4-93 | CN | H | H | P-3 | H | P-3 | H |
| 4-94 | CN | H | H | P-3 | P-3 | P-3 | H |
| 4-95 | H | CN | H | H | H | H | H |
| 4-96 | H | CN | H | tBu | H | H | H |
| 4-97 | H | CN | H | H | tBu | H | H |
| 4-98 | H | CN | H | H | H | tBu | H |
| 4-99 | H | CN | H | tBu | tBu | H | H |
| 4-100 | H | CN | H | H | tBu | tBu | H |
| 4-101 | H | CN | H | tBu | tBu | tBu | H |
| 4-102 | H | CN | H | Ph | H | H | H |
| 4-103 | H | CN | H | Ph | tBu | H | H |
| 4-104 | H | CN | H | Ph | H | tBu | H |
| 4-105 | H | CN | H | Ph | tBu | tBu | H |
| 4-106 | H | CN | H | F | H | H | H |
| 4-107 | H | CN | H | F | tBu | H | H |
| 4-108 | H | CN | H | F | H | tBu | H |
| 4-109 | H | CN | H | F | tBu | tBu | H |
| 4-110 | H | CN | H | P-1 | H | H | H |
| 4-111 | H | CN | H | P-1 | tBu | H | H |
| 4-112 | H | CN | H | P-1 | H | tBu | H |
| 4-113 | H | CN | H | P-1 | tBu | tBu | H |
| 4-114 | H | CN | H | P-2 | H | H | H |
| 4-115 | H | CN | H | P-2 | tBu | H | H |
| 4-116 | H | CN | H | P-2 | H | tBu | H |
| 4-117 | H | CN | H | P-2 | tBu | tBu | H |
| 4-118 | H | CN | H | P-3 | H | H | H |
| 4-119 | H | CN | H | P-3 | tBu | H | H |
| 4-120 | H | CN | H | P-3 | H | tBu | H |
| 4-121 | H | CN | H | P-3 | tBu | tBu | H |
| 4-122 | H | CN | H | P-4 | H | H | H |
| 4-123 | H | CN | H | P-4 | tBu | H | H |
| 4-124 | H | CN | H | P-4 | H | tBu | H |
| 4-125 | H | CN | H | P-4 | tBu | tBu | H |
| 4-126 | H | CN | H | P-5 | H | H | H |
| 4-127 | H | CN | H | P-5 | tBu | H | H |
| 4-128 | H | CN | H | P-5 | H | tBu | H |
| 4-129 | H | CN | H | P-5 | tBu | tBu | H |
| 4-130 | H | CN | H | H | Ph | H | H |
| 4-131 | H | CN | H | tBu | Ph | H | H |
| 4-132 | H | CN | H | H | Ph | tBu | H |
| 4-133 | H | CN | H | tBu | Ph | tBu | H |
| 4-134 | H | CN | H | H | F | H | H |
| 4-135 | H | CN | H | tBu | F | H | H |
| 4-136 | H | CN | H | H | F | tBu | H |
| 4-137 | H | CN | H | tBu | F | tBu | H |
| 4-138 | H | CN | H | H | P-1 | H | H |
| 4-139 | H | CN | H | tBu | P-1 | H | H |
| 4-140 | H | CN | H | H | P-1 | tBu | H |
| 4-141 | H | CN | H | tBu | P-1 | tBu | H |
| 4-142 | H | CN | H | H | P-2 | H | H |
| 4-143 | H | CN | H | tBu | P-2 | H | H |
| 4-144 | H | CN | H | H | P-2 | tBu | H |
| 4-145 | H | CN | H | tBu | P-2 | tBu | H |
| 4-146 | H | CN | H | H | P-3 | H | H |
| 4-147 | H | CN | H | tBu | P-3 | H | H |
| 4-148 | H | CN | H | H | P-3 | tBu | H |
| 4-149 | H | CN | H | tBu | P-3 | tBu | H |
| 4-150 | H | CN | H | H | P-4 | H | H |
| 4-151 | H | CN | H | tBu | P-4 | H | H |
| 4-152 | H | CN | H | H | P-4 | tBu | H |
| 4-153 | H | CN | H | tBu | P-4 | tBu | H |
| 4-154 | H | CN | H | H | P-5 | H | H |
| 4-155 | H | CN | H | tBu | P-5 | H | H |
| 4-156 | H | CN | H | H | P-5 | tBu | H |
| 4-157 | H | CN | H | tBu | P-5 | tBu | H |
| 4-158 | H | CN | H | H | H | Ph | H |
| 4-159 | H | CN | H | tBu | H | Ph | H |
| 4-160 | H | CN | H | H | tBu | Ph | H |
| 4-161 | H | CN | H | tBu | tBu | Ph | H |
| 4-162 | H | CN | H | H | H | F | H |
| 4-163 | H | CN | H | tBu | H | F | H |
| 4-164 | H | CN | H | H | tBu | F | H |
| 4-165 | H | CN | H | tBu | tBu | F | H |
| 4-166 | H | CN | H | H | H | P-1 | H |
| 4-167 | H | CN | H | tBu | H | P-1 | H |
| 4-168 | H | CN | H | H | tBu | P-1 | H |
| 4-169 | H | CN | H | tBu | tBu | P-1 | H |
| 4-170 | H | CN | H | H | H | P-2 | H |
| 4-171 | H | CN | H | tBu | H | P-2 | H |
| 4-172 | H | CN | H | H | tBu | P-2 | H |
| 4-173 | H | CN | H | tBu | tBu | P-2 | H |
| 4-174 | H | CN | H | H | H | P-3 | H |
| 4-175 | H | CN | H | tBu | H | P-3 | H |
| 4-176 | H | CN | H | H | tBu | P-3 | H |
| 4-177 | H | CN | H | tBu | tBu | P-3 | H |
| 4-178 | H | CN | H | H | H | P-4 | H |
| 4-179 | H | CN | H | tBu | H | P-4 | H |
| 4-180 | H | CN | H | H | tBu | P-4 | H |
| 4-181 | H | CN | H | tBu | tBu | P-4 | H |
| 4-182 | H | CN | H | H | H | P-5 | H |
| 4-183 | H | CN | H | tBu | H | P-5 | H |
| 4-184 | H | CN | H | H | tBu | P-5 | H |
| 4-185 | H | CN | H | tBu | tBu | P-5 | H |
| 4-186 | H | CN | H | P-3 | P-3 | H | H |
| 4-187 | H | CN | H | P-3 | H | P-3 | H |
| 4-188 | H | CN | H | P-3 | P-3 | P-3 | H |
| 4-189 | H | CN | H | H | H | H | tBu |
| 4-190 | H | CN | H | tBu | H | H | tBu |
| 4-191 | H | CN | H | H | tBu | H | tBu |
| 4-192 | H | CN | H | tBu | tBu | H | tBu |
| 4-193 | H | CN | H | F | H | H | tBu |
| 4-194 | H | CN | H | F | tBu | H | tBu |
| 4-195 | F | H | H | H | H | H | H |
| 4-196 | F | H | H | tBu | H | H | H |
| 4-197 | F | H | H | H | tBu | H | H |
| 4-198 | F | H | H | H | H | tBu | H |
| 4-199 | F | H | H | tBu | tBu | H | H |
| 4-200 | F | H | H | H | tBu | tBu | H |
| 4-201 | F | H | H | tBu | tBu | tBu | H |
| 4-202 | F | H | H | Ph | H | H | H |
| 4-203 | F | H | H | Ph | tBu | H | H |
| 4-204 | F | H | H | Ph | H | tBu | H |
| 4-205 | F | H | H | Ph | tBu | tBu | H |
| 4-206 | F | H | H | F | H | H | H |
| 4-207 | F | H | H | F | tBu | H | H |
| 4-208 | F | H | H | F | H | tBu | H |
| 4-209 | F | H | H | F | tBu | tBu | H |
| 4-210 | F | H | H | P-1 | H | H | H |
| 4-211 | F | H | H | P-1 | tBu | H | H |
| 4-212 | F | H | H | P-1 | H | tBu | H |
| 4-213 | F | H | H | P-1 | tBu | tBu | H |
| 4-214 | F | H | H | P-2 | H | H | H |
| 4-215 | F | H | H | P-2 | tBu | H | H |
| 4-216 | F | H | H | P-2 | H | tBu | H |
| 4-217 | F | H | H | P-2 | tBu | tBu | H |
| 4-218 | F | H | H | P-3 | H | H | H |
| 4-219 | F | H | H | P-3 | tBu | H | H |
| 4-220 | F | H | H | P-3 | H | tBu | H |
| 4-221 | F | H | H | P-3 | tBu | tBu | H |
| 4-222 | F | H | H | P-4 | H | H | H |
| 4-223 | F | H | H | P-4 | tBu | H | H |
| 4-224 | F | H | H | P-4 | H | tBu | H |
| 4-225 | F | H | H | P-4 | tBu | tBu | H |
| 4-226 | F | H | H | P-5 | H | H | H |
| 4-227 | F | H | H | P-5 | tBu | H | H |
| 4-228 | F | H | H | P-5 | H | tBu | H |
| 4-229 | F | H | H | P-5 | tBu | tBu | H |
| 4-230 | F | H | H | H | Ph | H | H |
| 4-231 | F | H | H | tBu | Ph | H | H |
| 4-232 | F | H | H | H | Ph | tBu | H |
| 4-233 | F | H | H | tBu | Ph | tBu | H |
| 4-234 | F | H | H | H | F | H | H |
| 4-235 | F | H | H | tBu | F | H | H |
| 4-236 | F | H | H | H | F | tBu | H |
| 4-237 | F | H | H | tBu | F | tBu | H |
| 4-238 | F | H | H | H | P-1 | H | H |
| 4-239 | F | H | H | tBu | P-1 | H | H |
| 4-240 | F | H | H | H | P-1 | tBu | H |
| 4-241 | F | H | H | tBu | P-1 | tBu | H |
| 4-242 | F | H | H | H | P-2 | H | H |
| 4-243 | F | H | H | tBu | P-2 | H | H |
| 4-244 | F | H | H | H | P-2 | tBu | H |
| 4-245 | F | H | H | tBu | P-2 | tBu | H |
| 4-246 | F | H | H | H | P-3 | H | H |
| 4-247 | F | H | H | tBu | P-3 | H | H |
| 4-248 | F | H | H | H | P-3 | tBu | H |
| 4-249 | F | H | H | tBu | P-3 | tBu | H |
| 4-250 | F | H | H | H | P-4 | H | H |
| 4-251 | F | H | H | tBu | P-4 | H | H |
| 4-252 | F | H | H | H | P-4 | tBu | H |
| 4-253 | F | H | H | tBu | P-4 | tBu | H |
| 4-254 | F | H | H | H | P-5 | H | H |
| 4-255 | F | H | H | tBu | P-5 | H | H |
| 4-256 | F | H | H | H | P-5 | tBu | H |
| 4-257 | F | H | H | tBu | P-5 | tBu | H |
| 4-258 | F | H | H | H | H | Ph | H |
| 4-259 | F | H | H | tBu | H | Ph | H |
| 4-260 | F | H | H | H | tBu | Ph | H |
| 4-261 | F | H | H | tBu | tBu | Ph | H |
| 4-262 | F | H | H | H | H | F | H |
| 4-263 | F | H | H | tBu | H | F | H |
| 4-264 | F | H | H | H | tBu | F | H |
| 4-265 | F | H | H | tBu | tBu | F | H |
| 4-266 | F | H | H | H | H | P-1 | H |
| 4-267 | F | H | H | tBu | H | P-1 | H |
| 4-268 | F | H | H | H | tBu | P-1 | H |
| 4-269 | F | H | H | tBu | tBu | P-1 | H |
| 4-270 | F | H | H | H | H | P-2 | H |
| 4-271 | F | H | H | tBu | H | P-2 | H |
| 4-272 | F | H | H | H | tBu | P-2 | H |
| 4-273 | F | H | H | tBu | tBu | P-2 | H |
| 4-274 | F | H | H | H | H | P-3 | H |
| 4-275 | F | H | H | tBu | H | P-3 | H |
| 4-276 | F | H | H | H | tBu | P-3 | H |
| 4-277 | F | H | H | tBu | tBu | P-3 | H |
| 4-278 | F | H | H | H | H | P-4 | H |
| 4-279 | F | H | H | tBu | H | P-4 | H |
| 4-280 | F | H | H | H | tBu | P-4 | H |
| 4-281 | F | H | H | tBu | tBu | P-4 | H |
| 4-282 | F | H | H | H | H | P-5 | H |
| 4-283 | F | H | H | tBu | H | P-5 | H |
| 4-284 | F | H | H | H | tBu | P-5 | H |
| 4-285 | F | H | H | tBu | tBu | P-5 | H |
| 4-286 | F | H | H | P-3 | P-3 | H | H |
| 4-287 | F | H | H | P-3 | H | P-3 | H |
| 4-288 | F | H | H | P-3 | P-3 | P-3 | H |
| 4-289 | H | F | H | H | H | H | H |
| 4-290 | H | F | H | tBu | H | H | H |
| 4-291 | H | F | H | H | tBu | H | H |
| 4-292 | H | F | H | H | H | tBu | H |
| 4-293 | H | F | H | tBu | tBu | H | H |
| 4-294 | H | F | H | H | tBu | tBu | H |
| 4-295 | H | F | H | tBu | tBu | tBu | H |
| 4-296 | H | F | H | Ph | H | H | H |
| 4-297 | H | F | H | Ph | tBu | H | H |
| 4-298 | H | F | H | Ph | H | tBu | H |
| 4-299 | H | F | H | Ph | tBu | tBu | H |
| 4-300 | H | F | H | F | H | H | H |
| 4-301 | H | F | H | F | tBu | H | H |
| 4-302 | H | F | H | F | H | tBu | H |
| 4-303 | H | F | H | F | tBu | tBu | H |
| 4-304 | H | F | H | P-1 | H | H | H |
| 4-305 | H | F | H | P-1 | tBu | H | H |
| 4-306 | H | F | H | P-1 | H | tBu | H |
| 4-307 | H | F | H | P-1 | tBu | tBu | H |
| 4-308 | H | F | H | P-2 | H | H | H |
| 4-309 | H | F | H | P-2 | tBu | H | H |
| 4-310 | H | F | H | P-2 | H | tBu | H |
| 4-311 | H | F | H | P-2 | tBu | tBu | H |
| 4-312 | H | F | H | P-3 | H | H | H |
| 4-313 | H | F | H | P-3 | tBu | H | H |
| 4-314 | H | F | H | P-3 | H | tBu | H |
| 4-315 | H | F | H | P-3 | tBu | tBu | H |
| 4-316 | H | F | H | P-4 | H | H | H |
| 4-317 | H | F | H | P-4 | tBu | H | H |
| 4-318 | H | F | H | P-4 | H | tBu | H |
| 4-319 | H | F | H | P-4 | tBu | tBu | H |
| 4-320 | H | F | H | P-5 | H | H | H |
| 4-321 | H | F | H | P-5 | tBu | H | H |
| 4-322 | H | F | H | P-5 | H | tBu | H |
| 4-323 | H | F | H | P-5 | tBu | tBu | H |
| 4-324 | H | F | H | H | Ph | H | H |
| 4-325 | H | F | H | tBu | Ph | H | H |
| 4-326 | H | F | H | H | Ph | tBu | H |
| 4-327 | H | F | H | tBu | Ph | tBu | H |
| 4-328 | H | F | H | H | F | H | H |
| 4-329 | H | F | H | tBu | F | H | H |
| 4-330 | H | F | H | H | F | tBu | H |
| 4-331 | H | F | H | tBu | F | tBu | H |
| 4-332 | H | F | H | H | P-1 | H | H |
| 4-333 | H | F | H | tBu | P-1 | H | H |
| 4-334 | H | F | H | H | P-1 | tBL | H |
| 4-335 | H | F | H | tBu | P-1 | tBu | H |
| 4-336 | H | F | H | H | P-2 | H | H |
| 4-337 | H | F | H | tBu | P-2 | H | H |
| 4-338 | H | F | H | H | P-2 | tBu | H |
| 4-339 | H | F | H | tBu | P-2 | tBu | H |
| 4-340 | H | F | H | H | P-3 | H | H |
| 4-341 | H | F | H | tBu | P-3 | H | H |
| 4-342 | H | F | H | H | P-3 | tBu | H |
| 4-343 | H | F | H | tBu | P-3 | tBu | H |
| 4-344 | H | F | H | H | P-4 | H | H |
| 4-345 | H | F | H | tBu | P-4 | H | H |
| 4-346 | H | F | H | H | P-4 | tBu | H |
| 4-347 | H | F | H | tBu | P-4 | tBu | H |
| 4-348 | H | F | H | H | P-5 | H | H |
| 4-349 | H | F | H | tBu | P-5 | H | H |
| 4-350 | H | F | H | H | P-5 | tBu | H |
| 4-351 | H | F | H | tBu | P-5 | tBu | H |
| 4-352 | H | F | H | H | H | Ph | H |
| 4-353 | H | F | H | tBu | H | Ph | H |
| 4-354 | H | F | H | H | tBu | Ph | H |
| 4-355 | H | F | H | tBu | tBu | Ph | H |
| 4-356 | H | F | H | H | H | F | H |
| 4-357 | H | F | H | tBu | H | F | H |
| 4-358 | H | F | H | H | tBu | F | H |
| 4-359 | H | F | H | tBu | tBu | F | H |
| 4-360 | H | F | H | H | H | P-1 | H |
| 4-361 | H | F | H | tBu | H | P-1 | H |
| 4-362 | H | F | H | H | tBu | P-1 | H |
| 4-363 | H | F | H | tBu | tBu | P-1 | H |
| 4-364 | H | F | H | H | H | P-2 | H |
| 4-365 | H | F | H | tBu | H | P-2 | H |
| 4-366 | H | F | H | H | tBu | P-2 | H |
| 4-367 | H | F | H | tBu | tBu | P-2 | H |
| 4-368 | H | F | H | H | H | P-3 | H |
| 4-369 | H | F | H | tBu | H | P-3 | H |
| 4-370 | H | F | H | H | tBu | P-3 | H |
| 4-371 | H | F | H | tBu | tBu | P-3 | H |
| 4-372 | H | F | H | H | H | P-4 | H |
| 4-373 | H | F | H | tBu | H | P-4 | H |
| 4-374 | H | F | H | H | tBu | P-4 | H |
| 4-375 | H | F | H | tBu | tBu | P-4 | H |
| 4-376 | H | F | H | H | H | P-5 | H |
| 4-377 | H | F | H | tBu | H | P-5 | H |
| 4-378 | H | F | H | H | tBu | P-5 | H |
| 4-379 | H | F | H | tBu | tBu | P-5 | H |
| 4-380 | H | F | H | P-3 | P-3 | H | H |
| 4-381 | H | F | H | P-3 | H | P-3 | H |
| 4-382 | H | F | H | P-3 | P-3 | P-3 | H |
| 4-383 | H | F | H | H | H | H | tBu |
| 4-384 | H | F | H | tBu | H | H | tBu |
| 4-385 | H | F | H | H | tBu | H | tBu |
| 4-386 | H | F | H | tBu | tBu | H | tBu |
| 4-387 | H | F | H | F | H | H | tBu |
| 4-388 | H | F | H | F | tBu | H | tBu |
| 4-389 | F | H | F | H | H | H | H |
| 4-390 | F | H | F | tBu | H | H | H |
| 4-391 | F | H | F | H | tBu | H | H |
| 4-392 | F | H | F | H | H | tBu | H |
| 4-393 | F | H | F | tBu | tBu | H | H |
| 4-394 | F | H | F | H | tBu | tBu | H |
| 4-395 | F | H | F | tBu | tBu | tBu | H |
| 4-396 | CF₃ | H | H | H | H | H | H |
| 4-397 | CF₃ | H | H | tBu | H | H | H |
| 4-398 | CF₃ | H | H | H | tBu | H | H |
| 4-399 | CF₃ | H | H | H | H | Bu | H |
| 4-400 | CF₃ | H | H | tBu | tBu | H | H |
| 4-401 | CF₃ | H | H | H | tBu | tBu | H |
| 4-402 | CF₃ | H | H | tBu | tBu | tBu | H |
| 4-403 | CF₃ | H | H | Ph | H | H | H |
| 4-404 | CF₃ | H | H | Ph | tBu | H | H |
| 4-405 | CF₃ | H | H | Ph | H | tBu | H |
| 4-406 | CF₃ | H | H | Ph | tBu | tBu | H |
| 4-407 | CF₃ | H | H | F | H | H | H |
| 4-408 | CF₃ | H | H | F | tBu | H | H |
| 4-409 | CF₃ | H | H | F | H | tBu | H |
| 4-410 | CF₃ | H | H | F | tBu | tBu | H |
| 4-411 | CF₃ | H | H | P-1 | H | H | H |
| 4-412 | CF₃ | H | H | P-1 | tBu | H | H |
| 4-413 | CF₃ | H | H | P-1 | H | tBu | H |
| 4-414 | CF₃ | H | H | P-1 | tBu | tBu | H |
| 4-415 | CF₃ | H | H | P-2 | H | H | H |
| 4-416 | CF₃ | H | H | P-2 | tBu | H | H |
| 4-417 | CF₃ | H | H | P-2 | H | tBu | H |
| 4-418 | CF₃ | H | H | P-2 | tBu | tBu | H |
| 4-419 | CF₃ | H | H | P-3 | H | H | H |
| 4-420 | CF₃ | H | H | P-3 | tBu | H | H |
| 4-421 | CF₃ | H | H | P-3 | H | tBu | H |
| 4-422 | CF₃ | H | H | P-3 | tBu | tBu | H |
| 4-423 | CF₃ | H | H | P-4 | H | H | H |
| 4-424 | CF₃ | H | H | P-4 | tBu | H | H |
| 4-425 | CF₃ | H | H | P-4 | H | tBu | H |
| 4-426 | CF₃ | H | H | P-4 | tBu | tBu | H |
| 4-427 | CF₃ | H | H | P-5 | H | H | H |
| 4-428 | CF₃ | H | H | P-5 | tBu | H | H |
| 4-429 | CF₃ | H | H | P-5 | H | tBu | H |
| 4-430 | CF₃ | H | H | P-5 | tBu | tBu | H |
| 4-431 | CF₃ | H | H | H | Ph | H | H |
| 4-432 | CF₃ | H | H | tBu | Ph | H | H |
| 4-433 | CF₃ | H | H | H | Ph | tBu | H |
| 4-434 | CF₃ | H | H | tBu | Ph | tBu | H |
| 4-435 | CF₃ | H | H | H | F | H | H |
| 4-436 | CF₃ | H | H | tBu | F | H | H |
| 4-437 | CF₃ | H | H | H | F | tBu | H |
| 4-438 | CF₃ | H | H | tBu | F | tBu | H |
| 4-439 | CF₃ | H | H | H | P-1 | H | H |
| 4-440 | CF₃ | H | H | tBu | P-1 | H | H |
| 4-441 | CF₃ | H | H | H | P-1 | tBu | H |
| 4-442 | CF₃ | H | H | tBu | P-1 | tBu | H |
| 4-443 | CF₃ | H | H | H | P-2 | H | H |
| 4-444 | CF₃ | H | H | tBu | P-2 | H | H |
| 4-445 | CF₃ | H | H | H | P-2 | tBu | H |
| 4-446 | CF₃ | H | H | tBu | P-2 | tBu | H |
| 4-447 | CF₃ | H | H | H | P-3 | H | H |
| 4-448 | CF₃ | H | H | tBu | P-3 | H | H |
| 4-449 | CF₃ | H | H | H | P-3 | tBu | H |
| 4-450 | CF₃ | H | H | tBu | P-3 | tBu | H |
| 4-451 | CF₃ | H | H | H | P-4 | H | H |
| 4-452 | CF₃ | H | H | tBu | P-4 | H | H |
| 4-453 | CF₃ | H | H | H | P-4 | tBu | H |
| 4-454 | CF₃ | H | H | tBu | P-4 | tBu | H |
| 4-455 | CF₃ | H | H | H | P-5 | H | H |
| 4-456 | CF₃ | H | H | tBu | P-5 | H | H |
| 4-457 | CF₃ | H | H | H | P-5 | tBu | H |
| 4-458 | CF₃ | H | H | tBu | P-5 | tBu | H |
| 4-459 | CF₃ | H | H | H | H | Ph | H |
| 4-460 | CF₃ | H | H | tBu | H | Ph | H |
| 4-461 | CF₃ | H | H | H | tBu | Ph | H |
| 4-462 | CF₃ | H | H | tBu | tBu | Ph | H |
| 4-463 | CF₃ | H | H | H | H | F | H |
| 4-464 | CF₃ | H | H | tBu | H | F | H |
| 4-465 | CF₃ | H | H | H | tBu | F | H |
| 4-466 | CF₃ | H | H | tBu | tBu | F | H |
| 4-467 | CF₃ | H | H | H | H | P-1 | H |
| 4-468 | CF₃ | H | H | tBu | H | P-1 | H |
| 4-469 | CF₃ | H | H | H | tBu | P-1 | H |
| 4-470 | CF₃ | H | H | tBu | tBu | P-1 | H |
| 4-471 | CF₃ | H | H | H | H | P-2 | H |
| 4-472 | CF₃ | H | H | tBu | H | P-2 | H |
| 4-473 | CF₃ | H | H | H | tBu | P-2 | H |
| 4-474 | CF₃ | H | H | tBu | tBu | P-2 | H |
| 4-475 | CF₃ | H | H | H | H | P-3 | H |
| 4-476 | CF₃ | H | H | tBu | H | P-3 | H |
| 4-477 | CF₃ | H | H | H | tBu | P-3 | H |
| 4-478 | CF₃ | H | H | tBu | tBu | P-3 | H |
| 4-479 | CF₃ | H | H | H | H | P-4 | H |
| 4-480 | CF₃ | H | H | tBu | H | P-4 | H |
| 4-481 | CF₃ | H | H | H | tBu | P-4 | H |
| 4-482 | CF₃ | H | H | tBu | tBu | P-4 | H |
| 4-483 | CF₃ | H | H | H | H | P-5 | H |
| 4-484 | CF₃ | H | H | tBu | H | P-5 | H |
| 4-485 | CF₃ | H | H | H | tBu | P-5 | H |
| 4-486 | CF₃ | H | H | tBu | tBu | P-5 | H |
| 4-487 | CF₃ | H | H | P-3 | P-3 | H | H |
| 4-488 | CF₃ | H | H | P-3 | H | P-3 | H |
| 4-489 | CF₃ | H | H | P-3 | P-3 | P-3 | H |
| 4-490 | H | CF₃ | H | H | H | H | H |
| 4-491 | H | CF₃ | H | tBu | H | H | H |
| 4-492 | H | CF₃ | H | H | tBu | H | H |
| 4-493 | H | CF₃ | H | H | H | tBu | H |
| 4-494 | H | CF₃ | H | tBu | tBu | H | H |
| 4-495 | H | CF₃ | H | H | tBu | tBu | H |
| 4-496 | H | CF₃ | H | tBu | tBu | tBu | H |
| 4-497 | H | CF₃ | H | Ph | H | H | H |
| 4-498 | H | CF₃ | H | Ph | tBu | H | H |
| 4-499 | H | CF₃ | H | Ph | H | tBu | H |
| 4-500 | H | CF₃ | H | Ph | tBu | tBu | H |
| 4-501 | H | CF₃ | H | F | H | H | H |
| 4-502 | H | CF₃ | H | F | tBu | H | H |
| 4-503 | H | CF₃ | H | F | H | tBu | H |
| 4-504 | H | CF₃ | H | F | tBu | tBu | H |
| 4-505 | H | CF₃ | H | P-1 | H | H | H |
| 4-506 | H | CF₃ | H | P-1 | tBu | H | H |
| 4-507 | H | CF₃ | H | P-1 | H | tBu | H |
| 4-508 | H | CF₃ | H | P-1 | tBu | tBu | H |
| 4-509 | H | CF₃ | H | P-2 | H | H | H |
| 4-510 | H | CF₃ | H | P-2 | tBu | H | H |
| 4-511 | H | CF₃ | H | P-2 | H | tBu | H |
| 4-512 | H | CF₃ | H | P-2 | tBu | tBu | H |
| 4-513 | H | CF₃ | H | P-3 | H | H | H |
| 4-514 | H | CF₃ | H | P-3 | tBu | H | H |
| 4-515 | H | CF₃ | H | P-3 | H | tBu | H |
| 4-516 | H | CF₃ | H | P-3 | tBu | tBu | H |
| 4-517 | H | CF₃ | H | P-4 | H | H | H |
| 4-518 | H | CF₃ | H | P-4 | tBu | H | H |
| 4-519 | H | CF₃ | H | P-4 | H | tBu | H |
| 4-520 | H | CF₃ | H | P-4 | tBu | tBu | H |
| 4-521 | H | CF₃ | H | P-5 | H | H | H |
| 4-522 | H | CF₃ | H | P-5 | tBu | H | H |
| 4-523 | H | CF₃ | H | P-5 | H | tBu | H |
| 4-524 | H | CF₃ | H | P-5 | tBu | tBu | H |
| 4-525 | H | CF₃ | H | H | Ph | H | H |
| 4-526 | H | CF₃ | H | tBu | Ph | H | H |
| 4-527 | H | CF₃ | H | H | Ph | tBu | H |
| 4-528 | H | CF₃ | H | tBu | Ph | tBu | H |
| 4-529 | H | CF₃ | H | H | F | H | H |
| 4-530 | H | CF₃ | H | tBu | F | H | H |
| 4-531 | H | CF₃ | H | H | F | tBu | H |
| 4-532 | H | CF₃ | H | tBu | F | tBu | H |
| 4-533 | H | CF₃ | H | H | P-1 | H | H |
| 4-534 | H | CF₃ | H | tBu | P-1 | H | H |
| 4-535 | H | CF₃ | H | H | P-1 | tBu | H |
| 4-536 | H | CF₃ | H | tBu | P-1 | tBu | H |
| 4-537 | H | CF₃ | H | H | P-2 | H | H |
| 4-538 | H | CF₃ | H | tBu | P-2 | H | H |
| 4-539 | H | CF₃ | H | H | P-2 | tBu | H |
| 4-540 | H | CF₃ | H | tBu | P-2 | tBu | H |
| 4-541 | H | CF₃ | H | H | P-3 | H | H |
| 4-542 | H | CF₃ | H | tBu | P-3 | H | H |
| 4-543 | H | CF₃ | H | H | P-3 | tBu | H |
| 4-544 | H | CF₃ | H | tBu | P-3 | tBu | H |
| 4-545 | H | CF₃ | H | H | P-4 | H | H |
| 4-546 | H | CF₃ | H | tBu | P-4 | H | H |
| 4-547 | H | CF₃ | H | H | P-4 | tBu | H |
| 4-548 | H | CF₃ | H | tBu | P-4 | tBu | H |
| 4-549 | H | CF₃ | H | H | P-5 | H | H |
| 4-550 | H | CF₃ | H | tBu | P-5 | H | H |
| 4-551 | H | CF₃ | H | H | P-5 | tBu | H |
| 4-552 | H | CF₃ | H | tBu | P-5 | tBu | H |
| 4-553 | H | CF₃ | H | H | H | Ph | H |
| 4-554 | H | CF₃ | H | tBu | H | Ph | H |
| 4-555 | H | CF₃ | H | H | tBu | Ph | H |
| 4-556 | H | CF₃ | H | tBu | tBu | Ph | H |
| 4-557 | H | CF₃ | H | H | H | F | H |
| 4-558 | H | CF₃ | H | tBu | H | F | H |
| 4-559 | H | CF₃ | H | H | tBu | F | H |
| 4-560 | H | CF₃ | H | tBu | tBu | F | H |
| 4-561 | H | CF₃ | H | H | H | P-1 | H |
| 4-562 | H | CF₃ | H | tBu | H | P-1 | H |
| 4-563 | H | CF₃ | H | H | tBu | P-1 | H |
| 4-564 | H | CF₃ | H | tBu | tBu | P-1 | H |
| 4-565 | H | CF₃ | H | H | H | P-2 | H |
| 4-566 | H | CF₃ | H | tBu | H | P-2 | H |
| 4-567 | H | CF₃ | H | H | tBu | P-2 | H |
| 4-568 | H | CF₃ | H | tBu | tBu | P-2 | H |
| 4-569 | H | CF₃ | H | H | H | P-3 | H |
| 4-570 | H | CF₃ | H | tBu | H | P-3 | H |
| 4-571 | H | CF₃ | H | H | tBu | P-3 | H |
| 4-572 | H | CF₃ | H | tBu | tBu | P-3 | H |
| 4-573 | H | CF₃ | H | H | H | P-4 | H |
| 4-574 | H | CF₃ | H | tBu | H | P-4 | H |
| 4-575 | H | CF₃ | H | H | tBu | P-4 | H |
| 4-576 | H | CF₃ | H | tBu | tBu | P-4 | H |
| 4-577 | H | CF₃ | H | H | H | P-5 | H |
| 4-578 | H | CF₃ | H | tBu | H | P-5 | H |
| 4-579 | H | CF₃ | H | H | tBu | P-5 | H |
| 4-580 | H | CF₃ | H | tBu | tBu | P-5 | H |
| 4-581 | H | CF₃ | H | P-3 | P-3 | H | H |
| 4-582 | H | CF₃ | H | P-3 | H | P-3 | H |
| 4-583 | H | CF₃ | H | P-3 | P-3 | P-3 | H |
| 4-584 | H | CN | H | CN | H | tBu | tBu |
| 4-585 | H | CN | H | CN | tBu | H | tBu |
| 4-586 | H | F | H | CN | H | tBu | tBu |
| 4-587 | H | F | H | CN | tBu | H | tBu |

the Compound 5-1 to Compound 5-270 each have the following structure: 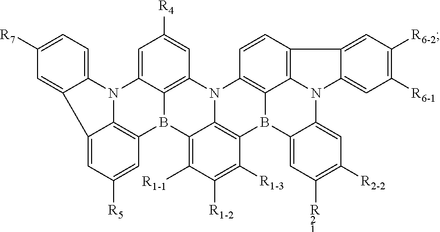
wherein R₇ and R₅ are identical; R₁₋₁, R₁₋₂, R₁₋₃, R₂₋₁, R₂₋₂, R₆₋₁, R₆₋₂, R₄, and R₇/R₅ are selected from atoms or groups in the following table, respectively;

| Compound | R₁₋₁ | R₁₋₂ | R₁₋₃ | R₂₋₁ | R₂₋₂ | R₆₋₁ | R₆₋₂ | R₄ | R₇/R₅ |
|---|---|---|---|---|---|---|---|---|---|
| 5-1 | CN | H | H | H | H | H | H | H | H |
| 5-2 | CN | H | H | tBu | H | H | H | H | H |
| 5-3 | CN | H | H | H | tBu | H | H | H | H |
| 5-4 | CN | H | H | H | H | tBu | H | H | H |
| 5-5 | CN | H | H | H | H | H | tBu | H | H |
| 5-6 | CN | H | H | H | H | H | H | tBu | H |
| 5-7 | CN | H | H | H | H | H | H | H | tBu |
| 5-8 | CN | H | H | tBu | H | tBu | H | H | H |
| 5-9 | CN | H | H | tBu | H | H | tBu | H | H |
| 5-10 | CN | H | H | tBu | H | H | H | tBu | H |
| 5-11 | CN | H | H | tBu | H | H | H | H | tBu |
| 5-12 | CN | H | H | H | tBu | tBu | H | H | H |
| 5-13 | CN | H | H | H | tBu | H | tBu | H | H |
| 5-14 | CN | H | H | H | tBu | H | H | tBu | H |
| 5-15 | CN | H | H | H | tBu | H | H | H | tBu |
| 5-16 | CN | H | H | H | H | tBu | H | tBu | H |
| 5-17 | CN | H | H | H | H | tBu | H | H | tBu |
| 5-18 | CN | H | H | H | H | H | tBu | tBu | H |
| 5-19 | CN | H | H | H | H | H | tBu | H | tBu |
| 5-20 | CN | H | H | H | H | H | H | tBu | tBu |
| 5-21 | CN | H | H | tBu | H | tBu | H | tBu | H |
| 5-22 | CN | H | H | tBu | H | tBu | H | H | tBu |
| 5-23 | CN | H | H | tBu | H | H | tBu | tBu | H |
| 5-24 | CN | H | H | tBu | H | H | tBu | H | tBu |
| 5-25 | CN | H | H | H | tBu | tBu | H | tBu | H |
| 5-26 | CN | H | H | H | tBu | tBu | H | H | tBu |
| 5-27 | CN | H | H | H | tBu | H | tBu | tBu | H |
| 5-28 | CN | H | H | H | tBu | H | tBu | H | tBu |
| 5-29 | CN | H | H | H | H | tBu | H | tBu | tBu |
| 5-30 | CN | H | H | H | H | H | tBu | tBu | tBu |
| 5-31 | H | CN | H | H | H | H | H | H | H |
| 5-32 | H | CN | H | tBu | H | H | H | H | H |
| 5-33 | H | CN | H | H | tBu | H | H | H | H |
| 5-34 | H | CN | H | H | H | tBu | H | H | H |
| 5-35 | H | CN | H | H | H | H | tBu | H | H |
| 5-36 | H | CN | H | H | H | H | H | tBu | H |
| 5-37 | H | CN | H | H | H | H | H | H | tBu |
| 5-38 | H | CN | H | tBu | H | tBu | H | H | H |
| 5-39 | H | CN | H | tBu | H | H | tBu | H | H |
| 5-40 | H | CN | H | tBu | H | H | H | tBu | H |
| 5-41 | H | CN | H | tBu | H | H | H | H | tBu |
| 5-42 | H | CN | H | H | tBu | tBu | H | H | H |
| 5-43 | H | CN | H | H | tBu | H | tBu | H | H |
| 5-44 | H | CN | H | H | tBu | H | H | tBu | H |
| 5-45 | H | CN | H | H | tBu | H | H | H | tBu |
| 5-46 | H | CN | H | H | H | tBu | H | tBu | H |
| 5-47 | H | CN | H | H | H | tBu | H | H | tBu |
| 5-48 | H | CN | H | H | H | H | tBu | tBu | H |
| 5-49 | H | CN | H | H | H | H | tBu | H | tBu |
| 5-50 | H | CN | H | H | H | H | H | tBu | tBu |
| 5-51 | H | CN | H | tBu | H | tBu | H | tBu | H |
| 5-52 | H | CN | H | tBu | H | tBu | H | H | tBu |
| 5-53 | H | CN | H | tBu | H | H | tBu | tBu | H |
| 5-54 | H | CN | H | tBu | H | H | tBu | H | tBu |
| 5-55 | H | CN | H | H | tBu | tBu | H | tBu | H |
| 5-56 | H | CN | H | H | tBu | tBu | H | H | tBu |
| 5-57 | H | CN | H | H | tBu | H | tBu | tBu | H |
| 5-58 | H | CN | H | H | tBu | H | tBu | H | tBu |
| 5-59 | H | CN | H | H | H | tBu | H | tBu | tBu |
| 5-60 | H | CN | H | H | H | H | tBu | tBu | tBu |
| 5-61 | H | H | CN | H | H | H | H | H | H |
| 5-62 | H | H | CN | tBu | H | H | H | H | H |
| 5-63 | H | H | CN | H | tBu | H | H | H | H |
| 5-64 | H | H | CN | H | H | tBu | H | H | H |
| 5-65 | H | H | CN | H | H | H | tBu | H | H |
| 5-66 | H | H | CN | H | H | H | H | tBu | H |
| 5-67 | H | H | CN | H | H | H | H | H | tBu |
| 5-68 | H | H | CN | tBu | H | tBu | H | H | H |
| 5-69 | H | H | CN | tBu | H | H | tBu | H | H |
| 5-70 | H | H | CN | tBu | H | H | H | tBu | H |
| 5-71 | H | H | CN | tBu | H | H | H | H | tBu |
| 5-72 | H | H | CN | H | tBu | tBu | H | H | H |
| 5-73 | H | H | CN | H | tBu | H | tBu | H | H |
| 5-74 | H | H | CN | H | tBu | H | H | tBu | H |
| 5-75 | H | H | CN | H | tBu | H | H | H | tBu |
| 5-76 | H | H | CN | H | H | tBu | H | tBu | H |
| 5-77 | H | H | CN | H | H | tBu | H | H | tBu |
| 5-78 | H | H | CN | H | H | H | tBu | tBu | H |
| 5-79 | H | H | CN | H | H | H | tBu | H | tBu |
| 5-80 | H | H | CN | H | H | H | H | tBu | tBu |
| 5-81 | H | H | CN | tBu | H | tBu | H | tBu | H |
| 5-82 | H | H | CN | tBu | H | tBu | H | H | tBu |
| 5-83 | H | H | CN | tBu | H | H | tBu | tBu | H |
| 5-84 | H | H | CN | tBu | H | H | tBu | H | tBu |
| 5-85 | H | H | CN | H | tBu | tBu | H | tBu | H |
| 5-86 | H | H | CN | H | tBu | tBu | H | H | tBu |
| 5-87 | H | H | CN | H | tBu | H | tBu | tBu | H |
| 5-88 | H | H | CN | H | tBu | H | tBu | H | tBu |
| 5-89 | H | H | CN | H | H | tBu | H | tBu | tBu |
| 5-90 | H | H | CN | H | H | H | tBu | tBu | tBu |
| 5-91 | F | H | H | H | H | H | H | H | H |
| 5-92 | F | H | H | tBu | H | H | H | H | H |
| 5-93 | F | H | H | H | tBu | H | H | H | H |
| 5-94 | F | H | H | H | H | tBu | H | H | H |
| 5-95 | F | H | H | H | H | H | tBu | H | H |
| 5-96 | F | H | H | H | H | H | H | tBu | H |
| 5-97 | F | H | H | H | H | H | H | H | tBu |
| 5-98 | F | H | H | tBu | H | tBu | H | H | H |
| 5-99 | F | H | H | tBu | H | H | tBu | H | H |
| 5-100 | F | H | H | tBu | H | H | H | tBu | H |
| 5-101 | F | H | H | tBu | H | H | H | H | tBu |
| 5-102 | F | H | H | H | tBu | tBu | H | H | H |
| 5-103 | F | H | H | H | tBu | H | tBu | H | H |
| 5-104 | F | H | H | H | tBu | H | H | tBu | H |
| 5-105 | F | H | H | H | tBu | H | H | H | tBu |
| 5-106 | F | H | H | H | H | tBu | H | tBu | H |
| 5-107 | F | H | H | H | H | tBu | H | H | tBu |
| 5-108 | F | H | H | H | H | H | tBu | tBu | H |
| 5-109 | F | H | H | H | H | H | tBu | H | tBu |
| 5-110 | F | H | H | H | H | H | H | tBu | tBu |
| 5-111 | F | H | H | tBu | H | tBu | H | tBu | H |
| 5-112 | F | H | H | tBu | H | tBu | H | H | tBu |
| 5-113 | F | H | H | tBu | H | H | tBu | tBu | H |
| 5-114 | F | H | H | tBu | H | H | tBu | H | tBu |
| 5-115 | F | H | H | H | tBu | tBu | H | tBu | H |
| 5-116 | F | H | H | H | tBu | tBu | H | H | tBu |
| 5-117 | F | H | H | H | tBu | H | tBu | tBu | H |
| 5-118 | F | H | H | H | tBu | H | tBu | H | tBu |
| 5-119 | F | H | H | H | H | tBu | H | tBu | tBl |
| 5-120 | F | H | H | H | H | H | tBu | tBu | tBu |
| 5-121 | H | F | H | H | H | H | H | H | H |
| 5-122 | H | F | H | tBu | H | H | H | H | H |
| 5-123 | H | F | H | H | tBu | H | H | H | H |
| 5-124 | H | F | H | H | H | tBu | H | H | H |
| 5-125 | H | F | H | H | H | H | tBu | H | H |
| 5-126 | H | F | H | H | H | H | H | tBu | H |
| 5-127 | H | F | H | H | H | H | H | H | tBu |
| 5-128 | H | F | H | tBu | H | tBu | H | H | H |
| 5-129 | H | F | H | tBu | H | H | tBu | H | H |
| 5-130 | H | F | H | tBu | H | H | H | tBu | H |
| 5-131 | H | F | H | tBu | H | H | H | H | tBu |
| 5-132 | H | F | H | H | tBu | tBu | H | H | H |
| 5-133 | H | F | H | H | tBu | H | tBu | H | H |
| 5-134 | H | F | H | H | tBu | H | H | tBu | H |
| 5-135 | H | F | H | H | tBu | H | H | H | tBu |
| 5-136 | H | F | H | H | H | tBu | H | tBu | H |
| 5-137 | H | F | H | H | H | tBu | H | H | tBu |
| 5-138 | H | F | H | H | H | H | tBu | tBu | H |
| 5-139 | H | F | H | H | H | H | tBu | H | tBu |
| 5-140 | H | F | H | H | H | H | H | tBu | tBu |
| 5-141 | H | F | H | tBu | H | tBu | H | tBu | H |
| 5-142 | H | F | H | tBu | H | tBu | H | H | tBu |
| 5-143 | H | F | H | tBu | H | H | tBu | tBu | H |
| 5-144 | H | F | H | tBu | H | H | tBu | H | tBu |
| 5-145 | H | F | H | H | tBu | tBu | H | tBu | H |
| 5-146 | H | F | H | H | tBu | tBu | H | H | tBu |
| 5-147 | H | F | H | H | tBu | H | tBu | tBu | H |
| 5-148 | H | F | H | H | tBu | H | tBu | H | tBu |
| 5-149 | H | F | H | H | H | tBu | H | tBu | tBu |
| 5-150 | H | F | H | H | H | H | tBu | tBu | tBu |
| 5-151 | H | H | F | H | H | H | H | H | H |
| 5-152 | H | H | F | tBu | H | H | H | H | H |
| 5-153 | H | H | F | H | tBu | H | H | H | H |
| 5-154 | H | H | F | H | H | tBu | H | H | H |
| 5-155 | H | H | F | H | H | H | tBu | H | H |
| 5-156 | H | H | F | H | H | H | H | tBu | H |
| 5-157 | H | H | F | H | H | H | H | H | tBu |
| 5-158 | H | H | F | tBu | H | tBu | H | H | H |
| 5-159 | H | H | F | tBu | H | H | tBu | H | H |
| 5-160 | H | H | F | tBu | H | H | H | tBu | H |
| 5-161 | H | H | F | tBu | H | H | H | H | tBu |
| 5-162 | H | H | F | H | tBu | tBu | H | H | H |
| 5-163 | H | H | F | H | tBu | H | tBu | H | H |
| 5-164 | H | H | F | H | tBu | H | H | tBu | H |
| 5-165 | H | H | F | H | tBu | H | H | H | tBu |
| 5-166 | H | H | F | H | H | tBu | H | tBu | H |
| 5-167 | H | H | F | H | H | tBu | H | H | tBu |
| 5-168 | H | H | F | H | H | H | tBl | tBu | H |
| 5-169 | H | H | F | H | H | H | tBu | H | tBu |
| 5-170 | H | H | F | H | H | H | H | tBu | tBu |
| 5-171 | H | H | F | tBu | H | tBu | H | tBu | H |
| 5-172 | H | H | F | tBu | H | tBu | H | H | tBu |
| 5-173 | H | H | F | tBu | H | H | tBu | tBu | H |
| 5-174 | H | H | F | tBu | H | H | tBu | H | tBu |
| 5-175 | H | H | F | H | tBu | tBu | H | tBu | H |
| 5-176 | H | H | F | H | tBu | tBu | H | H | tBu |
| 5-177 | H | H | F | H | tBu | H | tBu | tBu | H |
| 5-178 | H | H | F | H | tBu | H | tBu | H | tBu |
| 5-179 | H | H | F | H | H | tBu | H | tBu | tBu |
| 5-180 | H | H | F | H | H | H | tBu | tBu | tBu |
| 5-181 | CF₃ | H | H | H | H | H | H | H | H |
| 5-182 | CF₃ | H | H | tBu | H | H | H | H | H |
| 5-183 | CF₃ | H | H | H | tBu | H | H | H | H |
| 5-184 | CF₃ | H | H | H | H | tBu | H | H | H |
| 5-185 | CF₃ | H | H | H | H | H | tBu | H | H |
| 5-186 | CF₃ | H | H | H | H | H | H | tBu | H |
| 5-187 | CF₃ | H | H | H | H | H | H | H | tBu |
| 5-188 | CF₃ | H | H | tBu | H | tBu | H | H | H |
| 5-189 | CF₃ | H | H | tBu | H | H | tBu | H | H |
| 5-190 | CF₃ | H | H | tBu | H | H | H | tBu | H |
| 5-191 | CF₃ | H | H | tBu | H | H | H | H | tBu |
| 5-192 | CF₃ | H | H | H | tBu | tBu | H | H | H |
| 5-193 | CF₃ | H | H | H | tBu | H | tBu | H | H |
| 5-194 | CF₃ | H | H | H | tBu | H | H | tBu | H |
| 5-195 | CF₃ | H | H | H | tBu | H | H | H | tBu |
| 5-196 | CF₃ | H | H | H | H | tBu | H | tBu | H |
| 5-197 | CF₃ | H | H | H | H | tBu | H | H | tBu |
| 5-198 | CF₃ | H | H | H | H | H | tBu | tBu | H |
| 5-199 | CF₃ | H | H | H | H | H | tBu | H | tBu |
| 5-200 | CF₃ | H | H | H | H | H | H | tBu | tBu |
| 5-201 | CF₃ | H | H | tBu | H | tBu | H | tBu | H |
| 5-202 | CF₃ | H | H | tBu | H | tBu | H | H | tBu |
| 5-203 | CF₃ | H | H | tBu | H | H | tBu | tBu | H |
| 5-204 | CF₃ | H | H | tBu | H | H | tBu | H | tBu |
| 5-205 | CF₃ | H | H | H | tBu | tBu | H | tBu | H |
| 5-206 | CF₃ | H | H | H | tBu | tBu | H | H | tBu |
| 5-207 | CF₃ | H | H | H | tBu | H | tBu | tBu | H |
| 5-208 | CF₃ | H | H | H | tBu | H | tBu | H | tBu |
| 5-209 | CF₃ | H | H | H | H | tBu | H | tBu | tBu |
| 5-210 | CF₃ | H | H | H | H | H | tBu | tBu | tBu |
| 5-211 | H | CF₃ | H | H | H | H | H | H | H |
| 5-212 | H | CF₃ | H | tBu | H | H | H | H | H |
| 5-213 | H | CF₃ | H | H | tBu | H | H | H | H |
| 5-214 | H | CF₃ | H | H | H | tBu | H | H | H |
| 5-215 | H | CF₃ | H | H | H | H | tBu | H | H |
| 5-216 | H | CF₃ | H | H | H | H | H | tBu | H |
| 5-217 | H | CF₃ | H | H | H | H | H | H | tBu |
| 5-218 | H | CF₃ | H | tBu | H | tBu | H | H | H |
| 5-219 | H | CF₃ | H | tBu | H | H | tBu | H | H |
| 5-220 | H | CF₃ | H | tBu | H | H | H | tBu | H |
| 5-221 | H | CF₃ | H | tBu | H | H | H | H | tBu |
| 5-222 | H | CF₃ | H | H | tBu | tBu | H | H | H |
| 5-223 | H | CF₃ | H | H | tBu | H | tBu | H | H |
| 5-224 | H | CF₃ | H | H | tBu | H | H | tBu | H |
| 5-225 | H | CF₃ | H | H | tBu | H | H | H | tBu |
| 5-226 | H | CF₃ | H | H | H | tBu | H | tBu | H |
| 5-227 | H | CF₃ | H | H | H | tBu | H | H | tBu |
| 5-228 | H | CF₃ | H | H | H | H | tBu | tBu | H |
| 5-229 | H | CF₃ | H | H | H | H | tBu | H | tBu |
| 5-230 | H | CF₃ | H | H | H | H | H | tBu | tBu |
| 5-231 | H | CF₃ | H | tBu | H | tBu | H | tBu | H |
| 5-232 | H | CF₃ | H | tBu | H | tBu | H | H | tBu |
| 5-233 | H | CF₃ | H | tBu | H | H | tBu | tBu | H |
| 5-234 | H | CF₃ | H | tBu | H | H | tBu | H | tBu |
| 5-235 | H | CF₃ | H | H | tBu | tBu | H | tBu | H |
| 5-236 | H | CF₃ | H | H | tBu | tBu | H | H | tBu |
| 5-237 | H | CF₃ | H | H | tBu | H | tBu | tBu | H |
| 5-238 | H | CF₃ | H | H | tBu | H | tBu | H | tBu |
| 5-239 | H | CF₃ | H | H | H | tBu | H | tBu | tBu |
| 5-240 | H | CF₃ | H | H | H | H | tBu | tBu | tBu |
| 5-241 | H | H | CF₃ | H | H | H | H | H | H |
| 5-242 | H | H | CF₃ | tBu | H | H | H | H | H |
| 5-243 | H | H | CF₃ | H | tBu | H | H | H | H |
| 5-244 | H | H | CF₃ | H | H | tBu | H | H | H |
| 5-245 | H | H | CF₃ | H | H | H | tBu | H | H |
| 5-246 | H | H | CF₃ | H | H | H | H | tBu | H |
| 5-247 | H | H | CF₃ | H | H | H | H | H | tBu |
| 5-248 | H | H | CF₃ | tBu | H | tBu | H | H | H |
| 5-249 | H | H | CF₃ | tBu | H | H | tBu | H | H |
| 5-250 | H | H | CF₃ | tBu | H | H | H | tBu | H |
| 5-251 | H | H | CF₃ | tBu | H | H | H | H | tBu |
| 5-252 | H | H | CF₃ | H | tBu | tBu | H | H | H |
| 5-253 | H | H | CF₃ | H | tBu | H | tBu | H | H |
| 5-254 | H | H | CF₃ | H | tBu | H | H | tBu | H |
| 5-255 | H | H | CF₃ | H | tBu | H | H | H | tBu |
| 5-256 | H | H | CF₃ | H | H | tBu | H | tBu | H |
| 5-257 | H | H | CF₃ | H | H | tBu | H | H | tBu |
| 5-258 | H | H | CF₃ | H | H | H | tBu | tBu | H |
| 5-259 | H | H | CF₃ | H | H | H | tBu | H | tBu |
| 5-260 | H | H | CF₃ | H | H | H | H | tBu | tBu |
| 5-261 | H | H | CF₃ | tBu | H | tBu | H | tBu | H |
| 5-262 | H | H | CF₃ | tBu | H | tBu | H | H | tBu |
| 5-263 | H | H | CF₃ | tBu | H | H | tBu | tBu | H |
| 5-264 | H | H | CF₃ | tBu | H | H | tBu | H | tBu |
| 5-265 | H | H | CF₃ | H | tBu | tBu | H | tBl | H |
| 5-266 | H | H | CF₃ | H | tBu | tBu | H | H | tBu |
| 5-267 | H | H | CF₃ | H | tBu | H | tBu | tBu | H |
| 5-268 | H | H | CF₃ | H | tBu | H | tBu | H | tBu |
| 5-269 | H | H | CF₃ | H | H | tBu | H | tBu | tBu |
| 5-270 | H | H | CF₃ | H | H | H | tBu | tBu | tBu |

the Compound 6-1 to Compound 6-77 each have the following structure: 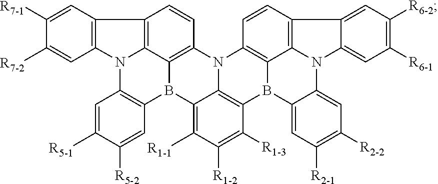
wherein R₂₋₁ and R₅₋₂ are identical, R₂₋₂ and R₅₋₁ are identical, R₆₋₁ and R₇₋₂ are identical, and R₆₋₂ and R₇₋₁ are identical; R₁₋₁, R₁₋₂, R₁₋₃, R₂₋₁/R₅₋₂, R₂₋₂/R₅₋₁, R₆₋₁/R₇₋₁, and R₆₋₂/R₇₋₁ are selected from atoms or groups in the following table, respectively;

| Com- | | | | R₂₋₁/ | R₂₋₂/ | R₆₋₁/ | R₆₋₂/ |
|---|---|---|---|---|---|---|---|
| pound | R₁₋₁ | R₁₋₂ | R₁₋₃ | R₅₋₂ | R₅₋₁ | R₇₋₂ | R₇₋₁ |
| 6-1 | CN | H | H | H | H | H | H |
| 6-2 | CN | H | H | tBu | H | H | H |
| 6-3 | CN | H | H | H | tBu | H | H |
| 6-4 | CN | H | H | H | H | tBu | H |
| 6-5 | CN | H | H | H | H | H | tBu |
| 6-6 | CN | H | H | tBu | H | tBu | H |
| 6-7 | CN | H | H | tBu | H | H | tBu |
| 6-8 | CN | H | H | H | tBu | tBu | H |
| 6-9 | CN | H | H | H | tBu | H | tBu |
| 6-10 | CN | H | H | H | H | tBu | tBu |
| 6-11 | CN | H | H | tBu | H | tBu | tBu |
| 6-12 | H | CN | H | H | H | H | H |
| 6-13 | H | CN | H | tBu | H | H | H |
| 6-14 | H | CN | H | H | tBu | H | H |
| 6-15 | H | CN | H | H | H | tBu | H |
| 6-16 | H | CN | H | H | H | H | tBu |
| 6-17 | H | CN | H | tBu | H | tBu | H |
| 6-18 | H | CN | H | tBu | H | H | tBu |
| 6-19 | H | CN | H | H | tBu | tBu | H |
| 6-20 | H | CN | H | H | tBu | H | tBu |
| 6-21 | H | CN | H | H | H | tBu | tBu |
| 6-22 | H | CN | H | tBu | H | tBu | tBu |
| 6-23 | F | H | H | H | H | H | H |
| 6-24 | F | H | H | tBu | H | H | H |
| 6-25 | F | H | H | H | tBu | H | H |
| 6-26 | F | H | H | H | H | tBu | H |
| 6-27 | F | H | H | H | H | H | tBu |
| 6-28 | F | H | H | tBu | H | tBu | H |
| 6-29 | F | H | H | tBu | H | H | tBu |
| 6-30 | F | H | H | H | tBu | tBu | H |
| 6-31 | F | H | H | H | tBu | H | tBu |
| 6-32 | F | H | H | H | H | tBu | tBu |
| 6-33 | F | H | H | tBu | H | tBu | tBu |
| 6-34 | H | F | H | H | H | H | H |
| 6-35 | H | F | H | tBu | H | H | H |
| 6-36 | H | F | H | H | tBu | H | H |
| 6-37 | H | F | H | H | H | tBu | H |
| 6-38 | H | F | H | H | H | H | tBu |
| 6-39 | H | F | H | tBu | H | tBu | H |
| 6-40 | H | F | H | tBu | H | H | tBu |
| 6-41 | H | F | H | H | tBu | tBu | H |
| 6-42 | H | F | H | H | tBu | H | tBu |
| 6-43 | H | F | H | H | H | tBu | tBu |
| 6-44 | H | F | H | tBu | H | tBu | tBu |
| 6-45 | F | H | F | H | H | H | H |
| 6-46 | F | H | F | tBu | H | H | H |
| 6-47 | F | H | F | H | tBu | H | H |
| 6-48 | F | H | F | H | H | tBu | H |
| 6-49 | F | H | F | H | H | H | tBu |
| 6-50 | F | H | F | tBu | H | tBu | H |
| 6-51 | F | H | F | tBu | H | H | tBu |
| 6-52 | F | H | F | H | tBu | tBu | H |
| 6-53 | F | H | F | H | tBu | H | tBu |
| 6-54 | F | H | F | H | H | tBu | tBu |
| 6-55 | F | H | F | tBu | H | tBu | tBu |
| 6-56 | CF₃ | H | H | H | H | H | H |
| 6-57 | CF₃ | H | H | tBu | H | H | H |
| 6-58 | CF₃ | H | H | H | tBu | H | H |
| 6-59 | CF₃ | H | H | H | H | tBu | H |
| 6-60 | CF₃ | H | H | H | H | H | tBu |
| 6-61 | CF₃ | H | H | tBu | H | tBu | H |
| 6-62 | CF₃ | H | H | tBu | H | H | tBu |
| 6-63 | CF₃ | H | H | H | tBu | tBu | H |
| 6-64 | CF₃ | H | H | H | tBu | H | tBu |
| 6-65 | CF₃ | H | H | H | H | tBu | tBu |
| 6-66 | CF₃ | H | H | tBu | H | tBu | tBu |
| 6-67 | H | CF₃ | H | H | H | H | H |
| 6-68 | H | CF₃ | H | tBu | H | H | H |
| 6-69 | H | CF₃ | H | H | tBu | H | H |
| 6-70 | H | CF₃ | H | H | H | tBu | H |
| 6-71 | H | CF₃ | H | H | H | H | tBu |
| 6-72 | H | CF₃ | H | tBu | H | tBu | H |
| 6-73 | H | CF₃ | H | tBu | H | H | tBu |
| 6-74 | H | CF₃ | H | H | tBu | tBu | H |
| 6-75 | H | CF₃ | H | H | tBu | H | tBu |
| 6-76 | H | CF₃ | H | H | H | tBu | tBu |
| 6-77 | H | CF₃ | H | tBu | H | tBu | tBu |

wherein L₁₋ₐ to L_{1-d} have the following structures: 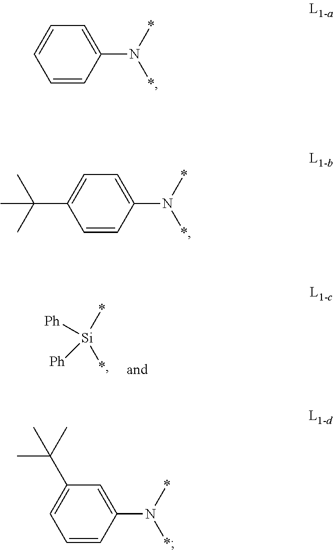
wherein P-1 to P-5 have the following structures: P 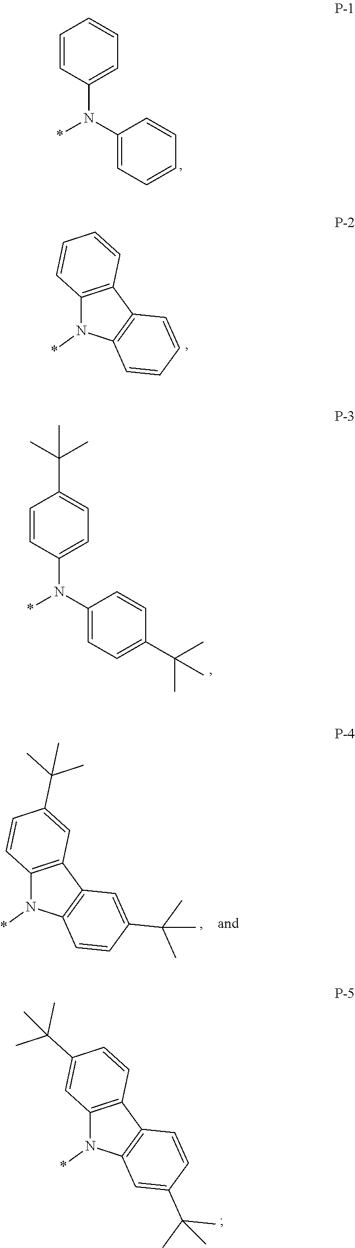
the Compound 7-1 to Compound 7-45 each have the following structure: 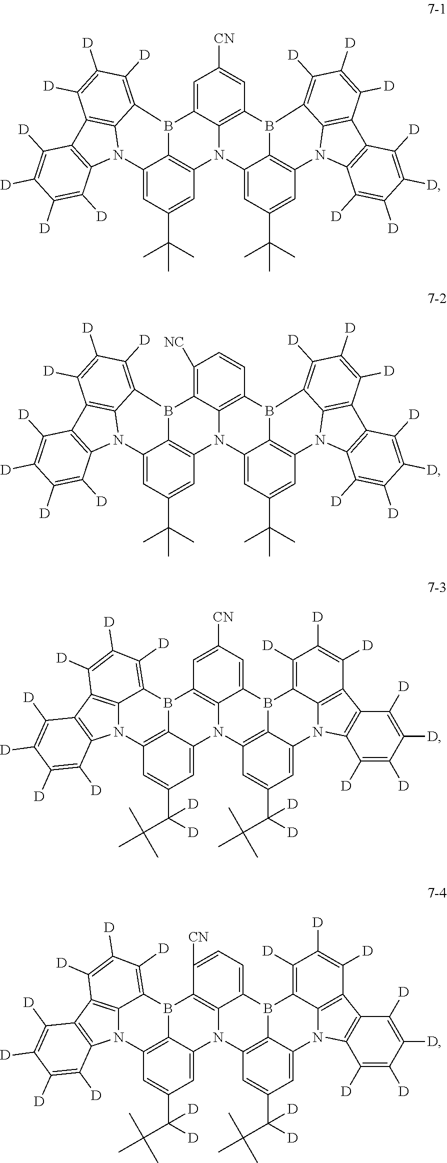 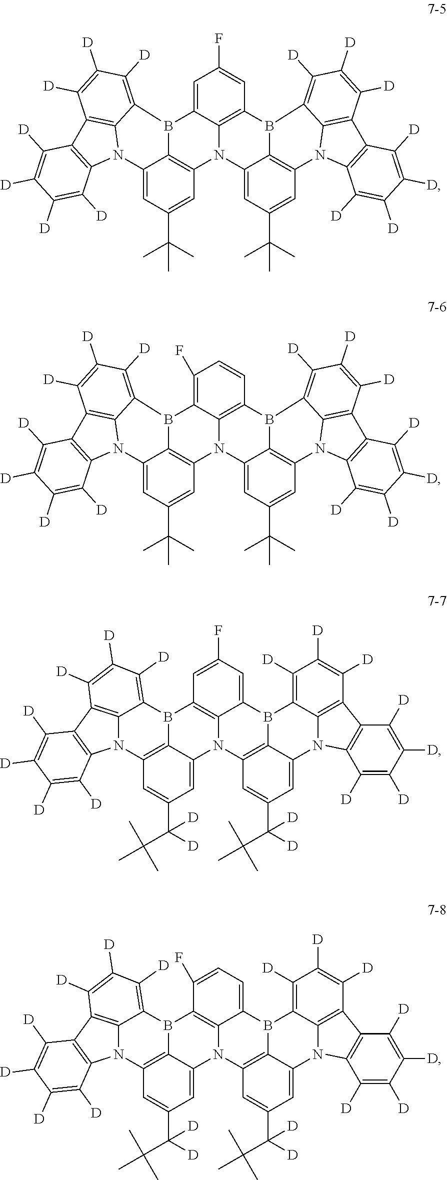 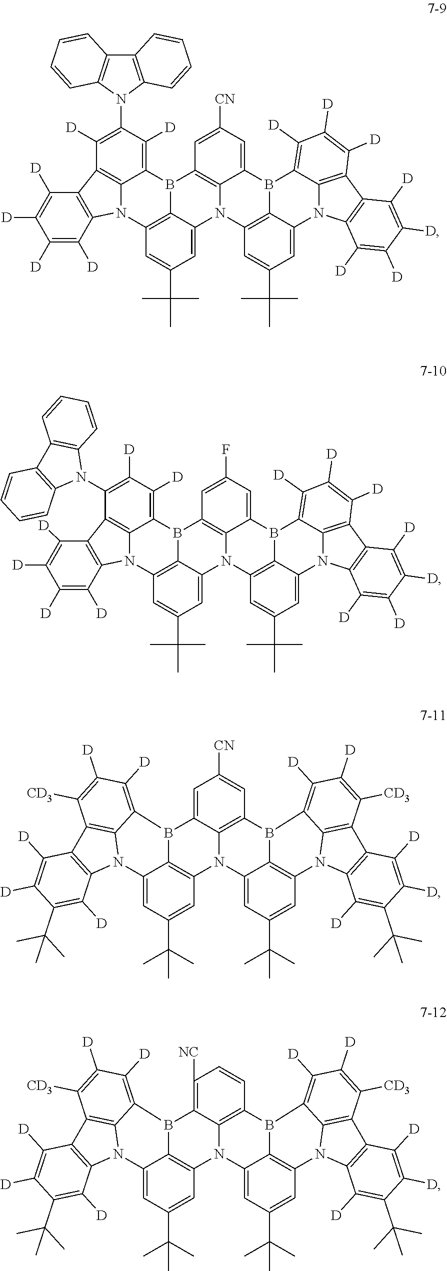 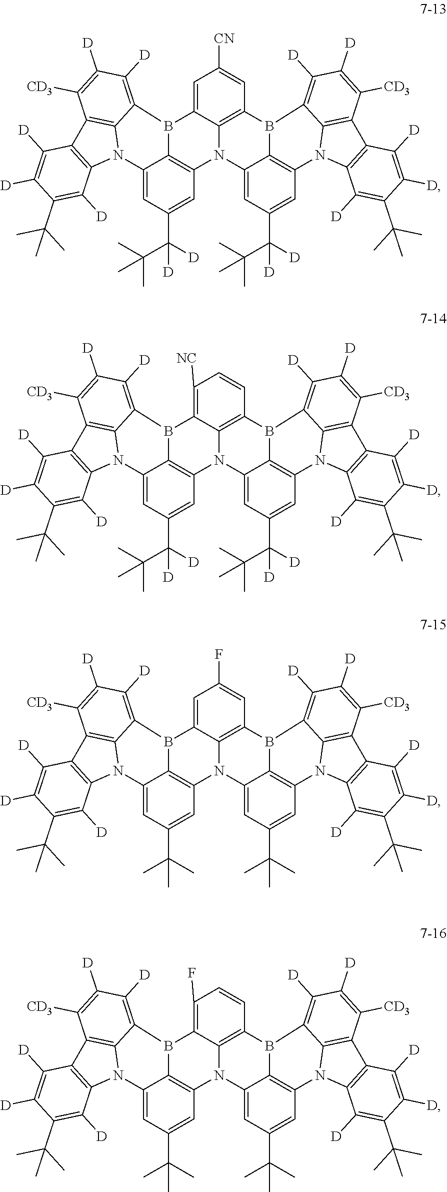 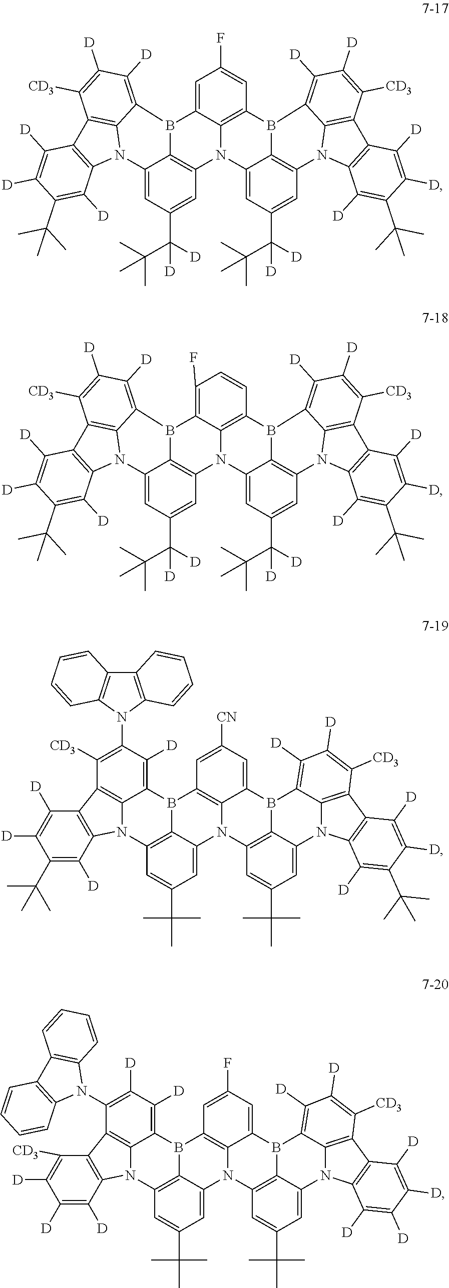 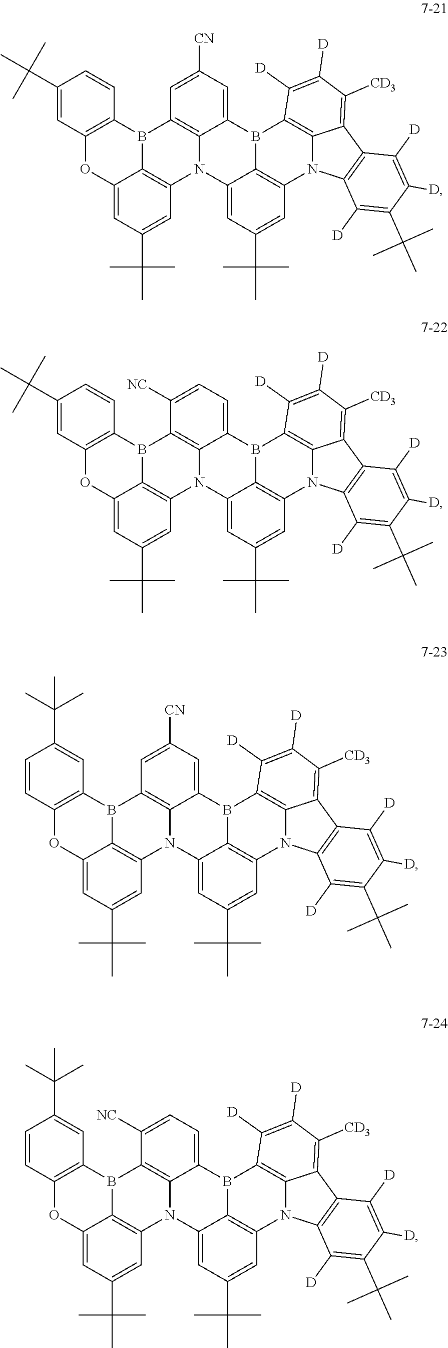 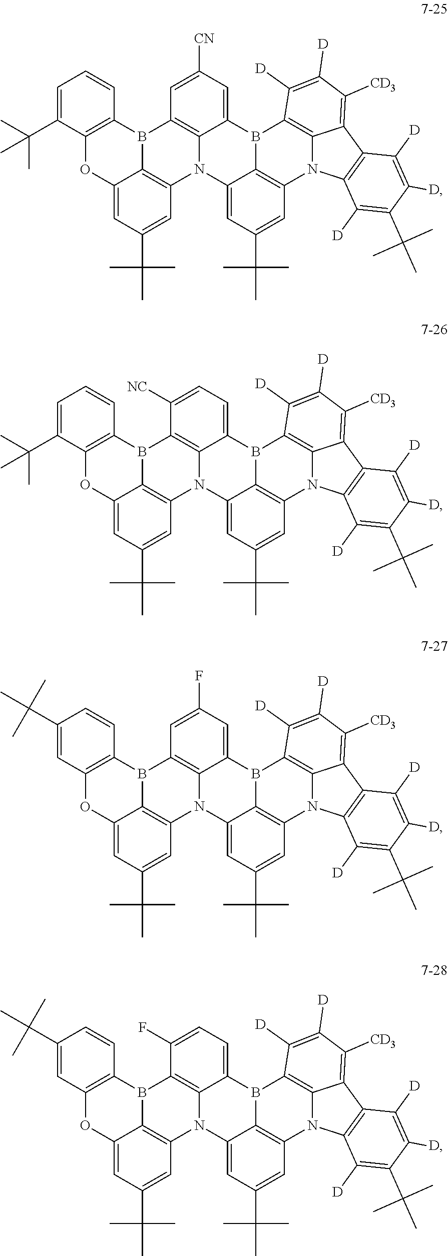 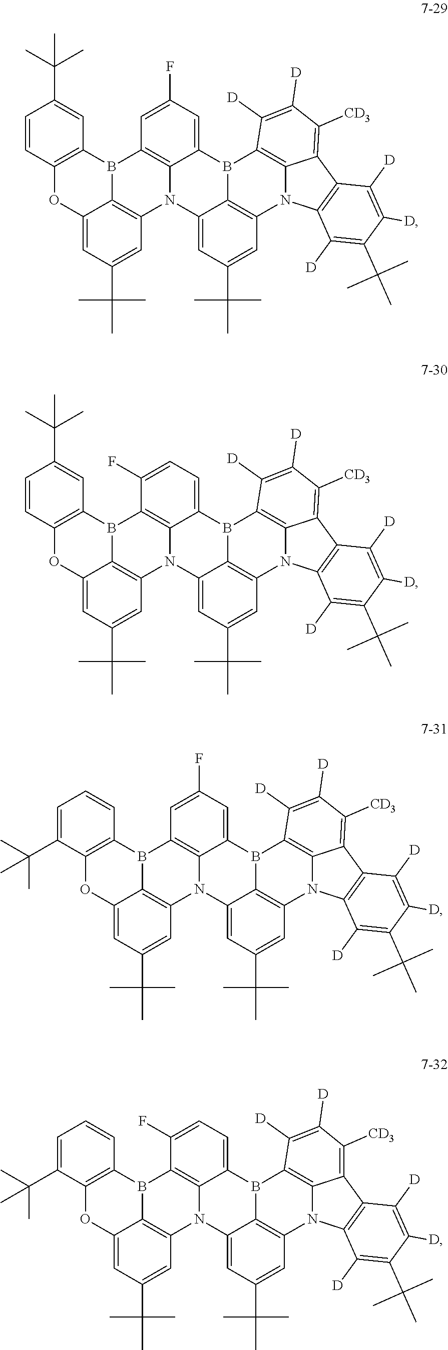 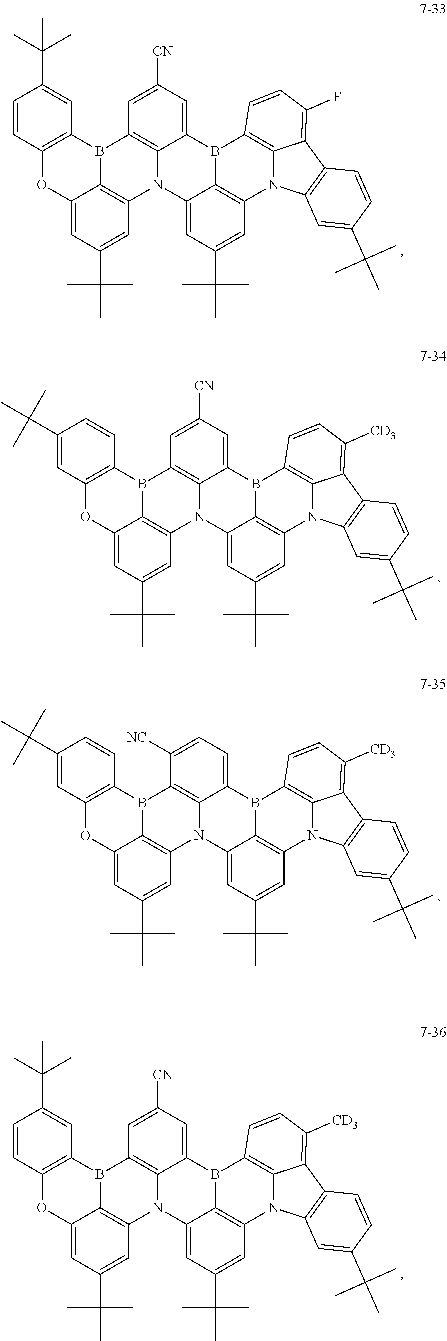 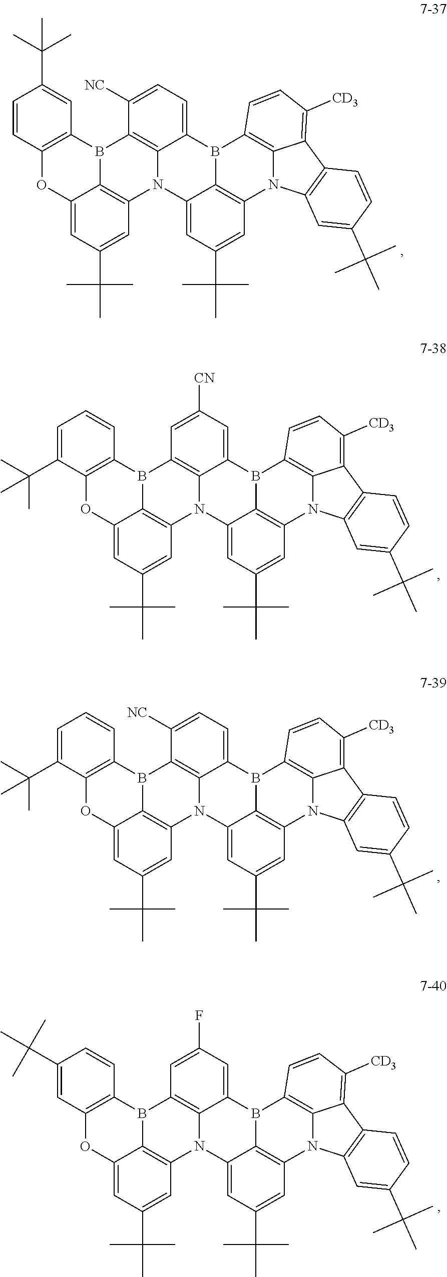 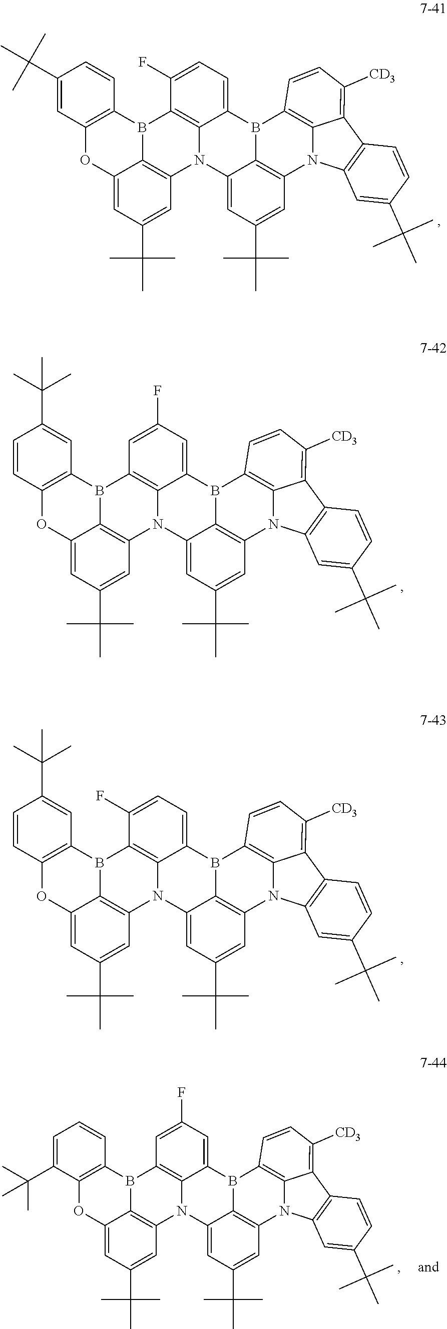 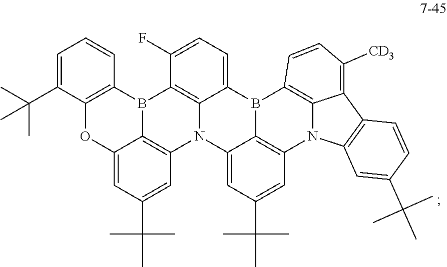 [SMILES: [2H]C([2H])([2H])c1ccc2c3c1c1ccc(C(C)(C)C)cc1n3-c1cc(C(C)(C)C)cc3c1B2c1ccc(F)c2c1N3c1cc(C(C)(C)C)cc3c1B2c1cccc(C(C)(C)C)c1O3]
optionally, hydrogens in the Compound 1-1 to Compound 1-898, Compound 2-1 to Compound 2-330, Compound 3-1 to Compound 3-162, Compound 4-1 to Compound 4-587, Compound 5-1 to Compound 5-270, Compound 6-1 to Compound 6-77, and Compound 7-1 to Compound 7-45 can be partially or fully substituted with deuterium.

13. An organic electroluminescent device, comprising:
an anode,
a cathode, and
an organic layer disposed between the anode and the cathode, wherein the organic layer comprises the compound according to claim 1.

14. The device according to claim 13, wherein the organic layer is an emissive layer, and the compound is a light-emitting material.

15. The device according to claim 14, wherein the emissive layer comprises at least a first host compound or comprises a first host compound and a second host compound;
preferably, the first host compound has a structure represented by Formula X-1 or Formula X-2: 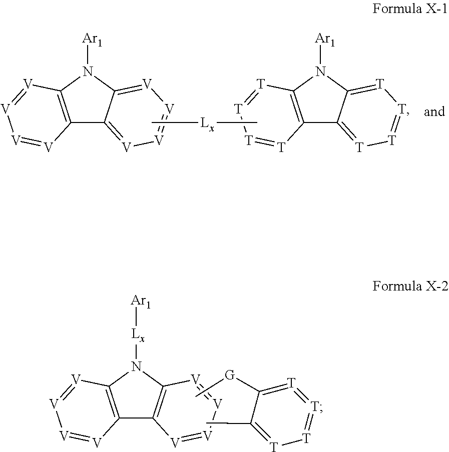
wherein,
Lₓ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms, or a combination thereof;
G is, at each occurrence identically or differently, selected from C(R_{g})₂, NR_{g}, O, or S;
V is, at each occurrence identically or differently, selected from C, CRᵥ, or N;
in Formula X-1, T is, at each occurrence identically or differently, selected from C, CRₜ, or N;
in Formula X-2, T is, at each occurrence identically or differently, selected from CRₜ or N;
R_{g}, Rᵥ, and Rₜ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
Ar₁ is, at each occurrence identically or differently, selected from substituted or unsubstituted aryl having 6 to 30 carbon atoms, substituted or unsubstituted heteroaryl having 3 to 30 carbon atoms, or a combination thereof;
adjacent substituents R_{g}, Rᵥ, and Rₜ can be optionally joined to form a ring;
the second host compound has a structure represented by Formula 6: 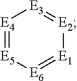
wherein,
E₁ to E₆ are, at each occurrence identically or differently, selected from C, CR_{c}, or N, at least two of E₁ to E₆ are N, and at least one of E₁ to E₆ is C and joined to Formula A: 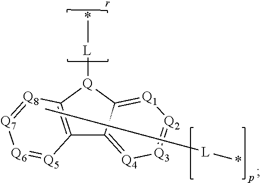
wherein,
Q is, at each occurrence identically or differently, selected from the group consisting of O, S, Se, N, NR_{Q}, CR_{Q}R_{Q}, SiR_{Q}R_{Q}, GeR_{Q}R_{Q}, and R_{Q}C═CR_{Q}; when two R_{Q} are present at the same time, the two R_{Q} may be identical or different;
p is 0 or 1; r is 0 or 1;
when Q is selected from N, p is 0, and r is 1;
when Q is selected from the group consisting of O, S, Se, NR_{Q}, CR_{Q}R_{Q}, SiR_{Q}R_{Q}, GeR_{Q}R_{Q}, and R_{Q}C═CR_{Q}, p is 1, and r is 0;
L_{q} is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms, or a combination thereof;
Q₁ to Q₈ are, at each occurrence identically or differently, selected from C, CR_{q}, or N;
Rₑ, R_{Q}, and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, a substituted or unsubstituted alkylgermanyl having 3 to 20 carbon atoms, a substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
“*” represents a position where Formula A is joined to Formula 6;
adjacent substituents Rₑ, R_{Q}, and R_{q} can be optionally joined to form a ring;
more preferably, the first host compound is selected from the group consisting of Compound PH-1 to Compound PH-115: 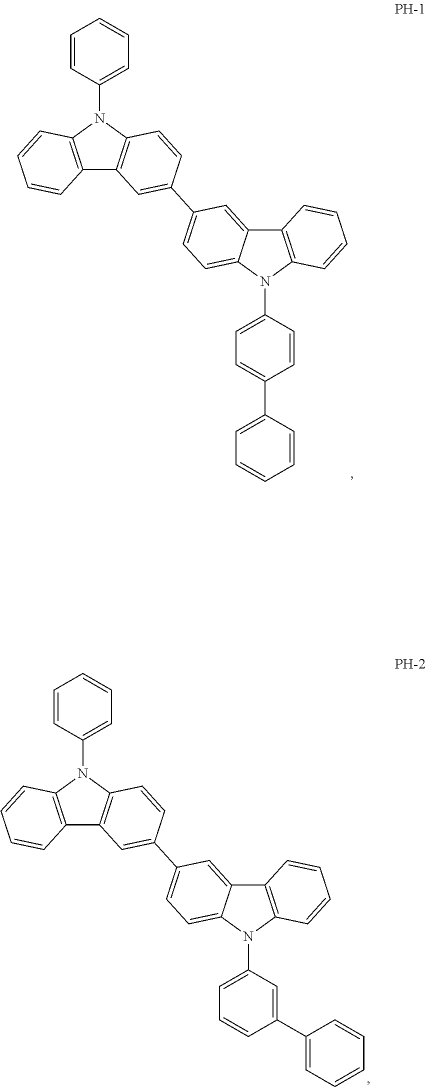 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cccc(-n3c4ccccc4c4cc(-c5ccc6c(c5)c5ccccc5n6-c5ccccc5)ccc43)c2)cc1] 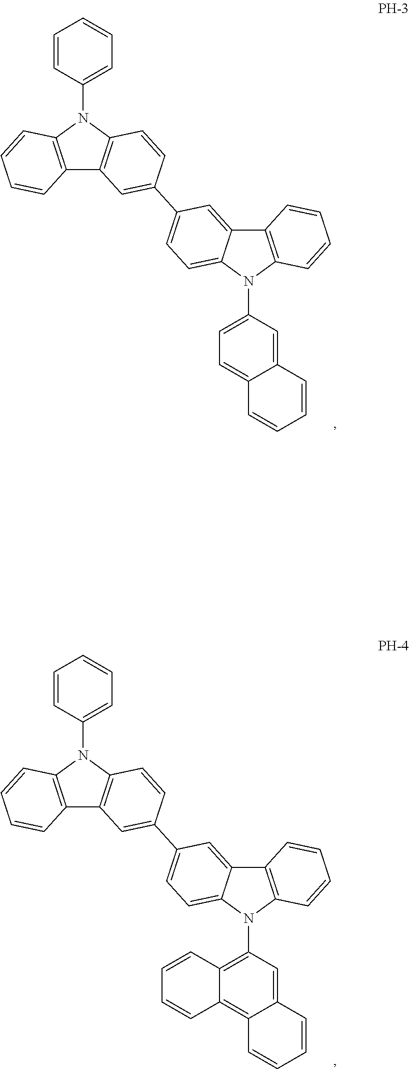 [SMILES: c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4cc5ccccc5c5ccccc45)ccc32)cc1] 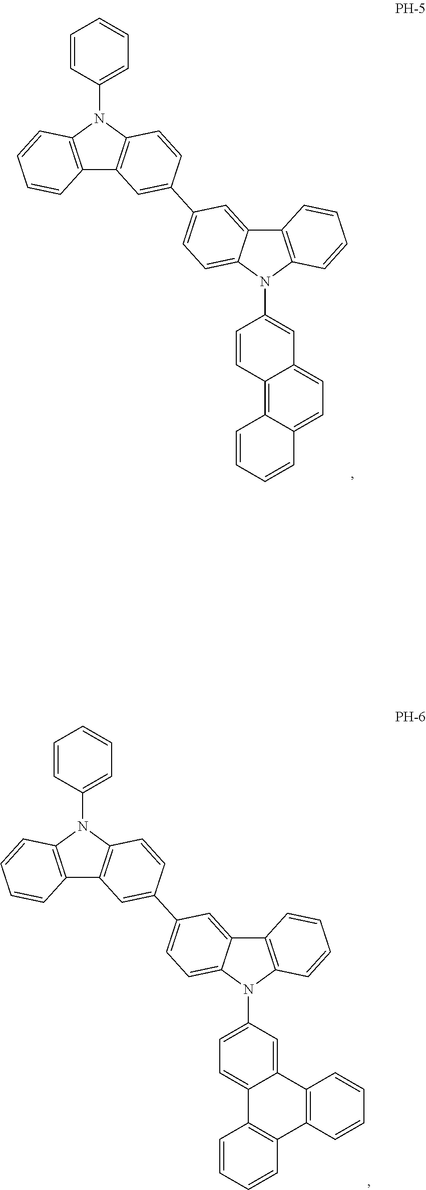 [SMILES: c1ccc(-n2c3ccccc3c3cc(-c4ccc5c(c4)c4ccccc4n5-c4ccc5c(ccc6ccccc65)c4)ccc32)cc1 ; c1ccc(-n2c3ccccc3c3cc(-c4ccc5c(c4)c4ccccc4n5-c4ccc5c6ccccc6c6ccccc6c5c4)ccc32)cc1] 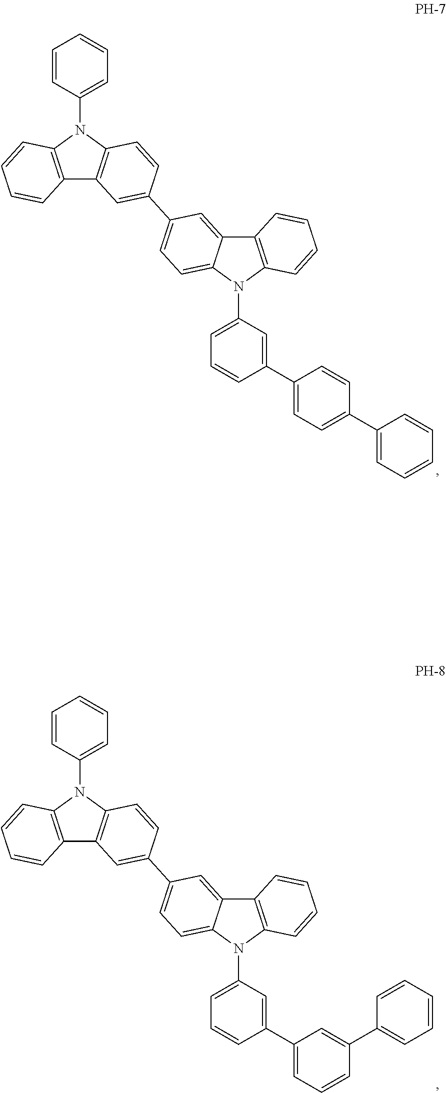 [SMILES: c1ccc(-c2ccc(-c3cccc(-n4c5ccccc5c5cc(-c6ccc7c(c6)c6ccccc6n7-c6ccccc6)ccc54)c3)cc2)cc1 ; c1ccc(-c2cccc(-c3cccc(-n4c5ccccc5c5cc(-c6ccc7c(c6)c6ccccc6n7-c6ccccc6)ccc54)c3)c2)cc1] 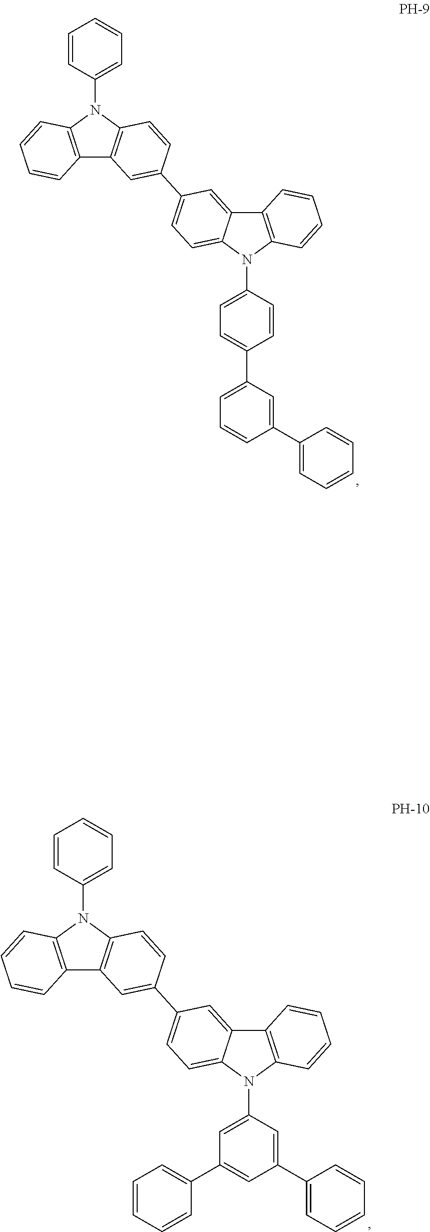 [SMILES: c1ccc(-c2cccc(-c3ccc(-n4c5ccccc5c5cc(-c6ccc7c(c6)c6ccccc6n7-c6ccccc6)ccc54)cc3)c2)cc1 ; c1ccc(-c2cc(-c3ccccc3)cc(-n3c4ccccc4c4cc(-c5ccc6c(c5)c5ccccc5n6-c5ccccc5)ccc43)c2)cc1] 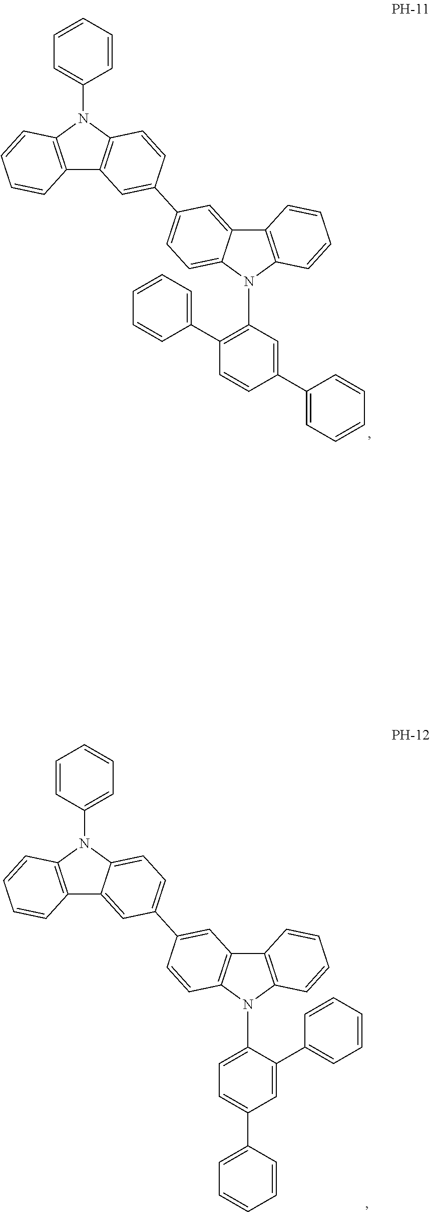 [SMILES: c1ccc(-c2ccc(-c3ccccc3)c(-n3c4ccccc4c4cc(-c5ccc6c(c5)c5ccccc5n6-c5ccccc5)ccc43)c2)cc1 ; c1ccc(-c2ccc(-n3c4ccccc4c4cc(-c5ccc6c(c5)c5ccccc5n6-c5ccccc5)ccc43)c(-c3ccccc3)c2)cc1] 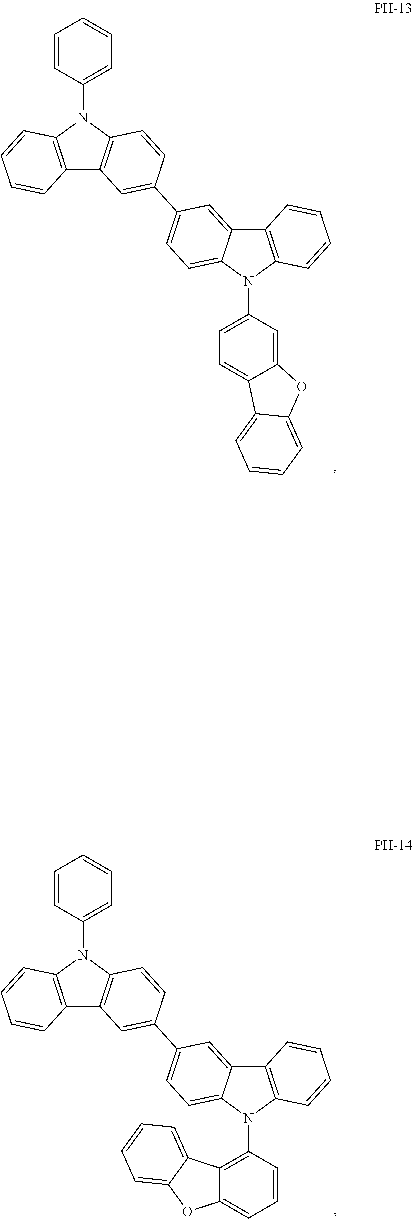 [SMILES: c1ccc(-n2c3ccccc3c3cc(-c4ccc5c(c4)c4ccccc4n5-c4ccc5c(c4)oc4ccccc45)ccc32)cc1 ; c1ccc(-n2c3ccccc3c3cc(-c4ccc5c(c4)c4ccccc4n5-c4cccc5oc6ccccc6c45)ccc32)cc1] 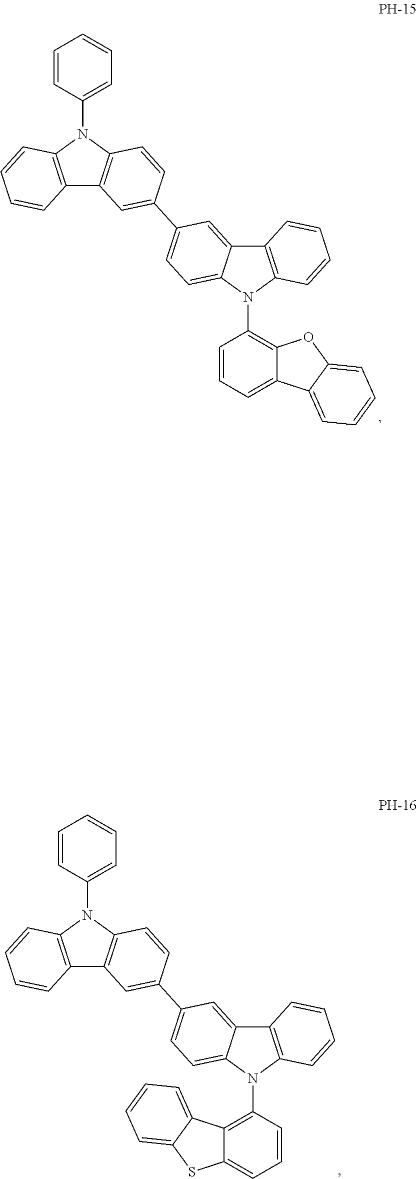 [SMILES: c1ccc(-n2c3ccccc3c3cc(-c4ccc5c(c4)c4ccccc4n5-c4cccc5c4oc4ccccc45)ccc32)cc1 ; c1ccc(-n2c3ccccc3c3cc(-c4ccc5c(c4)c4ccccc4n5-c4cccc5sc6ccccc6c45)ccc32)cc1] 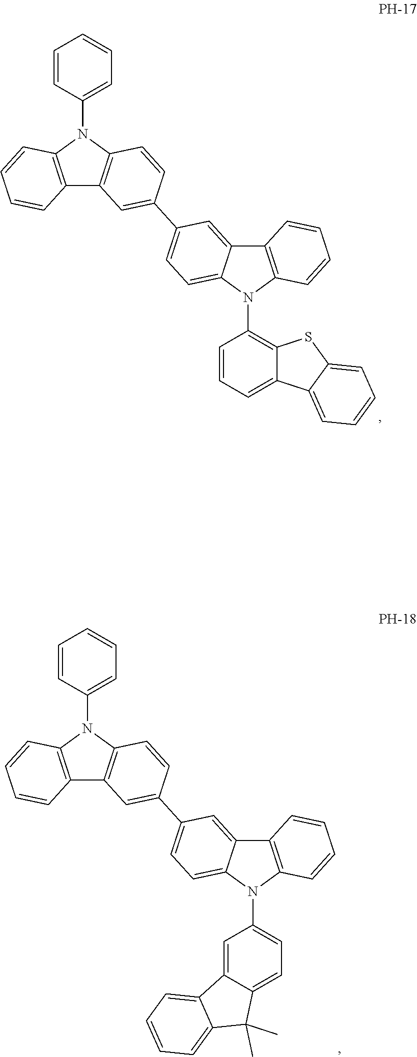 [SMILES: c1ccc(-n2c3ccccc3c3cc(-c4ccc5c(c4)c4ccccc4n5-c4cccc5c4sc4ccccc45)ccc32)cc1 ; CC1(C)c2ccccc2-c2cc(-n3c4ccccc4c4cc(-c5ccc6c(c5)c5ccccc5n6-c5ccccc5)ccc43)ccc21] 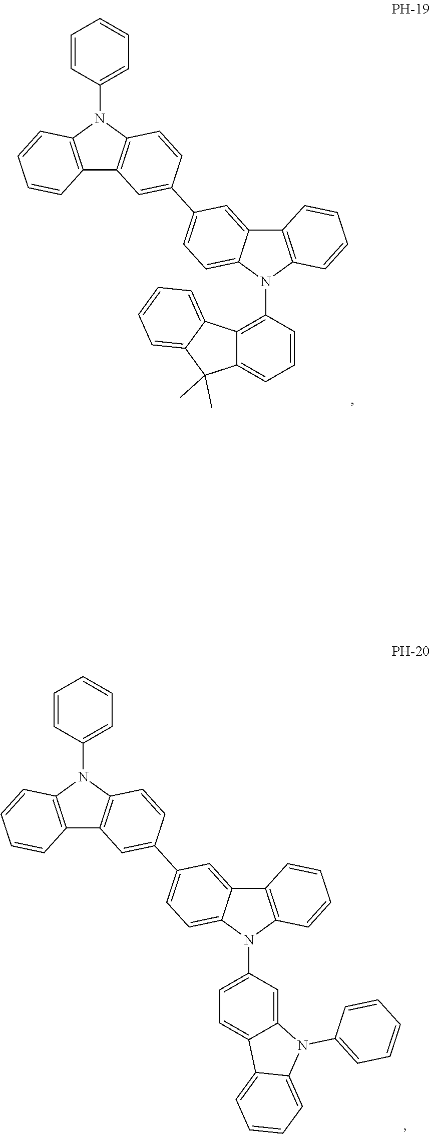 [SMILES: CC1(C)c2ccccc2-c2c(-n3c4ccccc4c4cc(-c5ccc6c(c5)c5ccccc5n6-c5ccccc5)ccc43)cccc21 ; c1ccc(-n2c3ccccc3c3cc(-c4ccc5c(c4)c4ccccc4n5-c4ccc5c6ccccc6n(-c6ccccc6)c5c4)ccc32)cc1] 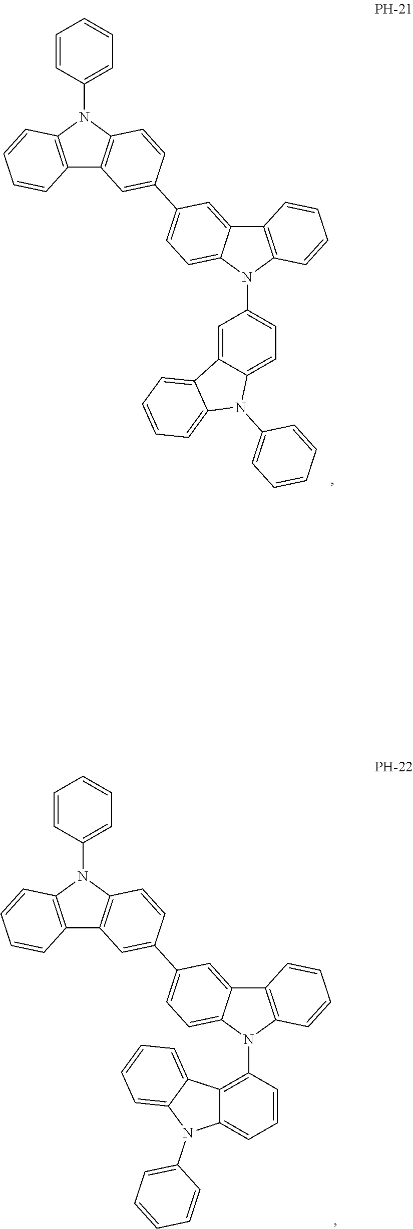 [SMILES: c1ccc(-n2c3ccccc3c3cc(-c4ccc5c(c4)c4ccccc4n5-c4ccc5c(c4)c4ccccc4n5-c4ccccc4)ccc32)cc1 ; c1ccc(-n2c3ccccc3c3cc(-c4ccc5c(c4)c4ccccc4n5-c4cccc5c4c4ccccc4n5-c4ccccc4)ccc32)cc1] 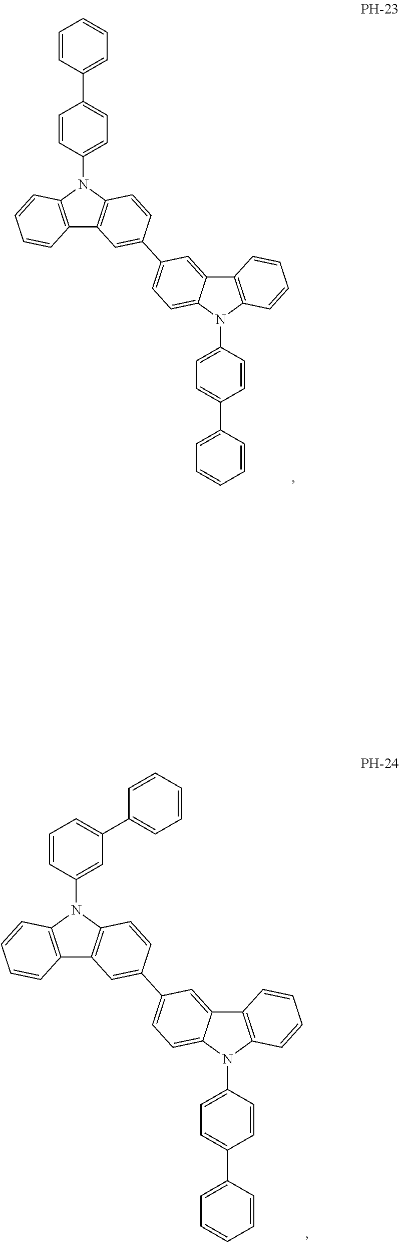 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1] 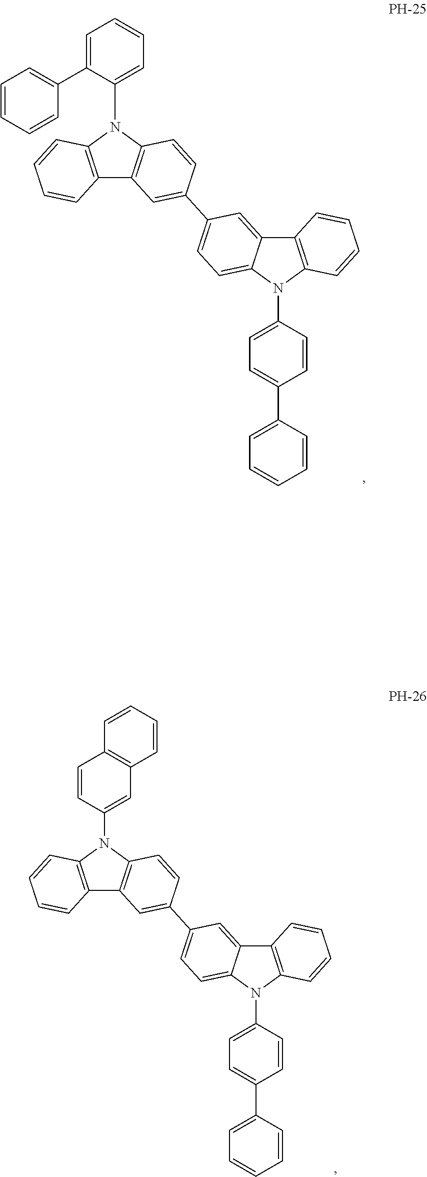 [SMILES: c1ccc(-c2ccc(-n3c4ccccc4c4cc(-c5ccc6c(c5)c5ccccc5n6-c5ccccc5-c5ccccc5)ccc43)cc2)cc1 ; c1ccc(-c2ccc(-n3c4ccccc4c4cc(-c5ccc6c(c5)c5ccccc5n6-c5ccc6ccccc6c5)ccc43)cc2)cc1] 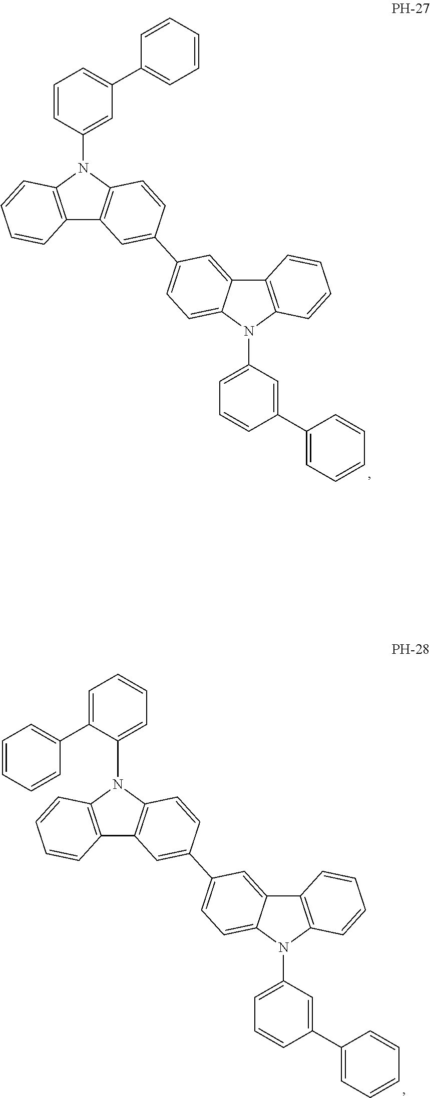 [SMILES: c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccccc5-c5ccccc5)ccc43)c2)cc1] 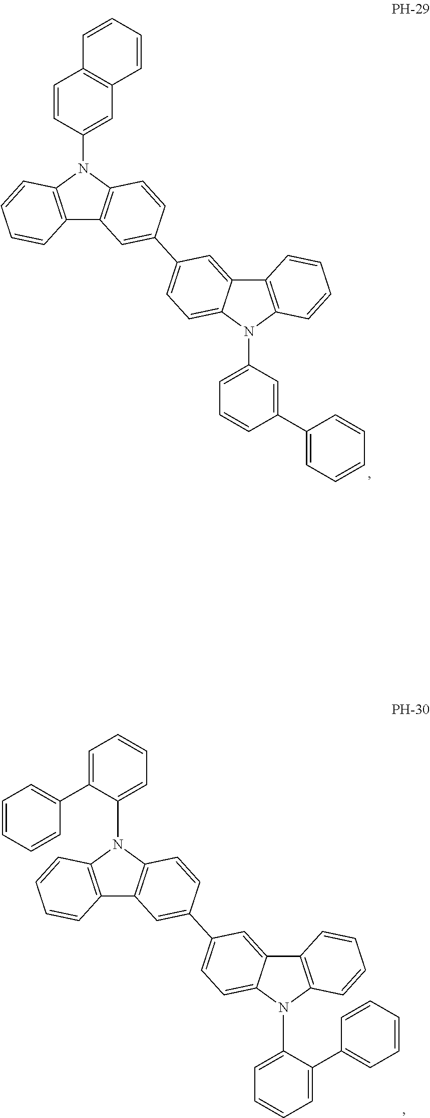 [SMILES: c1ccc(-c2cccc(-n3c4ccccc4c4cc(-c5ccc6c(c5)c5ccccc5n6-c5ccc6ccccc6c5)ccc43)c2)cc1 ; c1ccc(-c2ccccc2-n2c3ccccc3c3cc(-c4ccc5c(c4)c4ccccc4n5-c4ccccc4-c4ccccc4)ccc32)cc1] 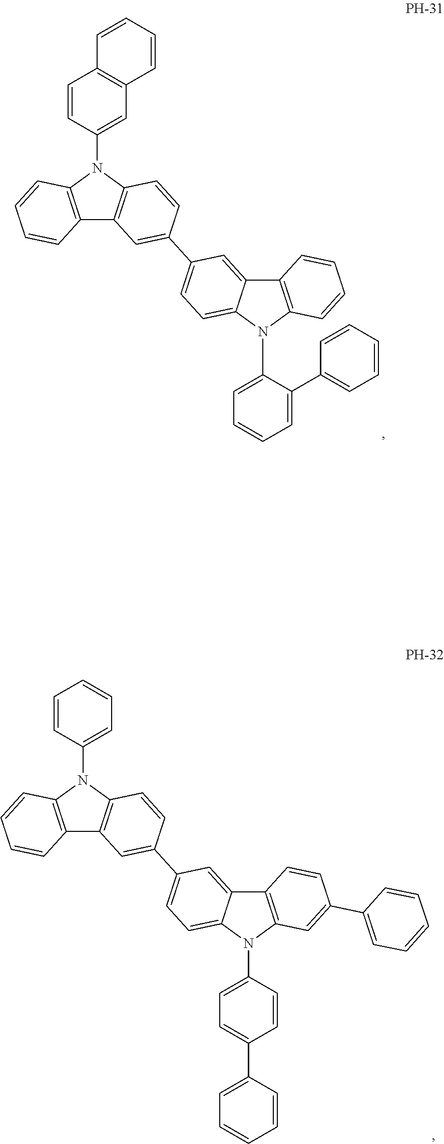 [SMILES: c1ccc(-c2ccccc2-n2c3ccccc3c3cc(-c4ccc5c(c4)c4ccccc4n5-c4ccc5ccccc5c4)ccc32)cc1 ; c1ccc(-c2ccc(-n3c4ccc(-c5ccc6c(c5)c5ccccc5n6-c5ccccc5)cc4c4ccc(-c5ccccc5)cc43)cc2)cc1] 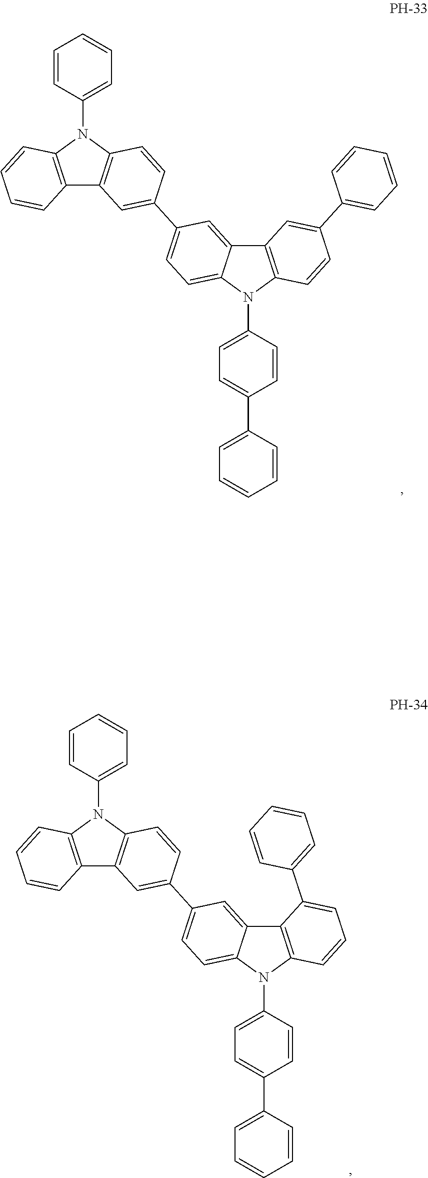 [SMILES: c1ccc(-c2ccc(-n3c4ccc(-c5ccccc5)cc4c4cc(-c5ccc6c(c5)c5ccccc5n6-c5ccccc5)ccc43)cc2)cc1 ; c1ccc(-c2ccc(-n3c4ccc(-c5ccc6c(c5)c5ccccc5n6-c5ccccc5)cc4c4c(-c5ccccc5)cccc43)cc2)cc1] 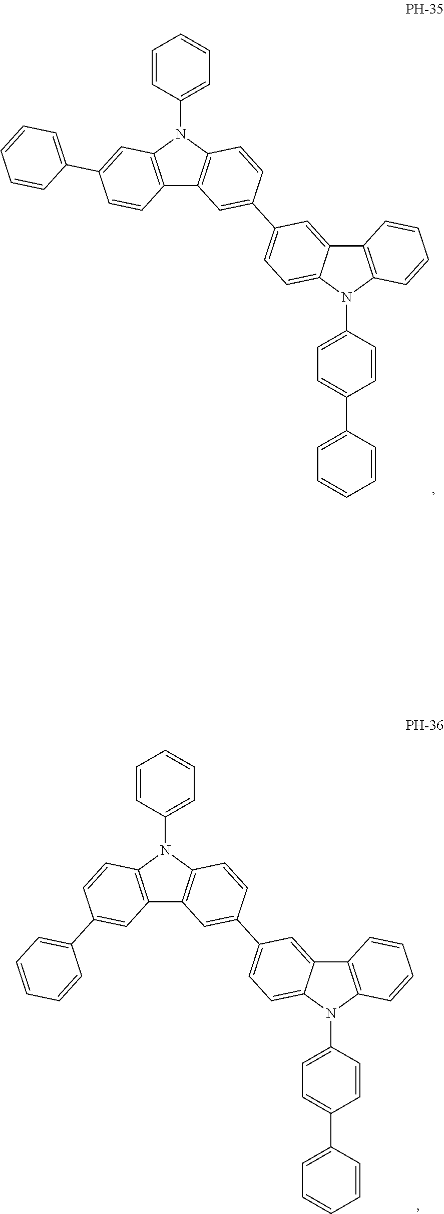 [SMILES: c1ccc(-c2ccc(-n3c4ccccc4c4cc(-c5ccc6c(c5)c5ccc(-c7ccccc7)cc5n6-c5ccccc5)ccc43)cc2)cc1 ; c1ccc(-c2ccc(-n3c4ccccc4c4cc(-c5ccc6c(c5)c5cc(-c7ccccc7)ccc5n6-c5ccccc5)ccc43)cc2)cc1] 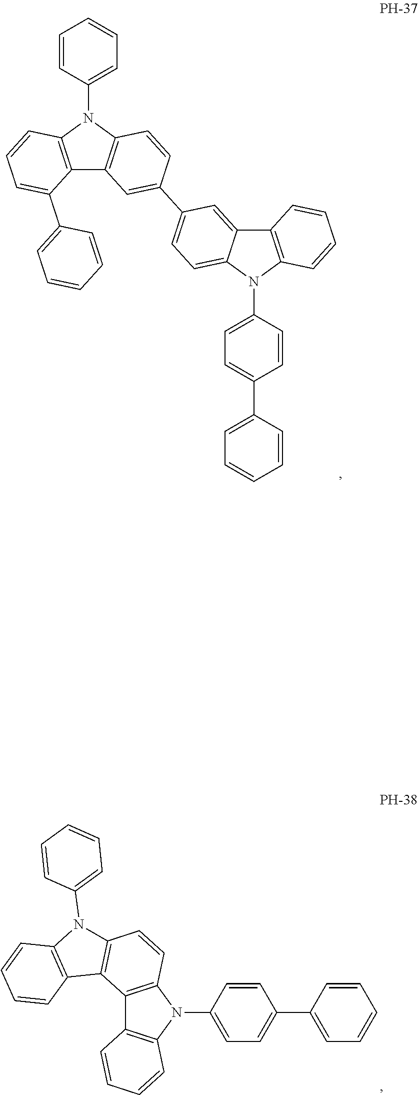 [SMILES: c1ccc(-c2ccc(-n3c4ccccc4c4cc(-c5ccc6c(c5)c5c(-c7ccccc7)cccc5n6-c5ccccc5)ccc43)cc2)cc1 ; c1ccc(-c2ccc(-n3c4ccccc4c4c5c6ccccc6n(-c6ccccc6)c5ccc43)cc2)cc1] 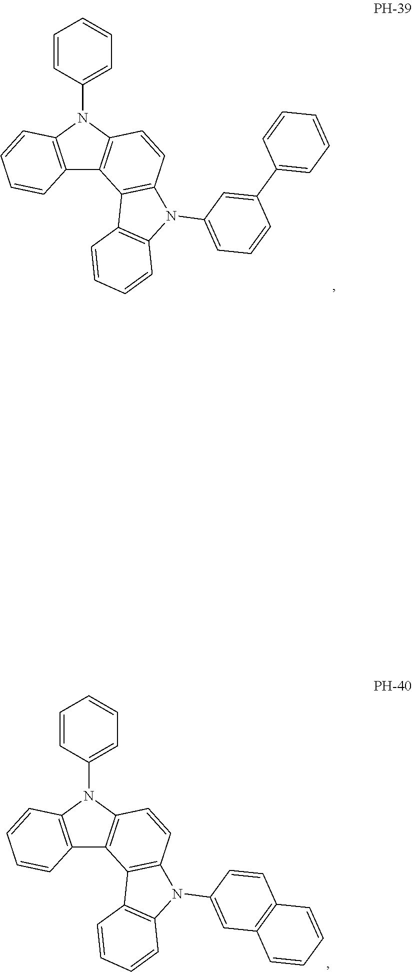 [SMILES: c1ccc(-c2cccc(-n3c4ccccc4c4c5c6ccccc6n(-c6ccccc6)c5ccc43)c2)cc1 ; c1ccc(-n2c3ccccc3c3c4c5ccccc5n(-c5ccc6ccccc6c5)c4ccc32)cc1] 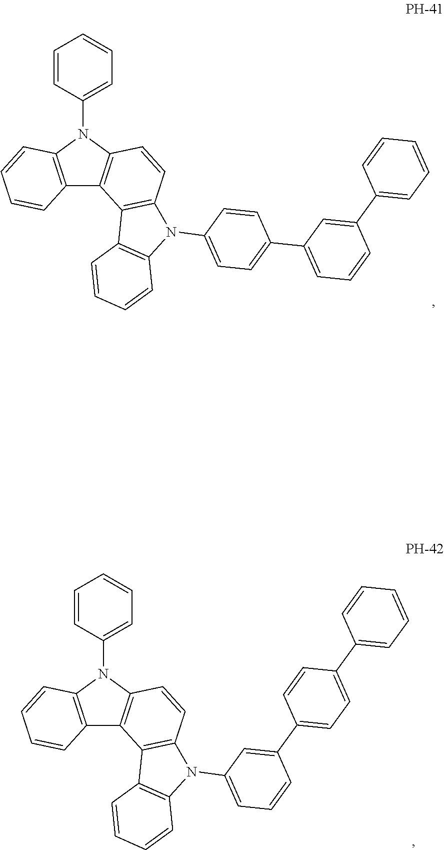 [SMILES: c1ccc(-c2cccc(-c3ccc(-n4c5ccccc5c5c6c7ccccc7n(-c7ccccc7)c6ccc54)cc3)c2)cc1 ; c1ccc(-c2ccc(-c3cccc(-n4c5ccccc5c5c6c7ccccc7n(-c7ccccc7)c6ccc54)c3)cc2)cc1] 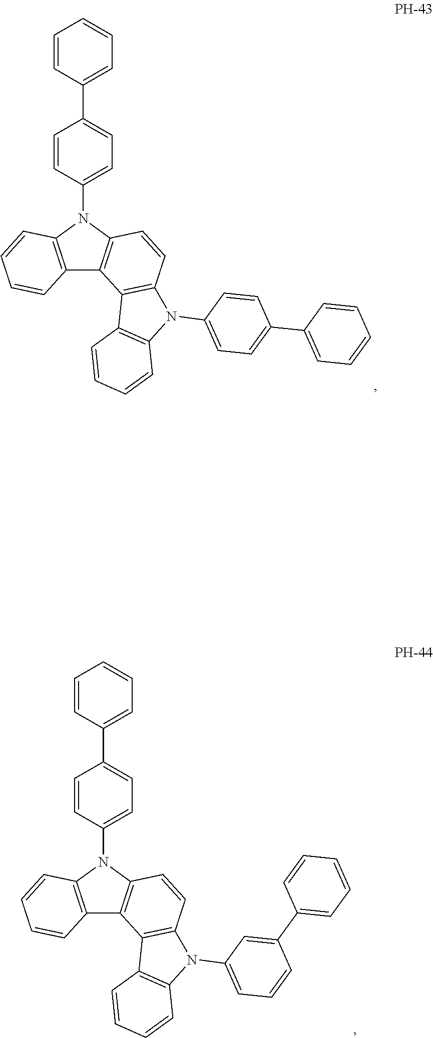 [SMILES: c1ccc(-c2ccc(-n3c4ccccc4c4c5c6ccccc6n(-c6ccc(-c7ccccc7)cc6)c5ccc43)cc2)cc1 ; c1ccc(-c2ccc(-n3c4ccccc4c4c5c6ccccc6n(-c6cccc(-c7ccccc7)c6)c5ccc43)cc2)cc1] 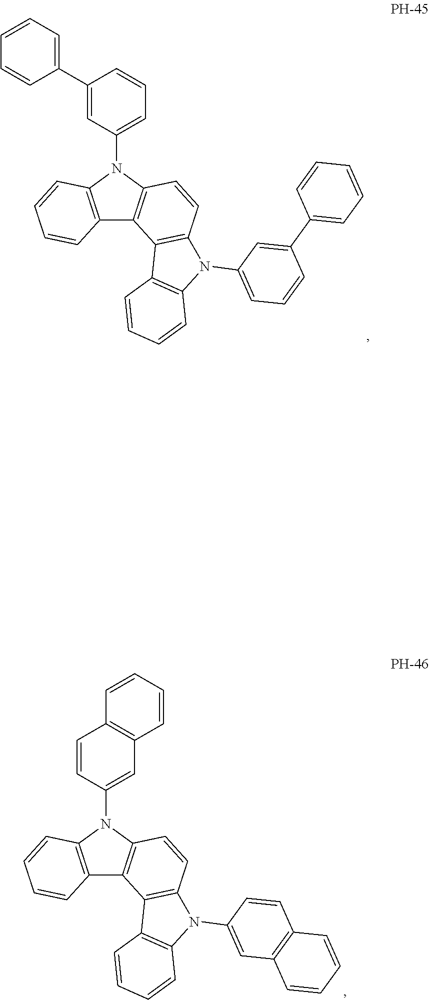 [SMILES: c1ccc(-c2cccc(-n3c4ccccc4c4c5c6ccccc6n(-c6cccc(-c7ccccc7)c6)c5ccc43)c2)cc1 ; c1ccc2cc(-n3c4ccccc4c4c5c6ccccc6n(-c6ccc7ccccc7c6)c5ccc43)ccc2c1] 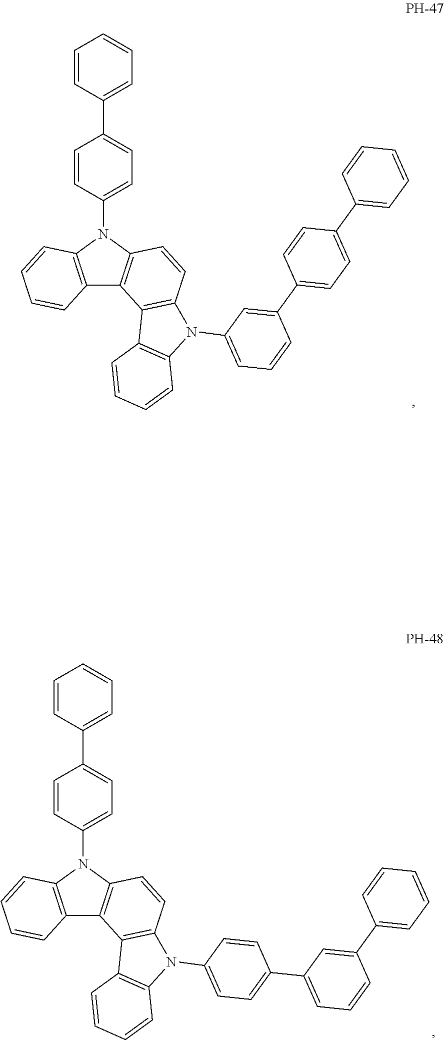 [SMILES: c1ccc(-c2ccc(-c3cccc(-n4c5ccccc5c5c6c7ccccc7n(-c7ccc(-c8ccccc8)cc7)c6ccc54)c3)cc2)cc1 ; c1ccc(-c2ccc(-n3c4ccccc4c4c5c6ccccc6n(-c6ccc(-c7cccc(-c8ccccc8)c7)cc6)c5ccc43)cc2)cc1] 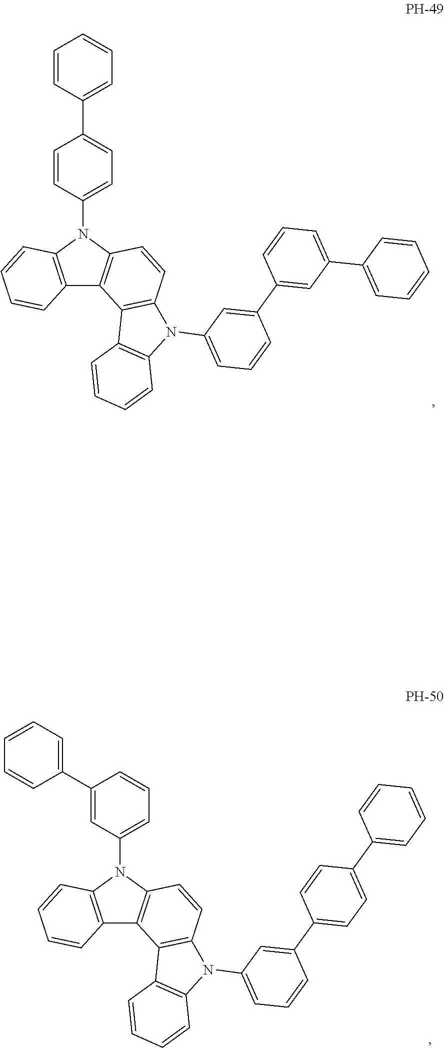 [SMILES: c1ccc(-c2ccc(-n3c4ccccc4c4c5c6ccccc6n(-c6cccc(-c7cccc(-c8ccccc8)c7)c6)c5ccc43)cc2)cc1 ; c1ccc(-c2ccc(-c3cccc(-n4c5ccccc5c5c6c7ccccc7n(-c7cccc(-c8ccccc8)c7)c6ccc54)c3)cc2)cc1] 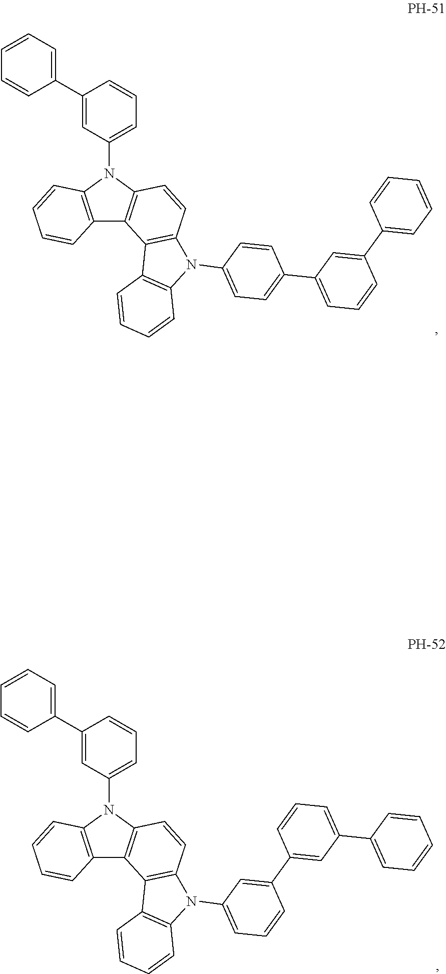 [SMILES: c1ccc(-c2cccc(-c3ccc(-n4c5ccccc5c5c6c7ccccc7n(-c7cccc(-c8ccccc8)c7)c6ccc54)cc3)c2)cc1 ; c1ccc(-c2cccc(-c3cccc(-n4c5ccccc5c5c6c7ccccc7n(-c7cccc(-c8ccccc8)c7)c6ccc54)c3)c2)cc1] 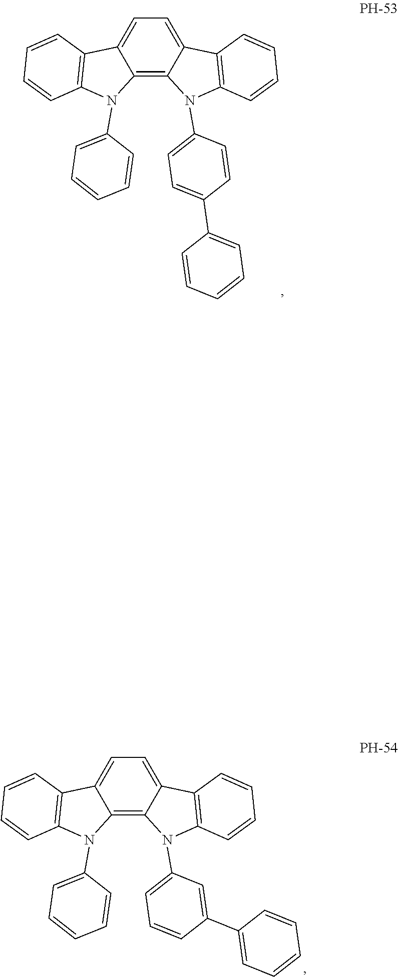 [SMILES: c1ccc(-c2ccc(-n3c4ccccc4c4ccc5c6ccccc6n(-c6ccccc6)c5c43)cc2)cc1 ; c1ccc(-c2cccc(-n3c4ccccc4c4ccc5c6ccccc6n(-c6ccccc6)c5c43)c2)cc1] 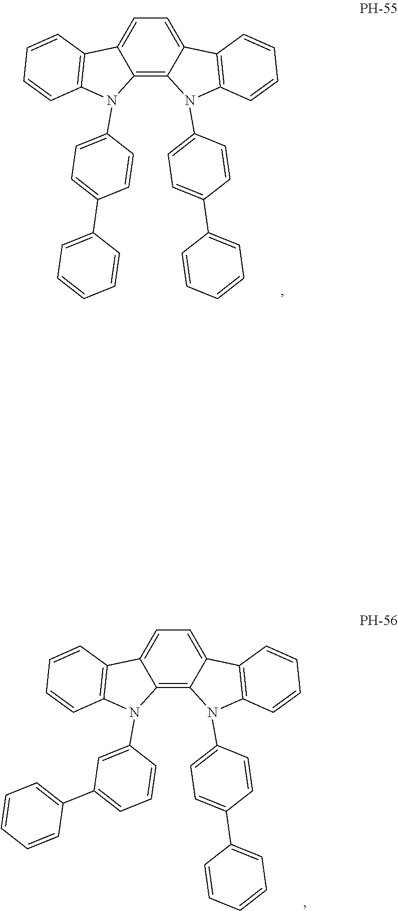 [SMILES: c1ccc(-c2ccc(-n3c4ccccc4c4ccc5c6ccccc6n(-c6ccc(-c7ccccc7)cc6)c5c43)cc2)cc1 ; c1ccc(-c2ccc(-n3c4ccccc4c4ccc5c6ccccc6n(-c6cccc(-c7ccccc7)c6)c5c43)cc2)cc1] 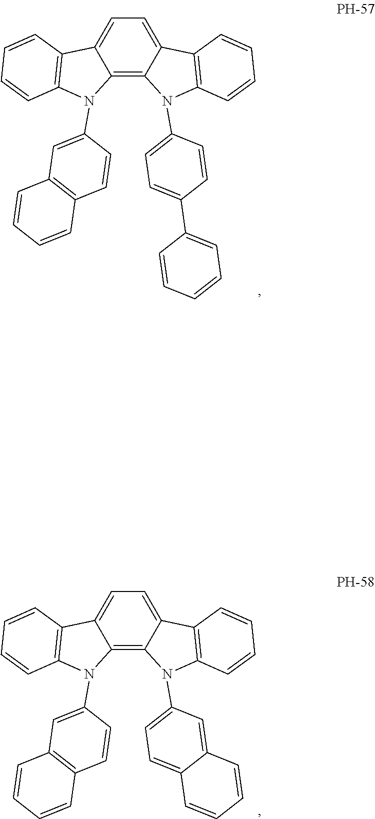 [SMILES: c1ccc(-c2ccc(-n3c4ccccc4c4ccc5c6ccccc6n(-c6ccc7ccccc7c6)c5c43)cc2)cc1 ; c1ccc2cc(-n3c4ccccc4c4ccc5c6ccccc6n(-c6ccc7ccccc7c6)c5c43)ccc2c1] 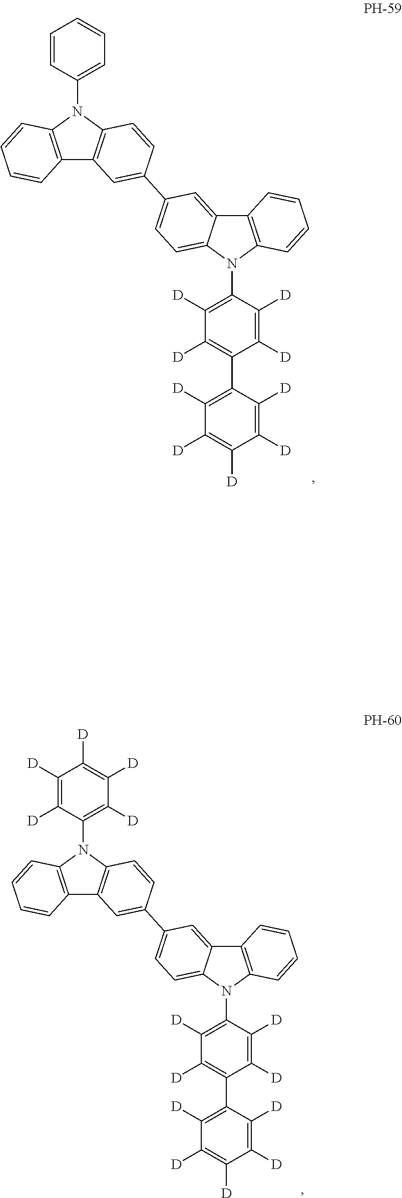 [SMILES: [2H]c1c([2H])c([2H])c(-c2c([2H])c([2H])c(-n3c4ccccc4c4cc(-c5ccc6c(c5)c5ccccc5n6-c5ccccc5)ccc43)c([2H])c2[2H])c([2H])c1[2H] ; [2H]c1c([2H])c([2H])c(-c2c([2H])c([2H])c(-n3c4ccccc4c4cc(-c5ccc6c(c5)c5ccccc5n6-c5c([2H])c([2H])c([2H])c([2H])c5[2H])ccc43)c([2H])c2[2H])c([2H])c1[2H]] 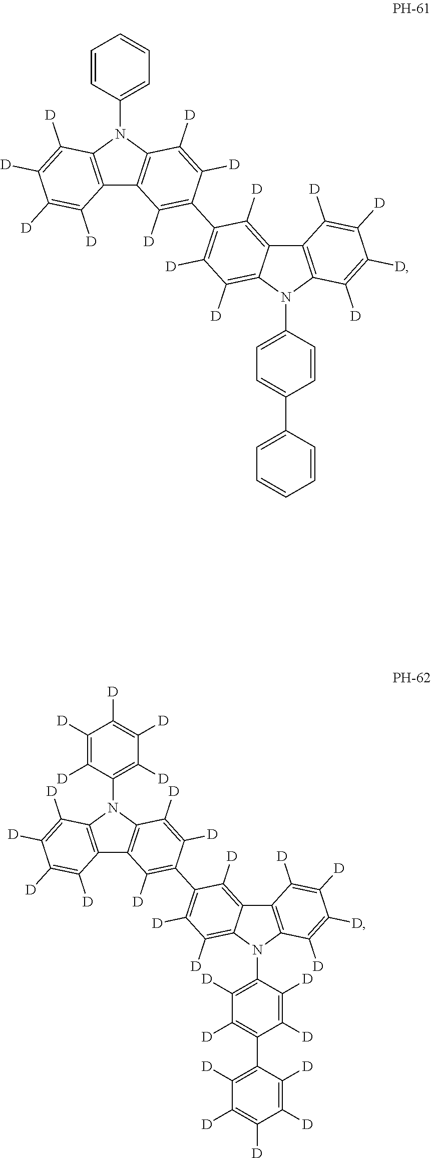 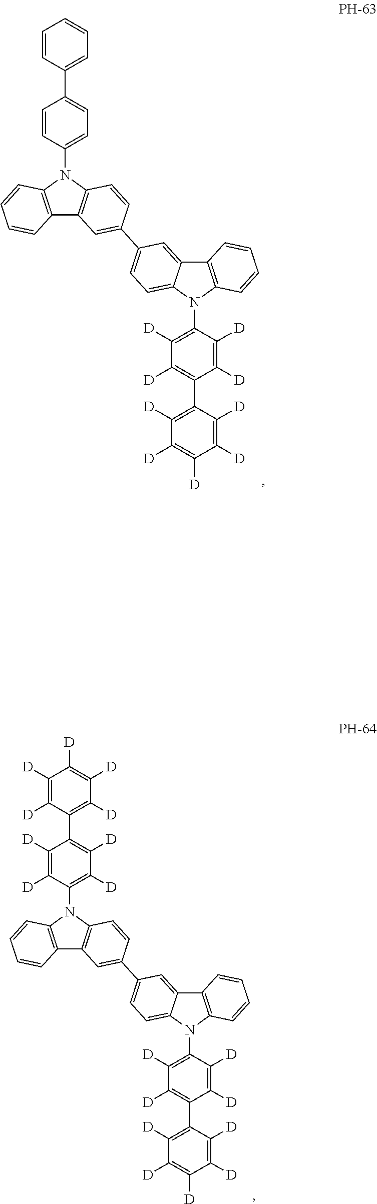 [SMILES: [2H]c1c([2H])c([2H])c(-c2c([2H])c([2H])c(-n3c4ccccc4c4cc(-c5ccc6c(c5)c5ccccc5n6-c5ccc(-c6ccccc6)cc5)ccc43)c([2H])c2[2H])c([2H])c1[2H] ; [2H]c1c([2H])c([2H])c(-c2c([2H])c([2H])c(-n3c4ccccc4c4cc(-c5ccc6c(c5)c5ccccc5n6-c5c([2H])c([2H])c(-c6c([2H])c([2H])c([2H])c([2H])c6[2H])c([2H])c5[2H])ccc43)c([2H])c2[2H])c([2H])c1[2H]] 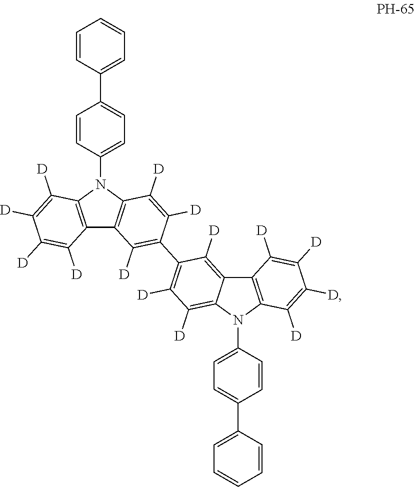 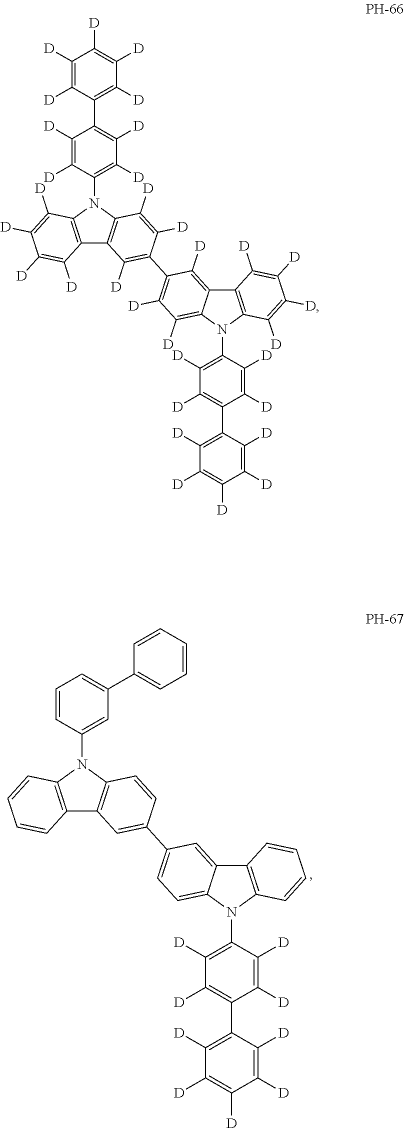 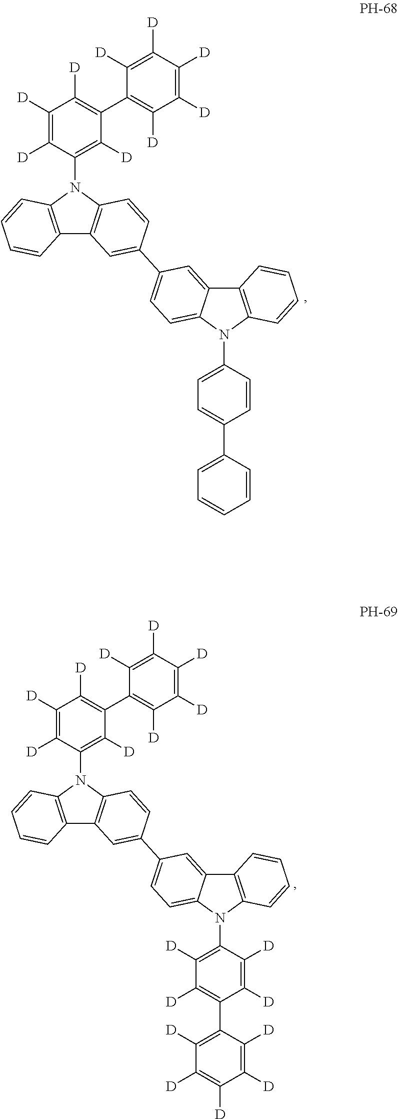 [SMILES: [2H]c1c([2H])c([2H])c(-c2c([2H])c([2H])c([2H])c(-n3c4ccccc4c4cc(-c5ccc6c(c5)c5ccccc5n6-c5ccc(-c6ccccc6)cc5)ccc43)c2[2H])c([2H])c1[2H] ; [2H]c1c([2H])c([2H])c(-c2c([2H])c([2H])c(-n3c4ccccc4c4cc(-c5ccc6c(c5)c5ccccc5n6-c5c([2H])c([2H])c([2H])c(-c6c([2H])c([2H])c([2H])c([2H])c6[2H])c5[2H])ccc43)c([2H])c2[2H])c([2H])c1[2H]] 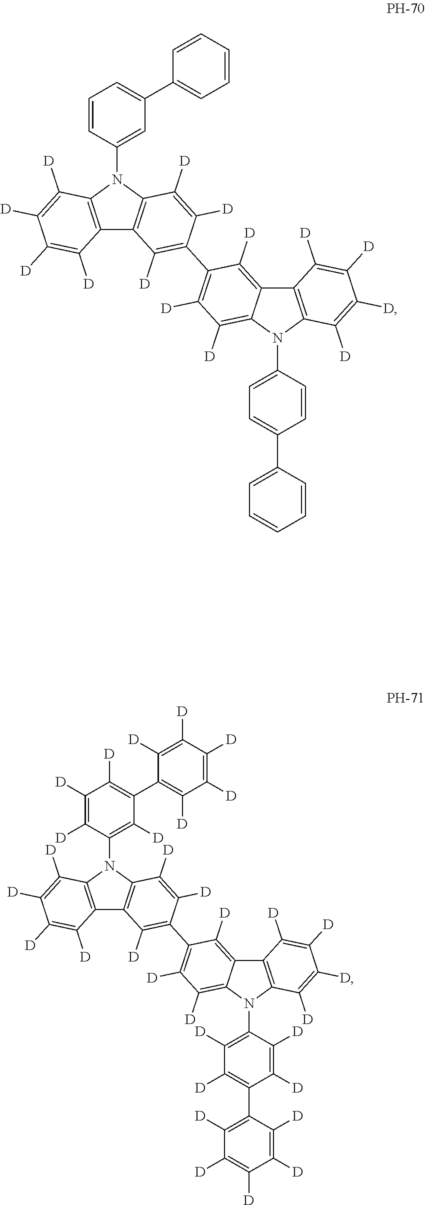 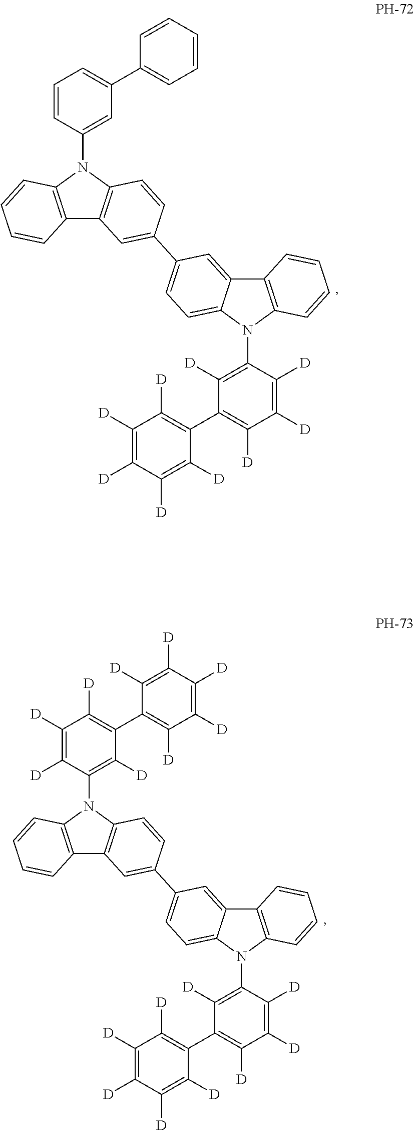 [SMILES: [2H]c1c([2H])c([2H])c(-c2c([2H])c([2H])c([2H])c(-n3c4ccccc4c4cc(-c5ccc6c(c5)c5ccccc5n6-c5cccc(-c6ccccc6)c5)ccc43)c2[2H])c([2H])c1[2H] ; [2H]c1c([2H])c([2H])c(-c2c([2H])c([2H])c([2H])c(-n3c4ccccc4c4cc(-c5ccc6c(c5)c5ccccc5n6-c5c([2H])c([2H])c([2H])c(-c6c([2H])c([2H])c([2H])c([2H])c6[2H])c5[2H])ccc43)c2[2H])c([2H])c1[2H]] 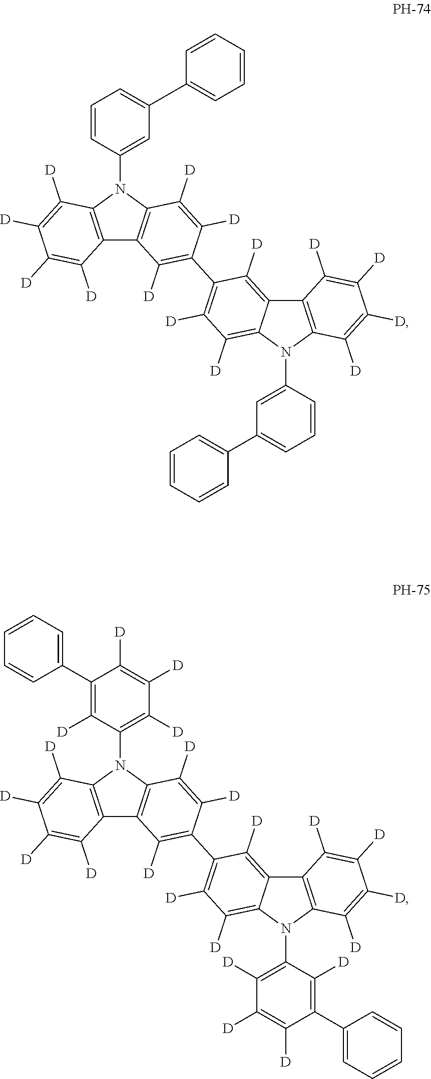 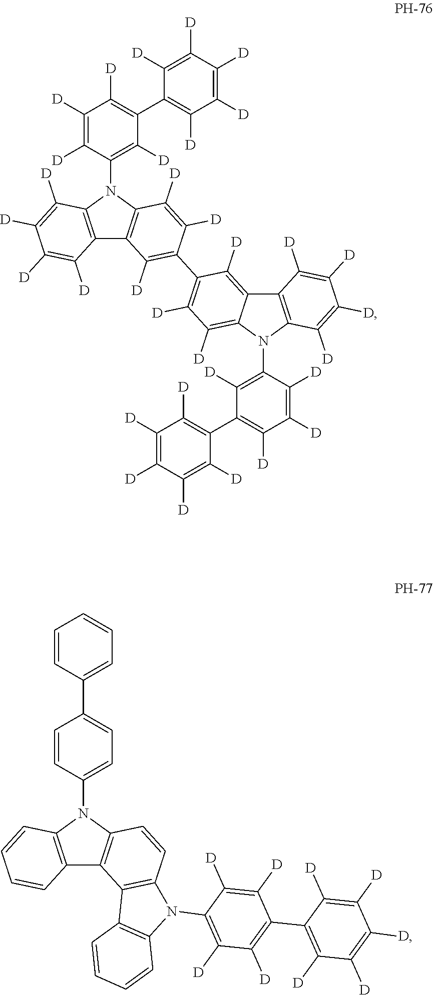 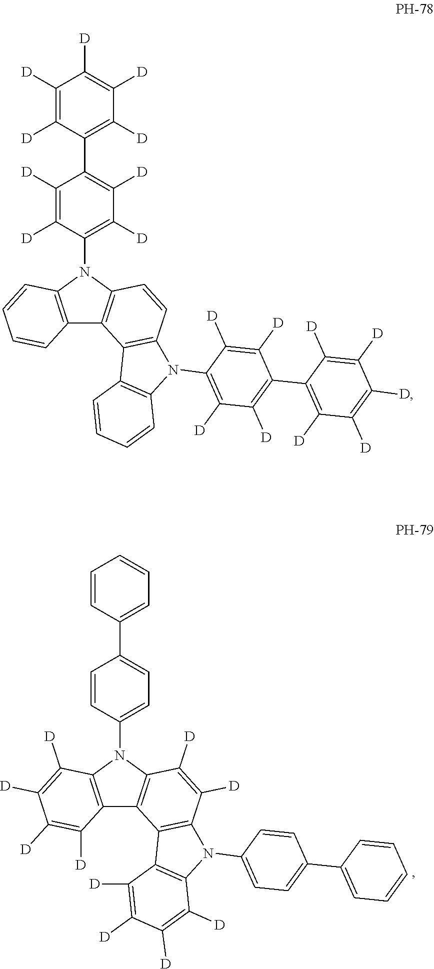 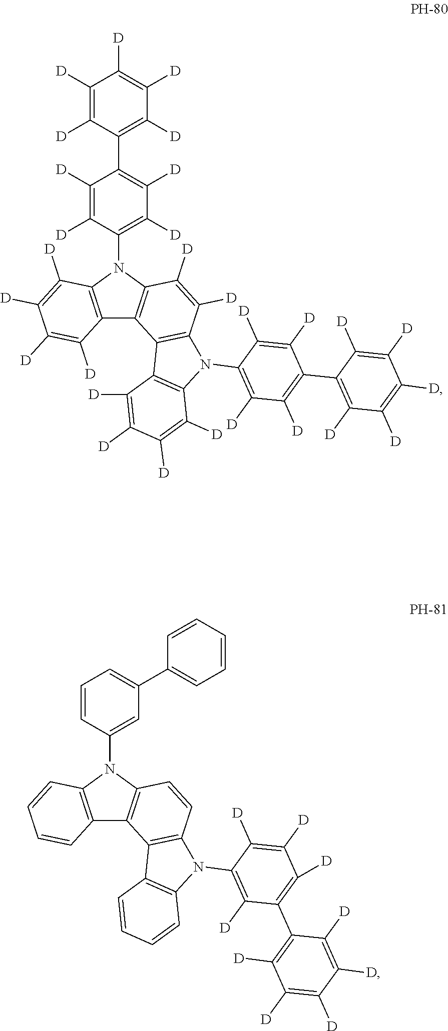 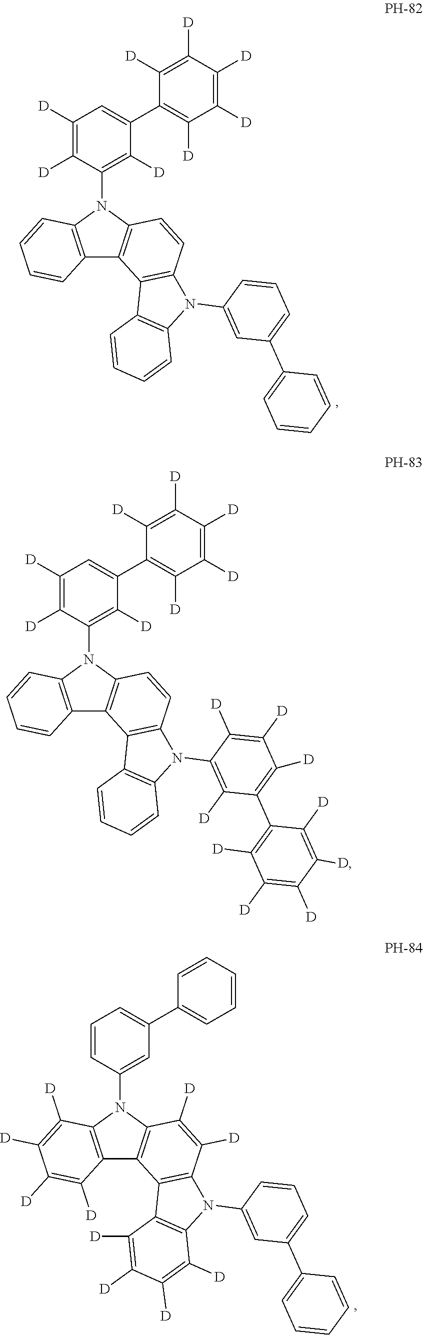 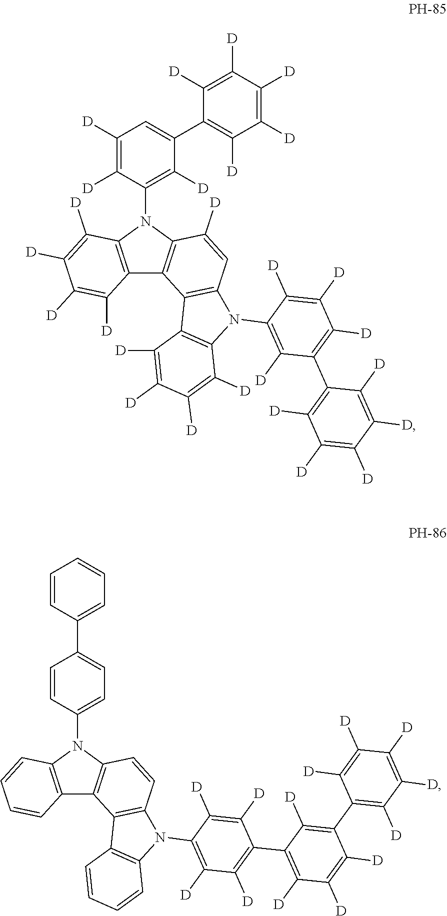 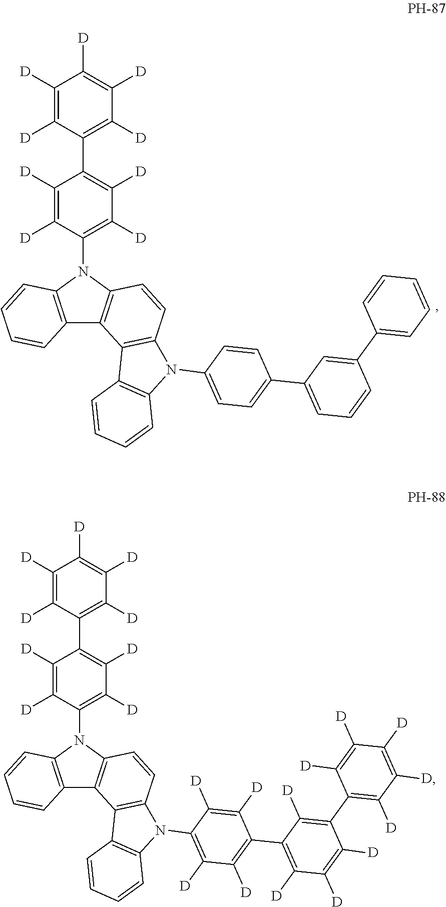 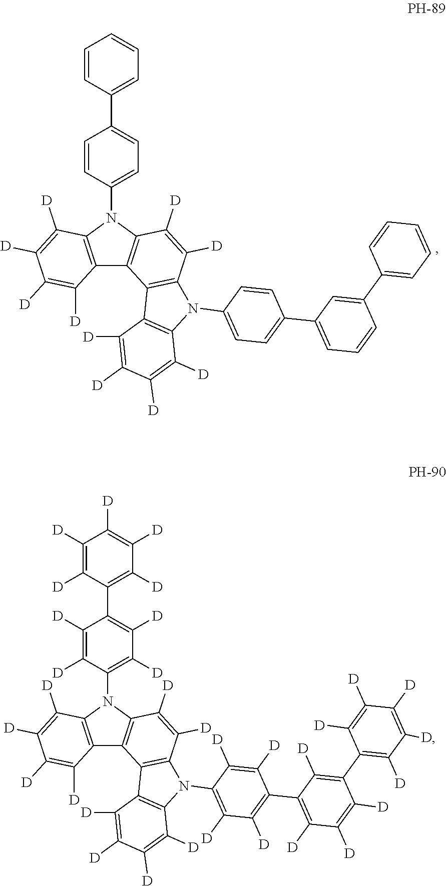 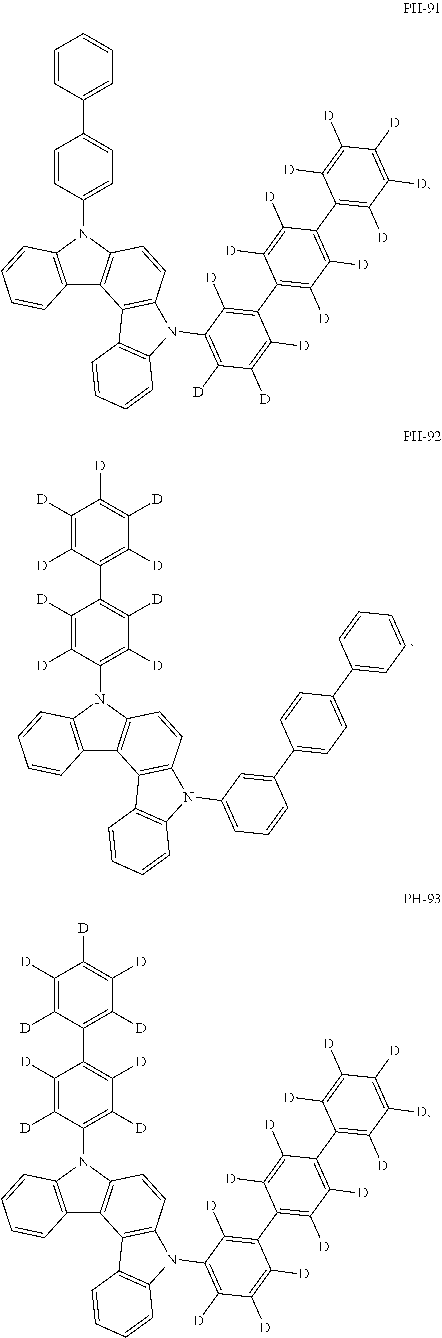 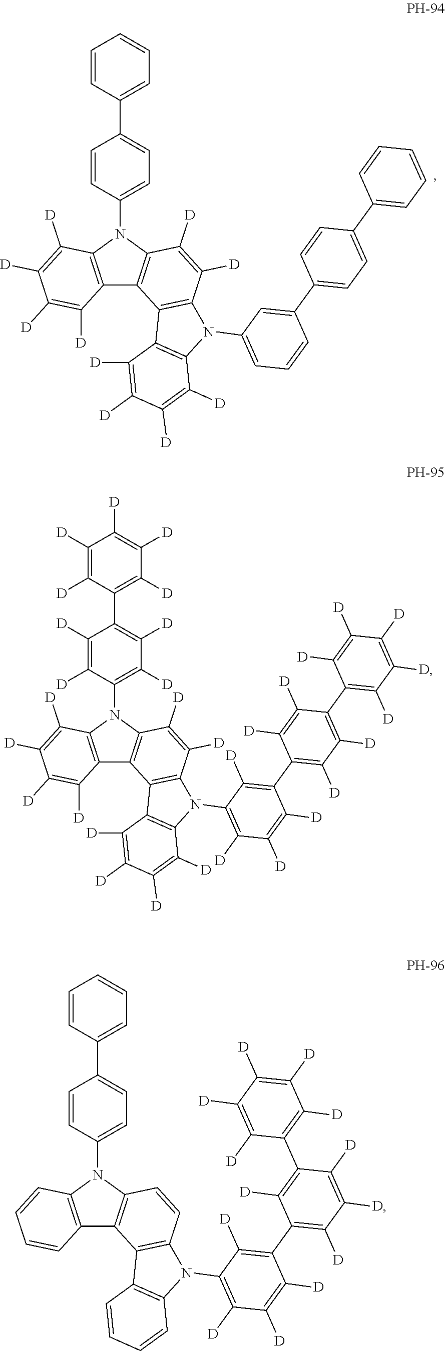 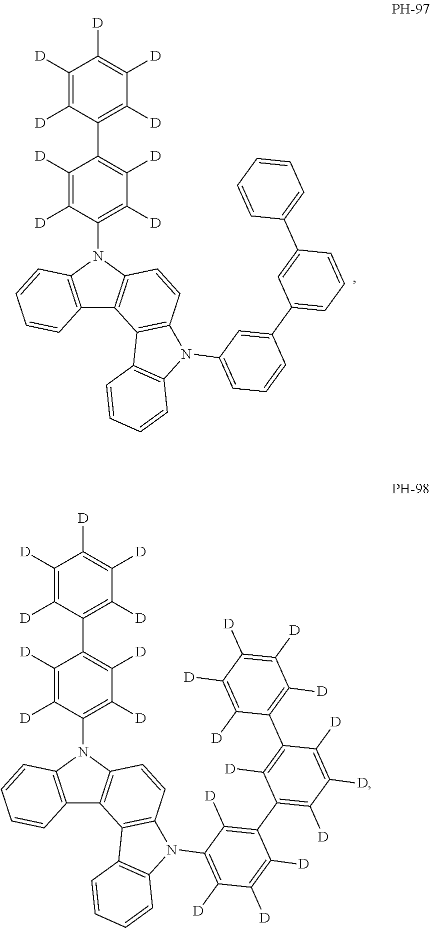 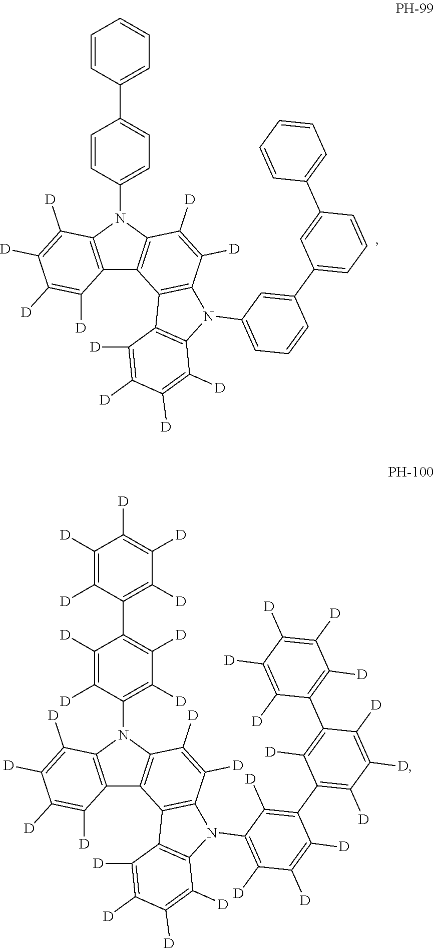 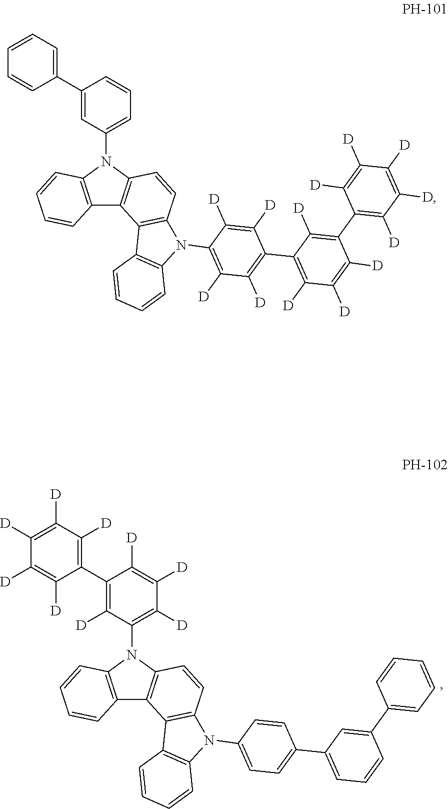 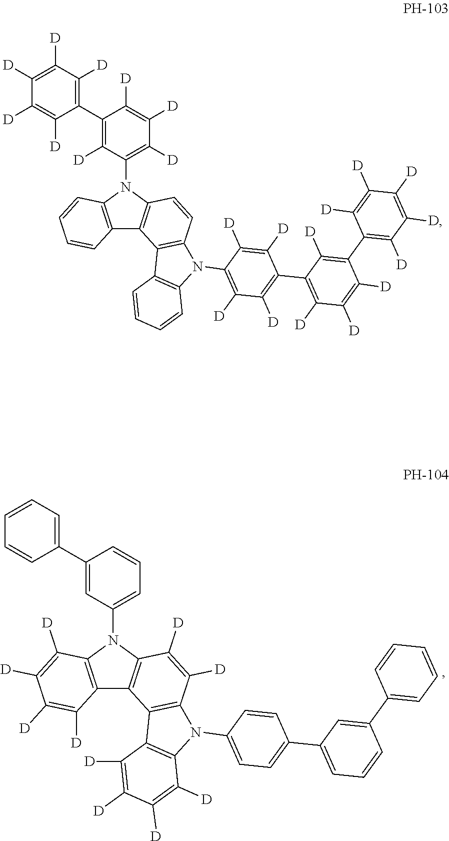 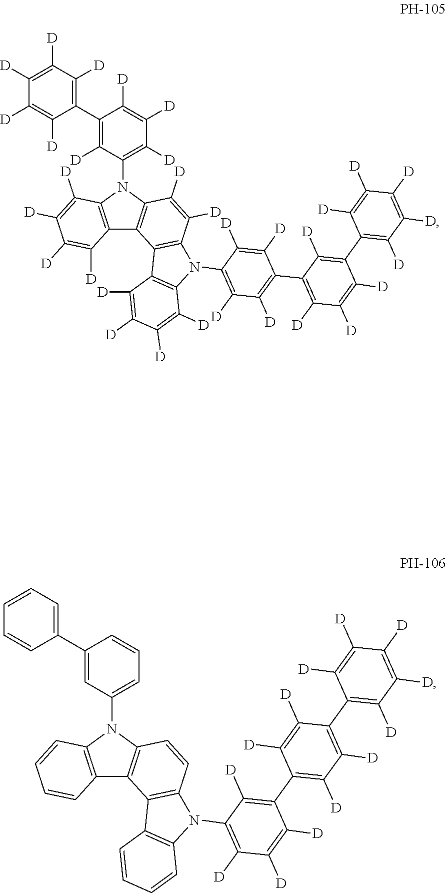 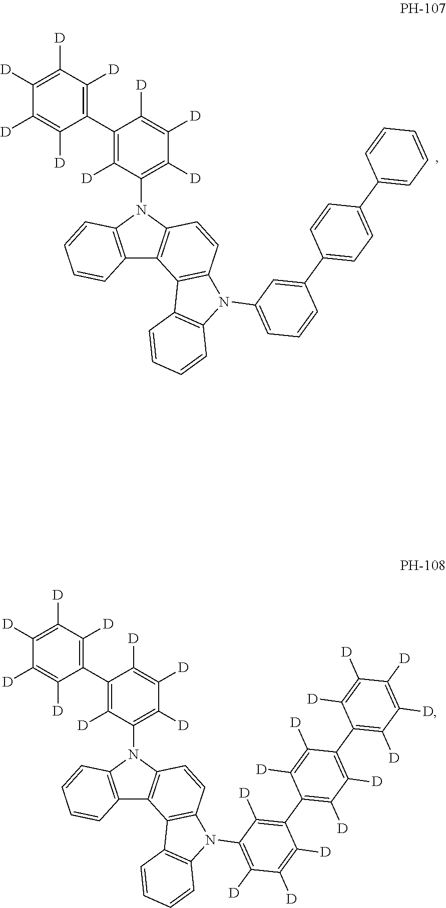 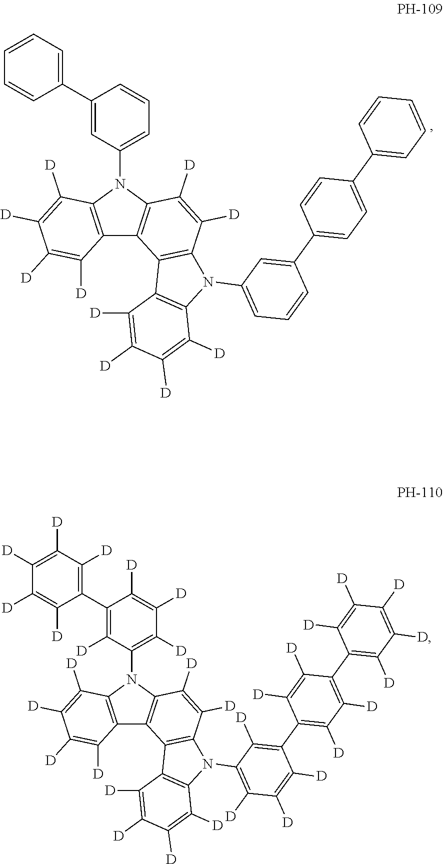 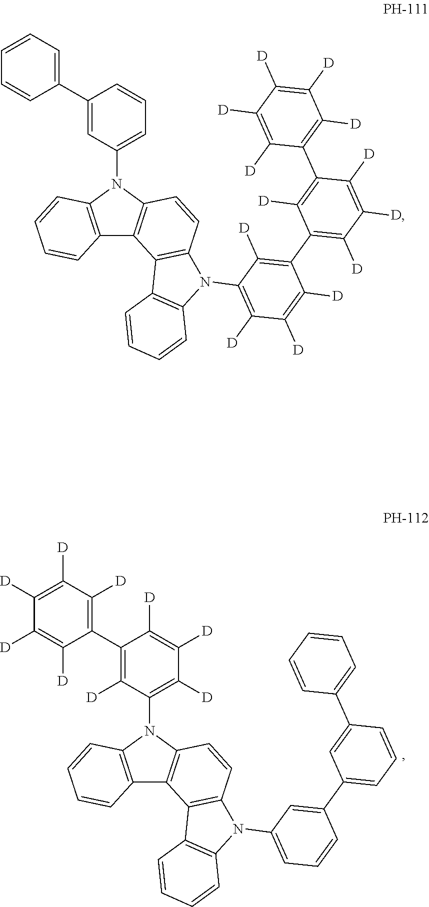 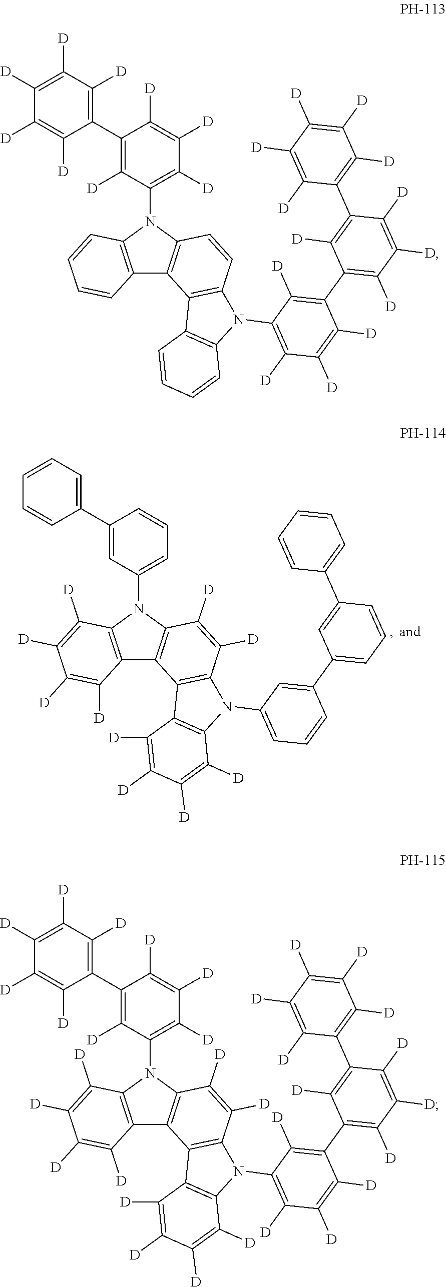
wherein optionally, hydrogens in the Compound PH-1 to Compound PH-115 can be partially or fully substituted with deuterium;
the second host compound is selected from the group consisting of Compound H-1 to Compound H-200: 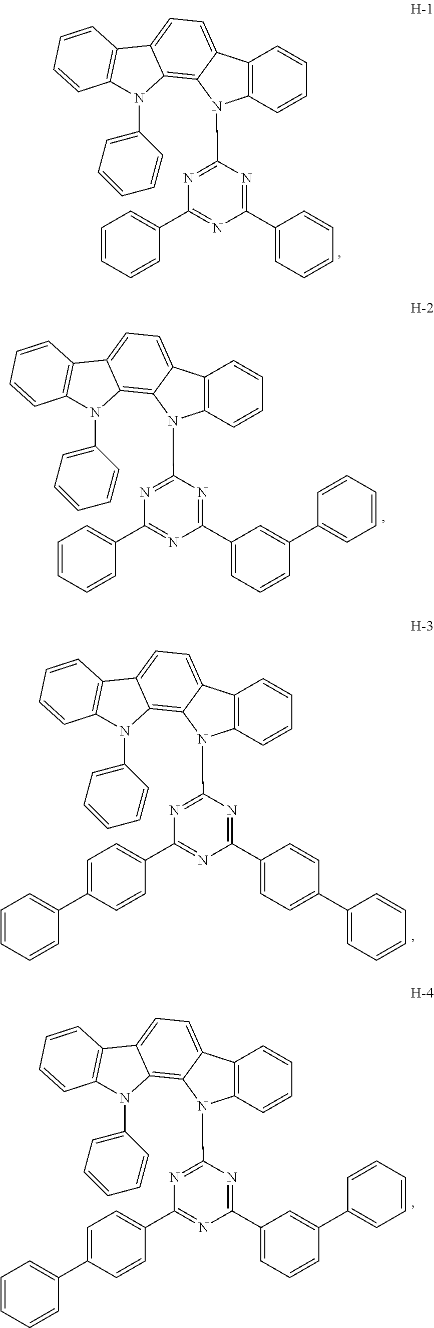 [SMILES: c1ccc(-c2nc(-c3ccccc3)nc(-n3c4ccccc4c4ccc5c6ccccc6n(-c6ccccc6)c5c43)n2)cc1 ; c1ccc(-c2cccc(-c3nc(-c4ccccc4)nc(-n4c5ccccc5c5ccc6c7ccccc7n(-c7ccccc7)c6c54)n3)c2)cc1 ; c1ccc(-c2ccc(-c3nc(-c4ccc(-c5ccccc5)cc4)nc(-n4c5ccccc5c5ccc6c7ccccc7n(-c7ccccc7)c6c54)n3)cc2)cc1 ; c1ccc(-c2ccc(-c3nc(-c4cccc(-c5ccccc5)c4)nc(-n4c5ccccc5c5ccc6c7ccccc7n(-c7ccccc7)c6c54)n3)cc2)cc1] 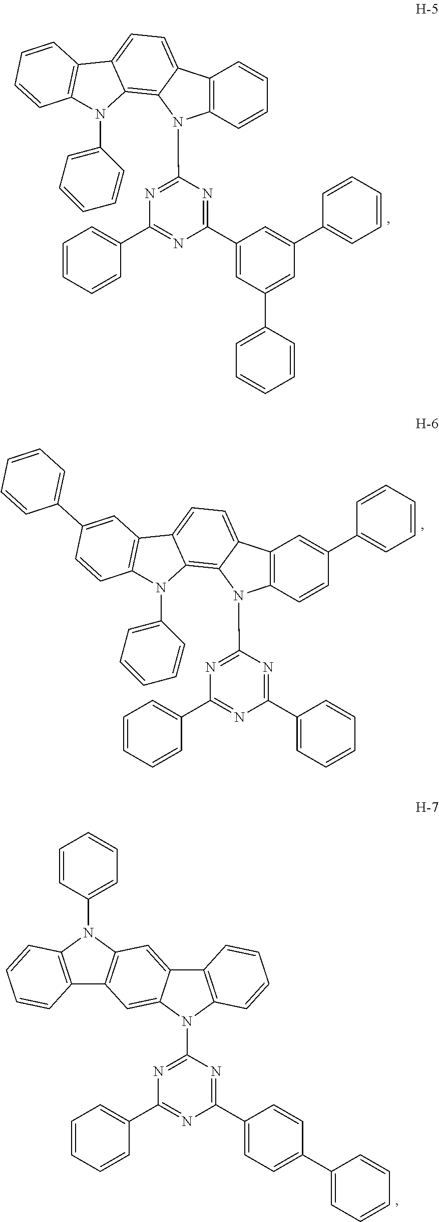 [SMILES: c1ccc(-c2cc(-c3ccccc3)cc(-c3nc(-c4ccccc4)nc(-n4c5ccccc5c5ccc6c7ccccc7n(-c7ccccc7)c6c54)n3)c2)cc1 ; c1ccc(-c2ccc3c(c2)c2ccc4c5cc(-c6ccccc6)ccc5n(-c5nc(-c6ccccc6)nc(-c6ccccc6)n5)c4c2n3-c2ccccc2)cc1 ; c1ccc(-c2ccc(-c3nc(-c4ccccc4)nc(-n4c5ccccc5c5cc6c(cc54)c4ccccc4n6-c4ccccc4)n3)cc2)cc1] 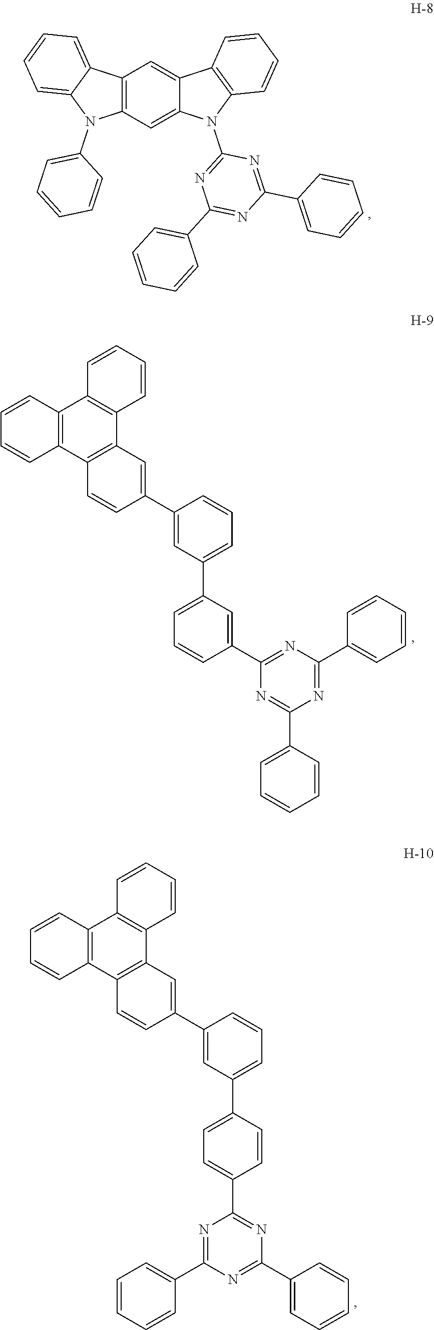 [SMILES: c1ccc(-c2nc(-c3ccccc3)nc(-n3c4ccccc4c4cc5c6ccccc6n(-c6ccccc6)c5cc43)n2)cc1 ; c1ccc(-c2nc(-c3ccccc3)nc(-c3cccc(-c4cccc(-c5ccc6c7ccccc7c7ccccc7c6c5)c4)c3)n2)cc1 ; c1ccc(-c2nc(-c3ccccc3)nc(-c3ccc(-c4cccc(-c5ccc6c7ccccc7c7ccccc7c6c5)c4)cc3)n2)cc1] 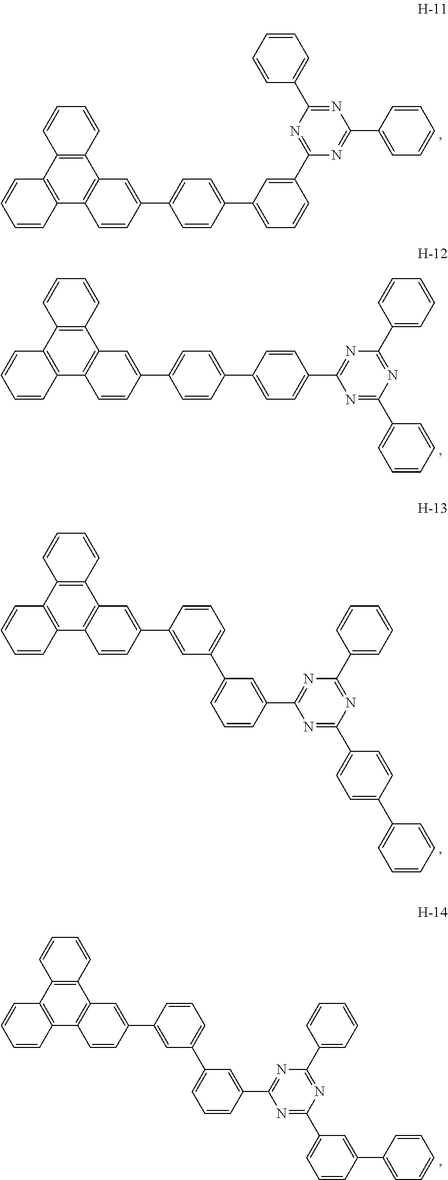 [SMILES: c1ccc(-c2nc(-c3ccccc3)nc(-c3cccc(-c4ccc(-c5ccc6c7ccccc7c7ccccc7c6c5)cc4)c3)n2)cc1 ; c1ccc(-c2nc(-c3ccccc3)nc(-c3ccc(-c4ccc(-c5ccc6c7ccccc7c7ccccc7c6c5)cc4)cc3)n2)cc1 ; c1ccc(-c2ccc(-c3nc(-c4ccccc4)nc(-c4cccc(-c5cccc(-c6ccc7c8ccccc8c8ccccc8c7c6)c5)c4)n3)cc2)cc1 ; c1ccc(-c2cccc(-c3nc(-c4ccccc4)nc(-c4cccc(-c5cccc(-c6ccc7c8ccccc8c8ccccc8c7c6)c5)c4)n3)c2)cc1] 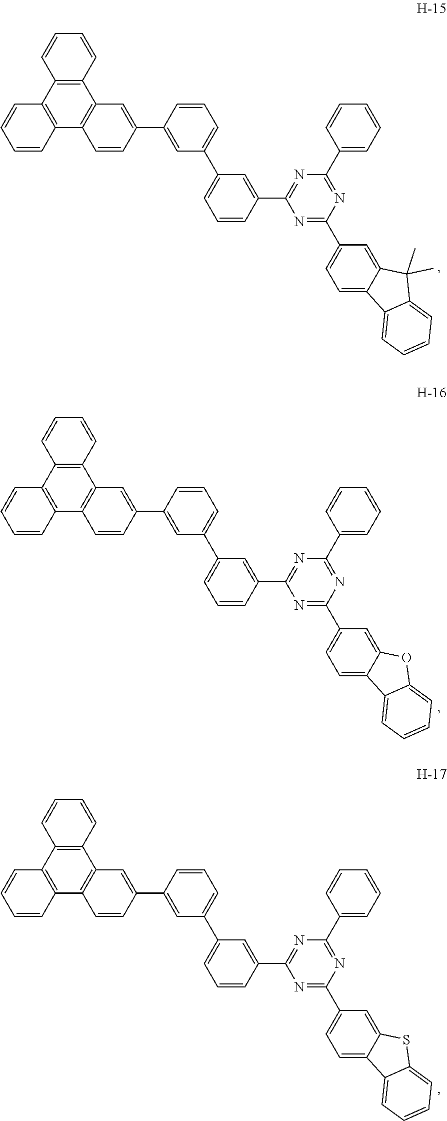 [SMILES: CC1(C)c2ccccc2-c2ccc(-c3nc(-c4ccccc4)nc(-c4cccc(-c5cccc(-c6ccc7c8ccccc8c8ccccc8c7c6)c5)c4)n3)cc21 ; c1ccc(-c2nc(-c3cccc(-c4cccc(-c5ccc6c7ccccc7c7ccccc7c6c5)c4)c3)nc(-c3ccc4c(c3)oc3ccccc34)n2)cc1 ; c1ccc(-c2nc(-c3cccc(-c4cccc(-c5ccc6c7ccccc7c7ccccc7c6c5)c4)c3)nc(-c3ccc4c(c3)sc3ccccc34)n2)cc1] 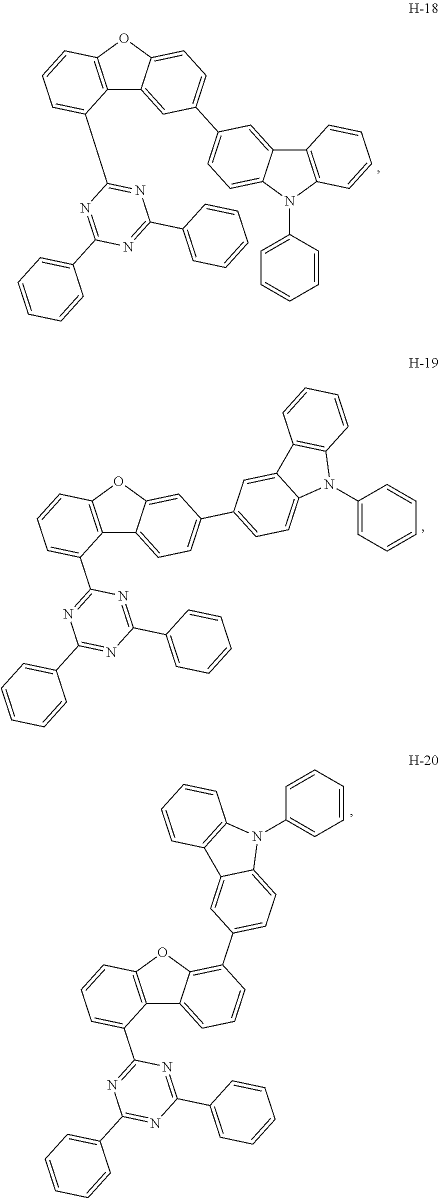 [SMILES: c1ccc(-c2nc(-c3ccccc3)nc(-c3cccc4oc5ccc(-c6ccc7c(c6)c6ccccc6n7-c6ccccc6)cc5c34)n2)cc1 ; c1ccc(-c2nc(-c3ccccc3)nc(-c3cccc4oc5cc(-c6ccc7c(c6)c6ccccc6n7-c6ccccc6)ccc5c34)n2)cc1 ; c1ccc(-c2nc(-c3ccccc3)nc(-c3cccc4oc5c(-c6ccc7c(c6)c6ccccc6n7-c6ccccc6)cccc5c34)n2)cc1] 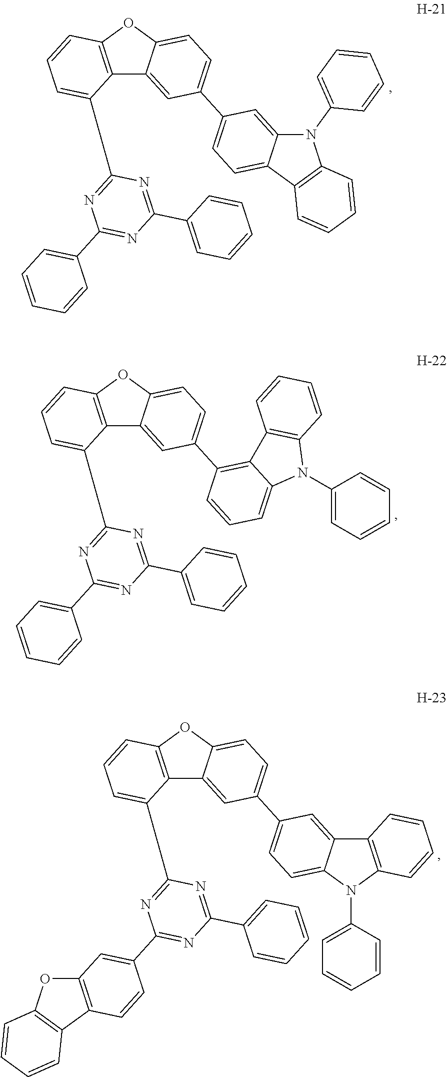 [SMILES: c1ccc(-c2nc(-c3ccccc3)nc(-c3cccc4oc5ccc(-c6ccc7c8ccccc8n(-c8ccccc8)c7c6)cc5c34)n2)cc1 ; c1ccc(-c2nc(-c3ccccc3)nc(-c3cccc4oc5ccc(-c6cccc7c6c6ccccc6n7-c6ccccc6)cc5c34)n2)cc1 ; c1ccc(-c2nc(-c3ccc4c(c3)oc3ccccc34)nc(-c3cccc4oc5ccc(-c6ccc7c(c6)c6ccccc6n7-c6ccccc6)cc5c34)n2)cc1] 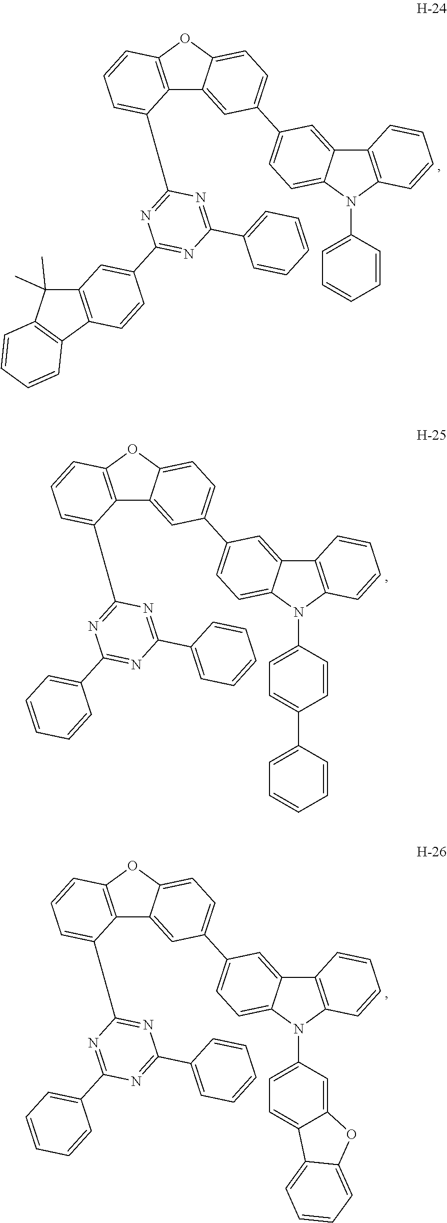 [SMILES: CC1(C)c2ccccc2-c2ccc(-c3nc(-c4ccccc4)nc(-c4cccc5oc6ccc(-c7ccc8c(c7)c7ccccc7n8-c7ccccc7)cc6c45)n3)cc21 ; c1ccc(-c2ccc(-n3c4ccccc4c4cc(-c5ccc6oc7cccc(-c8nc(-c9ccccc9)nc(-c9ccccc9)n8)c7c6c5)ccc43)cc2)cc1 ; c1ccc(-c2nc(-c3ccccc3)nc(-c3cccc4oc5ccc(-c6ccc7c(c6)c6ccccc6n7-c6ccc7c(c6)oc6ccccc67)cc5c34)n2)cc1] 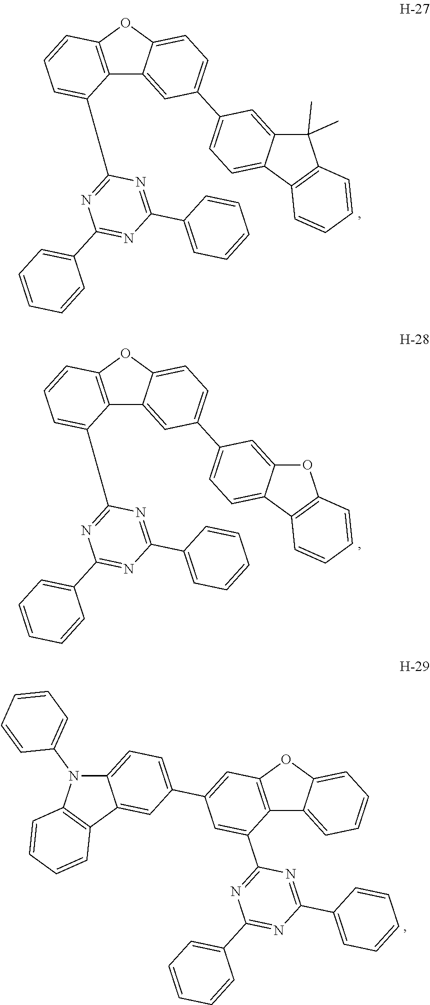 [SMILES: CC1(C)c2ccccc2-c2ccc(-c3ccc4oc5cccc(-c6nc(-c7ccccc7)nc(-c7ccccc7)n6)c5c4c3)cc21 ; c1ccc(-c2nc(-c3ccccc3)nc(-c3cccc4oc5ccc(-c6ccc7c(c6)oc6ccccc67)cc5c34)n2)cc1 ; c1ccc(-c2nc(-c3ccccc3)nc(-c3cc(-c4ccc5c(c4)c4ccccc4n5-c4ccccc4)cc4oc5ccccc5c34)n2)cc1] 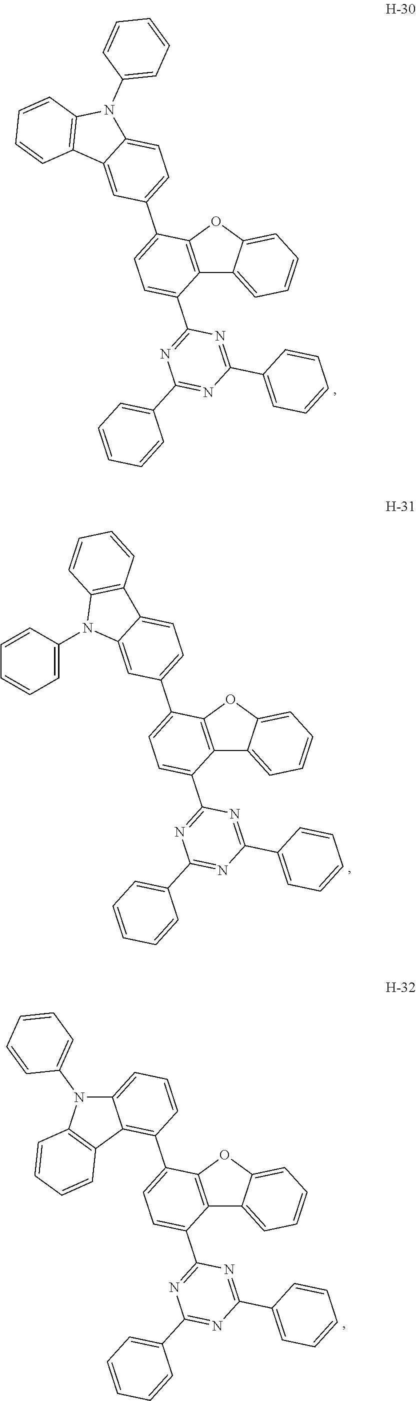 [SMILES: c1ccc(-c2nc(-c3ccccc3)nc(-c3ccc(-c4ccc5c(c4)c4ccccc4n5-c4ccccc4)c4oc5ccccc5c34)n2)cc1 ; c1ccc(-c2nc(-c3ccccc3)nc(-c3ccc(-c4ccc5c6ccccc6n(-c6ccccc6)c5c4)c4oc5ccccc5c34)n2)cc1 ; c1ccc(-c2nc(-c3ccccc3)nc(-c3ccc(-c4cccc5c4c4ccccc4n5-c4ccccc4)c4oc5ccccc5c34)n2)cc1] 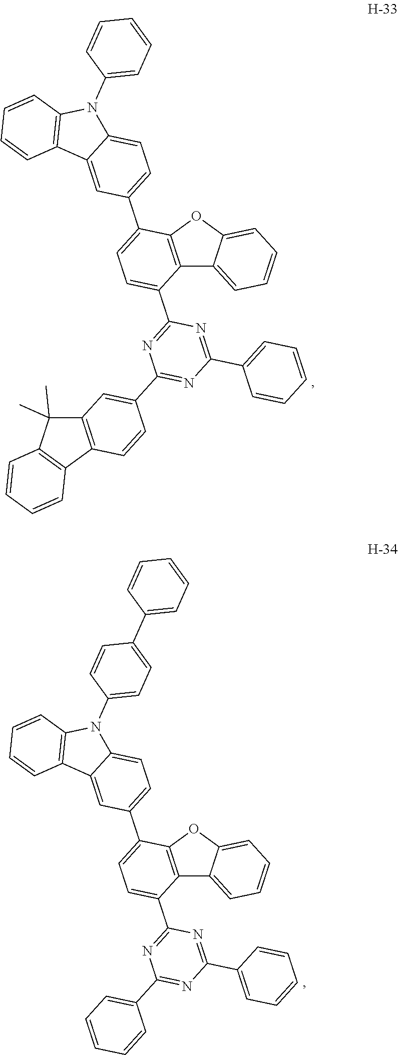 [SMILES: CC1(C)c2ccccc2-c2ccc(-c3nc(-c4ccccc4)nc(-c4ccc(-c5ccc6c(c5)c5ccccc5n6-c5ccccc5)c5oc6ccccc6c45)n3)cc21 ; c1ccc(-c2ccc(-n3c4ccccc4c4cc(-c5ccc(-c6nc(-c7ccccc7)nc(-c7ccccc7)n6)c6c5oc5ccccc56)ccc43)cc2)cc1] 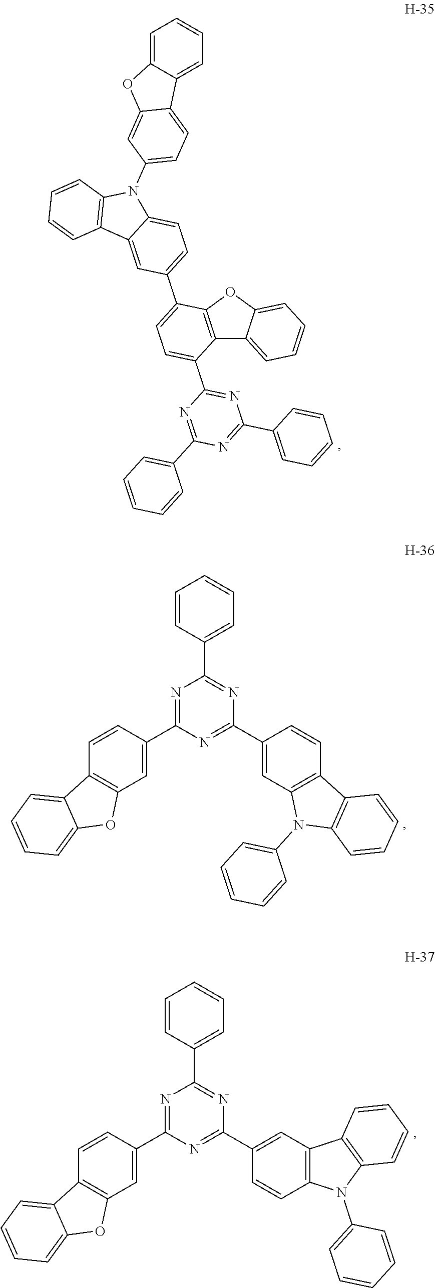 [SMILES: c1ccc(-c2nc(-c3ccccc3)nc(-c3ccc(-c4ccc5c(c4)c4ccccc4n5-c4ccc5c(c4)oc4ccccc45)c4oc5ccccc5c34)n2)cc1 ; c1ccc(-c2nc(-c3ccc4c(c3)oc3ccccc34)nc(-c3ccc4c5ccccc5n(-c5ccccc5)c4c3)n2)cc1 ; c1ccc(-c2nc(-c3ccc4c(c3)oc3ccccc34)nc(-c3ccc4c(c3)c3ccccc3n4-c3ccccc3)n2)cc1] 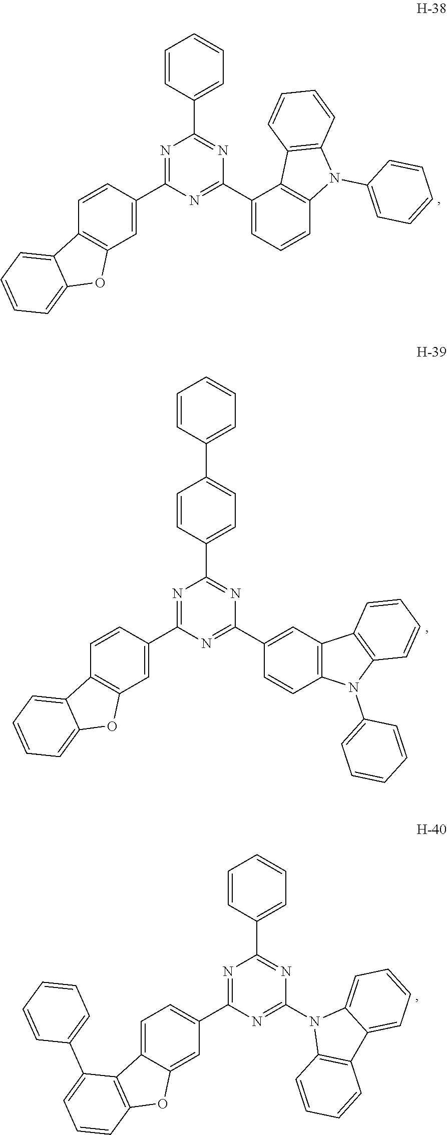 [SMILES: c1ccc(-c2nc(-c3ccc4c(c3)oc3ccccc34)nc(-c3cccc4c3c3ccccc3n4-c3ccccc3)n2)cc1 ; c1ccc(-c2ccc(-c3nc(-c4ccc5c(c4)oc4ccccc45)nc(-c4ccc5c(c4)c4ccccc4n5-c4ccccc4)n3)cc2)cc1 ; c1ccc(-c2nc(-c3ccc4c(c3)oc3cccc(-c5ccccc5)c34)nc(-n3c4ccccc4c4ccccc43)n2)cc1] 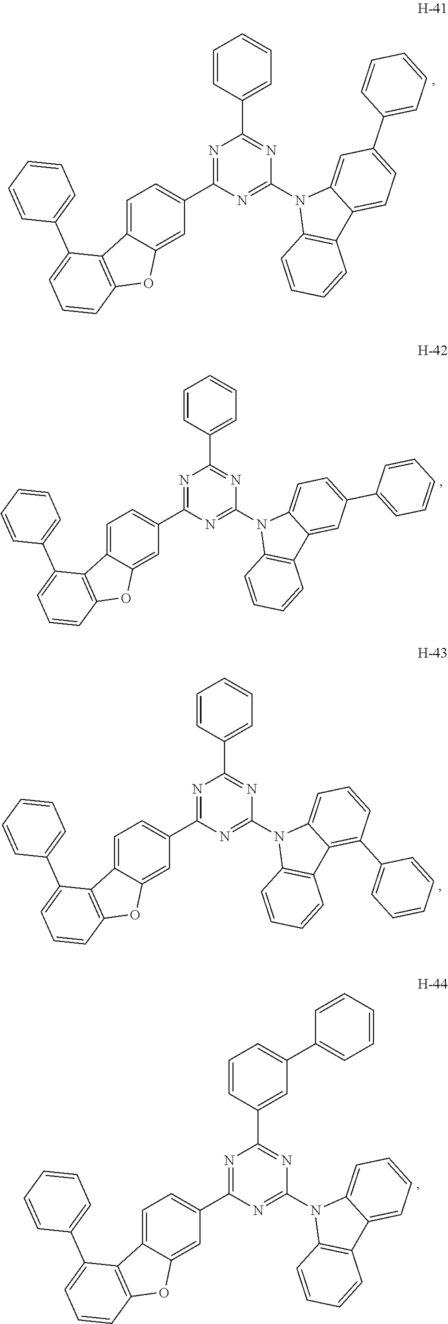 [SMILES: c1ccc(-c2ccc3c4ccccc4n(-c4nc(-c5ccccc5)nc(-c5ccc6c(c5)oc5cccc(-c7ccccc7)c56)n4)c3c2)cc1 ; c1ccc(-c2ccc3c(c2)c2ccccc2n3-c2nc(-c3ccccc3)nc(-c3ccc4c(c3)oc3cccc(-c5ccccc5)c34)n2)cc1 ; c1ccc(-c2nc(-c3ccc4c(c3)oc3cccc(-c5ccccc5)c34)nc(-n3c4ccccc4c4c(-c5ccccc5)cccc43)n2)cc1 ; c1ccc(-c2cccc(-c3nc(-c4ccc5c(c4)oc4cccc(-c6ccccc6)c45)nc(-n4c5ccccc5c5ccccc54)n3)c2)cc1] 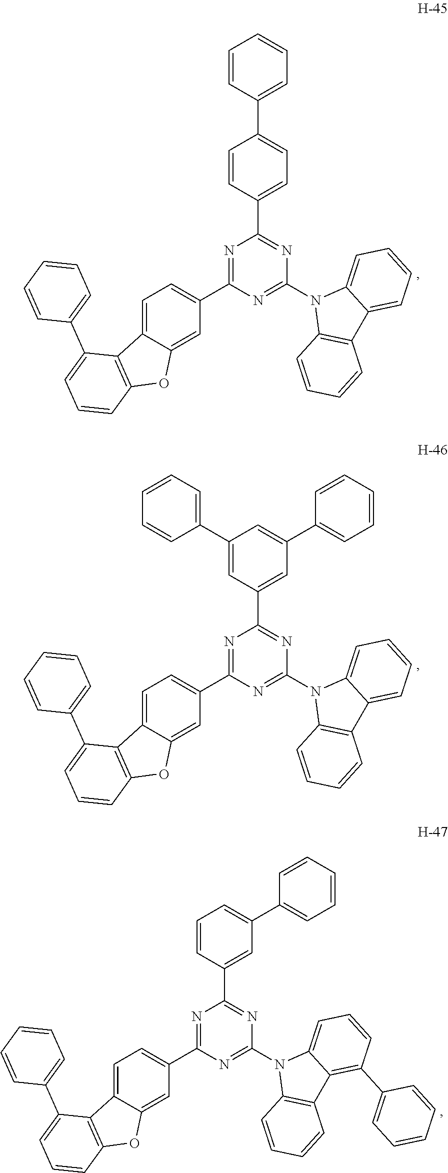 [SMILES: c1ccc(-c2ccc(-c3nc(-c4ccc5c(c4)oc4cccc(-c6ccccc6)c45)nc(-n4c5ccccc5c5ccccc54)n3)cc2)cc1 ; c1ccc(-c2cc(-c3ccccc3)cc(-c3nc(-c4ccc5c(c4)oc4cccc(-c6ccccc6)c45)nc(-n4c5ccccc5c5ccccc54)n3)c2)cc1 ; c1ccc(-c2cccc(-c3nc(-c4ccc5c(c4)oc4cccc(-c6ccccc6)c45)nc(-n4c5ccccc5c5c(-c6ccccc6)cccc54)n3)c2)cc1] 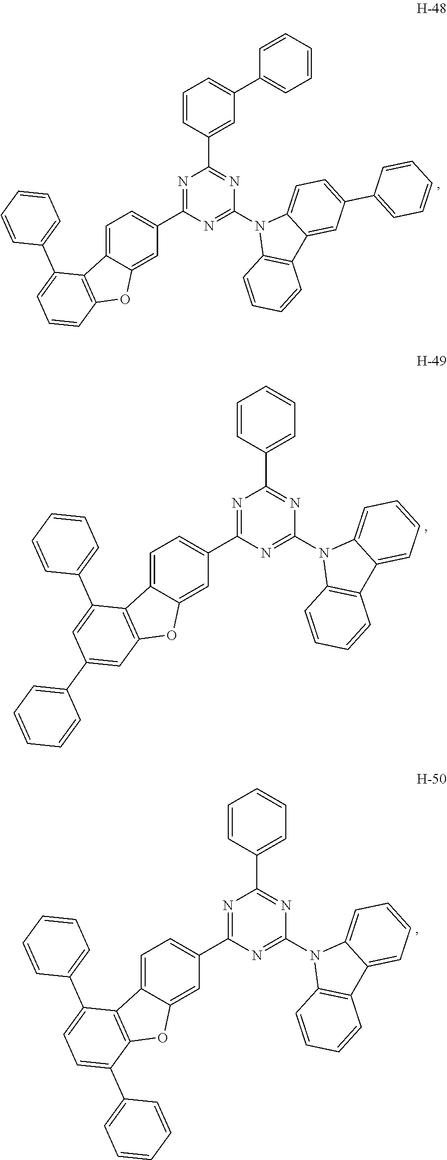 [SMILES: c1ccc(-c2cccc(-c3nc(-c4ccc5c(c4)oc4cccc(-c6ccccc6)c45)nc(-n4c5ccccc5c5cc(-c6ccccc6)ccc54)n3)c2)cc1 ; c1ccc(-c2cc(-c3ccccc3)c3c(c2)oc2cc(-c4nc(-c5ccccc5)nc(-n5c6ccccc6c6ccccc65)n4)ccc23)cc1 ; c1ccc(-c2nc(-c3ccc4c(c3)oc3c(-c5ccccc5)ccc(-c5ccccc5)c34)nc(-n3c4ccccc4c4ccccc43)n2)cc1] 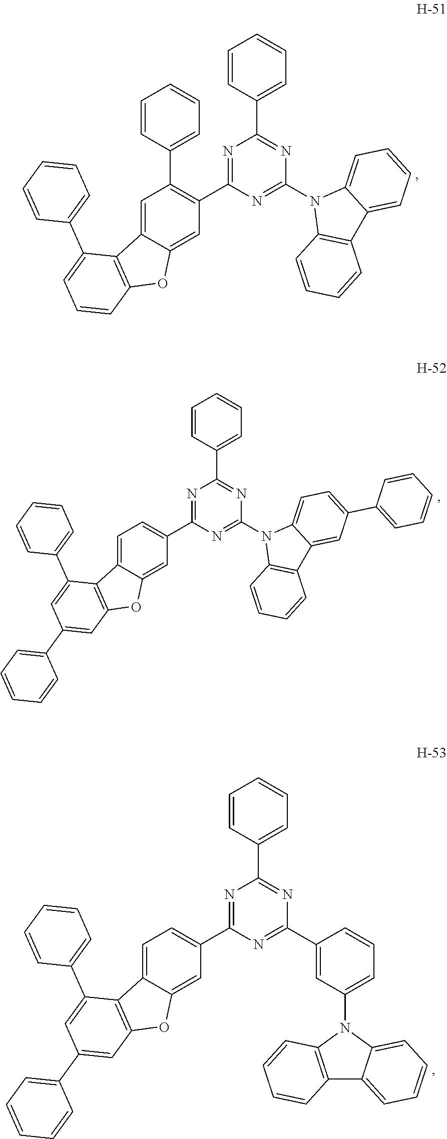 [SMILES: c1ccc(-c2nc(-c3cc4oc5cccc(-c6ccccc6)c5c4cc3-c3ccccc3)nc(-n3c4ccccc4c4ccccc43)n2)cc1 ; c1ccc(-c2cc(-c3ccccc3)c3c(c2)oc2cc(-c4nc(-c5ccccc5)nc(-n5c6ccccc6c6cc(-c7ccccc7)ccc65)n4)ccc23)cc1 ; c1ccc(-c2cc(-c3ccccc3)c3c(c2)oc2cc(-c4nc(-c5ccccc5)nc(-c5cccc(-n6c7ccccc7c7ccccc76)c5)n4)ccc23)cc1] 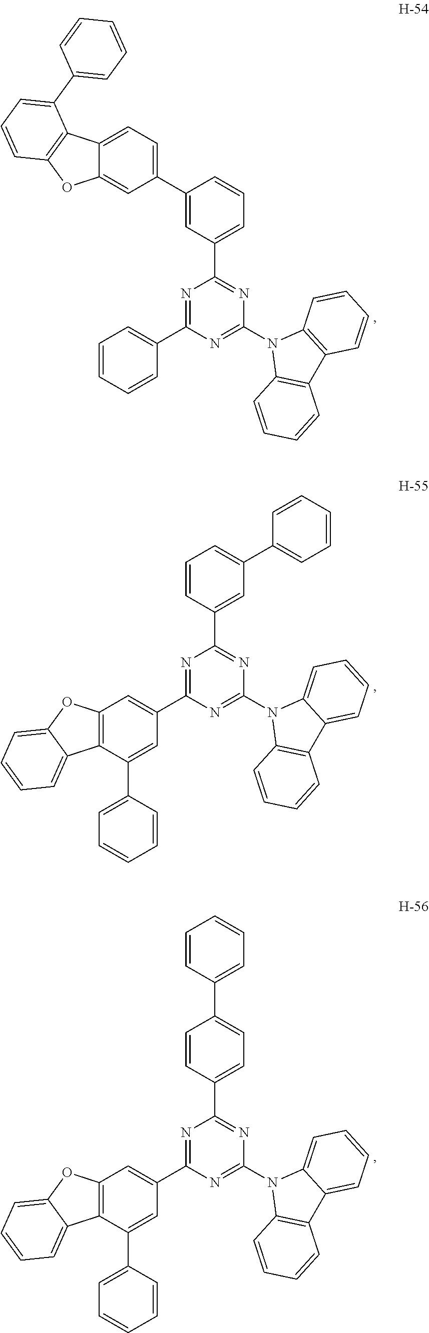 [SMILES: c1ccc(-c2nc(-c3cccc(-c4ccc5c(c4)oc4cccc(-c6ccccc6)c45)c3)nc(-n3c4ccccc4c4ccccc43)n2)cc1 ; c1ccc(-c2cccc(-c3nc(-c4cc(-c5ccccc5)c5c(c4)oc4ccccc45)nc(-n4c5ccccc5c5ccccc54)n3)c2)cc1 ; c1ccc(-c2ccc(-c3nc(-c4cc(-c5ccccc5)c5c(c4)oc4ccccc45)nc(-n4c5ccccc5c5ccccc54)n3)cc2)cc1] 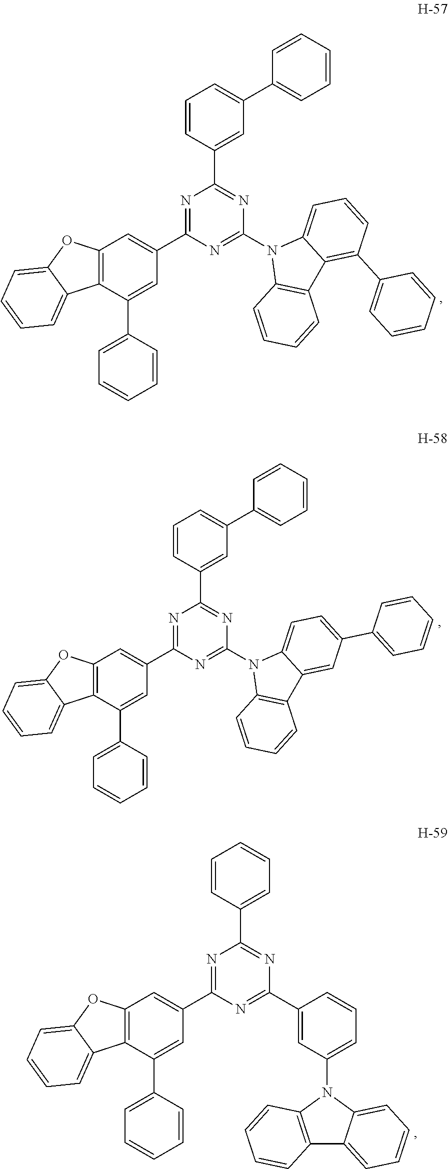 [SMILES: c1ccc(-c2cccc(-c3nc(-c4cc(-c5ccccc5)c5c(c4)oc4ccccc45)nc(-n4c5ccccc5c5c(-c6ccccc6)cccc54)n3)c2)cc1 ; c1ccc(-c2cccc(-c3nc(-c4cc(-c5ccccc5)c5c(c4)oc4ccccc45)nc(-n4c5ccccc5c5cc(-c6ccccc6)ccc54)n3)c2)cc1 ; c1ccc(-c2nc(-c3cccc(-n4c5ccccc5c5ccccc54)c3)nc(-c3cc(-c4ccccc4)c4c(c3)oc3ccccc34)n2)cc1] 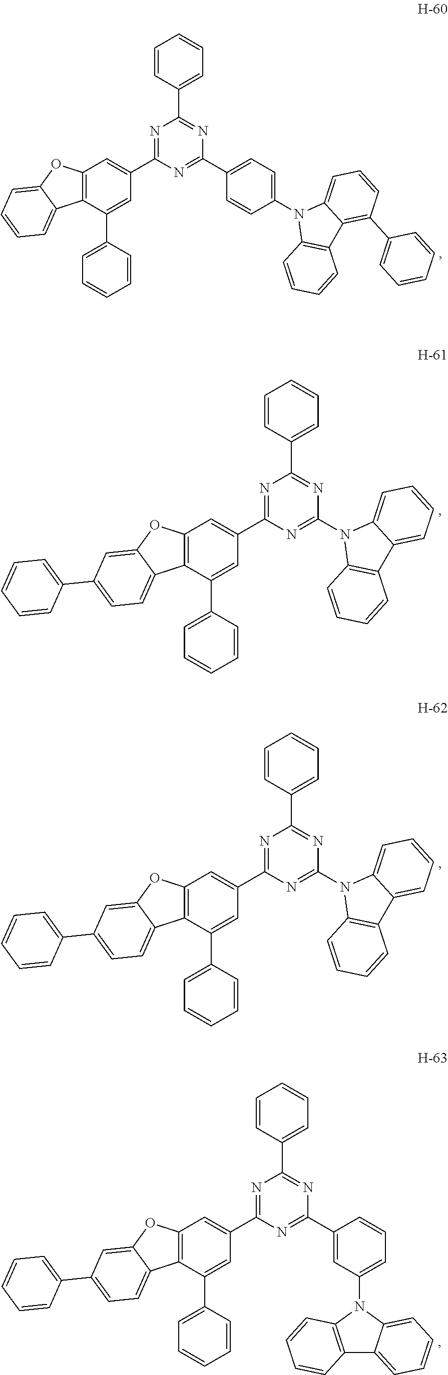 [SMILES: c1ccc(-c2nc(-c3ccc(-n4c5ccccc5c5c(-c6ccccc6)cccc54)cc3)nc(-c3cc(-c4ccccc4)c4c(c3)oc3ccccc34)n2)cc1 ; c1ccc(-c2ccc3c(c2)oc2cc(-c4nc(-c5ccccc5)nc(-n5c6ccccc6c6ccccc65)n4)cc(-c4ccccc4)c23)cc1 ; c1ccc(-c2ccc3c(c2)oc2cc(-c4nc(-c5ccccc5)nc(-n5c6ccccc6c6ccccc65)n4)cc(-c4ccccc4)c23)cc1 ; c1ccc(-c2ccc3c(c2)oc2cc(-c4nc(-c5ccccc5)nc(-c5cccc(-n6c7ccccc7c7ccccc76)c5)n4)cc(-c4ccccc4)c23)cc1] 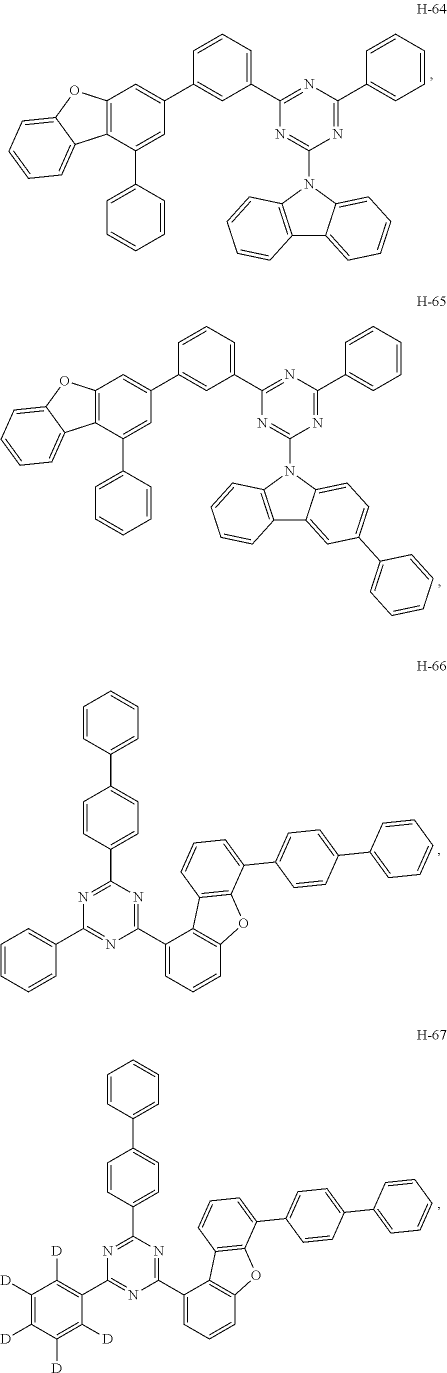 [SMILES: c1ccc(-c2nc(-c3cccc(-c4cc(-c5ccccc5)c5c(c4)oc4ccccc45)c3)nc(-n3c4ccccc4c4ccccc43)n2)cc1 ; c1ccc(-c2ccc3c(c2)c2ccccc2n3-c2nc(-c3ccccc3)nc(-c3cccc(-c4cc(-c5ccccc5)c5c(c4)oc4ccccc45)c3)n2)cc1 ; c1ccc(-c2ccc(-c3nc(-c4ccccc4)nc(-c4cccc5oc6c(-c7ccc(-c8ccccc8)cc7)cccc6c45)n3)cc2)cc1 ; [2H]c1c([2H])c([2H])c(-c2nc(-c3ccc(-c4ccccc4)cc3)nc(-c3cccc4oc5c(-c6ccc(-c7ccccc7)cc6)cccc5c34)n2)c([2H])c1[2H]] 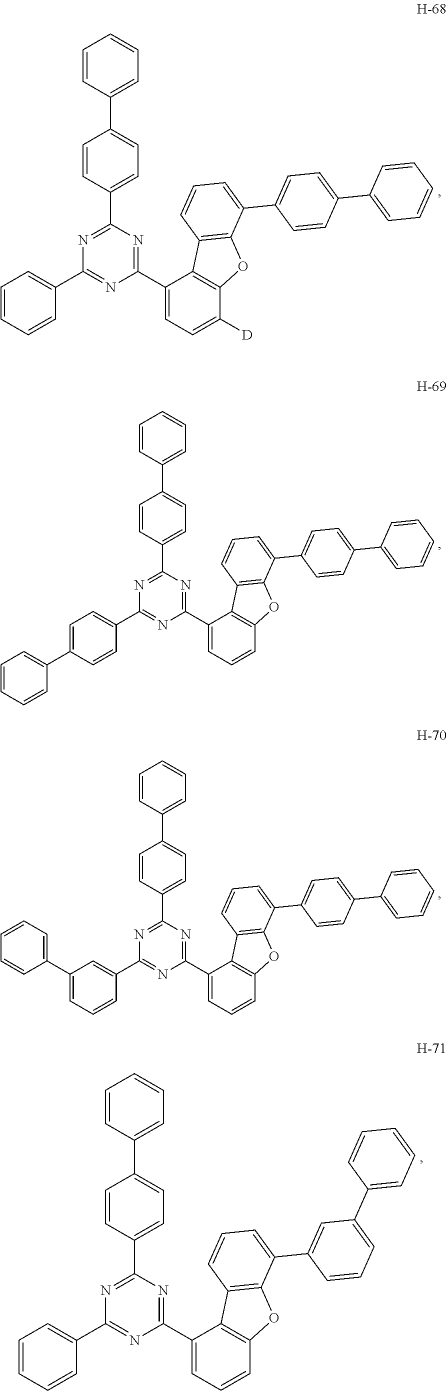 [SMILES: [2H]c1ccc(-c2nc(-c3ccccc3)nc(-c3ccc(-c4ccccc4)cc3)n2)c2c1oc1c(-c3ccc(-c4ccccc4)cc3)cccc12 ; c1ccc(-c2ccc(-c3nc(-c4ccc(-c5ccccc5)cc4)nc(-c4cccc5oc6c(-c7ccc(-c8ccccc8)cc7)cccc6c45)n3)cc2)cc1 ; c1ccc(-c2ccc(-c3nc(-c4cccc(-c5ccccc5)c4)nc(-c4cccc5oc6c(-c7ccc(-c8ccccc8)cc7)cccc6c45)n3)cc2)cc1 ; c1ccc(-c2ccc(-c3nc(-c4ccccc4)nc(-c4cccc5oc6c(-c7cccc(-c8ccccc8)c7)cccc6c45)n3)cc2)cc1] 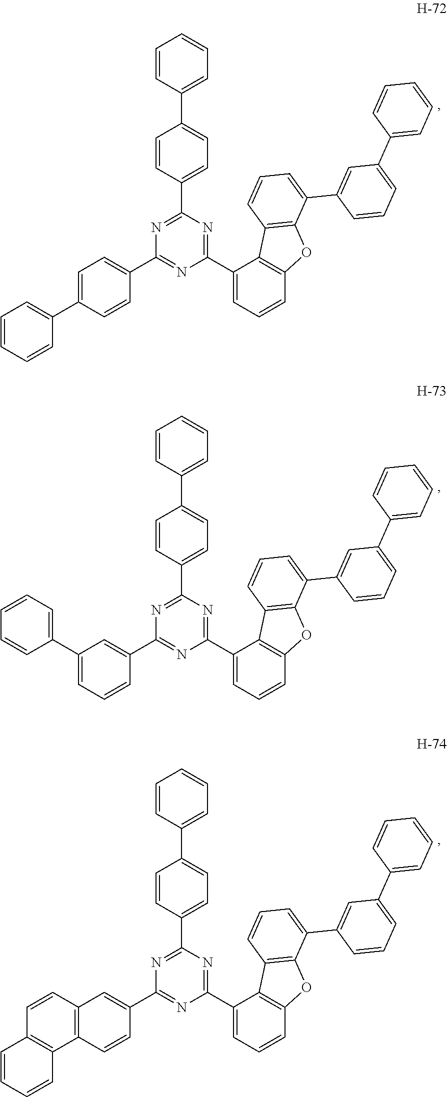 [SMILES: c1ccc(-c2ccc(-c3nc(-c4ccc(-c5ccccc5)cc4)nc(-c4cccc5oc6c(-c7cccc(-c8ccccc8)c7)cccc6c45)n3)cc2)cc1 ; c1ccc(-c2ccc(-c3nc(-c4cccc(-c5ccccc5)c4)nc(-c4cccc5oc6c(-c7cccc(-c8ccccc8)c7)cccc6c45)n3)cc2)cc1 ; c1ccc(-c2ccc(-c3nc(-c4ccc5c(ccc6ccccc65)c4)nc(-c4cccc5oc6c(-c7cccc(-c8ccccc8)c7)cccc6c45)n3)cc2)cc1] 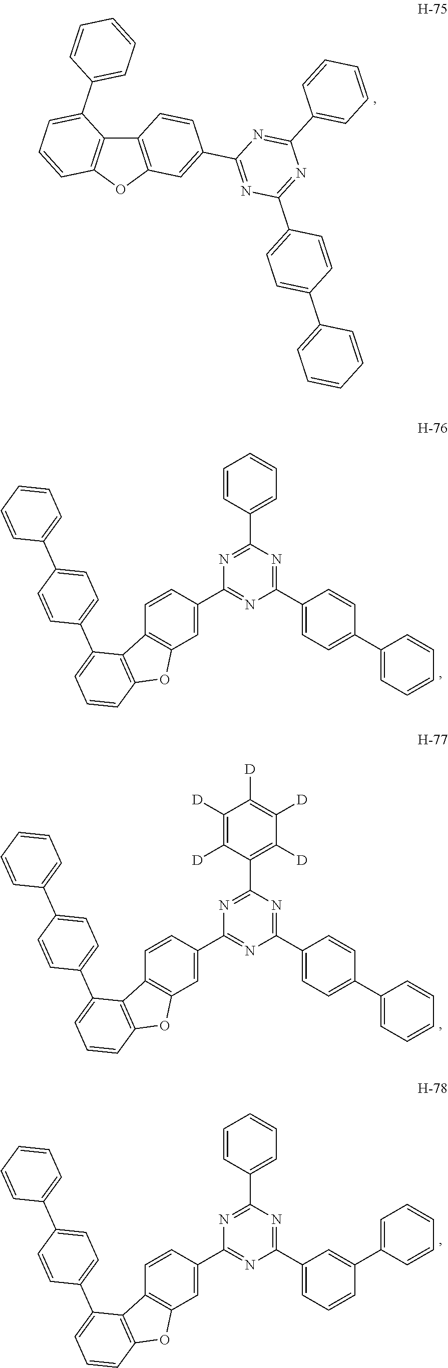 [SMILES: c1ccc(-c2ccc(-c3nc(-c4ccccc4)nc(-c4ccc5c(c4)oc4cccc(-c6ccccc6)c45)n3)cc2)cc1 ; c1ccc(-c2ccc(-c3nc(-c4ccccc4)nc(-c4ccc5c(c4)oc4cccc(-c6ccc(-c7ccccc7)cc6)c45)n3)cc2)cc1 ; [2H]c1c([2H])c([2H])c(-c2nc(-c3ccc(-c4ccccc4)cc3)nc(-c3ccc4c(c3)oc3cccc(-c5ccc(-c6ccccc6)cc5)c34)n2)c([2H])c1[2H] ; c1ccc(-c2ccc(-c3cccc4oc5cc(-c6nc(-c7ccccc7)nc(-c7cccc(-c8ccccc8)c7)n6)ccc5c34)cc2)cc1] 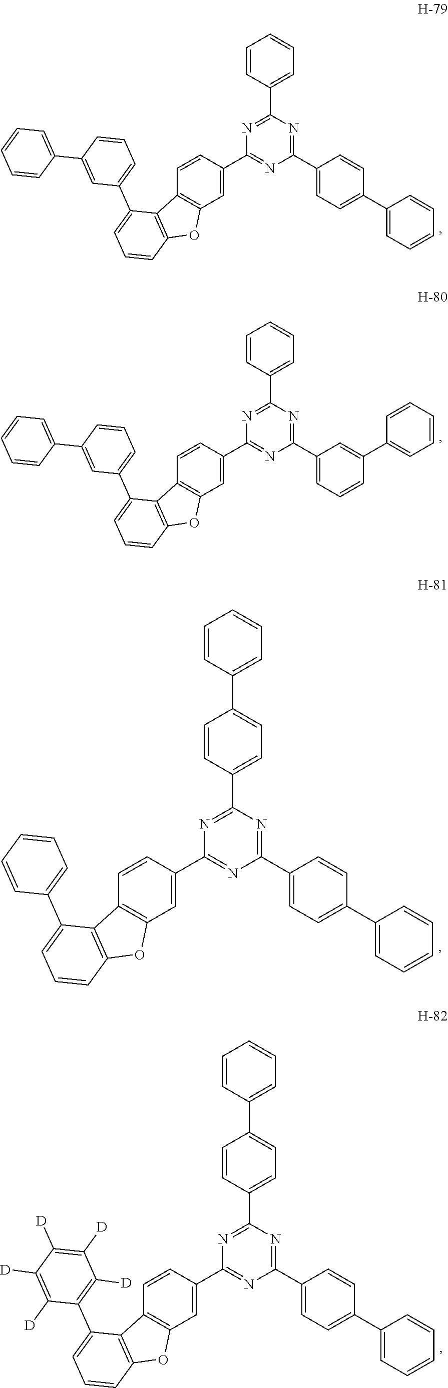 [SMILES: c1ccc(-c2ccc(-c3nc(-c4ccccc4)nc(-c4ccc5c(c4)oc4cccc(-c6cccc(-c7ccccc7)c6)c45)n3)cc2)cc1 ; c1ccc(-c2cccc(-c3nc(-c4ccccc4)nc(-c4ccc5c(c4)oc4cccc(-c6cccc(-c7ccccc7)c6)c45)n3)c2)cc1 ; c1ccc(-c2ccc(-c3nc(-c4ccc(-c5ccccc5)cc4)nc(-c4ccc5c(c4)oc4cccc(-c6ccccc6)c45)n3)cc2)cc1 ; [2H]c1c([2H])c([2H])c(-c2cccc3oc4cc(-c5nc(-c6ccc(-c7ccccc7)cc6)nc(-c6ccc(-c7ccccc7)cc6)n5)ccc4c23)c([2H])c1[2H]] 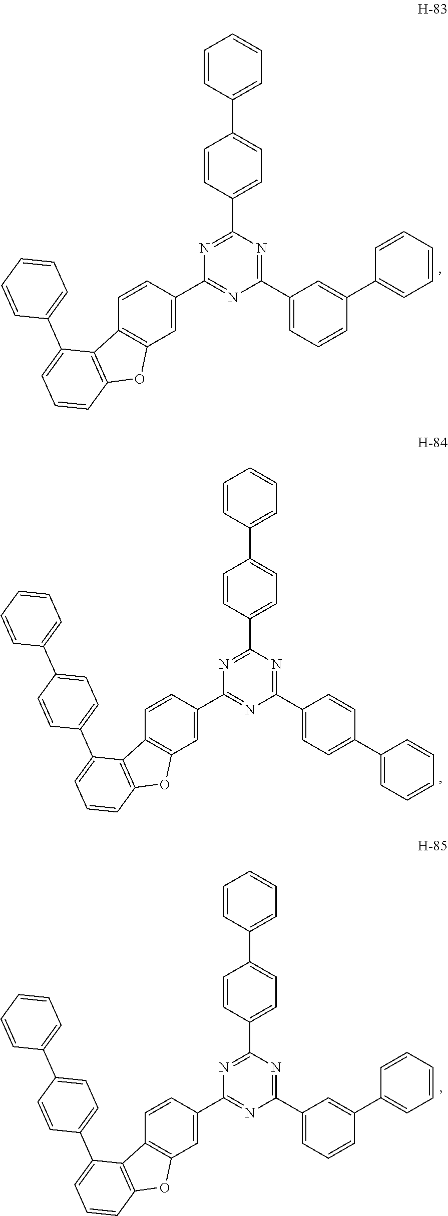 [SMILES: c1ccc(-c2ccc(-c3nc(-c4cccc(-c5ccccc5)c4)nc(-c4ccc5c(c4)oc4cccc(-c6ccccc6)c45)n3)cc2)cc1 ; c1ccc(-c2ccc(-c3nc(-c4ccc(-c5ccccc5)cc4)nc(-c4ccc5c(c4)oc4cccc(-c6ccc(-c7ccccc7)cc6)c45)n3)cc2)cc1 ; c1ccc(-c2ccc(-c3nc(-c4cccc(-c5ccccc5)c4)nc(-c4ccc5c(c4)oc4cccc(-c6ccc(-c7ccccc7)cc6)c45)n3)cc2)cc1] 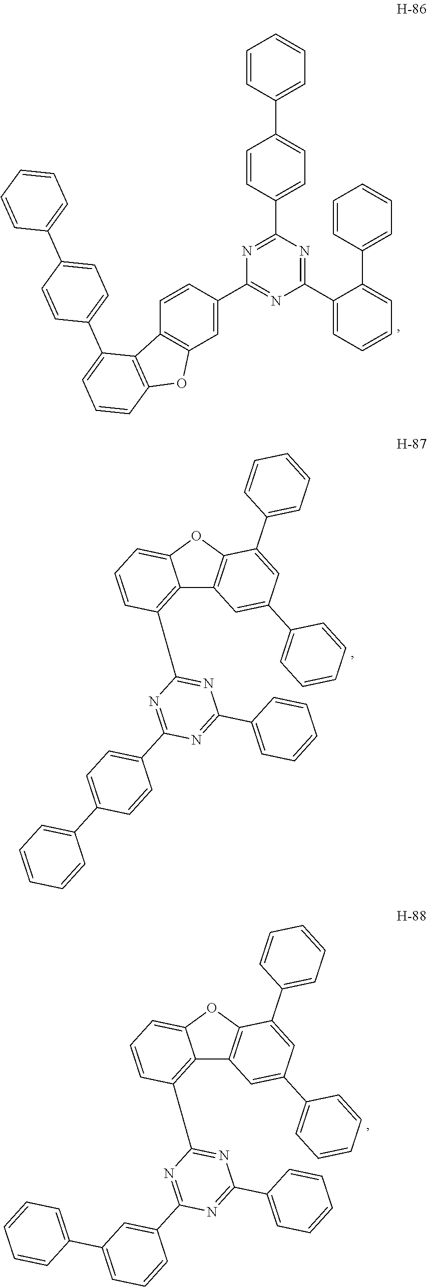 [SMILES: c1ccc(-c2ccc(-c3nc(-c4ccc5c(c4)oc4cccc(-c6ccc(-c7ccccc7)cc6)c45)nc(-c4ccccc4-c4ccccc4)n3)cc2)cc1 ; c1ccc(-c2ccc(-c3nc(-c4ccccc4)nc(-c4cccc5oc6c(-c7ccccc7)cc(-c7ccccc7)cc6c45)n3)cc2)cc1 ; c1ccc(-c2cccc(-c3nc(-c4ccccc4)nc(-c4cccc5oc6c(-c7ccccc7)cc(-c7ccccc7)cc6c45)n3)c2)cc1] 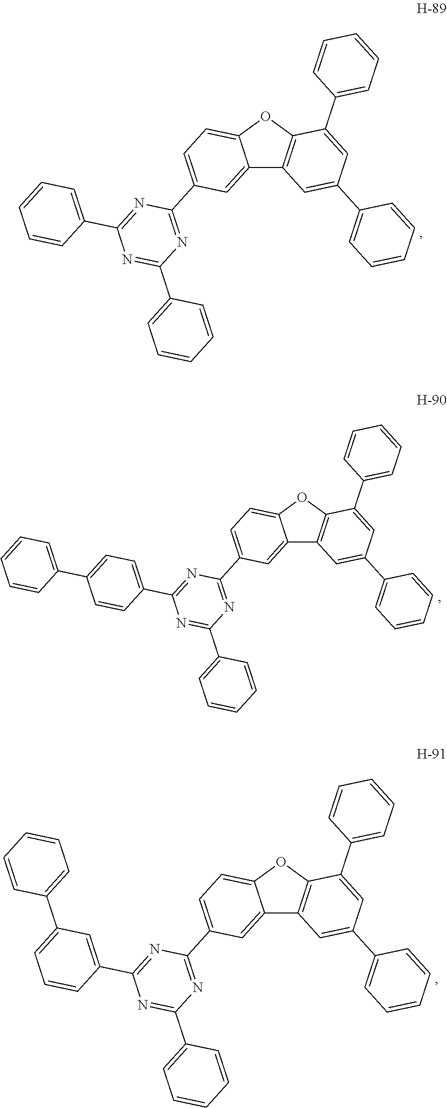 [SMILES: c1ccc(-c2cc(-c3ccccc3)c3oc4ccc(-c5nc(-c6ccccc6)nc(-c6ccccc6)n5)cc4c3c2)cc1 ; c1ccc(-c2ccc(-c3nc(-c4ccccc4)nc(-c4ccc5oc6c(-c7ccccc7)cc(-c7ccccc7)cc6c5c4)n3)cc2)cc1 ; c1ccc(-c2cccc(-c3nc(-c4ccccc4)nc(-c4ccc5oc6c(-c7ccccc7)cc(-c7ccccc7)cc6c5c4)n3)c2)cc1] 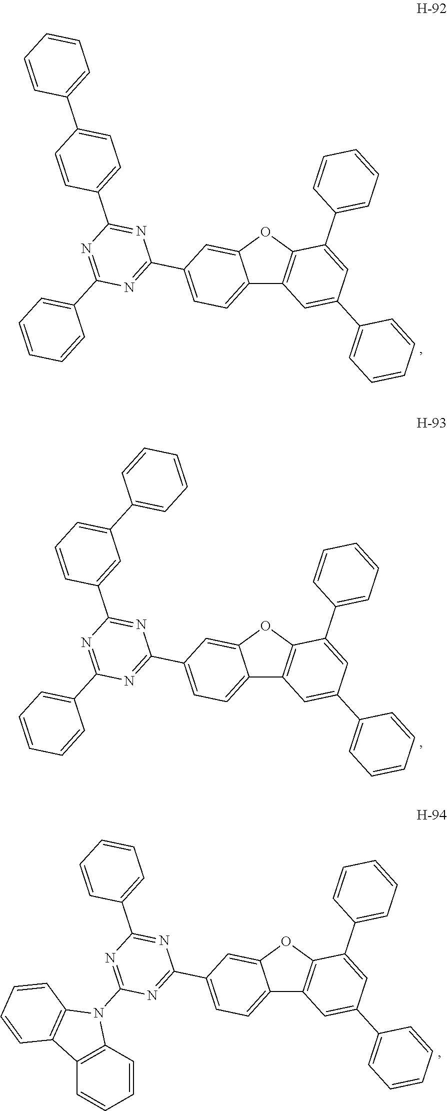 [SMILES: c1ccc(-c2ccc(-c3nc(-c4ccccc4)nc(-c4ccc5c(c4)oc4c(-c6ccccc6)cc(-c6ccccc6)cc45)n3)cc2)cc1 ; c1ccc(-c2cccc(-c3nc(-c4ccccc4)nc(-c4ccc5c(c4)oc4c(-c6ccccc6)cc(-c6ccccc6)cc45)n3)c2)cc1 ; c1ccc(-c2cc(-c3ccccc3)c3oc4cc(-c5nc(-c6ccccc6)nc(-n6c7ccccc7c7ccccc76)n5)ccc4c3c2)cc1] 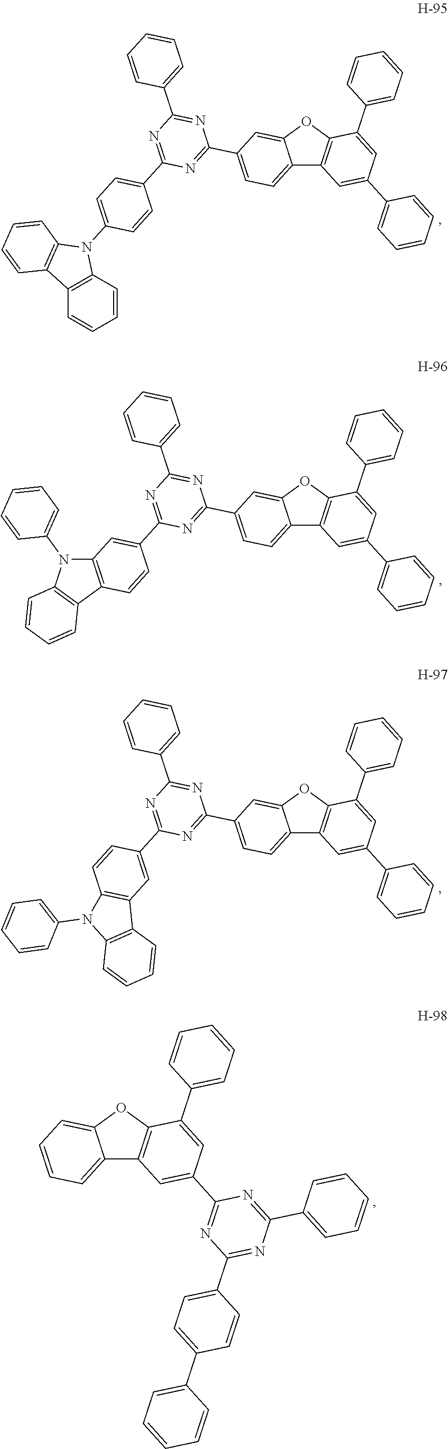 [SMILES: c1ccc(-c2cc(-c3ccccc3)c3oc4cc(-c5nc(-c6ccccc6)nc(-c6ccc(-n7c8ccccc8c8ccccc87)cc6)n5)ccc4c3c2)cc1 ; c1ccc(-c2cc(-c3ccccc3)c3oc4cc(-c5nc(-c6ccccc6)nc(-c6ccc7c8ccccc8n(-c8ccccc8)c7c6)n5)ccc4c3c2)cc1 ; c1ccc(-c2cc(-c3ccccc3)c3oc4cc(-c5nc(-c6ccccc6)nc(-c6ccc7c(c6)c6ccccc6n7-c6ccccc6)n5)ccc4c3c2)cc1 ; c1ccc(-c2ccc(-c3nc(-c4ccccc4)nc(-c4cc(-c5ccccc5)c5oc6ccccc6c5c4)n3)cc2)cc1] 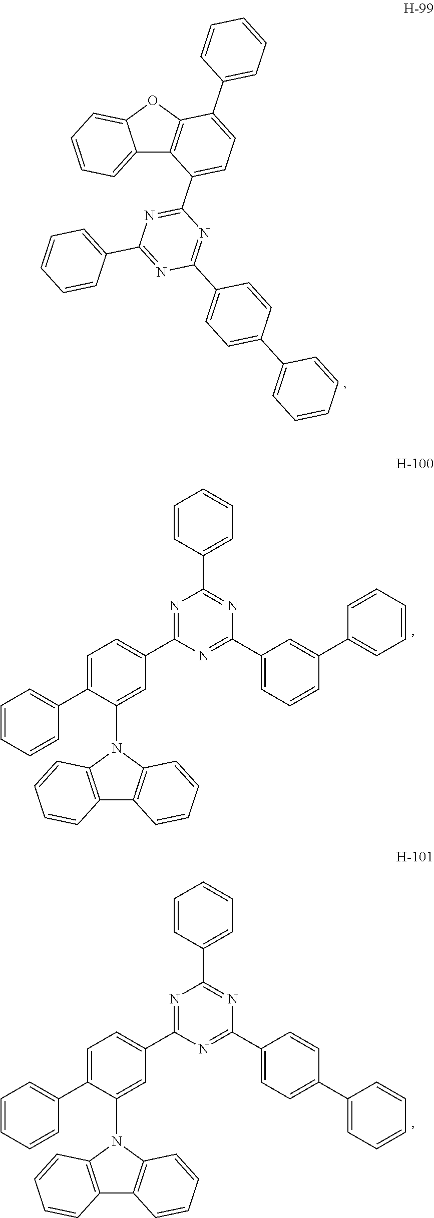 [SMILES: c1ccc(-c2ccc(-c3nc(-c4ccccc4)nc(-c4ccc(-c5ccccc5)c5oc6ccccc6c45)n3)cc2)cc1 ; c1ccc(-c2cccc(-c3nc(-c4ccccc4)nc(-c4ccc(-c5ccccc5)c(-n5c6ccccc6c6ccccc65)c4)n3)c2)cc1 ; c1ccc(-c2ccc(-c3nc(-c4ccccc4)nc(-c4ccc(-c5ccccc5)c(-n5c6ccccc6c6ccccc65)c4)n3)cc2)cc1] 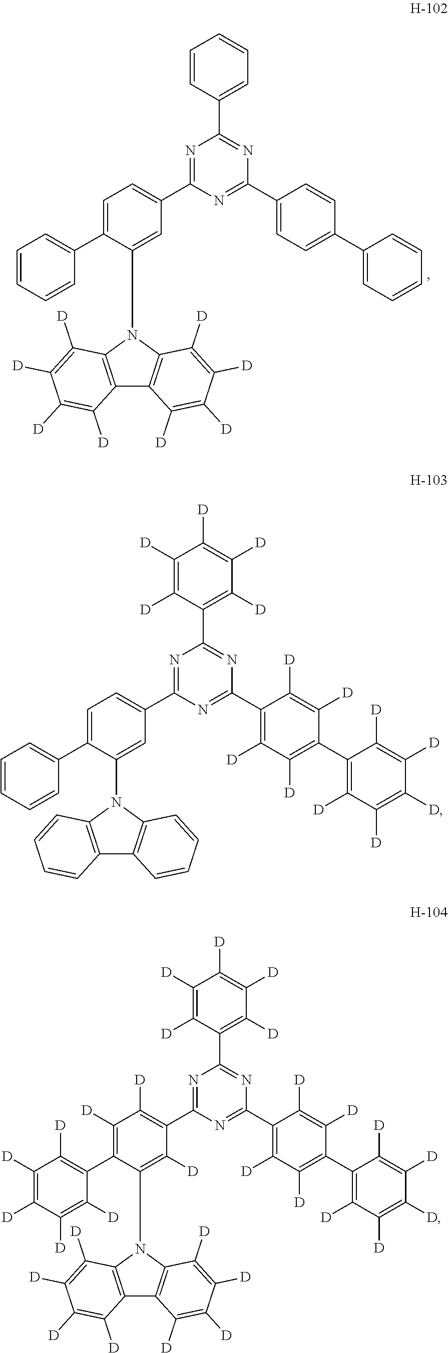 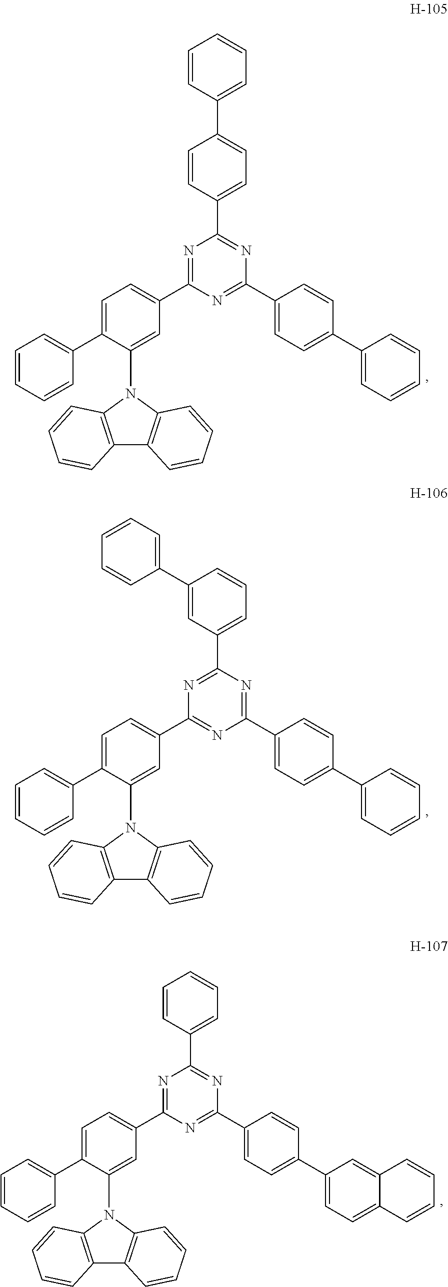 [SMILES: c1ccc(-c2ccc(-c3nc(-c4ccc(-c5ccccc5)cc4)nc(-c4ccc(-c5ccccc5)c(-n5c6ccccc6c6ccccc65)c4)n3)cc2)cc1 ; c1ccc(-c2ccc(-c3nc(-c4cccc(-c5ccccc5)c4)nc(-c4ccc(-c5ccccc5)c(-n5c6ccccc6c6ccccc65)c4)n3)cc2)cc1 ; c1ccc(-c2nc(-c3ccc(-c4ccc5ccccc5c4)cc3)nc(-c3ccc(-c4ccccc4)c(-n4c5ccccc5c5ccccc54)c3)n2)cc1] 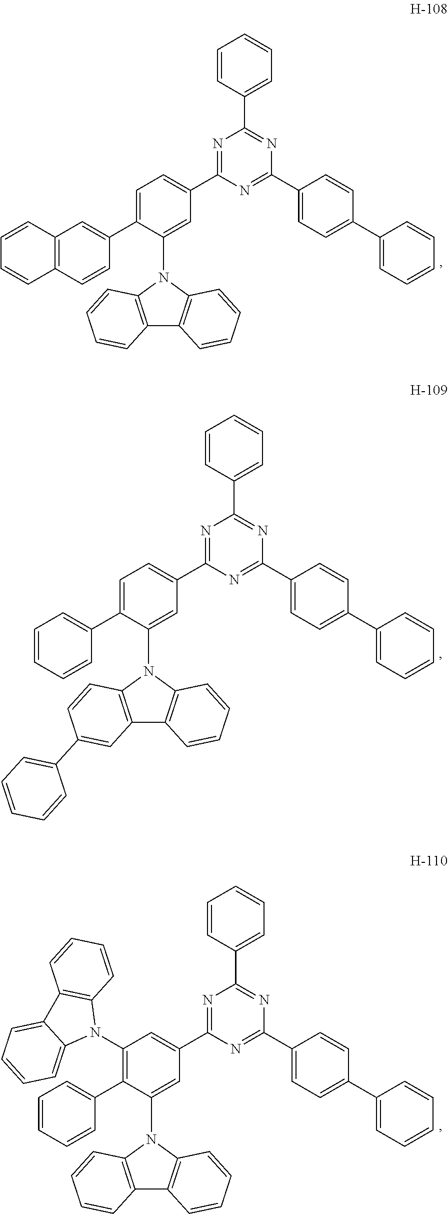 [SMILES: c1ccc(-c2ccc(-c3nc(-c4ccccc4)nc(-c4ccc(-c5ccc6ccccc6c5)c(-n5c6ccccc6c6ccccc65)c4)n3)cc2)cc1 ; c1ccc(-c2ccc(-c3nc(-c4ccccc4)nc(-c4ccc(-c5ccccc5)c(-n5c6ccccc6c6cc(-c7ccccc7)ccc65)c4)n3)cc2)cc1 ; c1ccc(-c2ccc(-c3nc(-c4ccccc4)nc(-c4cc(-n5c6ccccc6c6ccccc65)c(-c5ccccc5)c(-n5c6ccccc6c6ccccc65)c4)n3)cc2)cc1] 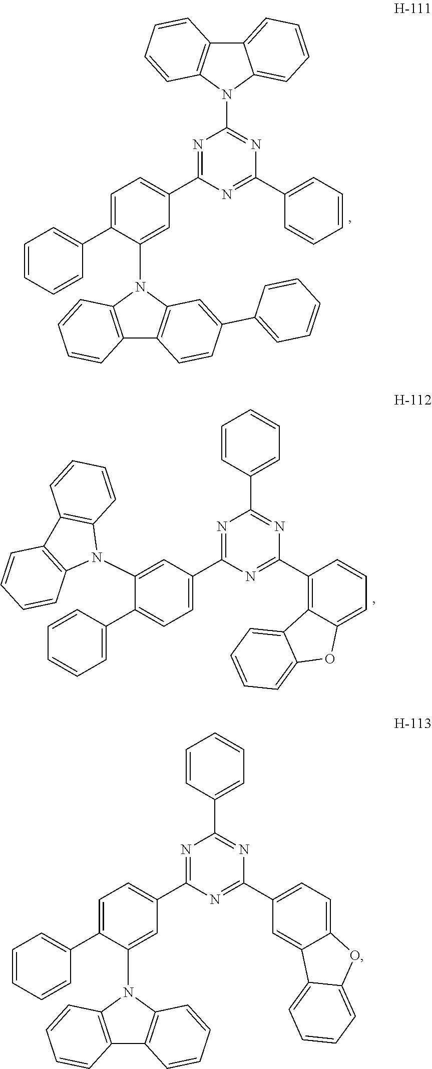 [SMILES: c1ccc(-c2ccc3c4ccccc4n(-c4cc(-c5nc(-c6ccccc6)nc(-n6c7ccccc7c7ccccc76)n5)ccc4-c4ccccc4)c3c2)cc1 ; c1ccc(-c2nc(-c3ccc(-c4ccccc4)c(-n4c5ccccc5c5ccccc54)c3)nc(-c3cccc4oc5ccccc5c34)n2)cc1 ; c1ccc(-c2nc(-c3ccc(-c4ccccc4)c(-n4c5ccccc5c5ccccc54)c3)nc(-c3ccc4oc5ccccc5c4c3)n2)cc1] 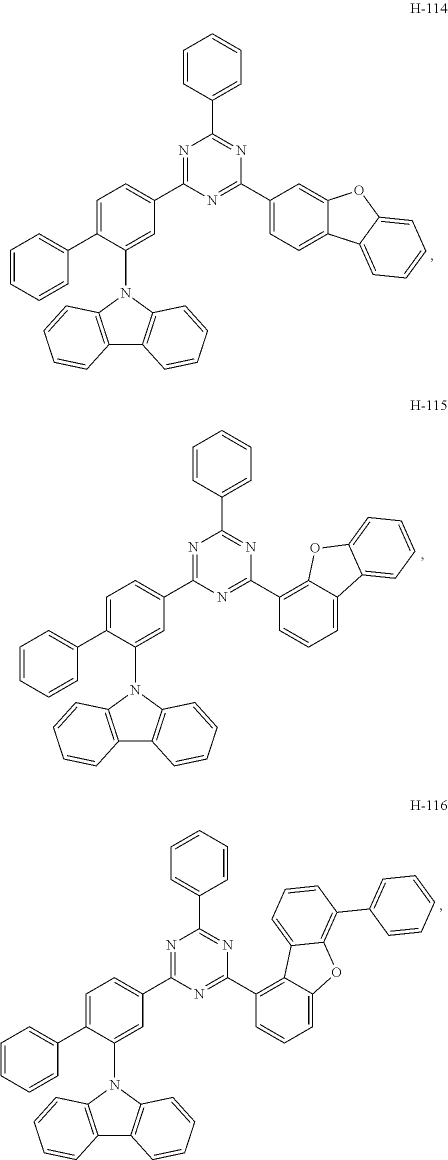 [SMILES: c1ccc(-c2nc(-c3ccc(-c4ccccc4)c(-n4c5ccccc5c5ccccc54)c3)nc(-c3ccc4c(c3)oc3ccccc34)n2)cc1 ; c1ccc(-c2nc(-c3ccc(-c4ccccc4)c(-n4c5ccccc5c5ccccc54)c3)nc(-c3cccc4c3oc3ccccc34)n2)cc1 ; c1ccc(-c2nc(-c3ccc(-c4ccccc4)c(-n4c5ccccc5c5ccccc54)c3)nc(-c3cccc4oc5c(-c6ccccc6)cccc5c34)n2)cc1] 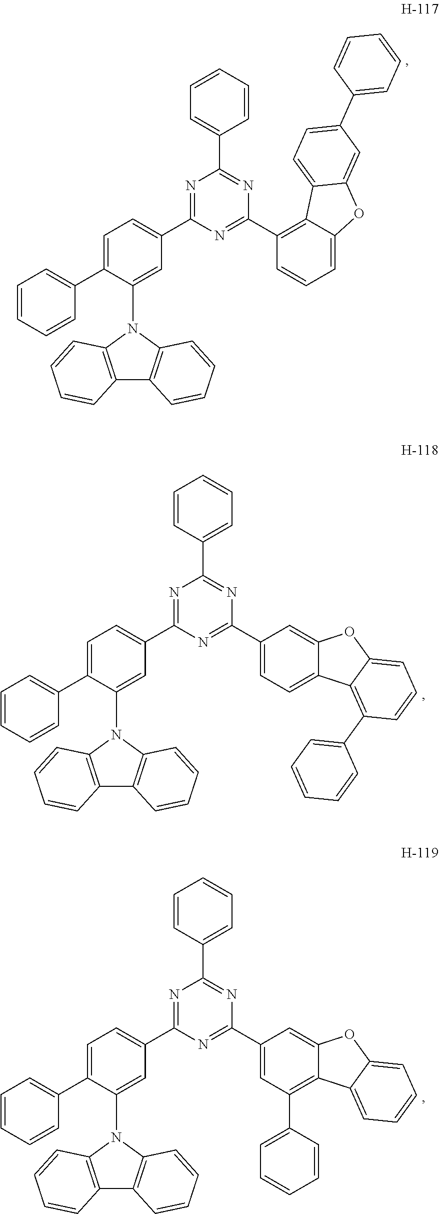 [SMILES: c1ccc(-c2ccc3c(c2)oc2cccc(-c4nc(-c5ccccc5)nc(-c5ccc(-c6ccccc6)c(-n6c7ccccc7c7ccccc76)c5)n4)c23)cc1 ; c1ccc(-c2nc(-c3ccc(-c4ccccc4)c(-n4c5ccccc5c5ccccc54)c3)nc(-c3ccc4c(c3)oc3cccc(-c5ccccc5)c34)n2)cc1 ; c1ccc(-c2nc(-c3ccc(-c4ccccc4)c(-n4c5ccccc5c5ccccc54)c3)nc(-c3cc(-c4ccccc4)c4c(c3)oc3ccccc34)n2)cc1] 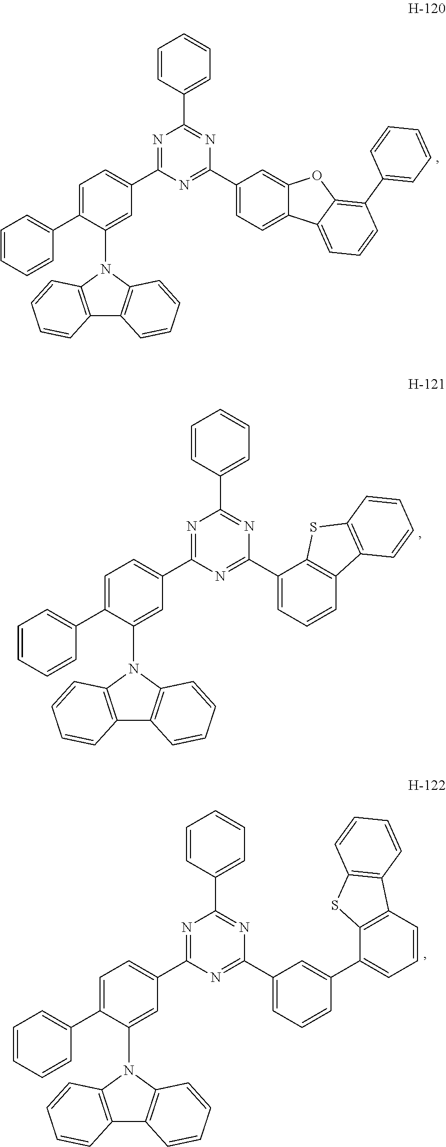 [SMILES: c1ccc(-c2nc(-c3ccc(-c4ccccc4)c(-n4c5ccccc5c5ccccc54)c3)nc(-c3ccc4c(c3)oc3c(-c5ccccc5)cccc34)n2)cc1 ; c1ccc(-c2nc(-c3ccc(-c4ccccc4)c(-n4c5ccccc5c5ccccc54)c3)nc(-c3cccc4c3sc3ccccc34)n2)cc1 ; c1ccc(-c2nc(-c3cccc(-c4cccc5c4sc4ccccc45)c3)nc(-c3ccc(-c4ccccc4)c(-n4c5ccccc5c5ccccc54)c3)n2)cc1] 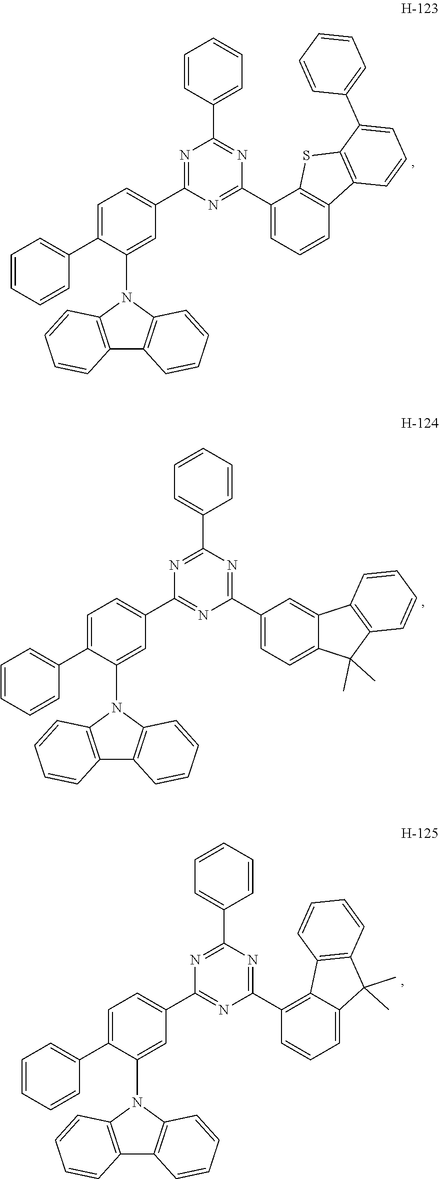 [SMILES: c1ccc(-c2nc(-c3ccc(-c4ccccc4)c(-n4c5ccccc5c5ccccc54)c3)nc(-c3cccc4c3sc3c(-c5ccccc5)cccc34)n2)cc1 ; CC1(C)c2ccccc2-c2cc(-c3nc(-c4ccccc4)nc(-c4ccc(-c5ccccc5)c(-n5c6ccccc6c6ccccc65)c4)n3)ccc21 ; CC1(C)c2ccccc2-c2c(-c3nc(-c4ccccc4)nc(-c4ccc(-c5ccccc5)c(-n5c6ccccc6c6ccccc65)c4)n3)cccc21] 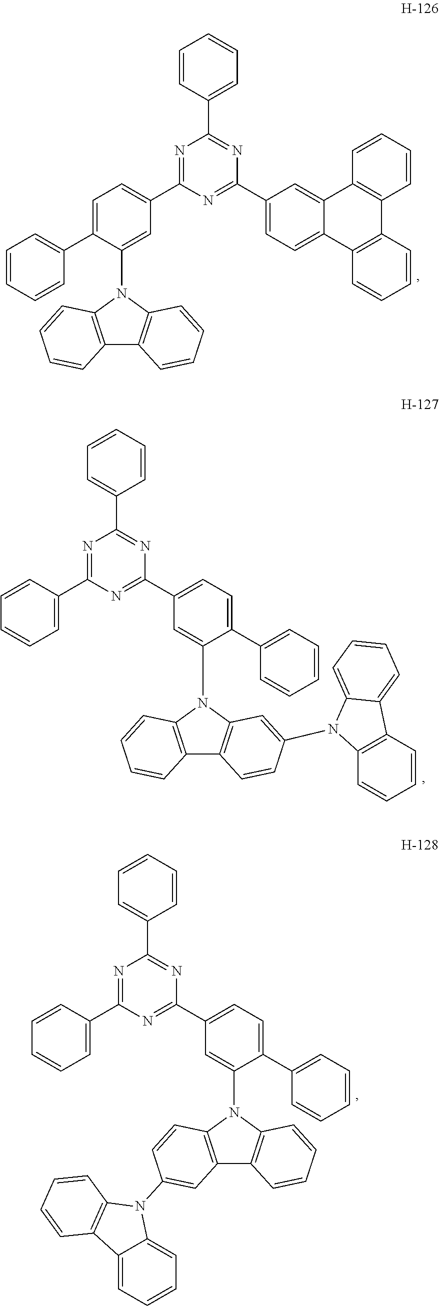 [SMILES: c1ccc(-c2nc(-c3ccc(-c4ccccc4)c(-n4c5ccccc5c5ccccc54)c3)nc(-c3ccc4c5ccccc5c5ccccc5c4c3)n2)cc1 ; c1ccc(-c2nc(-c3ccccc3)nc(-c3ccc(-c4ccccc4)c(-n4c5ccccc5c5ccc(-n6c7ccccc7c7ccccc76)cc54)c3)n2)cc1 ; c1ccc(-c2nc(-c3ccccc3)nc(-c3ccc(-c4ccccc4)c(-n4c5ccccc5c5cc(-n6c7ccccc7c7ccccc76)ccc54)c3)n2)cc1] 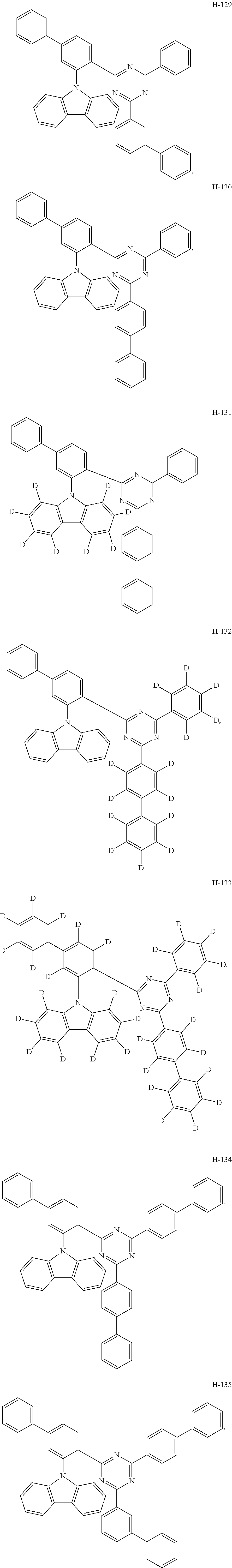 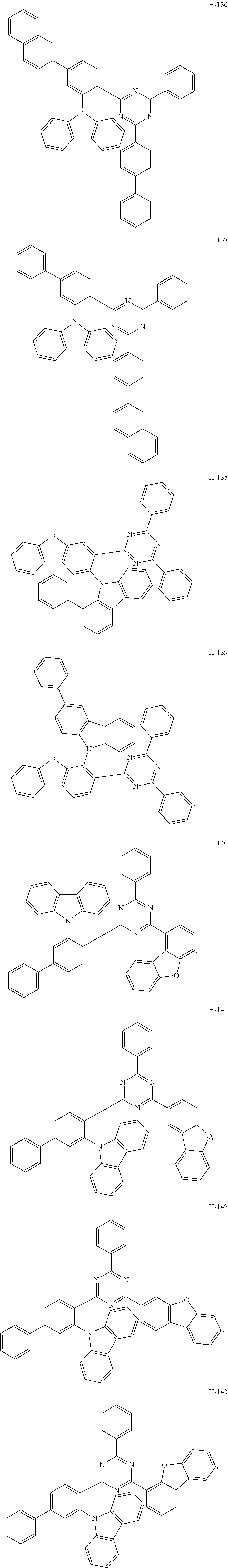 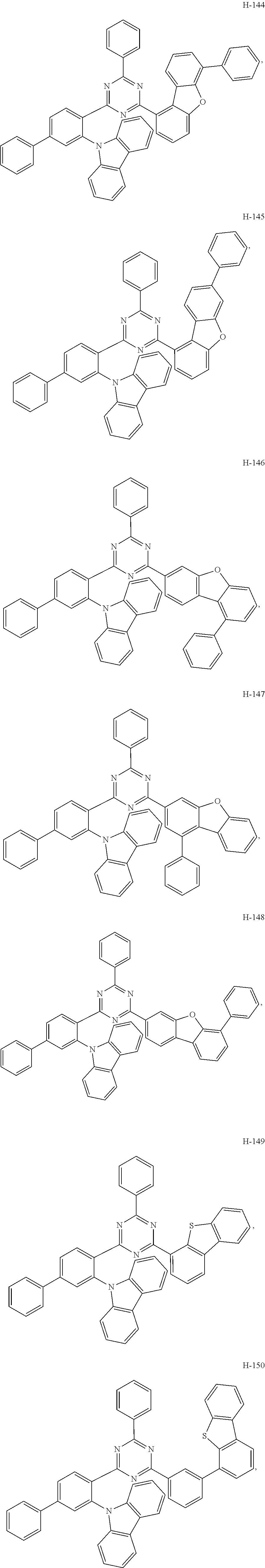 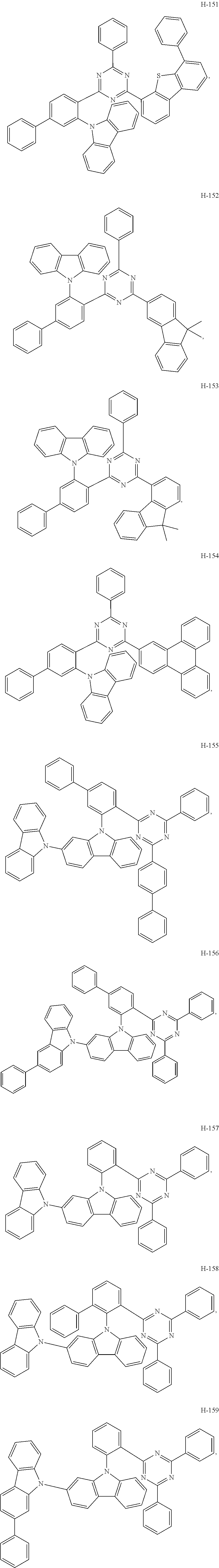 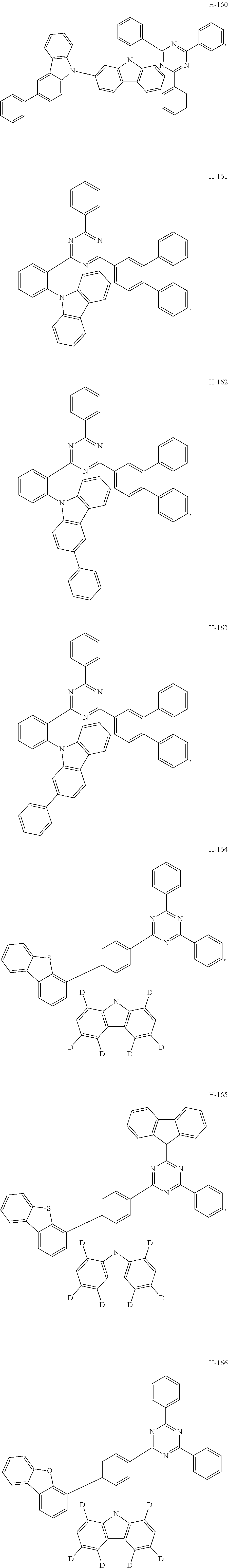 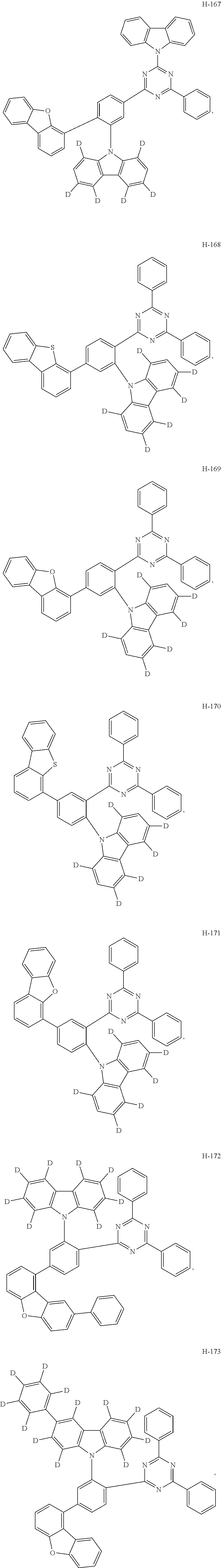 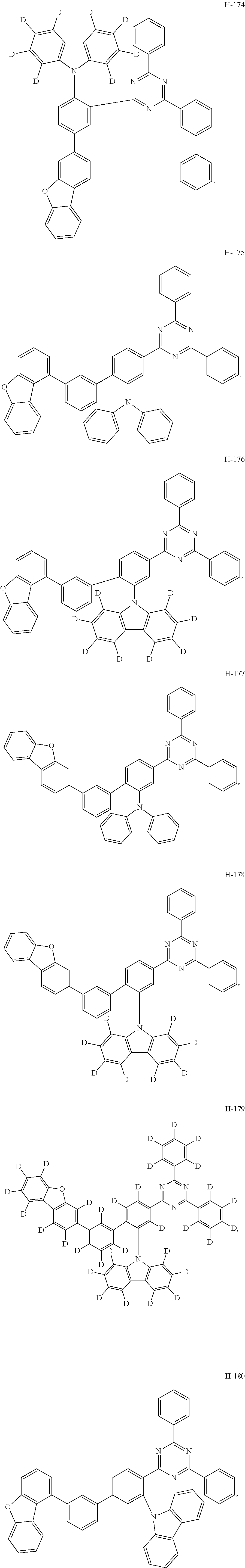 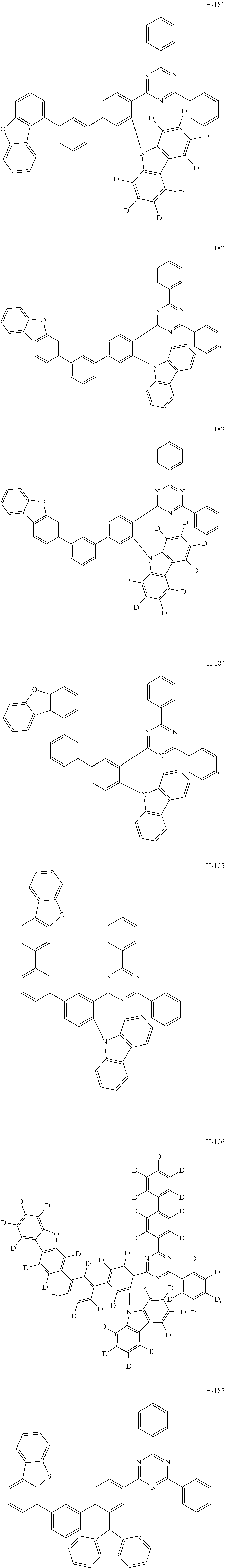 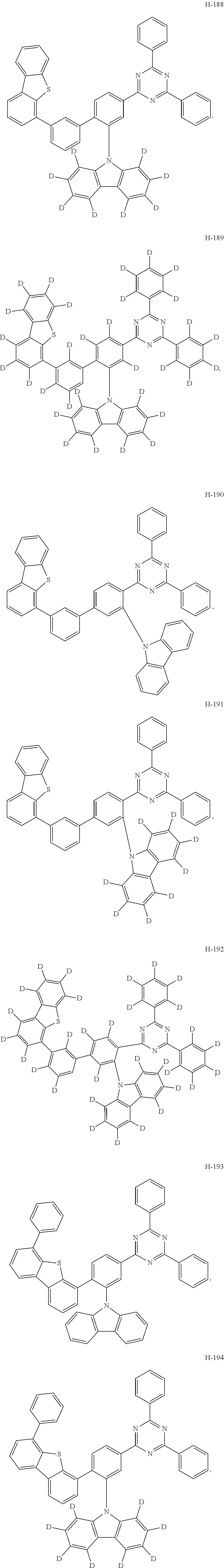 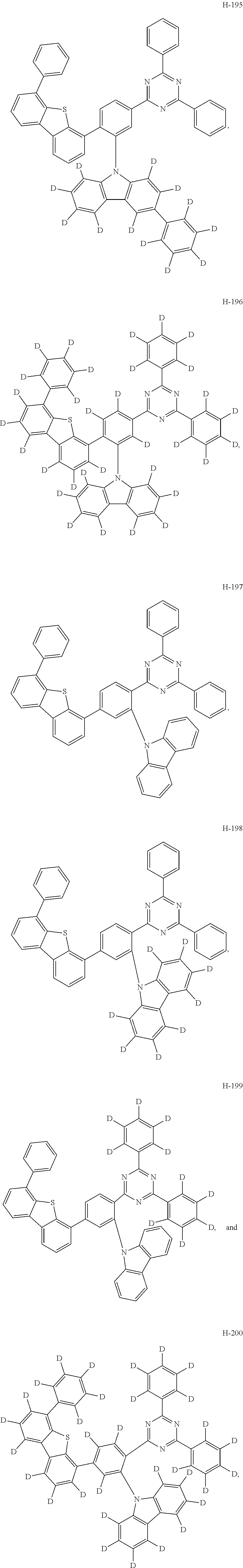
wherein optionally, hydrogens in the structures of the Compound H-1 to Compound H-200 can be partially or fully substituted with deuterium.

16. The organic electroluminescent device according to claim 14, wherein the emissive layer comprises at least one metal complex;
preferably, the metal complex is a phosphorescent sensitizer;
more preferably, the metal complex has a general formula of M(Lₐ)ₘ(L_{b})ₙ(L_{c})_{q};
the metal M is selected from a metal with a relative atomic mass greater than 40;
Lₐ, L_{b}, and L_{c} are a first ligand, a second ligand, and a third ligand coordinated to the metal M, respectively, and Lₐ, L_{b}, and L_{c} can be optionally joined to form a multidentate ligand;
Lₐ, L_{b}, and L_{c} are identical or different; m is 1, 2, or 3, n is 0, 1, or 2, q is 0, 1, or 2, and m+n+q is equal to the oxidation state of the metal M; when m is greater than or equal to 2, multiple Lₐ are identical or different; when n is 2, two L_{b} are identical or different; when q is 2, two L_{c} are identical or different;
Lₐ is, at each occurrence identically or differently, selected from a structure represented by Formula 2: 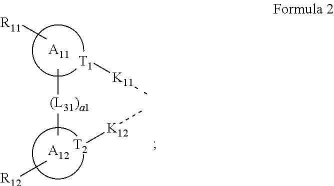
wherein,
the ring A₁₁ and the ring A₁₂ are each selected from an aromatic ring having 6 to 30 ring atoms, a heteroaromatic ring having 5 to 30 ring atoms, or a combination thereof;
T₁ and T₂ are, at each occurrence identically or differently, selected from C or N;
K₁₁ and K₁₂ are, at each occurrence identically or differently, selected from a single bond, O, S, or NRₖ;
L₃₁ is, at each occurrence identically or differently, selected from the group consisting of: a single bond, BR_{L11}, CR_{L11}R_{L11}, NR_{L11}, O, SiR_{L11}R_{L11}, PR_{L11}, S, GeR_{L11}R_{L11}, Se, substituted or unsubstituted vinylene, ethynylene, substituted or unsubstituted arylene having 6 to 30 carbon atoms, substituted or unsubstituted heteroarylene having 3 to 30 carbon atoms, and combinations thereof; when two R_{L11} are present at the same time, the two R_{L11} are identical or different;
a₁ is selected from 0 or 1;
R₁₁ and R₁₂ represent, at each occurrence identically or differently, mono-substitution, multiple substitutions, or non-substitution;
R_{L11}, R₁₁, R₁₂, and Rₖ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R_{L11}, R₁₁, and R₁₂ can be optionally joined to form a ring;
L_{b} and L_{c} are, at each occurrence identically or differently, selected from any one of the following structures: 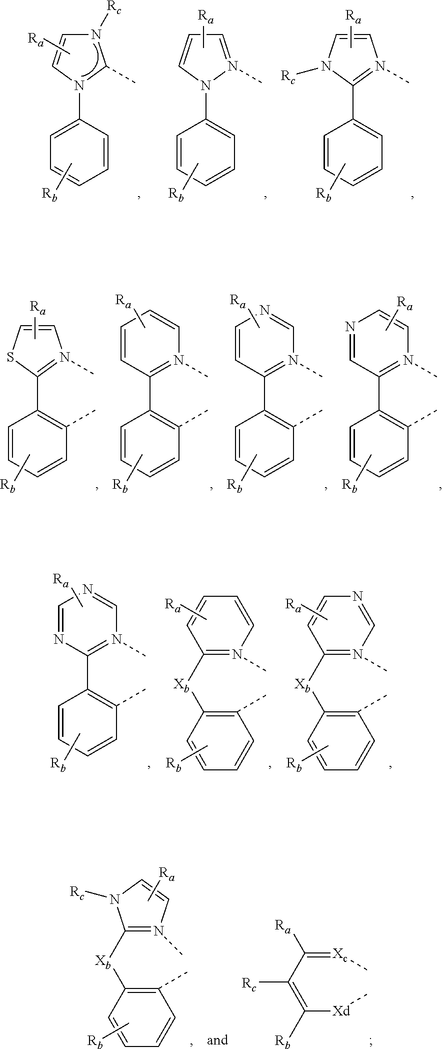
wherein,
Rₐ, R_{b}, and R_{c} represent, at each occurrence identically or differently, mono-substitution, multiple substitutions, or non-substitution;
X_{b} is, at each occurrence identically or differently, selected from the group consisting of: O, S, Se, NR_{N1}, and CR_{C1}R_{C2};
X_{c} and X_{d} are, at each occurrence identically or differently, selected from the group consisting of: O, S, Se, and NR_{N2};
Rₐ, R_{b}, R_{c}, R_{N1}, R_{N2}, R_{C1}, and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic groups having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents Rₐ, R_{b}, R_{c}, R_{N1}, R_{N2}, R_{C1}, and R_{C2} can be optionally joined to form a ring;
most preferably, the metal complex is selected from the group consisting of Compound GD1 to Compound GD185: 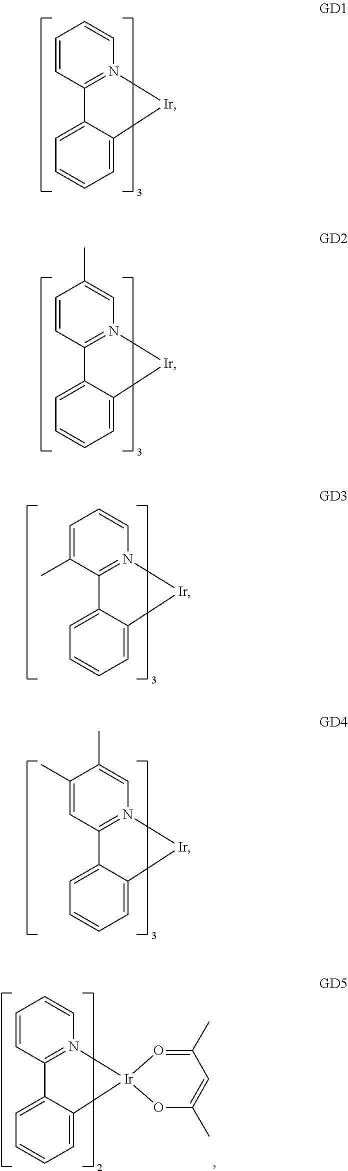 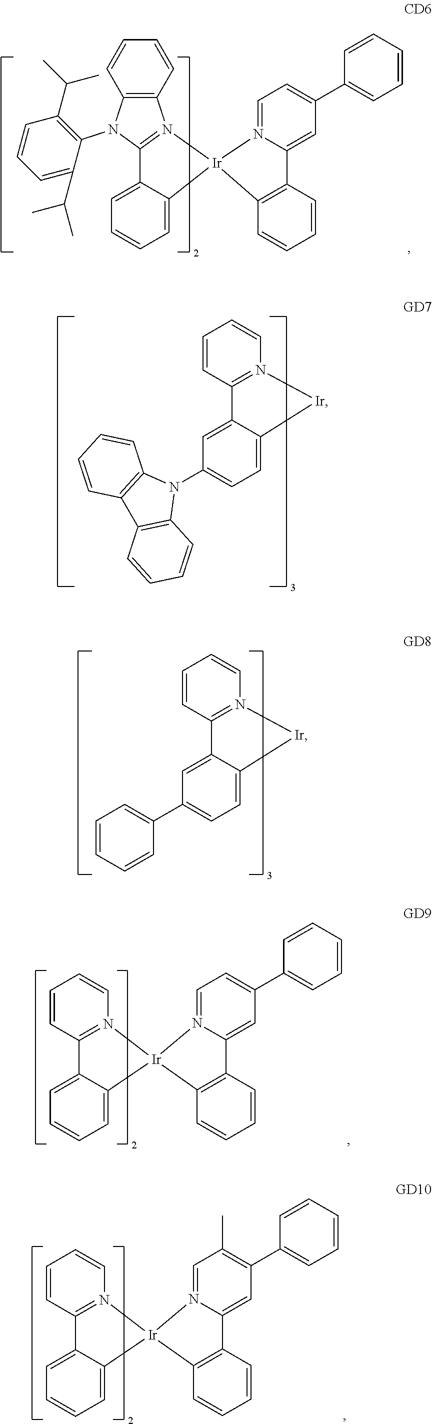 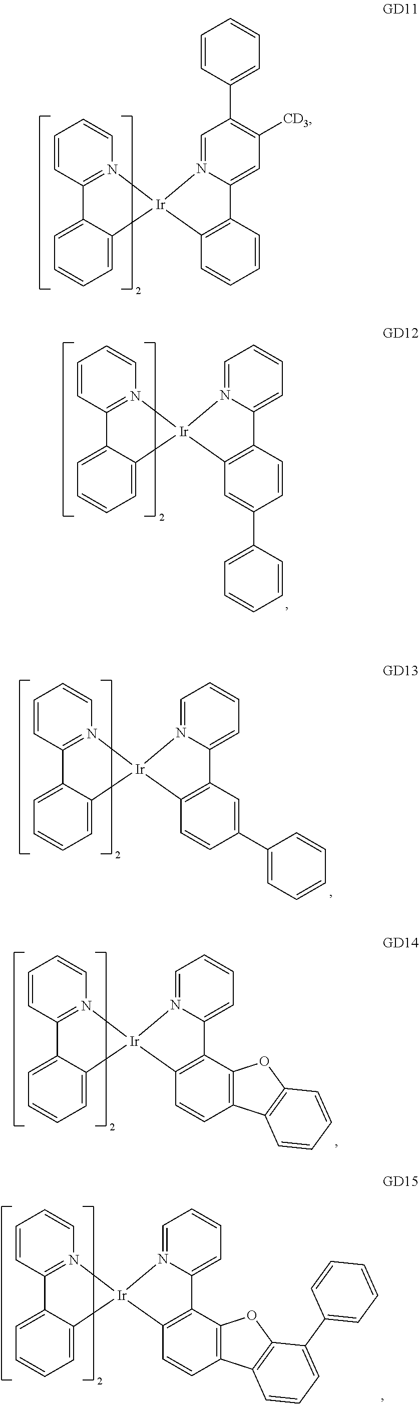 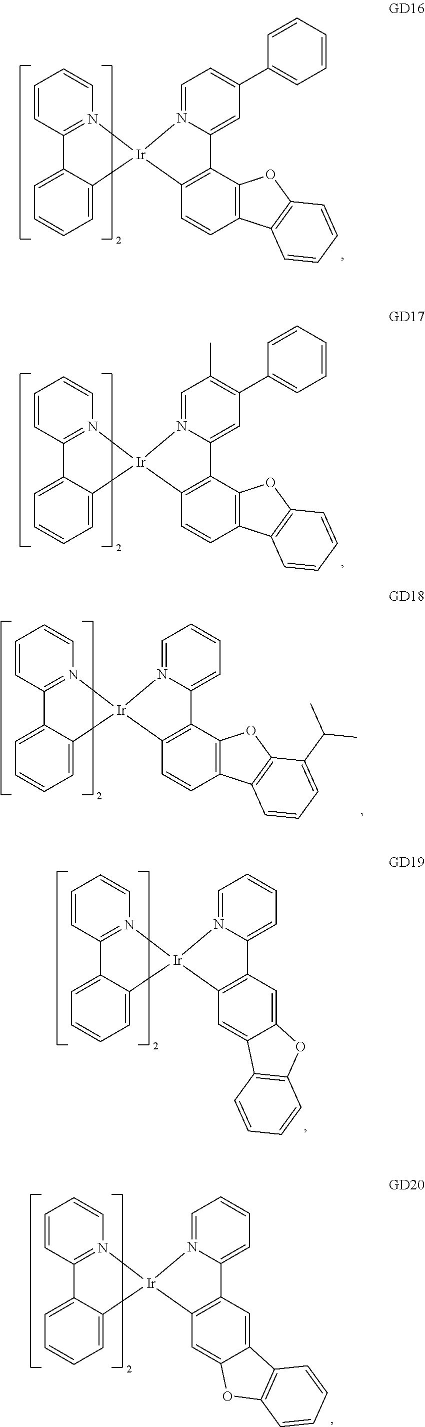 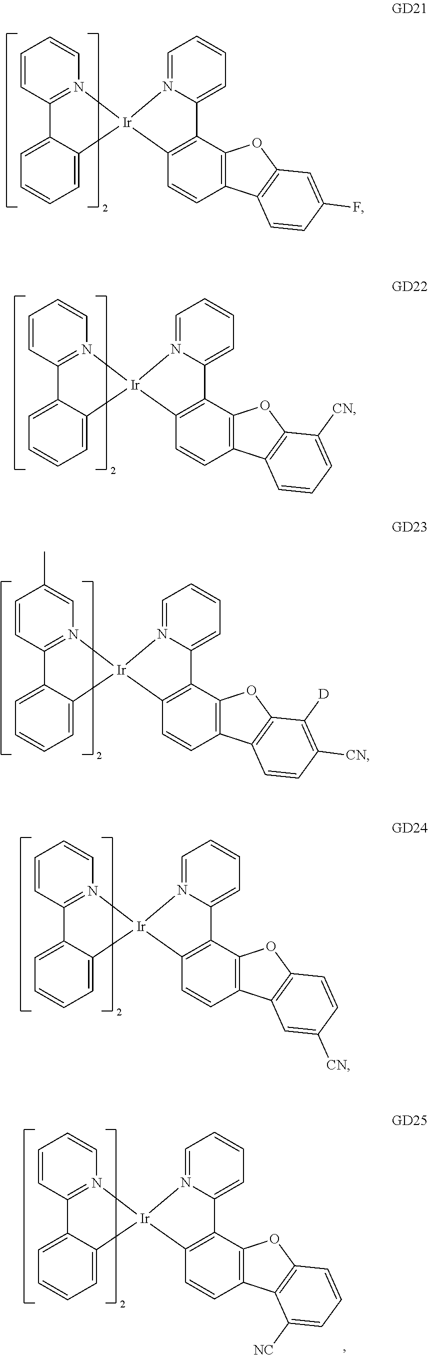 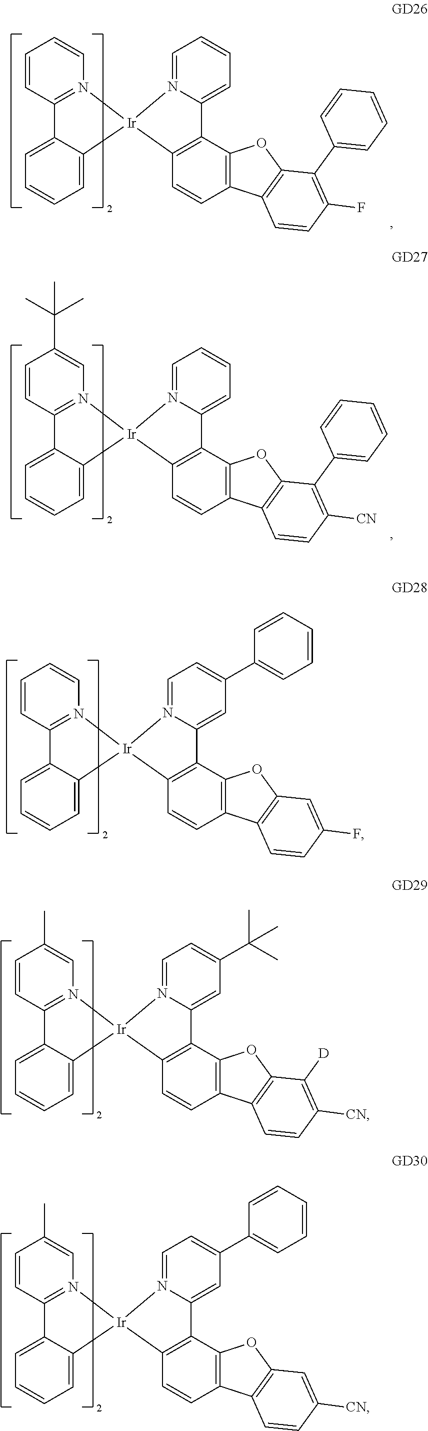 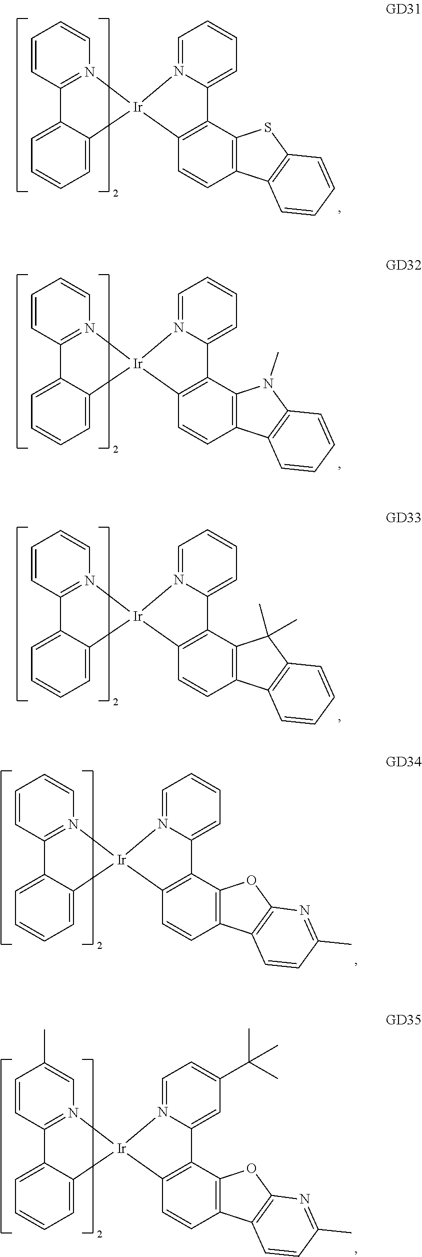 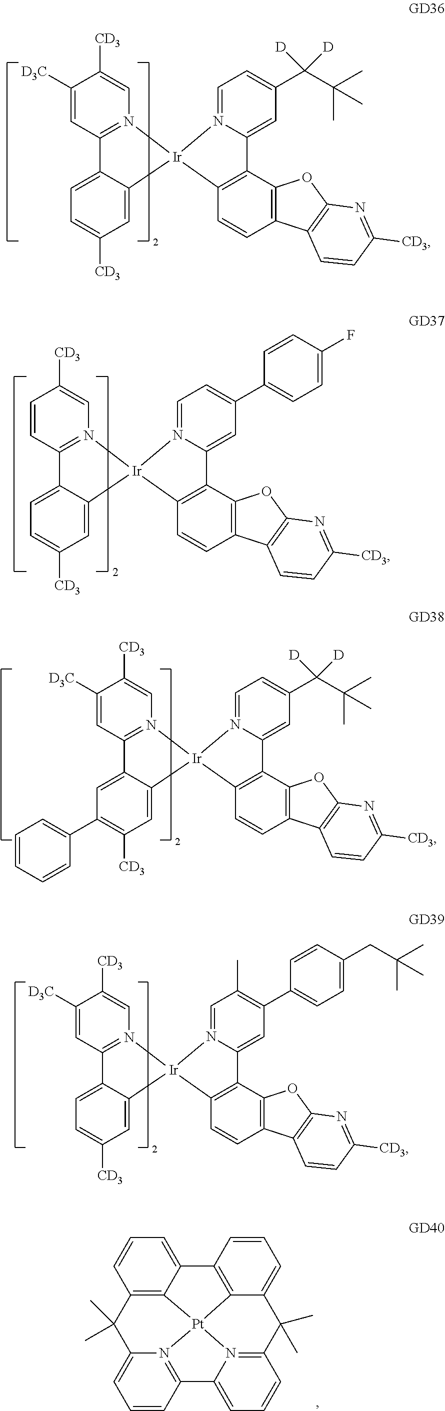 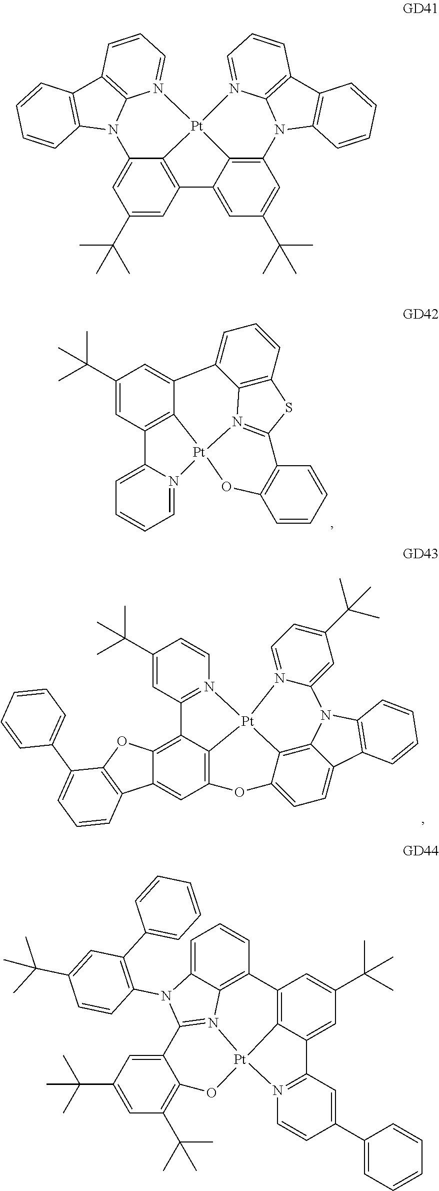 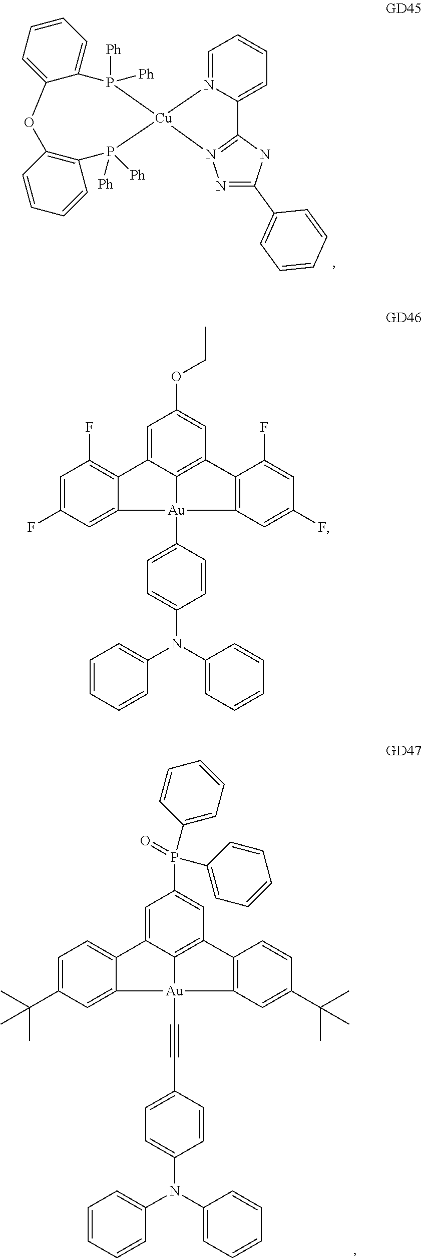 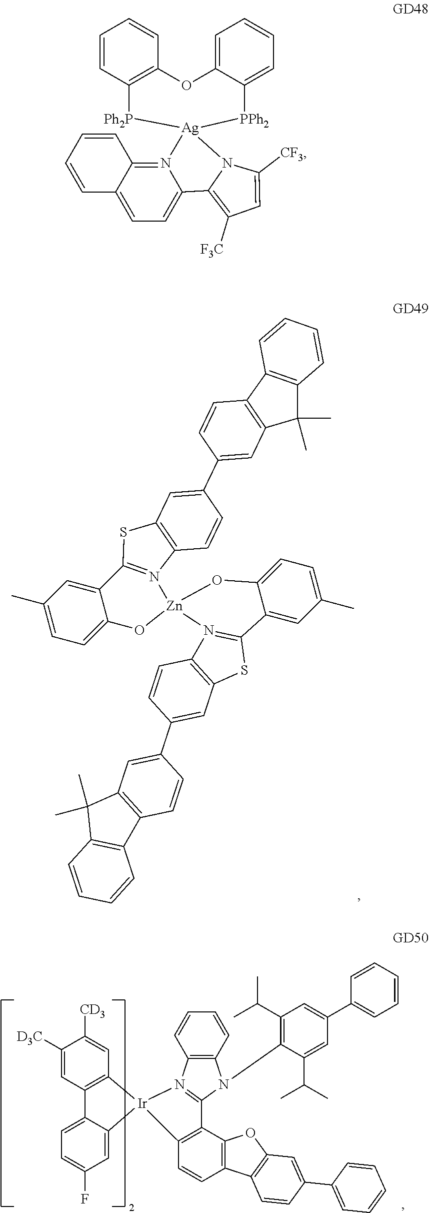 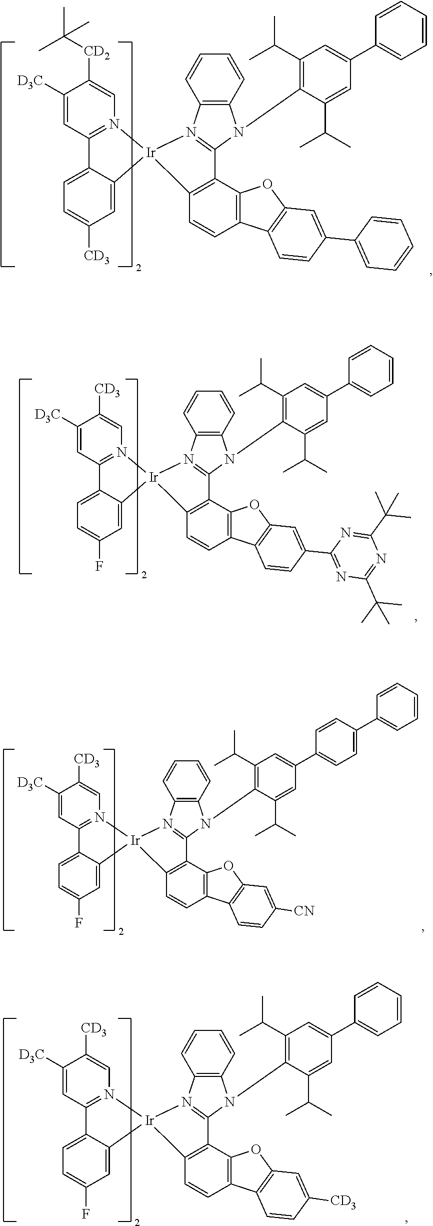 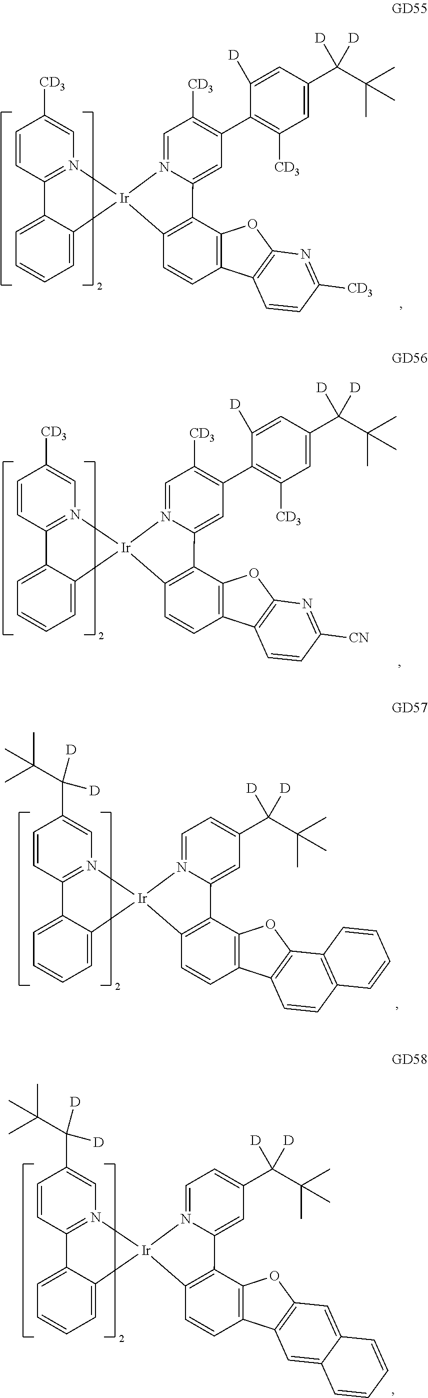 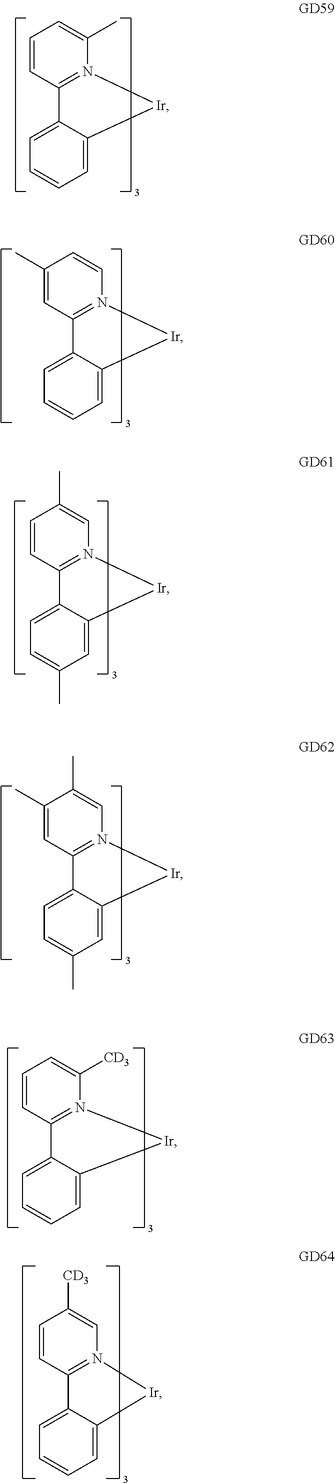 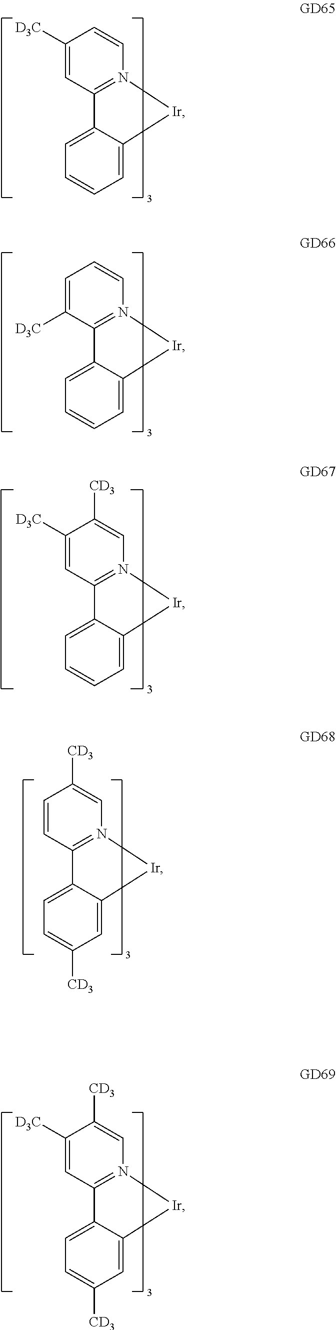 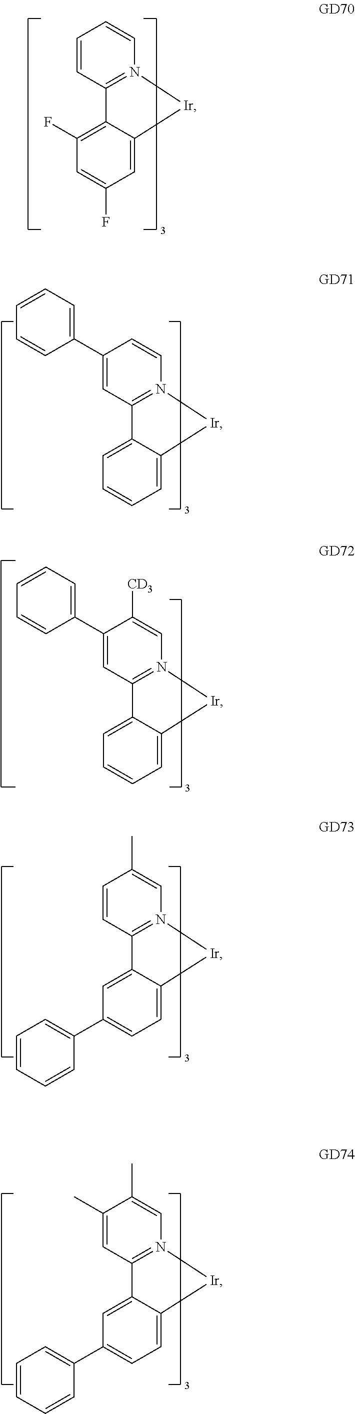 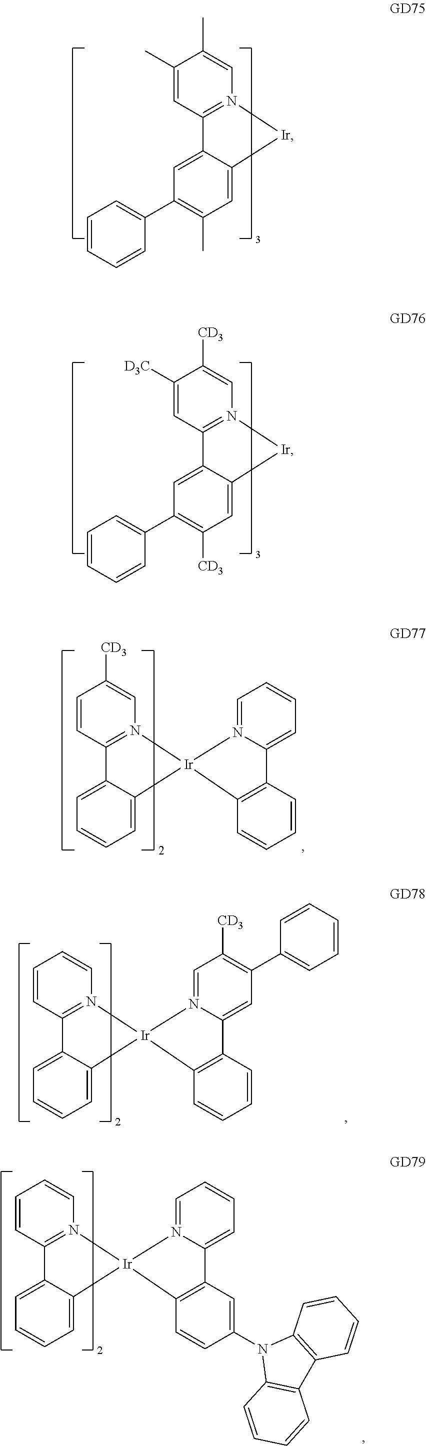 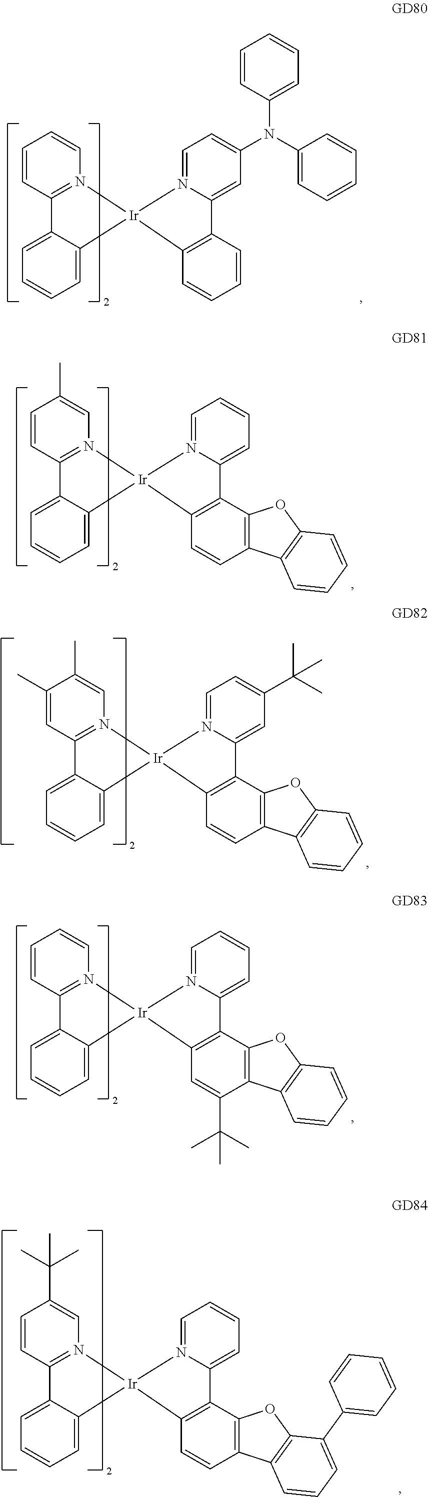 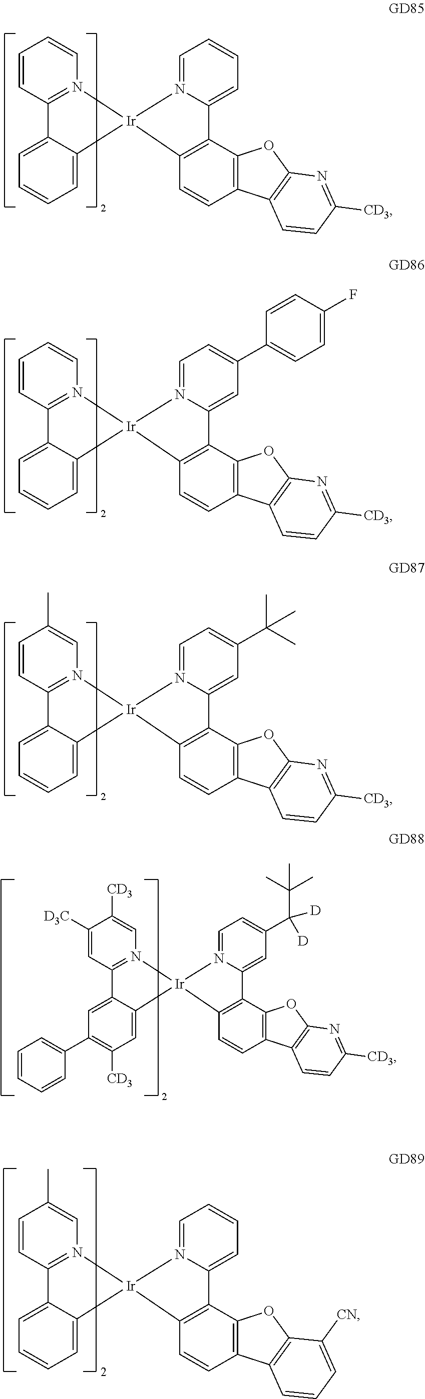 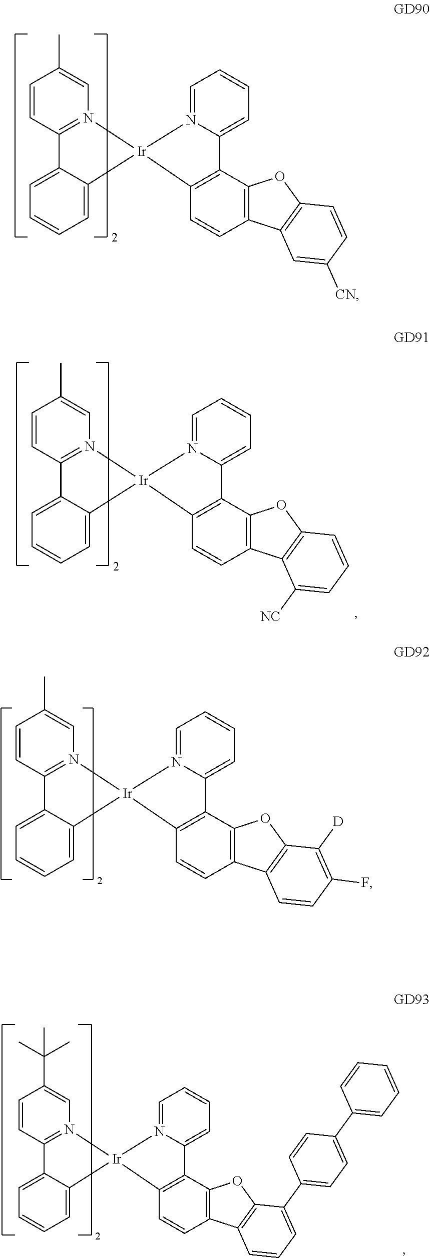 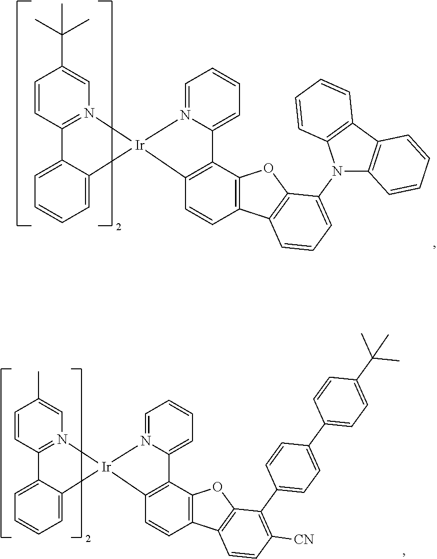 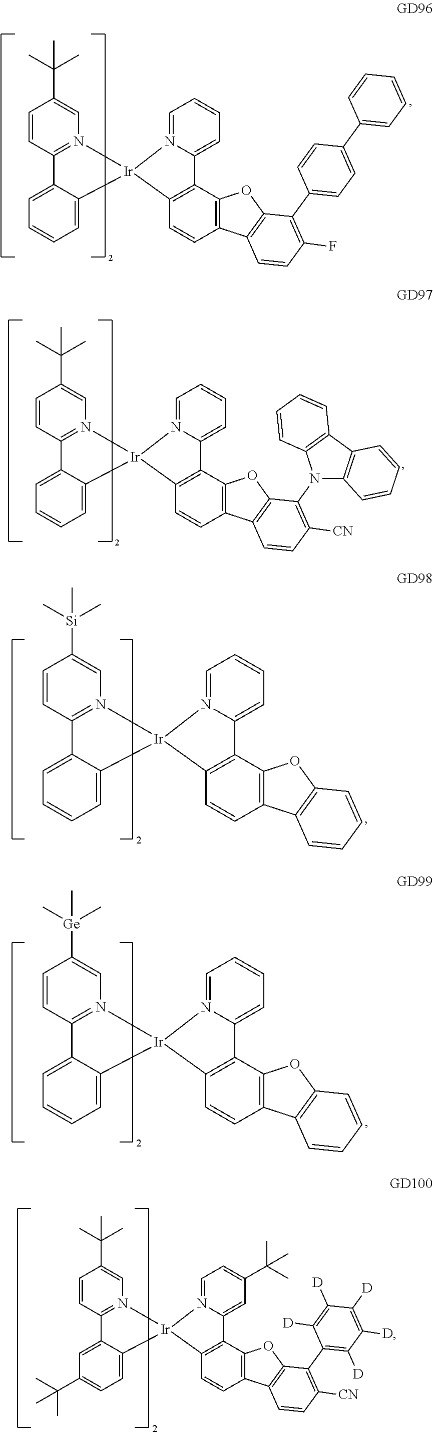 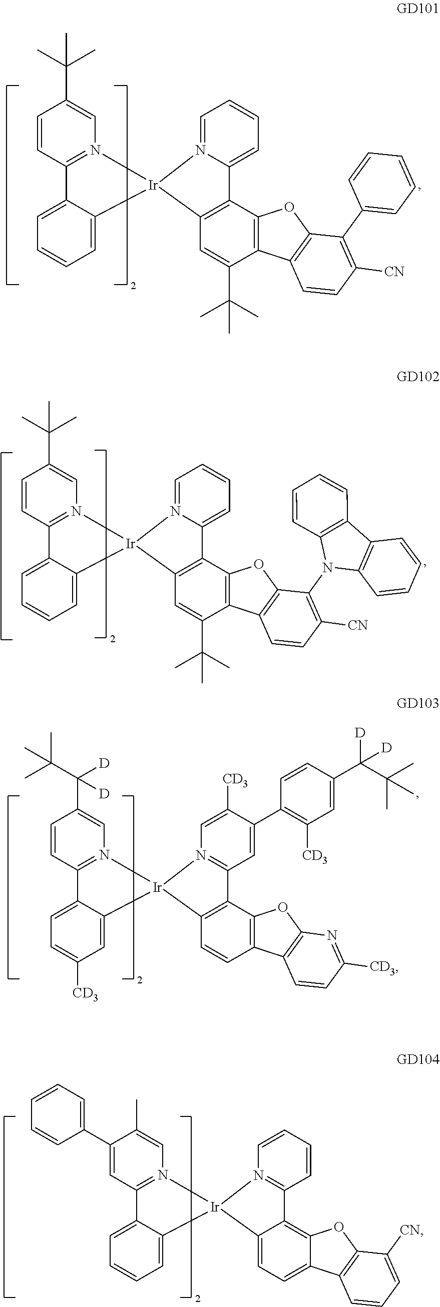 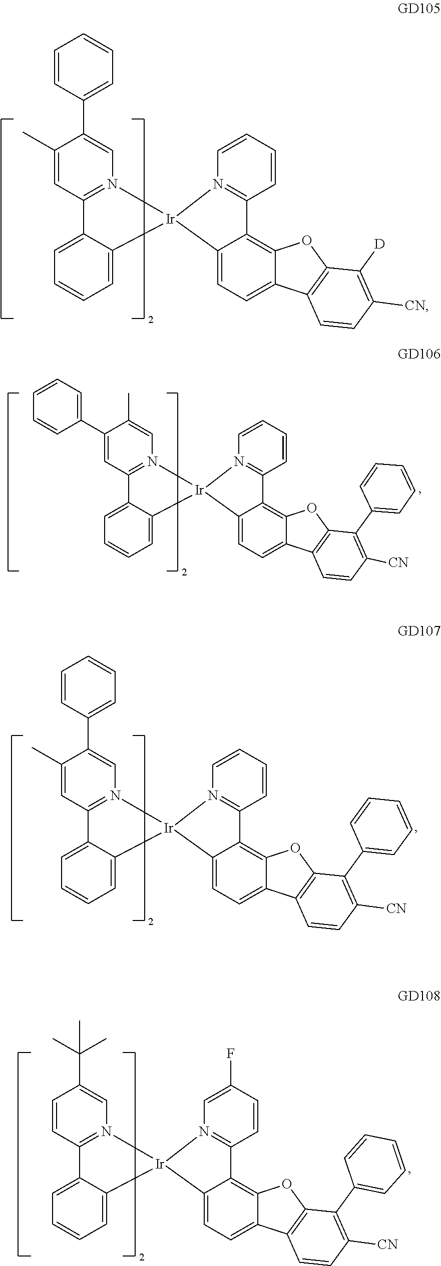 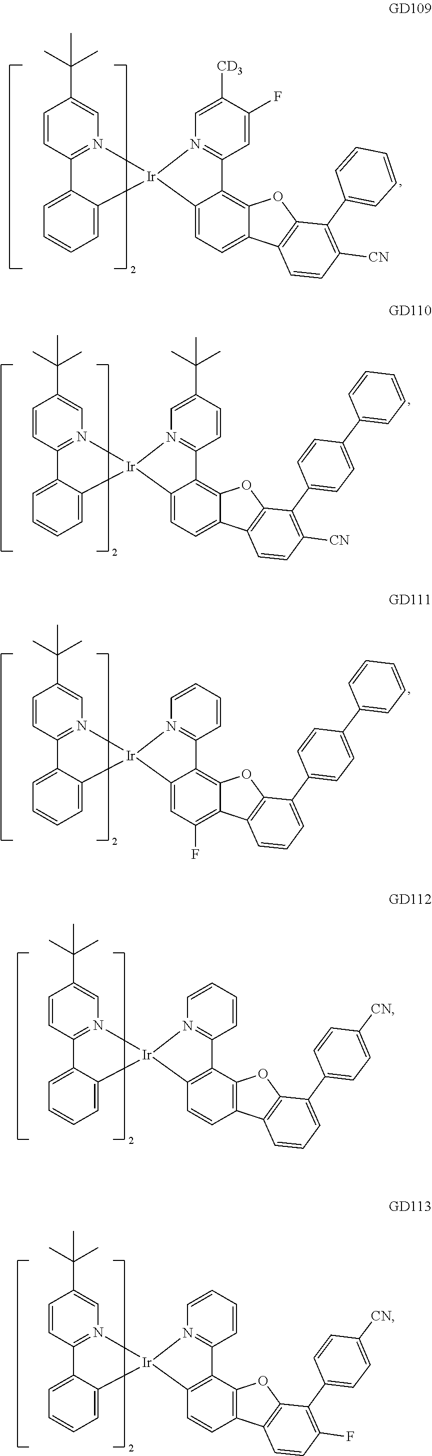 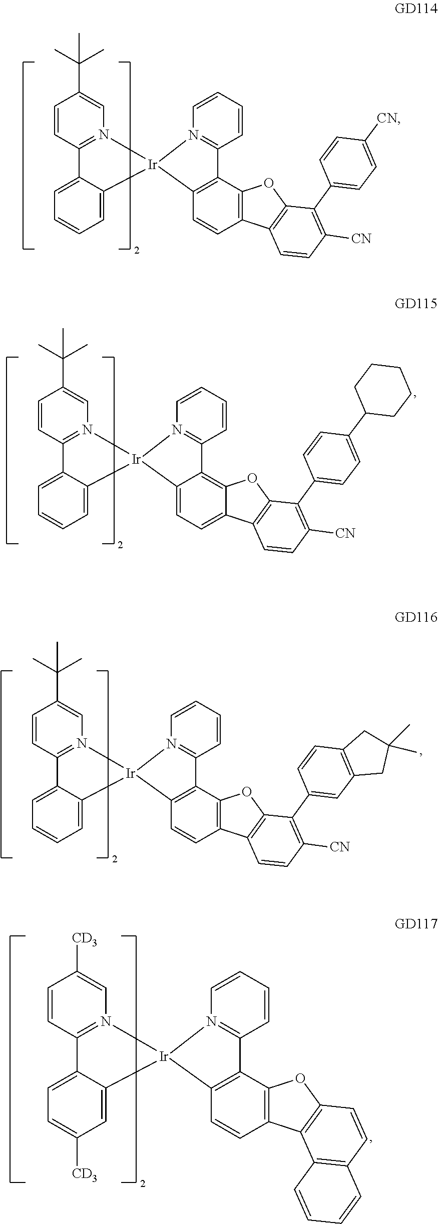 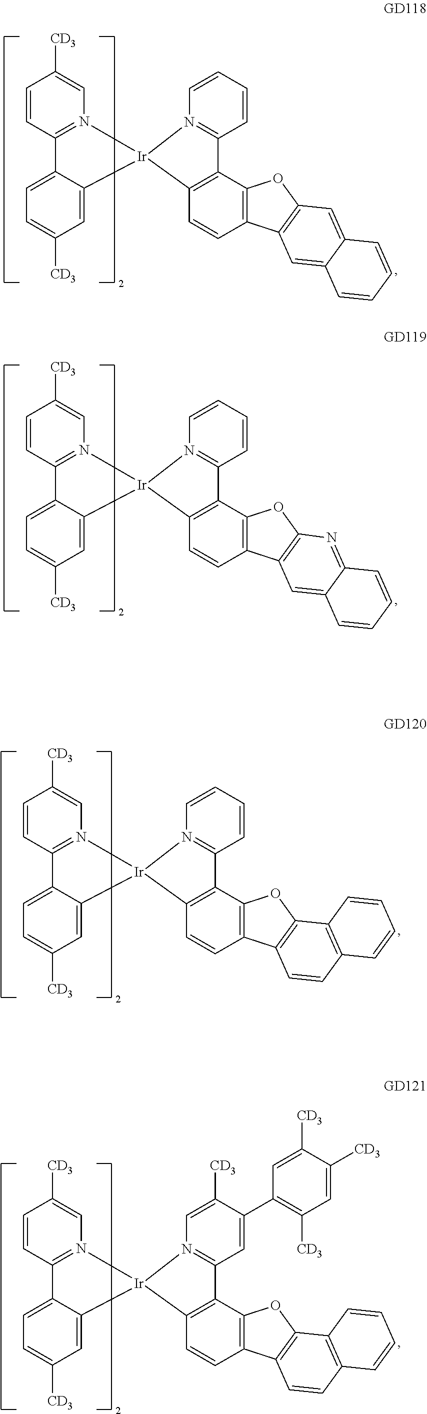 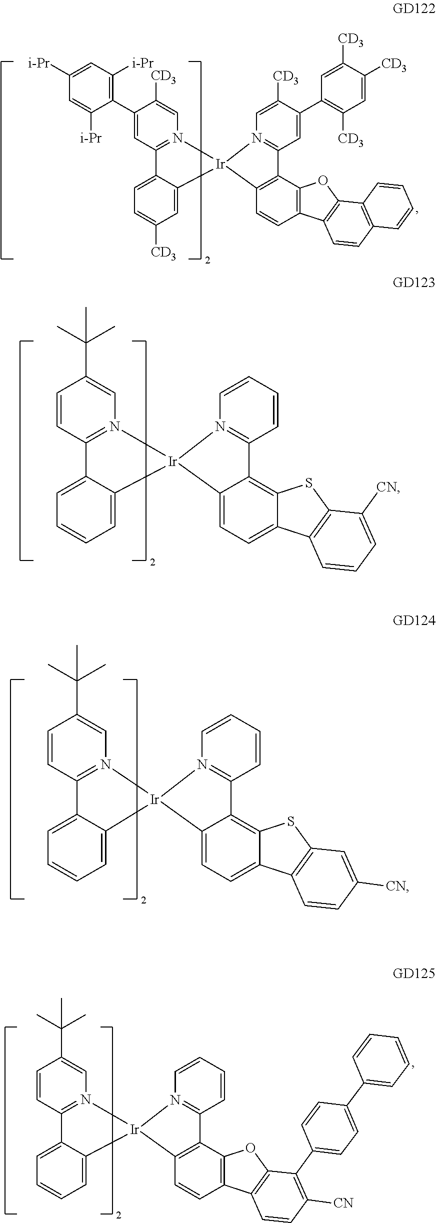 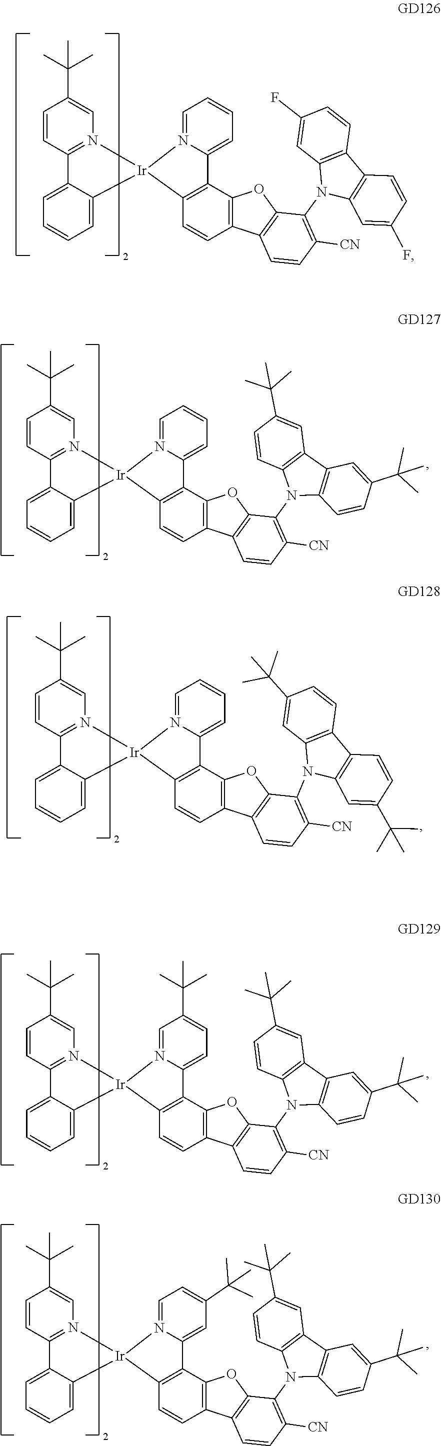 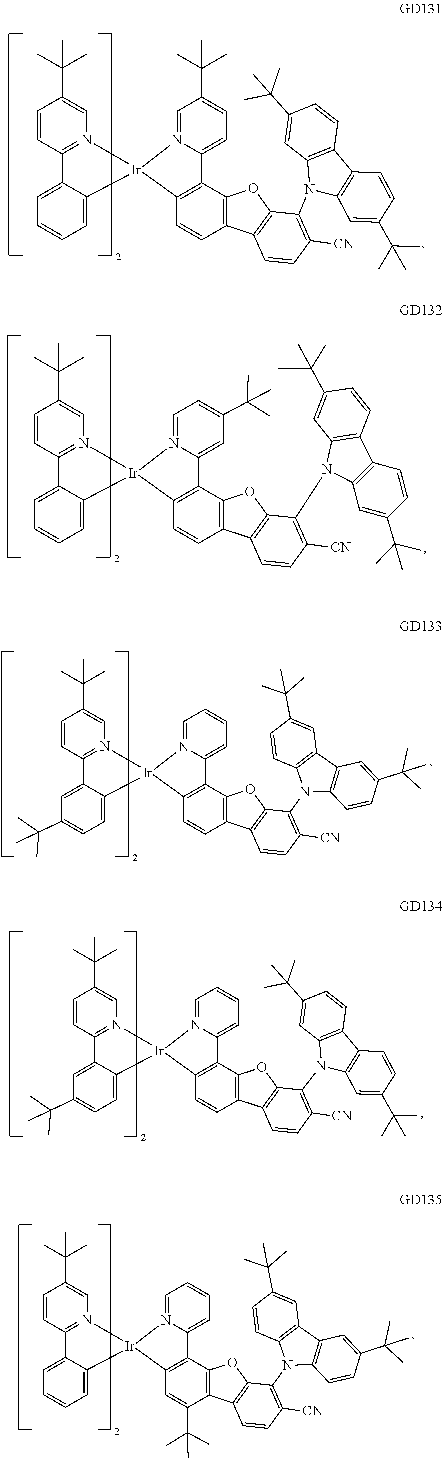 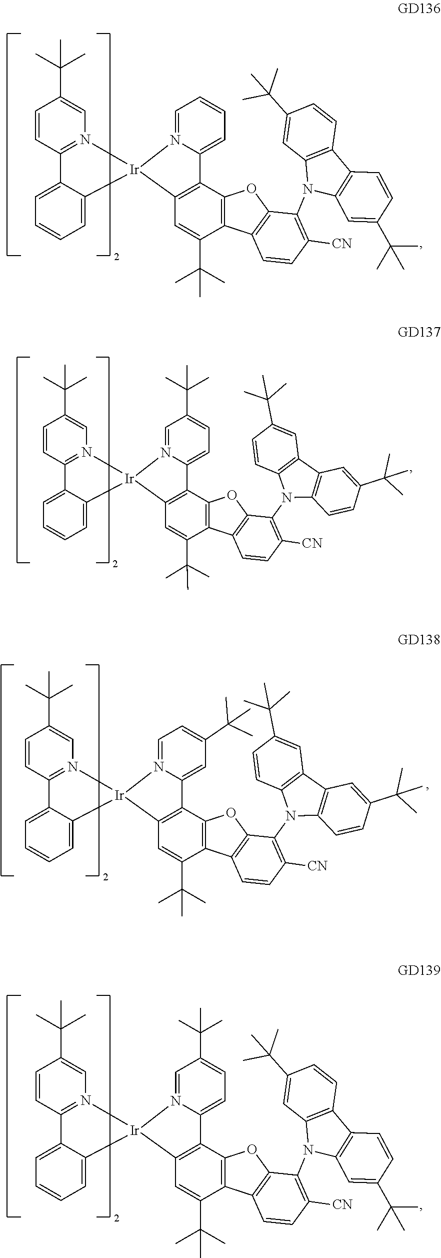 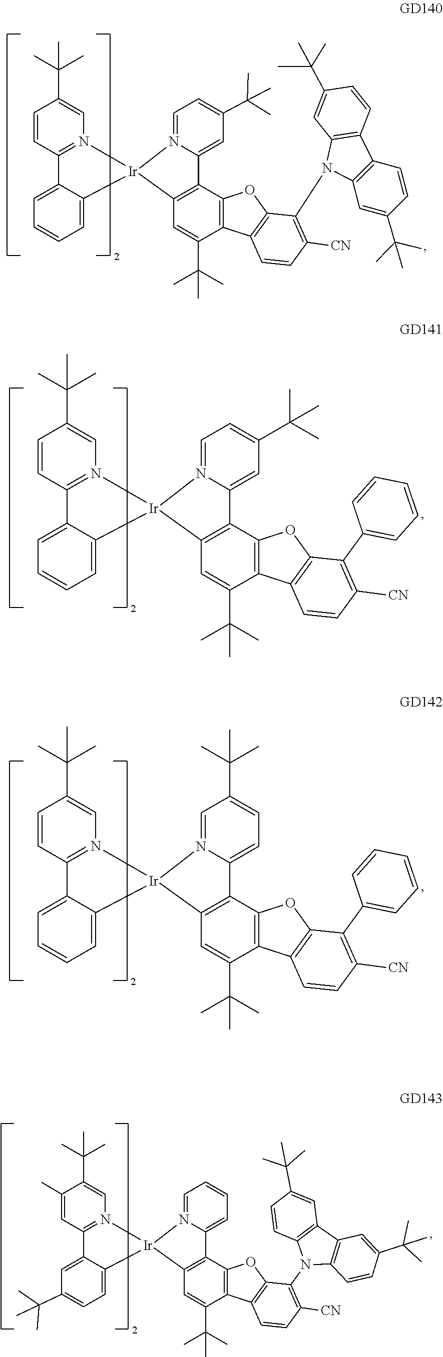 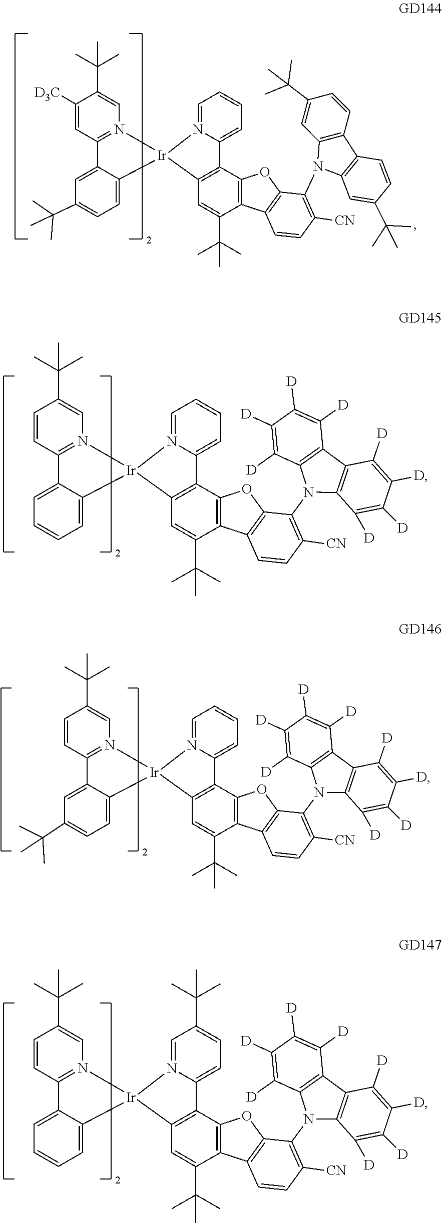 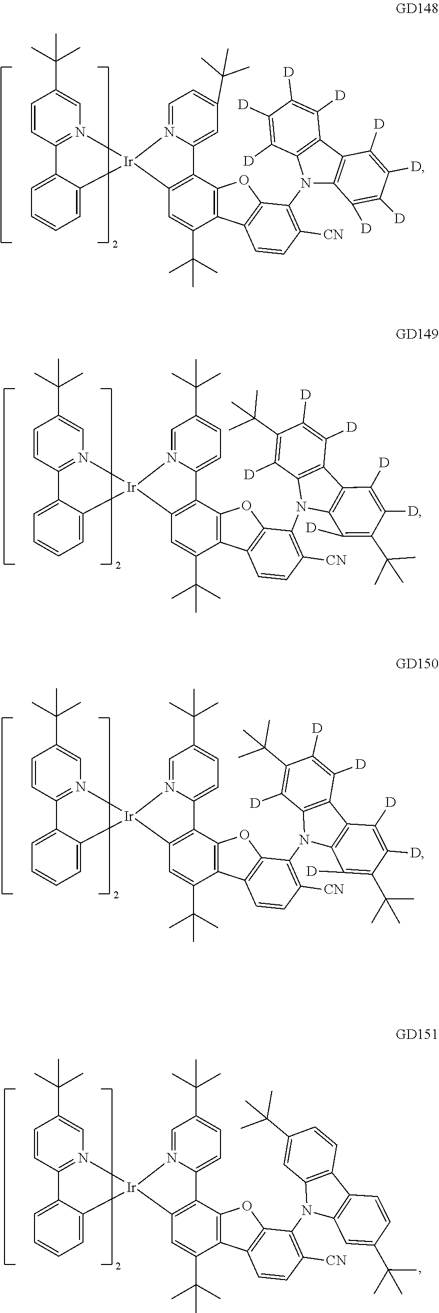 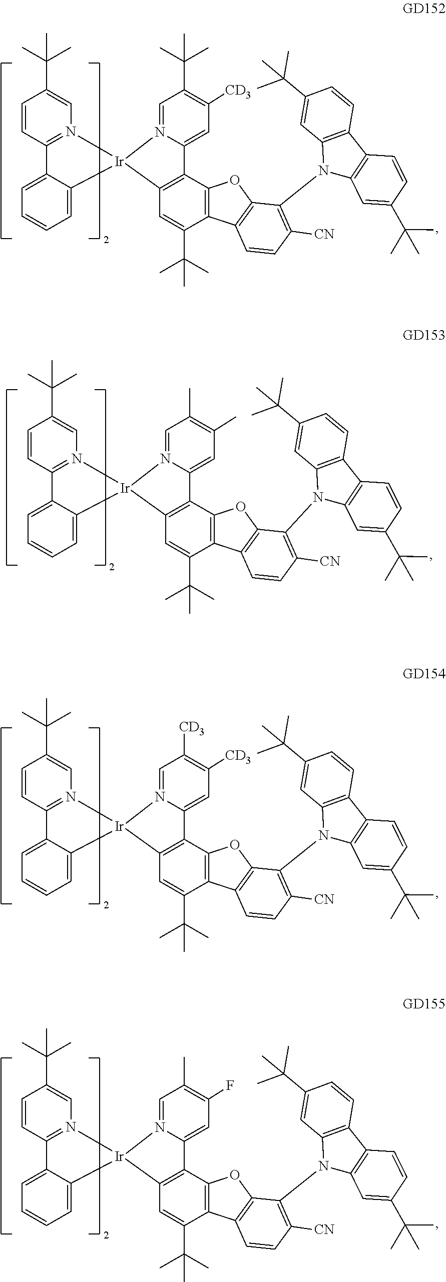 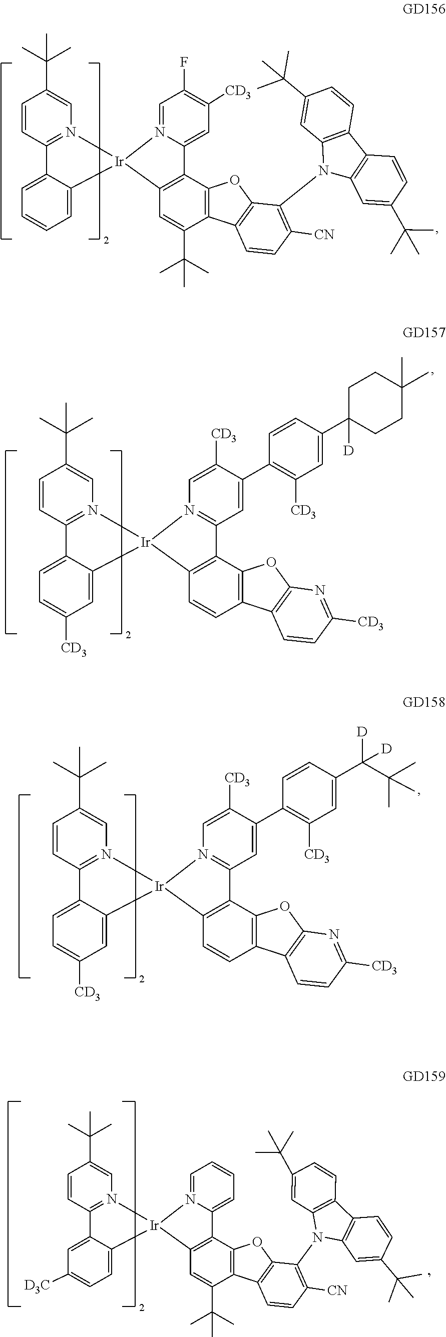 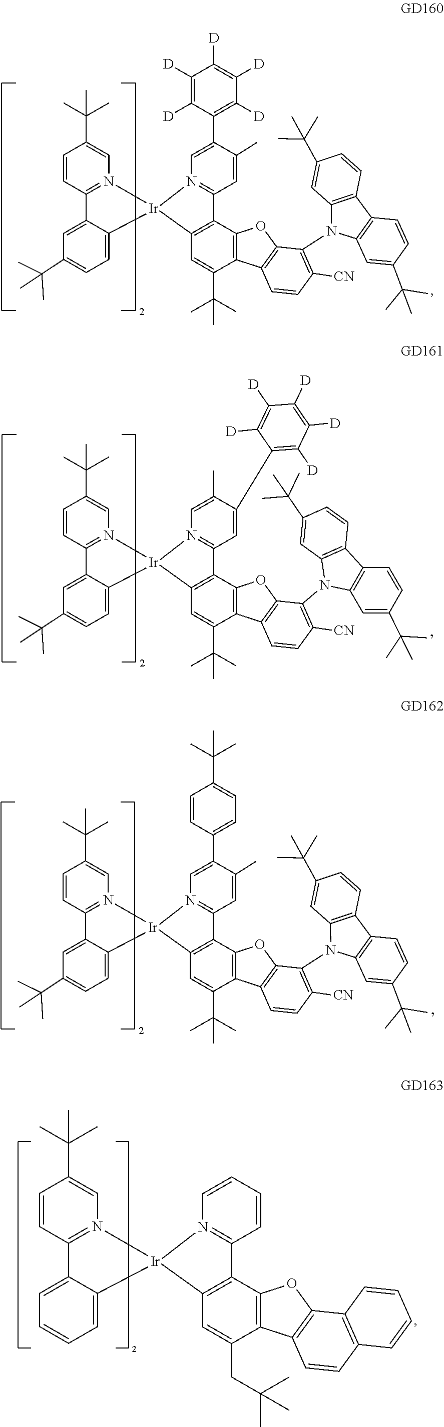 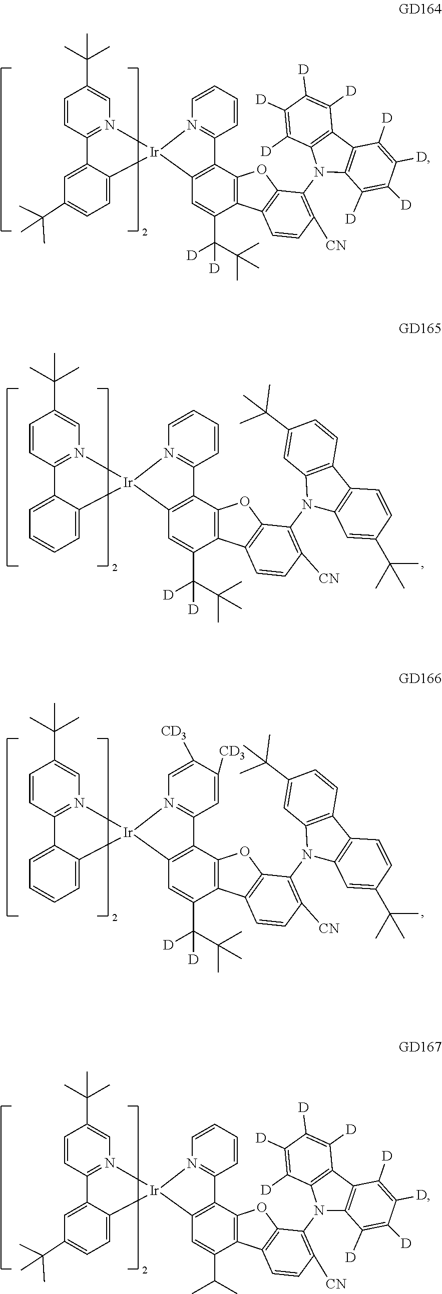 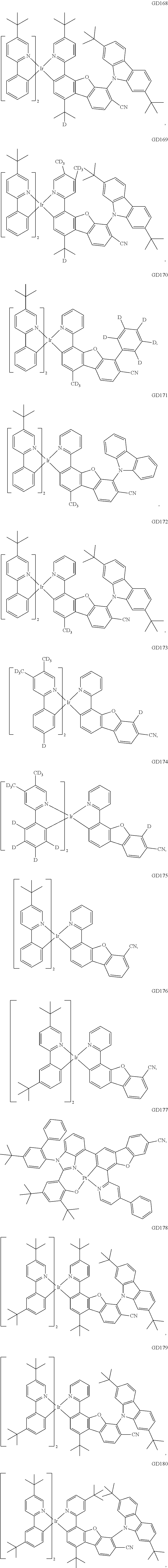 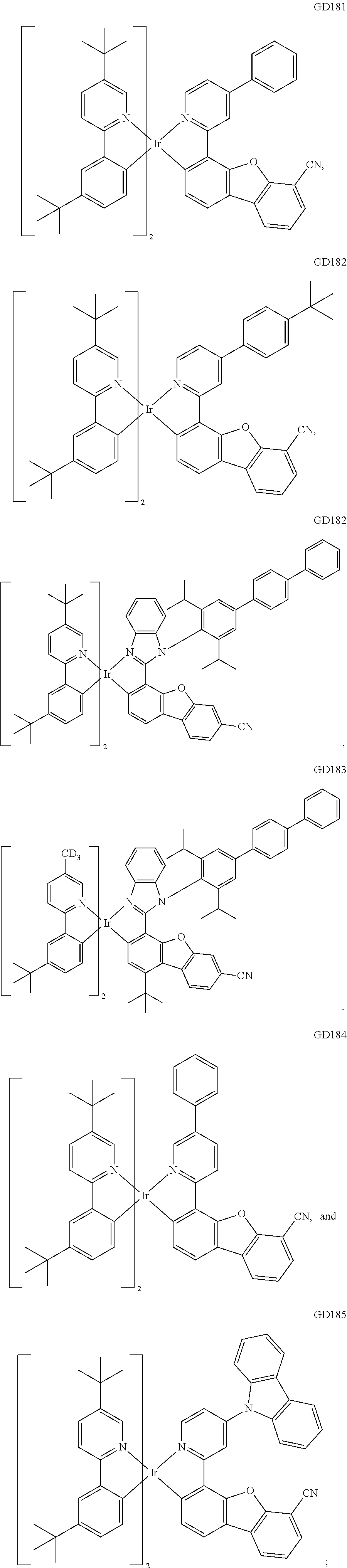
wherein optionally, hydrogens in the structures of the Compound GD1 to Compound GD185 can be partially or fully substituted with deuterium.

17. A compound composition, comprising the compound according to claim 1.
